(19) United States
(12) Patent Application Publication
(10) Pub. No.: US 2023/0209987 A1
(43) Pub. Date: Jun. 29, 2023

(54) ORGANIC LIGHT EMITTING DIODE AND ORGANIC LIGHT EMITTING DISPLAY DEVICE HAVING THE SAME

(71) Applicant: LG DISPLAY CO., LTD., Seoul (KR)

(72) Inventors: TaeRyang HONG, Seoul (KR); Gyuhyeong KIM, Jeonju-si (KR)

(73) Assignee: LG DISPLAY CO., LTD., Seoul (KR)

(21) Appl. No.: 17/976,247

(22) Filed: Oct. 28, 2022

(30) Foreign Application Priority Data
Dec. 29, 2021 (KR) 10-2021-0191273

(51) Int. Cl. H01L 51/00; H01L 51/50; H01L 51/52

(52) U.S. Cl. CPC H01L 51/0085; H01L 51/5004; H01L 51/5024; H01L 51/5072; H01L 51/5296; H01L 2251/5376

(57) ABSTRACT

An organic light emitting diode includes an anode, an emission layer disposed on the anode and including a host, a phosphorescent dopant represented by Chemical Formula 1 and a fluorescent dopant represented by Chemical Formula 2, and a cathode disposed on the emission layer formed by mixing the fluorescent dopant with the phosphorescent dopant bonded to an acceptor at a specific site, thereby energy loss during an emission process can be minimized and energy transfer efficiency can be improved, and an organic light emitting diode with improved luminous efficiency and an organic light emitting display device having the same can be provided.

### CROSS-REFERENCE TO RELATED APPLICATION

This application claims the priority of Korean Patent Application No. 10-2021-0191273 filed on Dec. 29, 2021, which is hereby incorporated by reference in its entirety.

### BACKGROUND

### Field of the Disclosure

The present disclosure relates to an organic light emitting diode and an organic light emitting display device having the same and more particularly, to an organic light emitting diode with excellent luminous efficiency and an organic light emitting display device having the same.

### Description of the Background

An organic light emitting display device (OLED) uses an organic light emitting diode that emits light by itself. Thus, the OLED has a simple structure and can be easily fabricated. Also, the OLED has an advantage in terms of power consumption due to a low voltage driving. Further, the OLED is excellent in color implementation, luminance, viewing angle, response speed and contrast ratio and thus is being studied as a next generation display.

When a voltage is applied to the organic light emitting diode, holes injected from an anode and electrons injected from a cathode recombine in an emission layer to form excitons. The organic light emitting diode emits light via an organic light emission phenomenon when the excitons transit from an unstable excited state to a stable ground state.

In recent years, displays using organic light emitting diodes have been scaled up and thinned. In line with this trend, the displays have been required to be driven with low power while having lifespan and luminous efficiency equal to or greater than those of conventional displays.

In conventional organic light emitting display devices, an emission layer is formed by adding a fluorescent dopant to a host material. When holes and electrons recombine to form excitons, singlet excitons in a paired spin state and triplet excitons in an unpaired spin state are generated in a ratio of 1:3 depending on spin configurations. In the case of a general fluorescent material, only singlet excitons participate in light emission and the remaining 75%, triplet excitons, do not participate in light emission. Thus, the luminous efficiency of the fluorescent material is low.

Accordingly, the use of a phosphorescent material as a dopant has been proposed to improve the luminous efficiency. A phosphorescent material most commonly used as an emission dopant is a heavy metal complex compound. Such a phosphorescent material can convert singlet excitons into triplet excitons through intersystem crossing (ISC), and energy in a triplet state can be transferred to a ground state due to strong spin-orbit coupling by the heavy metal. That is, the triplet excitons as well as the singlet excitons of the phosphorescent material participate in light emission, and, thus, the phosphorescent material has higher luminous efficiency than a fluorescent dopant.

However, the phosphorescent material has a shorter lifespan than the fluorescent material. Particularly, a blue phosphorescent material has low color purity and thus has limitations to be applied alone to a display device. Accordingly, there has been proposed an organic light emitting diode including an emission layer formed by mixing a fluorescent material and a phosphorescent material to secure color purity and luminous efficiency.

### SUMMARY

Accordingly, the present disclosure is to provide an organic light emitting diode and an organic light emitting display device having the same. The organic light emitting diode is improved in luminous efficiency by improving the energy transfer efficiency between a fluorescent dopant and a phosphorescent dopant when an emission layer is formed by mixing the fluorescent dopant and the phosphorescent dopant.

The present disclosure is not limited to the above-mentioned and other features, which are not mentioned above, can be clearly understood by those skilled in the art from the following descriptions.

In an aspect of the present disclosure, an organic light emitting diode includes an anode. Also, the organic light emitting diode includes an emission layer disposed on the anode and including a host, a phosphorescent dopant represented by the following Chemical Formula 1 and a fluorescent dopant represented by the following Chemical Formula 2. Further, the organic light emitting diode includes a cathode disposed on the emission layer.

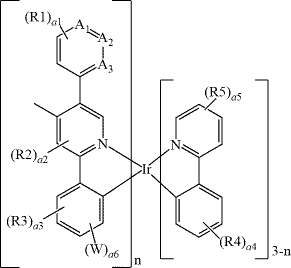

In Chemical Formula 1, each of A1 to A3 is independently nitrogen or carbon, at least one of A1 to A3 is nitrogen, and each of a1 and a3 to a5 is independently an integer of 0 to 4. In Chemical Formula 1, a2 is an integer of 0 to 2, a6 is an integer of 1 to 4, and the sum of a3 and a6 is 4 or less. In Chemical Formula 1, each of R1 to R5 is independently selected from hydrogen, deuterium, tritium, an alkyl group having 1 to 20 carbon atoms, an aryl group having 6 to 30 carbon atoms and a heteroaryl group having 3 to 40 carbon atoms. Each substituent may form a fused ring with a neighboring substituent. In Chemical Formula 1, W is selected from a cyano group, a nitro group, a halogen group, a substituted alkyl group having 1 to 20 carbon atoms, a substituted aryl group having 6 to 30 carbon atoms and a substituted heteroaryl group having 3 to 40 carbon atoms. In this case, each of the substituted alkyl group, the substituted aryl group and the substituted heteroaryl group includes at least one substituent selected from a cyano group, a nitro group and a halogen group. In Chemical Formula 1, n is an integer of 0 to 3.

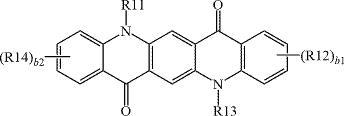

In Chemical Formula 2, each of b1 and b2 is independently an integer of 0 to 4 and each of R11 to R14 is selected from hydrogen, deuterium, tritium, an alkyl group having 1 to 20 carbon atoms, an aryl group having 6 to 30 carbon atoms and a heteroaryl group having 3 to 40 carbon atoms. Each substituent may form a fused ring with a neighboring substituent.

According to another aspect of the present disclosure, an organic light emitting display device includes a substrate, a thin film transistor on the substrate and the above-described organic light emitting diode disposed on the thin film transistor.

Other detailed matters of the exemplary aspects are included in the detailed description and the drawings.

According to the present disclosure, a fluorescent dopant is mixed with a phosphorescent dopant including a substituent serving as an acceptor at a specific site to be used for an emission layer. Since the acceptor is introduced at a specific site, an emission peak wavelength of the phosphorescent dopant is shifted to a short wavelength range. Also, an emission peak of the phosphorescent dopant overlaps with an absorption peak of the fluorescent dopant. Accordingly, energy loss during an emission process can be minimized and the energy transfer efficiency between luminous materials can be improved. Further, it is possible to provide an organic light emitting diode which can be driven at a low voltage and is highly improved in luminous efficiency, and an organic light emitting display device having the same.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic cross-sectional view of an organic light emitting diode according to an exemplary aspect of the present disclosure;

FIG. 2 is a graph showing an absorption spectrum of a fluorescent dopant represented by Chemical Formula 2 and an emission spectrum of a phosphorescent dopant without a substituent W;

FIG. 3 is a graph showing the absorption spectrum of the fluorescent dopant represented by Chemical Formula 2 and an emission spectrum of a phosphorescent dopant represented by Chemical Formula 1; and

FIG. 4 is a schematic cross-sectional view of an organic light emitting display device according to an exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure can be partially or entirely adhered to or combined with each other and can be interlocked and operated in technically various ways, and the aspects can be carried out independently of or in association with each other.

As used herein, the term “substitution” refers to replacement of a hydrogen atom or hydrogen atom group of an original compound with a substituent.

A hydrogen atom of a compound described in this specification may be substituted with deuterium or tritium.

As used herein, the term “hetero” means that at least one of carbon atoms constituting a cyclic saturated or unsaturated hydrocarbon is substituted with a heteroatom such as N, O, S and Se.

As used herein, the term “alkyl” refers to a monovalent organic group derived from linear or branched saturated hydrocarbons. For example, the alkyl may include methyl, ethyl, propyl, n-butyl, iso-butyl, n-pentyl, hexyl and tert-butyl, but is not limited thereto.

As used herein, the term “aryl” refers to a monovalent organic group derived from aromatic hydrocarbons and may have a form in which two or more rings are simply connected to each other in a pendant form or are fused with each other. For example, the aryl may include a phenyl group, a naphthyl group and a phenanthryl group, but is not limited thereto.

As used herein, the term “heteroaryl” refers to a monovalent organic group derived from aromatic hydrocarbons of which at least one carbon in a ring is substituted with a heteroatom such as N, O, S or Se. Furthermore, the heteroaryl may have a form in which two or more rings are simply connected to each other in a pendant form or are fused with each other, or are fused with an aryl group. For example, the heteroaryl may include a pyridine group, a pyrazine group, a pyrimidine group, a pyridazine group, a triazine group, a phenoxazine group, an indolizine group, a benzothiazole group, a benzoxazole group, a benzofuran group, purinyl, quinolyl, carbazolyl, N-imidazolyl, 2-pyridinyl and 2-pyrimidinyl, but is not limited thereto.

Hereinafter, an organic light emitting diode and an organic light emitting display device according to exemplary aspects of the present disclosure will be described in detail with reference to accompanying drawings.

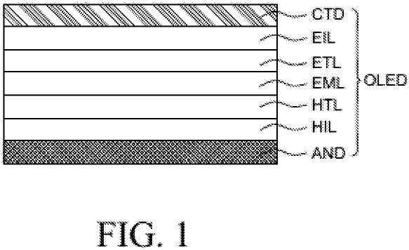

FIG. 1 is a schematic cross-sectional view of an organic light emitting diode according to an exemplary aspect of the present disclosure.

Referring to FIG. 1, an organic light emitting diode OLED according to an exemplary aspect of the present disclosure includes an anode AND, a hole injection layer HIL, a hole transport layer HTL, an emission layer EML, an electron transport layer ETL, an electron injection layer EIL and a cathode CTD. Although the organic light emitting diode having a single stack structure including a single emission unit is illustrated for the convenience of description, the present disclosure is not limited thereto. For example, the organic light emitting diode may be implemented as an organic light emitting diode having a tandem structure including a plurality of emission units.

The anode AND is configured to supply holes to the emission layer EML and is made of a conductive material having a high work function. The anode AND may be a transparent conductive layer made of transparent conductive oxide. For example, the anode AND may be made of one or more transparent conductive oxides selected from indium-tin-oxide (ITO), indium-zinc-oxide (IZO), indium-tin-zinc oxide (ITZO), tin oxide (SnO₂), zinc oxide (ZnO), indium-copper-oxide (ICO) and Al-doped ZnO (AZO), but is not limited thereto.

If the organic light emitting diode OLED is driven in a top emission type, a reflective layer may be disposed under the anode AND in order for light emitted from the emission layer EML to be output in an upward direction. The reflective layer may be made of a metallic material having high reflectivity. For example, the reflective layer may be made of an aluminum-palladium-copper alloy.

The hole injection layer HIL for injecting holes supplied from the anode AND to the emission layer EML is disposed on the anode AND. The hole injection layer HIL is made of a material for improving the interface characteristics between the anode AND and the hole transport layer HTL and enabling holes to be smoothly injected to the emission layer EML.

For example, the hole injection layer HIL may be made of one or more compounds selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenylamino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-Diphenyl-N,N′-bis(1naphthyl)-1,1′-biphenyl-4,4″-diamine (NPB or NPD), 1,4,5,8,9,11-hexaazatriphenylenehexacarbonitrile, dipyrazino[2,3-f:2′3′-h]quinoxaline-2,3,6,7,10,11-hexacarbonitrile (HAT-CN), 1,3,5-tris[4-(diphenylamino)phenyl]benzene (TDAPB), poly(3,4-ethylenedioxythiphene):polystyrene sulfonate (PEDOT:PSS), N-(biphenyl-4-yl)-9,9-dimethyl-N-(4-(9-phenyl-9H-carbazol-3-yl)phenyl)-9H-fluoren-2-amine, etc., but is not limited thereto.

The hole transport layer HTL for smoothly transferring holes from the hole injection layer HIL to the emission layer EML may be disposed on the hole injection layer HIL.

For example, the hole transport layer HTL may be made of one or more compounds selected from the group consisting of N,N′-diphenyl-N,N′-bis(3-methylphenyl)-1,1′-biphenyl-4,4′-diamine (TPD), NPD (or NPB), MTDATA, 4,4′-bis(N-carbazolyl)-1,1′-biphenyl (CBP), poly [N,N′-bis(4-butylpnehyl)-N,N′-bi s(phenyl)-benzidine] (Poly-TPD), poly[(9,9-dioctylfluorenyl-2,7-diyl)-co-(4,4′-(N-(4-sec-butylphenyl)diphenylamine))] (TFB), di-[4-(N,N-dip-tolyl-amino)-phenyl]cyclohexane (TAPC), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, etc.

The hole injection layer HIL or the hole transport layer HTL may be omitted as necessary. The hole injection layer HIL and the hole transport layer HTL may also be formed as one layer.

For example, each of the hole injection layer HIL and the hole transport layer HTL may be formed to a thickness of 5 nm to 200 nm.

The emission layer EML is disposed on the hole transport layer HTL. The emission layer EML emits light by recombination of electrons and holes. The emission layer EML includes a host, a phosphorescent dopant and a fluorescent dopant. The host enables holes supplied from the anode AND and electrons supplied from the cathode CTD to be trapped in the emission layer EML without loss. The phosphorescent dopant and the fluorescent dopant are materials that actually emit light.

For example, the host may be selected from carbazole-based compounds, dibenzofuran-based compounds, dibenzothiophene-based compounds, a carbazole group, a dibenzofuran group and/or a dibenzothiophene group. Specifically, for example, the host may include at least one selected from the following Compound 3-1 to Compound 3-24, but is not limited thereto.

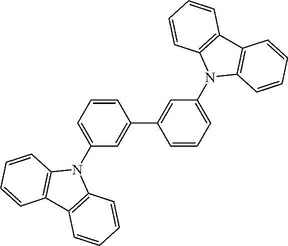 [SMILES: c1cc(-c2cccc(-n3c4ccccc4c4ccccc43)c2)cc(-n2c3ccccc3c3ccccc32)c1]

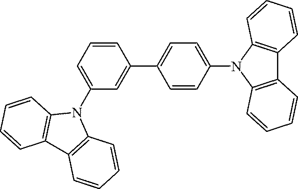 [SMILES: c1cc(-c2ccc(-n3c4ccccc4c4ccccc43)cc2)cc(-n2c3ccccc3c3ccccc32)c1]

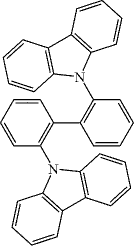 [SMILES: c1ccc(-n2c3ccccc3c3ccccc32)c(-c2ccccc2-n2c3ccccc3c3ccccc32)c1]

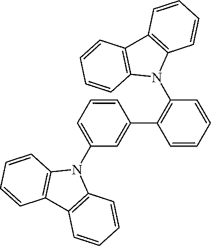 [SMILES: c1cc(-c2ccccc2-n2c3ccccc3c3ccccc32)cc(-n2c3ccccc3c3ccccc32)c1]

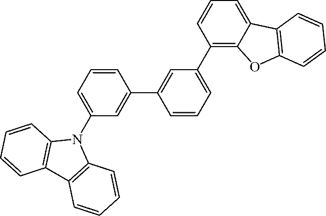 [SMILES: c1cc(-c2cccc(-n3c4ccccc4c4ccccc43)c2)cc(-c2cccc3c2oc2ccccc23)c1]

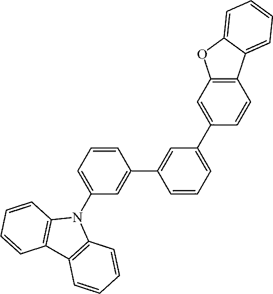 [SMILES: c1cc(-c2cccc(-n3c4ccccc4c4ccccc43)c2)cc(-c2ccc3c(c2)oc2ccccc23)c1]

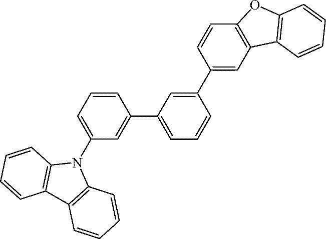 [SMILES: c1cc(-c2cccc(-n3c4ccccc4c4ccccc43)c2)cc(-c2ccc3oc4ccccc4c3c2)c1]

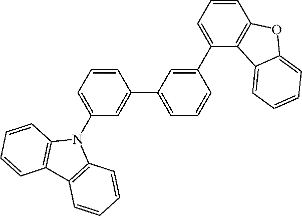 [SMILES: c1cc(-c2cccc(-n3c4ccccc4c4ccccc43)c2)cc(-c2cccc3oc4ccccc4c23)c1]

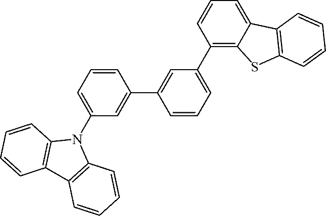 [SMILES: c1cc(-c2cccc(-n3c4ccccc4c4ccccc43)c2)cc(-c2cccc3c2sc2ccccc23)c1]

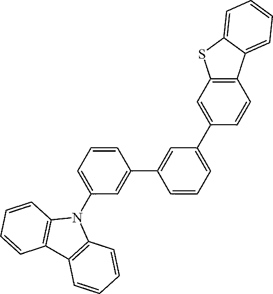 [SMILES: c1cc(-c2cccc(-n3c4ccccc4c4ccccc43)c2)cc(-c2ccc3c(c2)sc2ccccc23)c1]

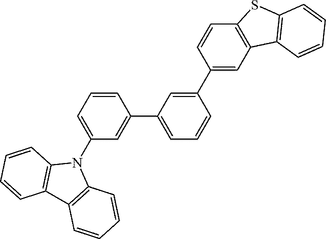 [SMILES: c1cc(-c2cccc(-n3c4ccccc4c4ccccc43)c2)cc(-c2ccc3sc4ccccc4c3c2)c1]

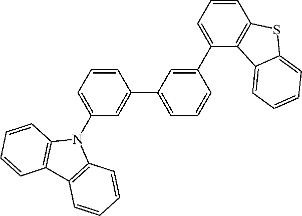 [SMILES: c1cc(-c2cccc(-n3c4ccccc4c4ccccc43)c2)cc(-c2cccc3sc4ccccc4c23)c1]

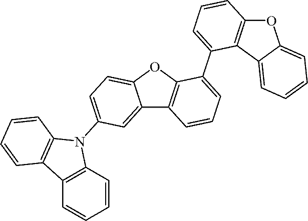 [SMILES: c1ccc2c(c1)oc1cccc(-c3cccc4c3oc3ccc(-n5c6ccccc6c6ccccc65)cc34)c12]

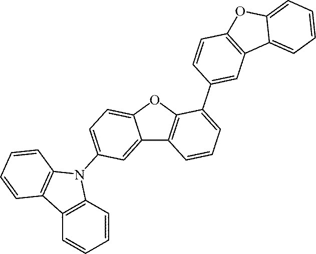 [SMILES: c1ccc2c(c1)oc1ccc(-c3cccc4c3oc3ccc(-n5c6ccccc6c6ccccc65)cc34)cc12]

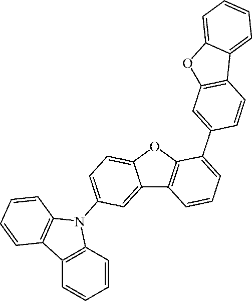 [SMILES: c1ccc2c(c1)oc1cc(-c3cccc4c3oc3ccc(-n5c6ccccc6c6ccccc65)cc34)ccc12]

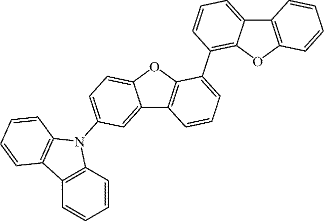 [SMILES: c1ccc2c(c1)oc1c(-c3cccc4c3oc3ccc(-n5c6ccccc6c6ccccc65)cc34)cccc12]

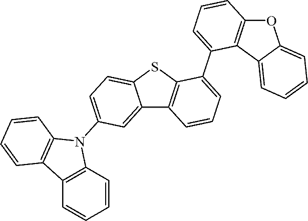 [SMILES: c1ccc2c(c1)oc1cccc(-c3cccc4c3sc3ccc(-n5c6ccccc6c6ccccc65)cc34)c12]

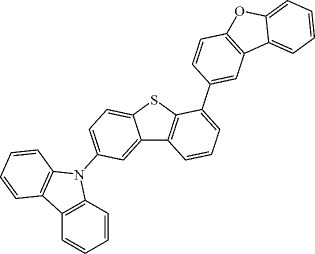 [SMILES: c1ccc2c(c1)oc1ccc(-c3cccc4c3sc3ccc(-n5c6ccccc6c6ccccc65)cc34)cc12]

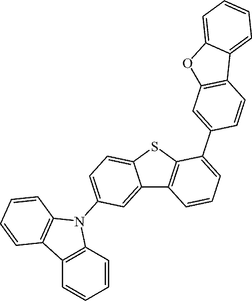 [SMILES: c1ccc2c(c1)oc1cc(-c3cccc4c3sc3ccc(-n5c6ccccc6c6ccccc65)cc34)ccc12]

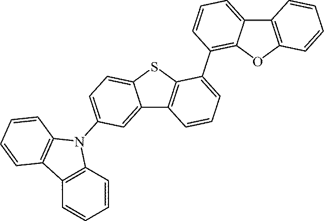 [SMILES: c1ccc2c(c1)oc1c(-c3cccc4c3sc3ccc(-n5c6ccccc6c6ccccc65)cc34)cccc12]

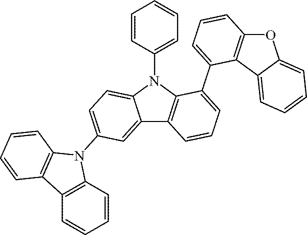 [SMILES: c1ccc(-n2c3ccc(-n4c5ccccc5c5ccccc54)cc3c3cccc(-c4cccc5oc6ccccc6c45)c32)cc1]

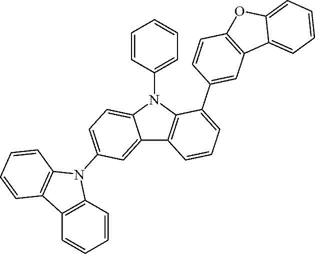 [SMILES: c1ccc(-n2c3ccc(-n4c5ccccc5c5ccccc54)cc3c3cccc(-c4ccc5oc6ccccc6c5c4)c32)cc1]

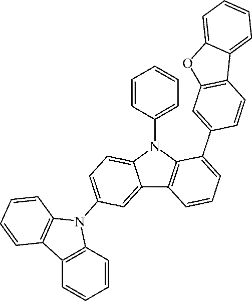 [SMILES: c1ccc(-n2c3ccc(-n4c5ccccc5c5ccccc54)cc3c3cccc(-c4ccc5c(c4)oc4ccccc45)c32)cc1]

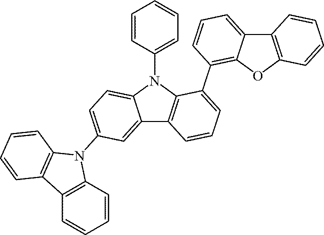 [SMILES: c1ccc(-n2c3ccc(-n4c5ccccc5c5ccccc54)cc3c3cccc(-c4cccc5c4oc4ccccc45)c32)cc1]

Although the emission layer having a monolayer structure is illustrated for the convenience of description, it may be formed to have a multilayer structure as necessary. In this case, at least one of a plurality of emission layers is formed including a host, a phosphorescent dopant represented by Chemical Formula 1 and a fluorescent dopant represented by Chemical Formula 2.

The phosphorescent dopant and the fluorescent dopant will be described in detail later.

An electron blocking layer may be disposed between the hole transport layer HTL and the emission layer EML. The electron blocking layer improves the efficiency of forming excitons in the emission layer EML by controlling a transfer of electrons injected to the emission layer EML to the hole transport layer HTL. For example, the electron blocking layer may be made of a compound selected from TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPC, N,N′-bis[4-[bis(3-methylphenyl)amino]phenyl]-N,N′-diphenyl-[1,1′-biphenyl]-4,4′-diamine (DNTPD), TDAPB, 2,8-bis(9-phenyl-9H-carbazol-3-yl)dibenzo[b,d]thiophene, etc., but is not limited thereto.

The electron transport layer ETL is disposed on the emission layer EML. The electron transport layer ETL accelerates the transport of electrons to the emission layer EML. The electron transport layer ETL enables electrons supplied from the cathode CTD to be readily transferred to the emission layer EML.

For example, the electron transport layer ETL may be selected from Alq₃ [tris-(8-hydroxyquinolinato)aluminum], TPBI [2,2′,2″-(1,3,5-benzinetriyl)-tris(1-phenyl-1-H-benzimidazole)], Bphen [4,7-diphenyl-1,10-phenanthroline], TAZ [3-(4-biphenylyl)-4-phenyl-5-tertbutylphenyl-1,2,4-triazole], BCP [2,9-di-methyl-4,7-diphenyl1,10-phenanthroline], PBD [2-(4-biphenylyl)-5-(4-tert-butylphenyl)-1,3,4-oxadiazole], Liq (8-hydroxyquinolinolato-lithium), BAlq (bis(2-methyl-8-quinolinolate)-4-(phenylphenolato)aluminum), TpPyPB, TmPPPyTz, PFNBr, TPQ, etc., but is not limited thereto.

A hole blocking layer may be disposed between the emission layer EML and the electron transport layer ETL. The hole blocking layer blocks the leakage of holes, which are injected from the hole transport layer HTL to the emission layer EML, to the electron transport layer ETL without forming excitons. Therefore, electrons are trapped in the emission layer EML, and, thus, the performance of the organic light emitting diode OLED may be improved.

For example, the hole blocking layer may be made of a material selected from oxadiazole-based, triazole-based, phenanthroline-based, benzoxazole-based, benzothiazole-based, benzimidazole-based and triazine-based compounds. Specifically, for example, the hole blocking layer may be made of a material selected from BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, etc., but is not limited thereto.

The electron injection layer EIL is disposed on the electron transport layer ETL. The electron injection layer EIL enables electrons supplied from the cathode CTD to be readily injected to the electron transport layer ETL. For example, the electron injection layer EIL may include one of BaF₂, LiF, CsF, NaF, BaF₂, Li₂O, BaO, Liq and lithium benzoate, but is not limited thereto. The electron injection layer EIL or the electron transport layer ETL may be omitted as necessary, or may also be formed as one layer.

The cathode CTD is disposed on the electron injection layer EIL. The cathode CTD may be made of a metallic material having a low work function to readily supply electrons to the emission layer EML. For example, the cathode CTD may be made of a metallic material selected from Ca, Ba, Al, Ag and alloys including one or more of them, but is not limited thereto.

Hereinafter, a phosphorescent dopant and a fluorescent dopant included in the emission layer EML of the present disclosure will be described in detail.

First, the phosphorescent dopant is a compound represented by the following Chemical Formula 1.

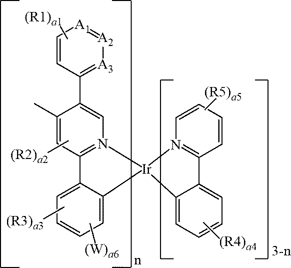

In Chemical Formula 1, each of A1 to A3 is independently nitrogen or carbon, and at least one of A1 to A3 is nitrogen.

In Chemical Formula 1, each of a1 and a3 to a5 is independently an integer of 0 to 4, a2 is an integer of 0 to 2, a6 is an integer of 1 to 4, and the sum of a3 and a6 is 4 or less.

In Chemical Formula 1, each of R1 to R5 is independently selected from hydrogen, deuterium, tritium, an alkyl group having 1 to 20 carbon atoms, an aryl group having 6 to 30 carbon atoms and a heteroaryl group having 3 to 40 carbon atoms. Each substituent may form a fused ring with a neighboring substituent.

In Chemical Formula 1, W is selected from a cyano group, a nitro group, a halogen group, a substituted alkyl group having 1 to 20 carbon atoms, a substituted aryl group having 6 to 30 carbon atoms and a substituted heteroaryl group having 3 to 40 carbon atoms. In this case, each of the substituted alkyl group, the substituted aryl group and the substituted heteroaryl group includes at least one substituent selected from a cyano group, a nitro group and a halogen group.

In Chemical Formula 1, n is an integer of 0 to 3.

The phosphorescent dopant represented by Chemical Formula 1 is introduced with a substituent W including a cyano group, a nitro group or a halogen group at a specific site. These substituents W serve as acceptors and shift an emission peak wavelength of the phosphorescent dopant to a short wavelength range. Accordingly, the difference between the emission peak wavelength of the phosphorescent dopant and an absorption peak wavelength of the fluorescent dopant can be reduced. Thus, the energy transfer efficiency from the phosphorescent dopant to the fluorescent dopant can be improved. Therefore, the luminous efficiency of the organic light emitting diode can be improved.

Specifically, for example, in Chemical Formula 1, one of A1 to A3 may be nitrogen and the others may be carbon. In Chemical Formula 1, each of a1 to a5 may be 0 and a6 may be an integer of 1 to 4. In Chemical Formula 1, W may be selected from a cyano group, a nitro group, a halogen group and an alkyl group substituted with at least one substituent selected from a cyano group, a nitro group and a halogen group and having 1 to 20 carbon atoms. In Chemical Formula 1, n may be 1. In this case, the difference between the emission peak wavelength of the phosphorescent dopant and the absorption peak wavelength of the fluorescent dopant can be further reduced. Therefore, the luminous efficiency can be further improved.

More specifically, for example, the phosphorescent dopant represented by Chemical Formula 1 may be a compound selected from Compound 1-1 to Compound 1-315.

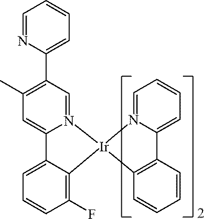

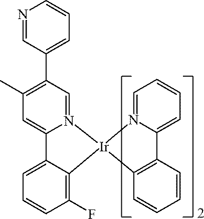

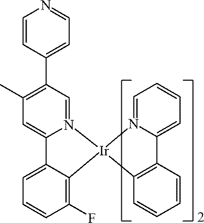

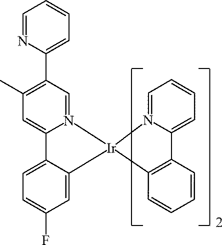

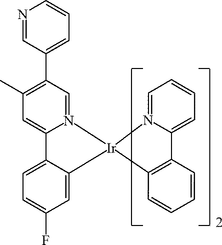

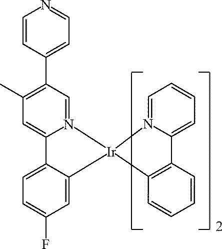

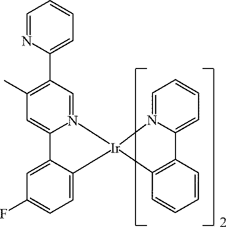

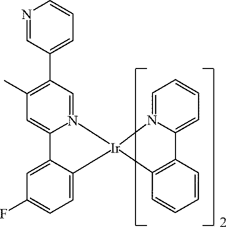

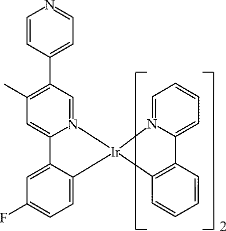

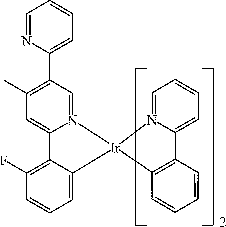

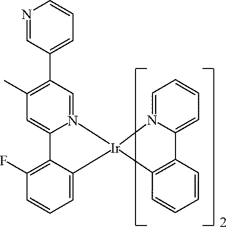

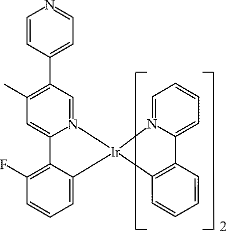

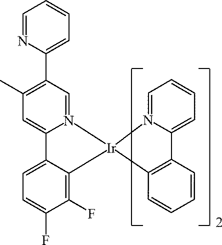

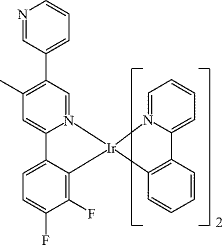

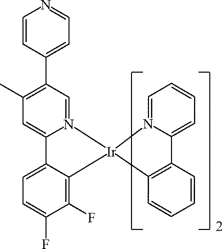

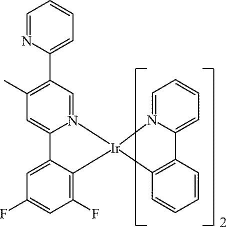

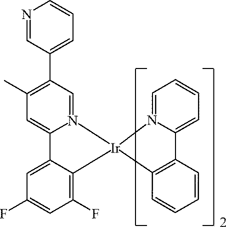

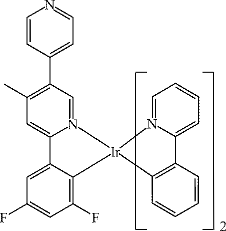

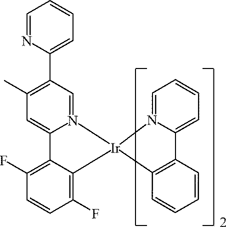

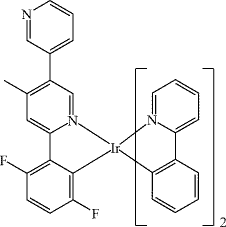

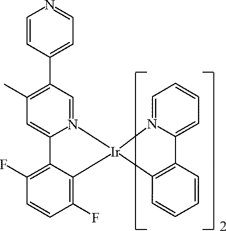

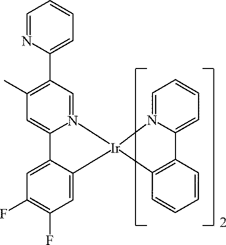

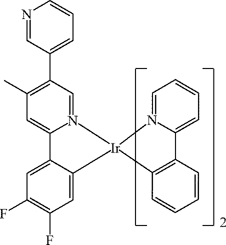

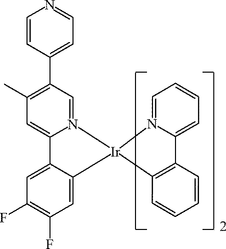

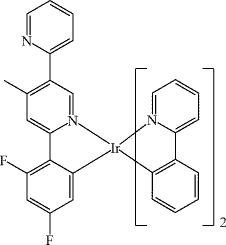

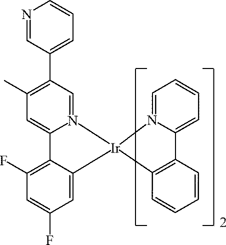

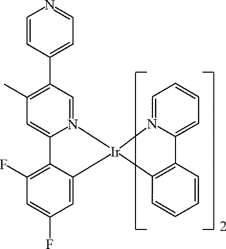

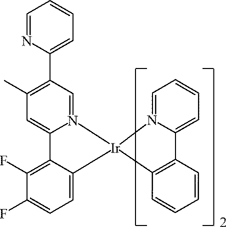

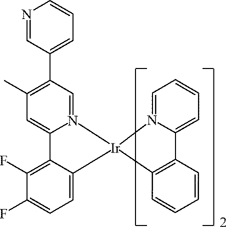

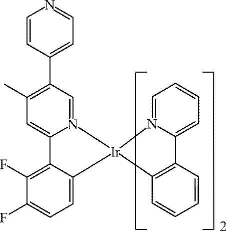

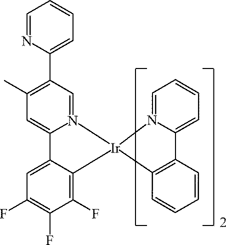

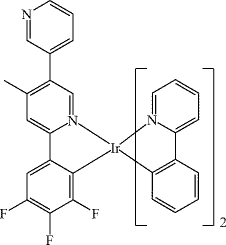

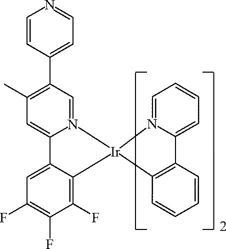

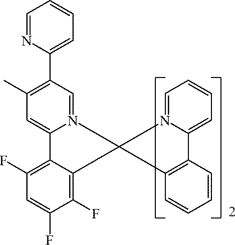

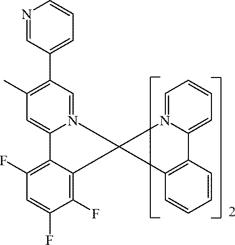

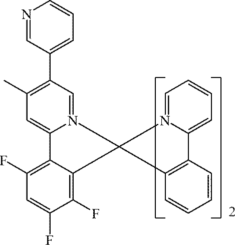

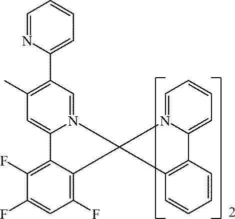

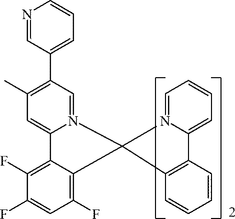

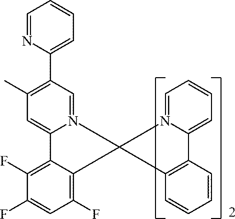

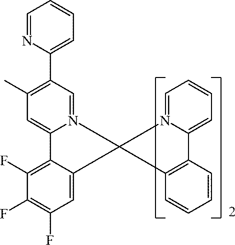

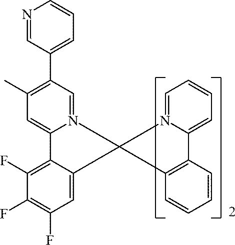

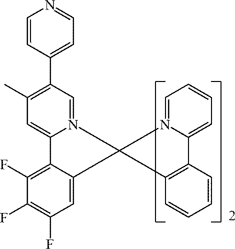

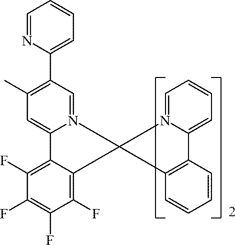

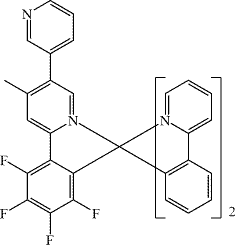

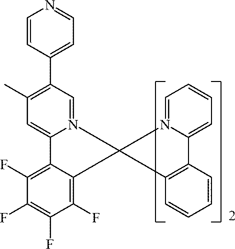

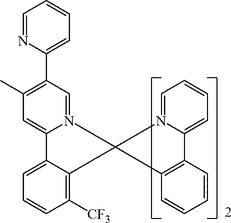

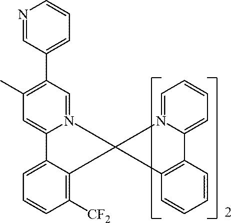

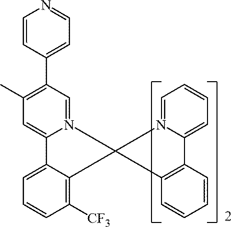

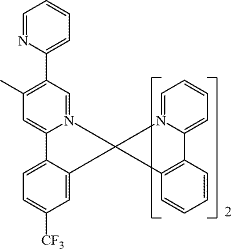

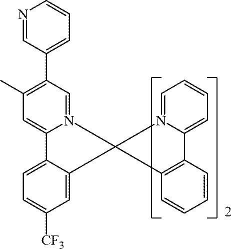

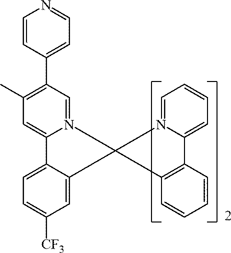

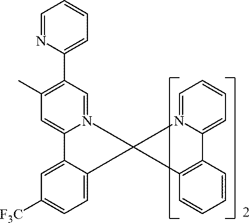

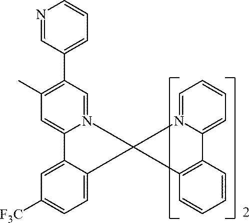

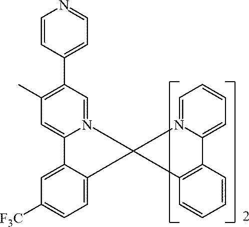

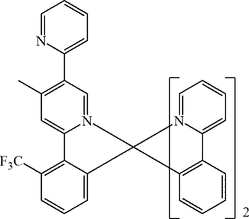

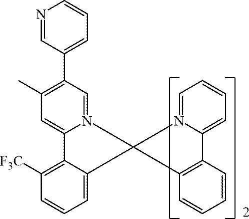

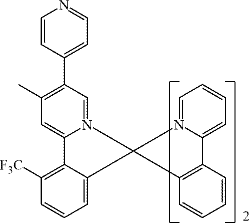

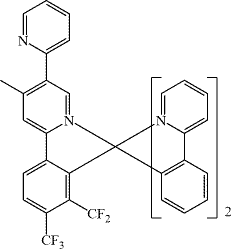

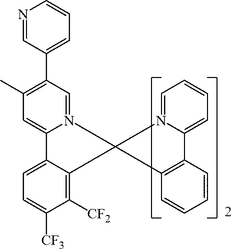

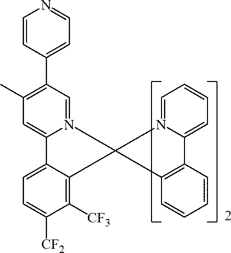

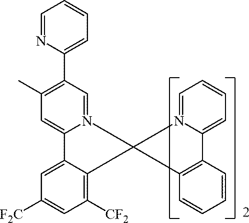

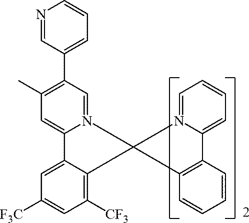

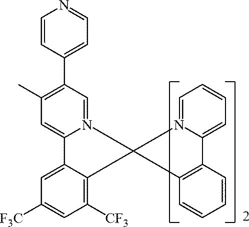

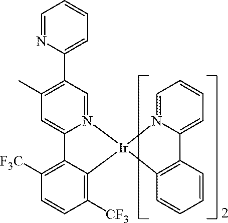

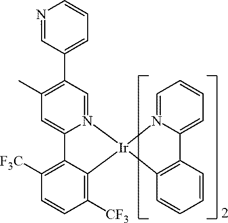

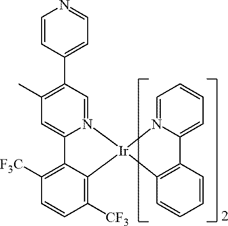

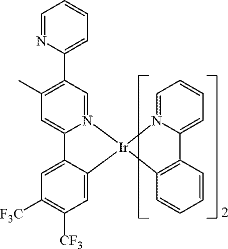

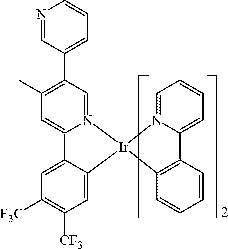

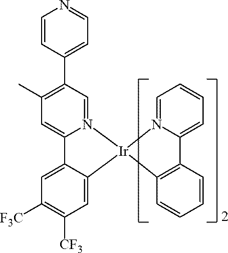

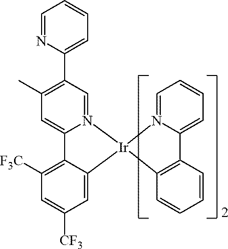

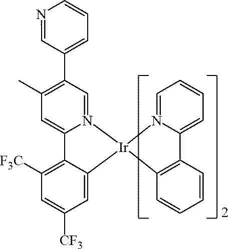

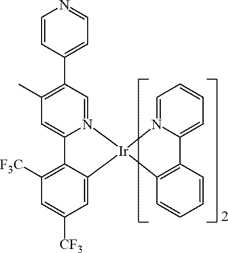

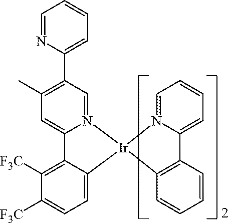

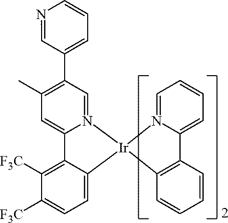

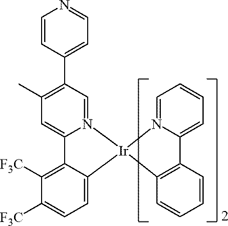

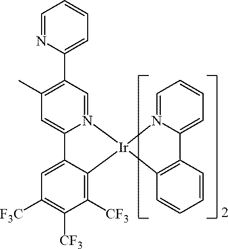

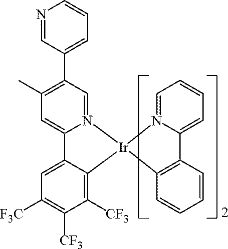

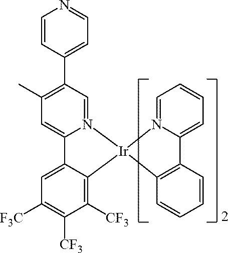

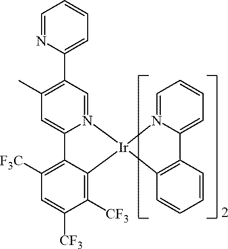

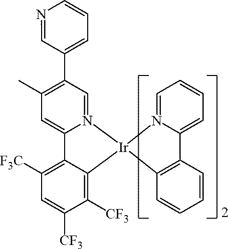

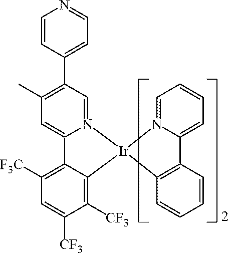

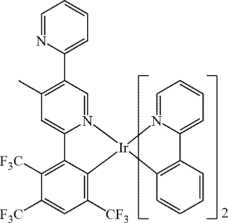

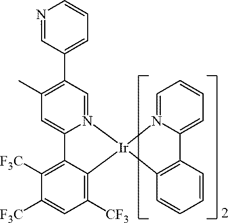

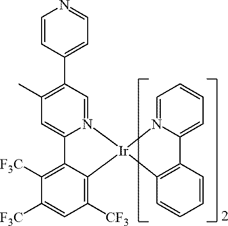

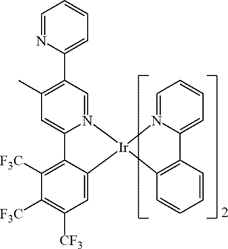

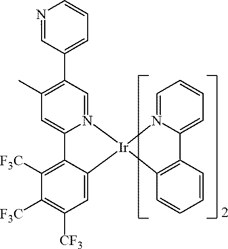

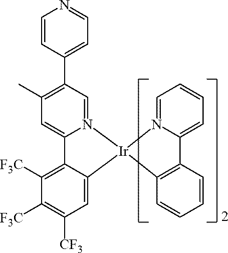

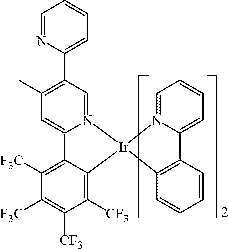

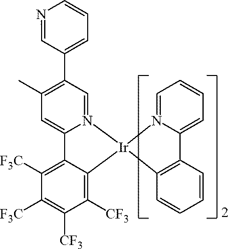

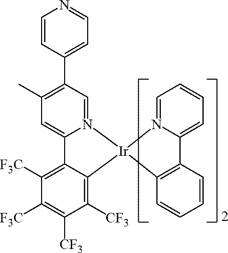

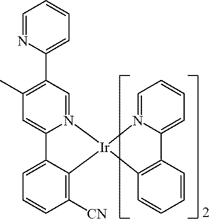

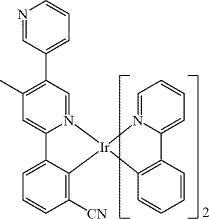

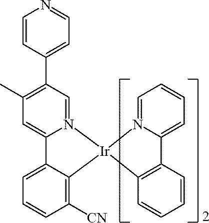

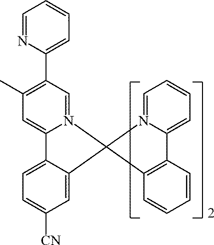

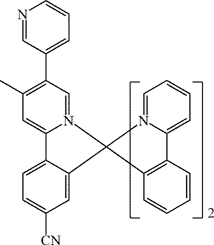

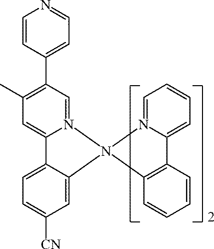

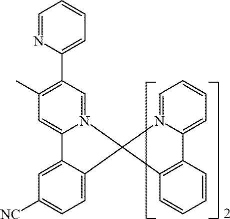

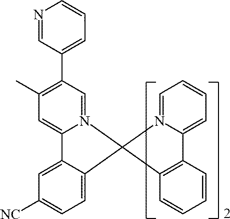

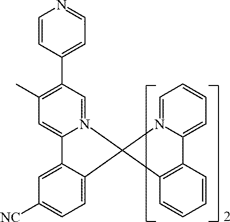

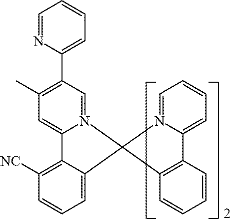

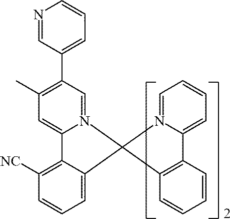

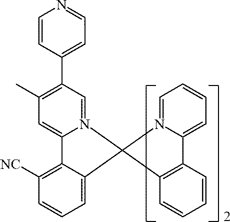

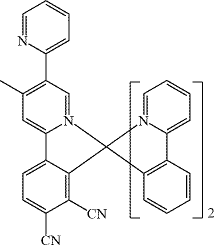

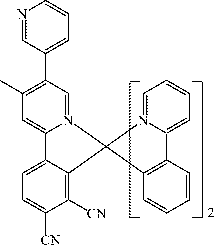

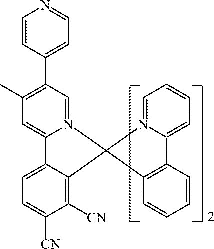

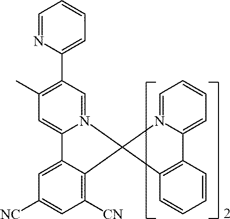

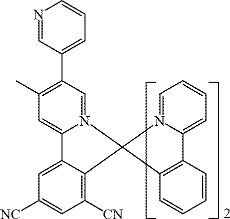

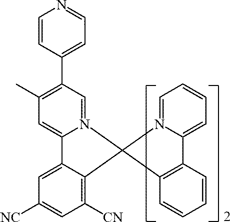

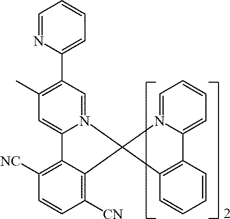

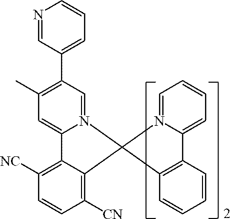

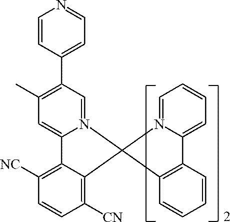

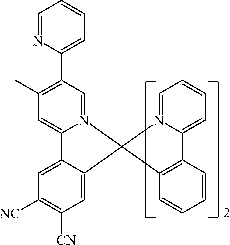

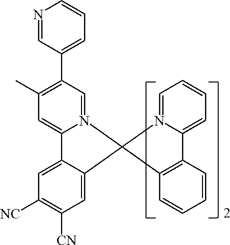

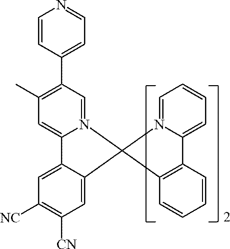

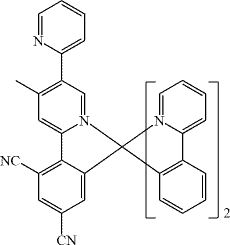

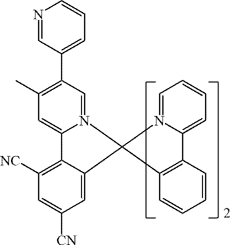

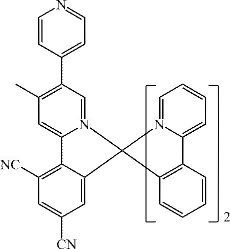

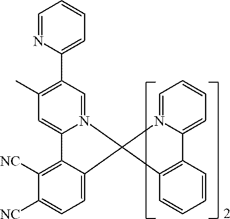

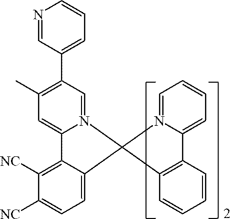

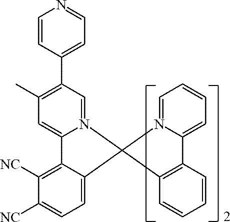

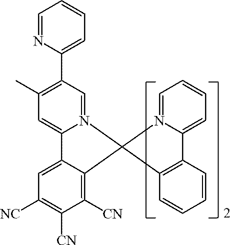

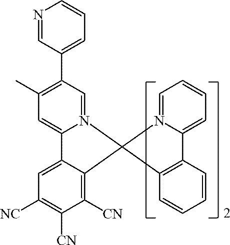

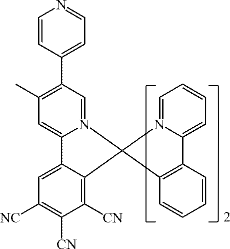

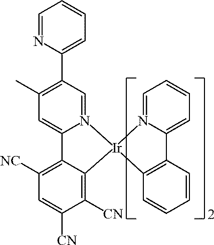

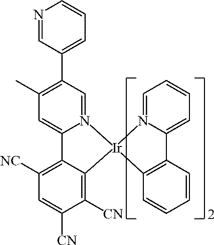

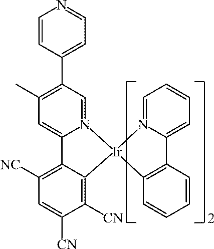

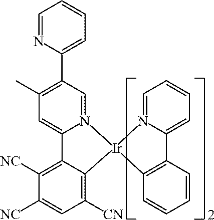

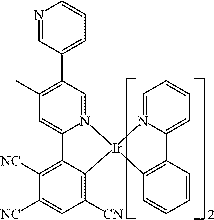

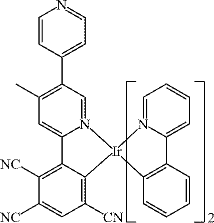

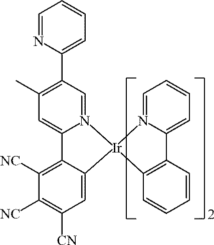

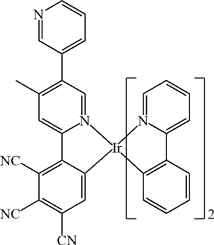

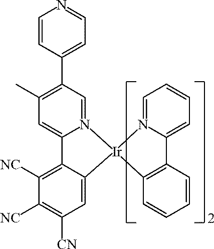

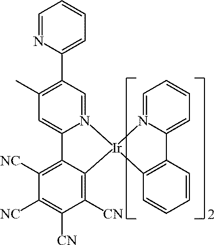

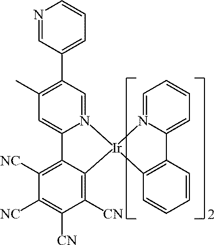

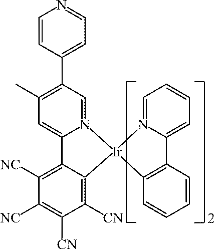

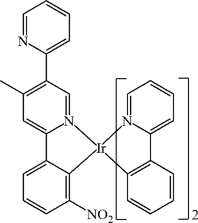

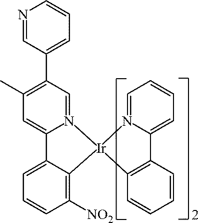

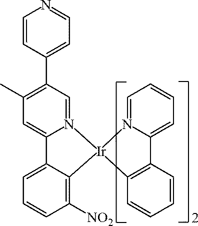

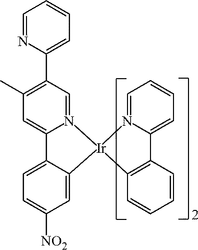

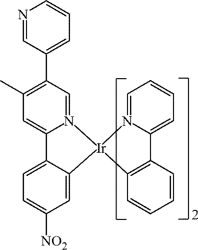

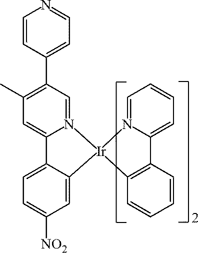

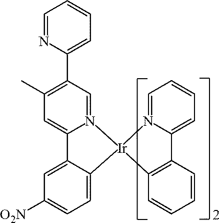

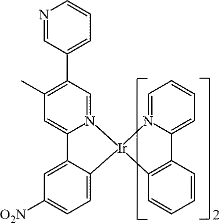

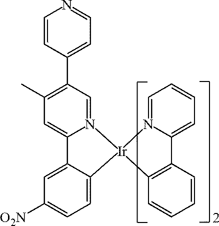

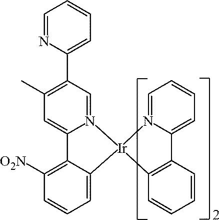

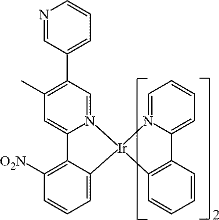

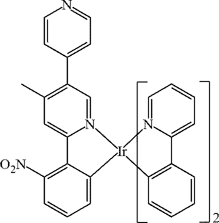

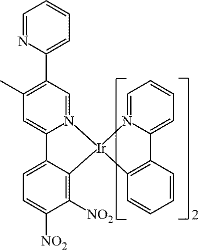

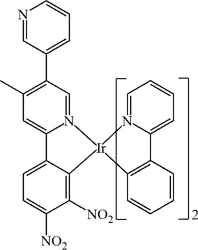

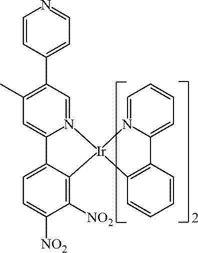

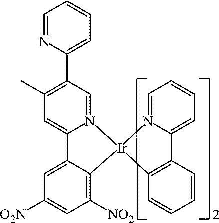

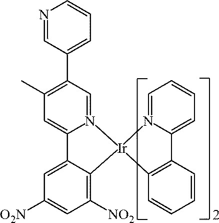

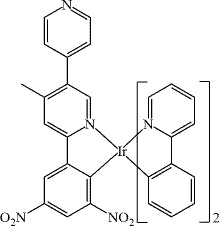

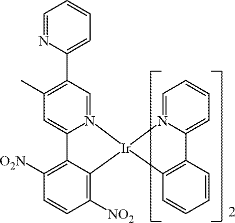

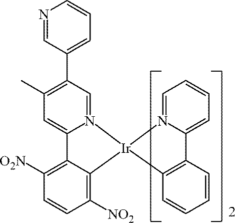

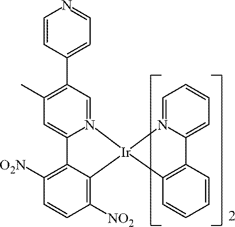

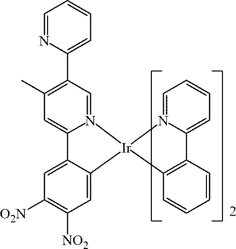

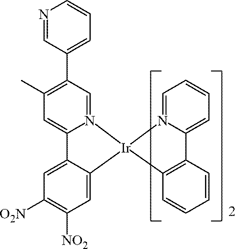

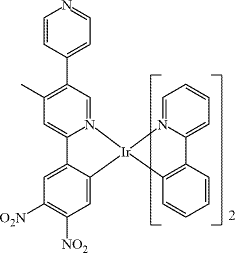

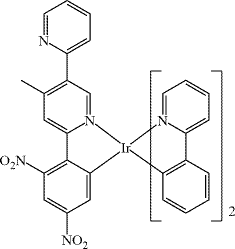

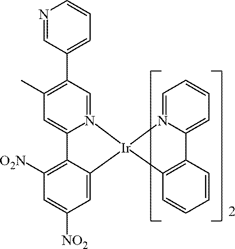

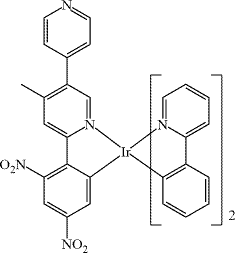

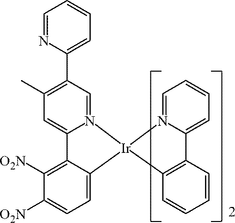

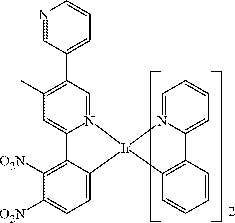

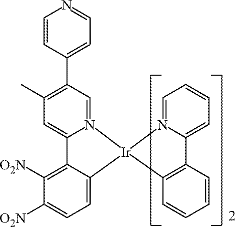

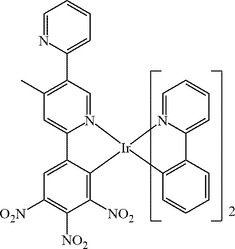

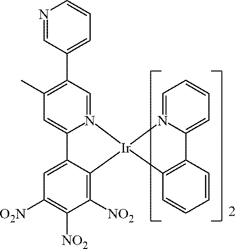

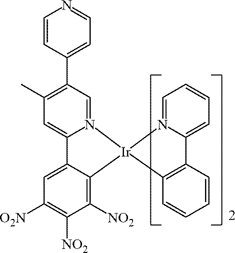

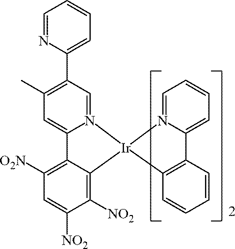

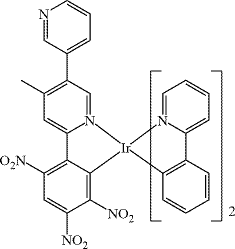

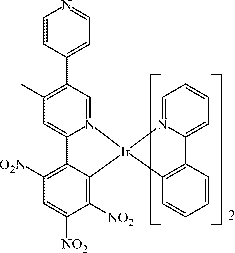

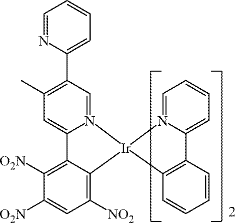

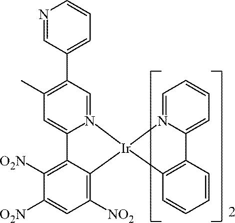

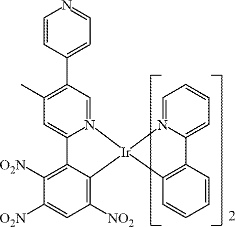

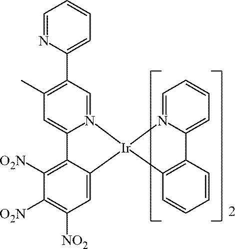

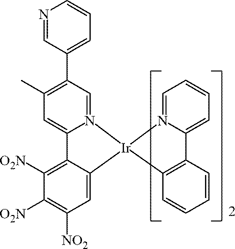

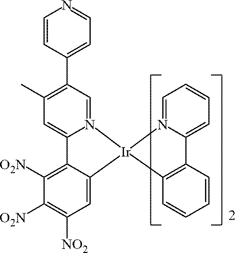

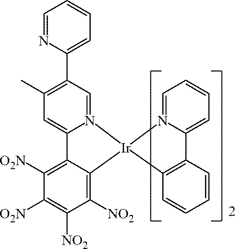

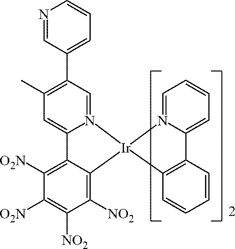

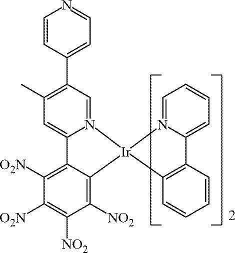

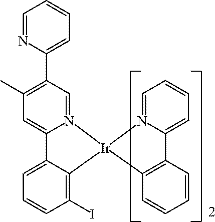

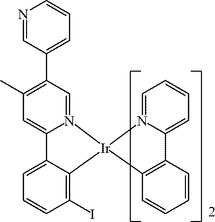

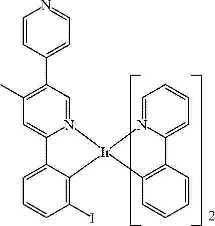

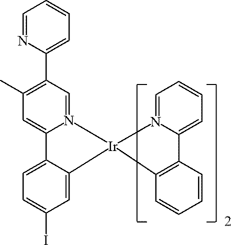

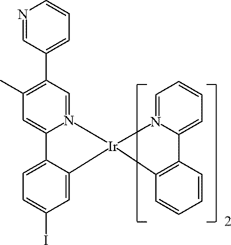

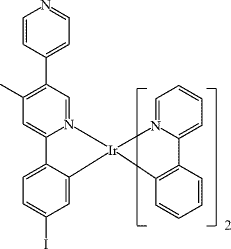

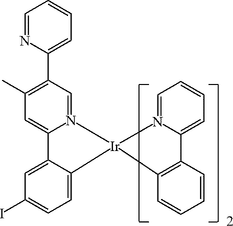

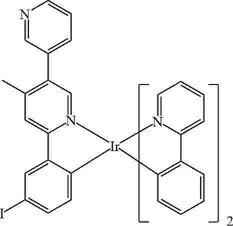

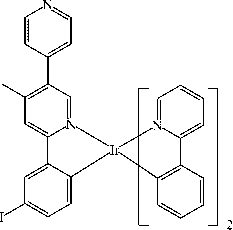

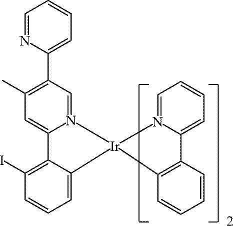

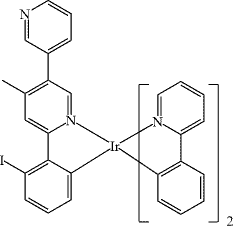

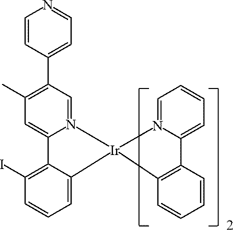

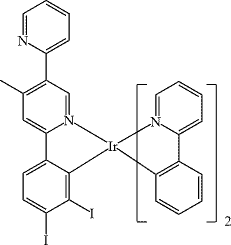

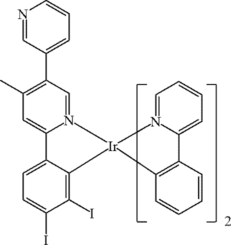

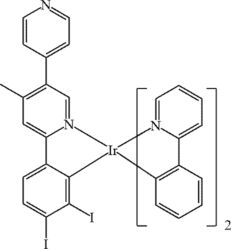

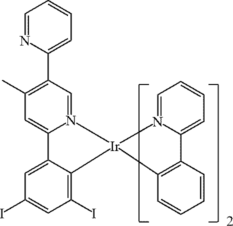

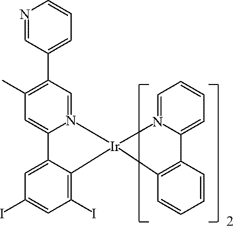

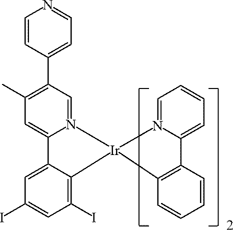

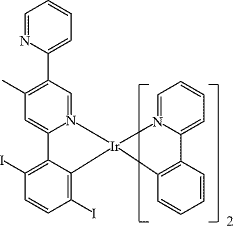

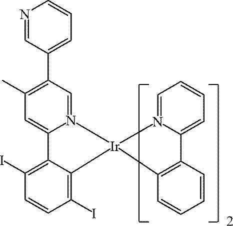

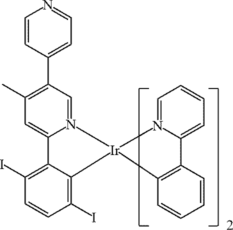

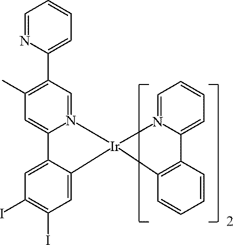

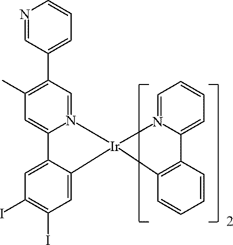

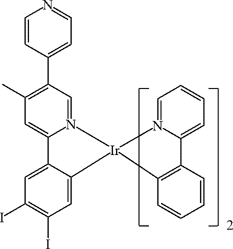

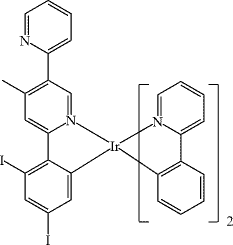

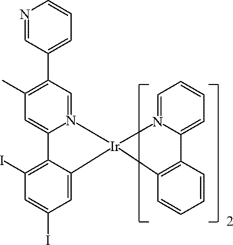

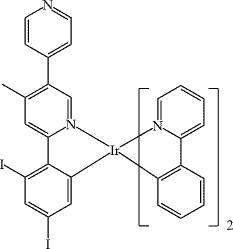

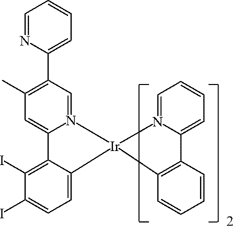

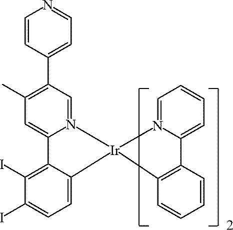

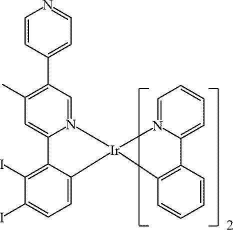

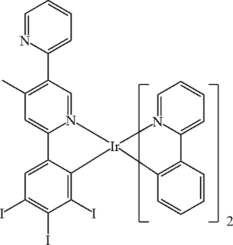

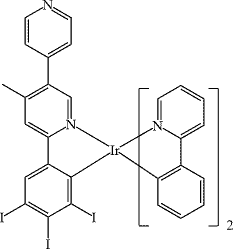

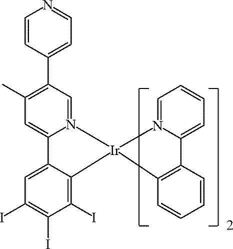

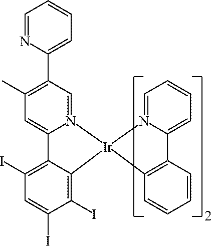

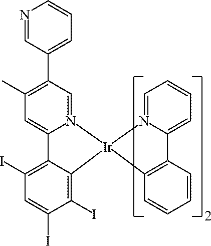

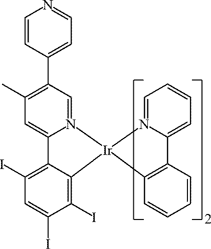

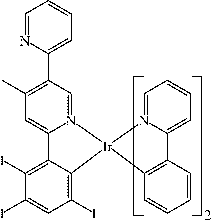

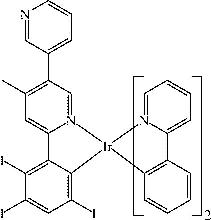

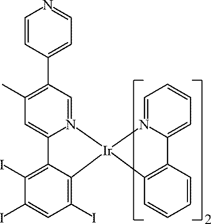

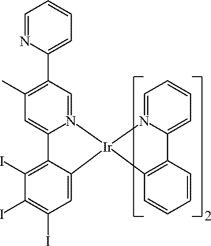

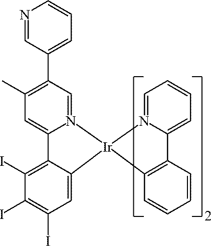

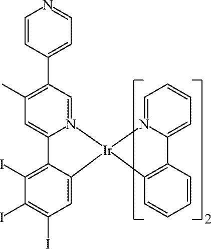

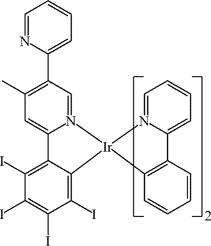

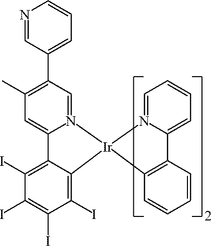

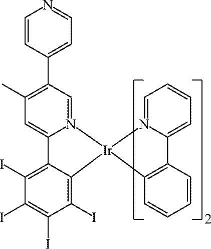

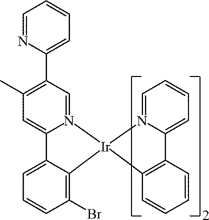

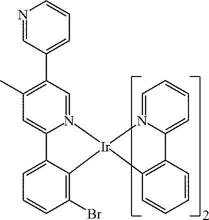

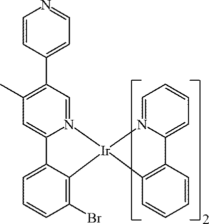

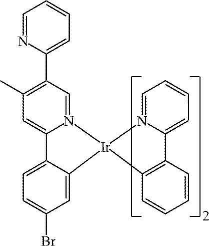

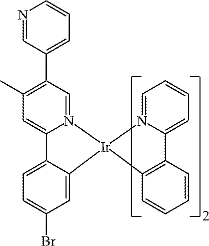

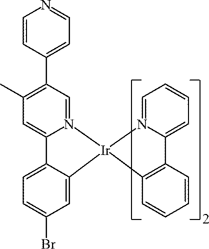

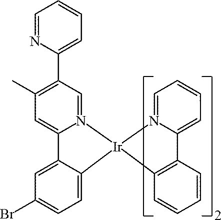

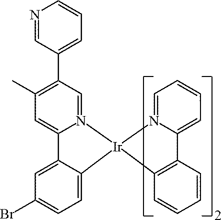

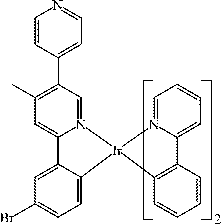

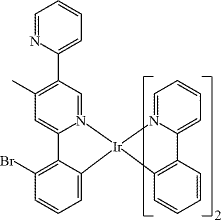

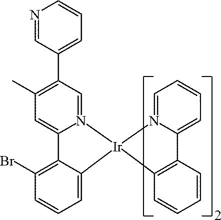

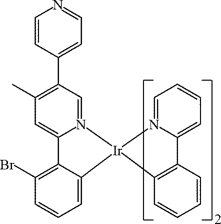

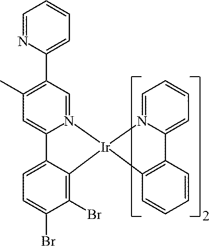

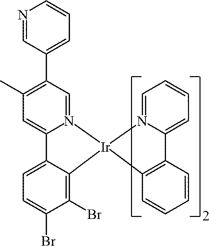

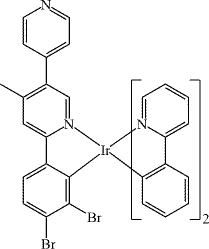

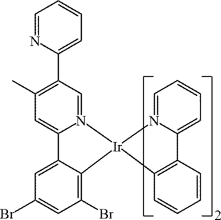

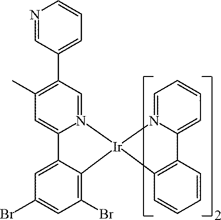

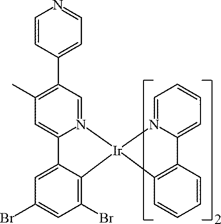

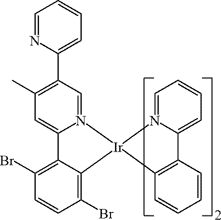

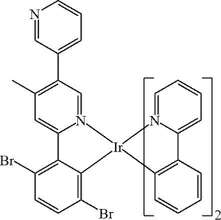

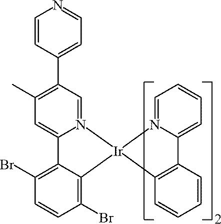

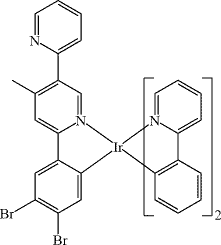

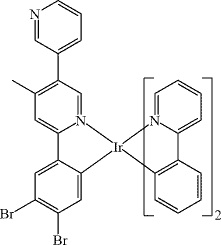

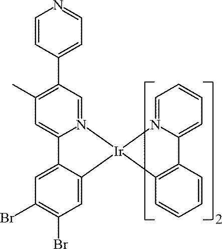

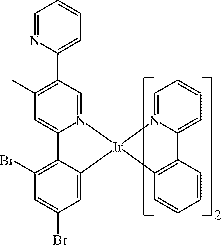

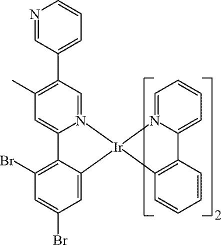

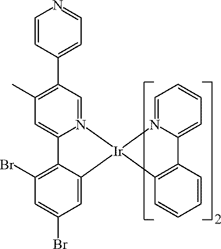

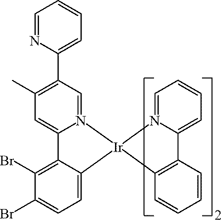

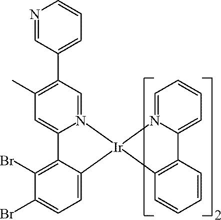

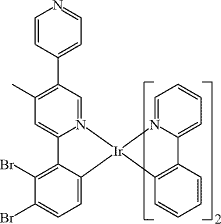

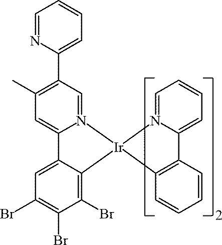

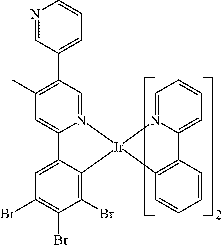

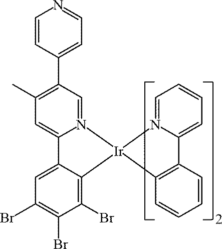

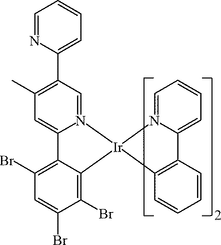

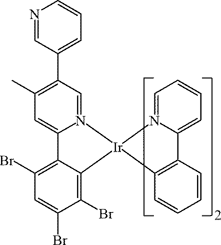

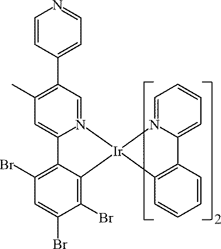

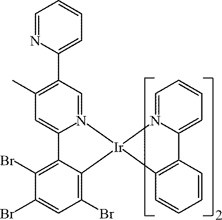

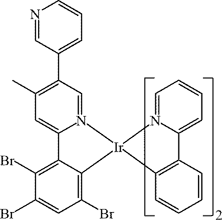

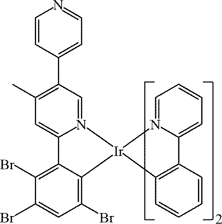

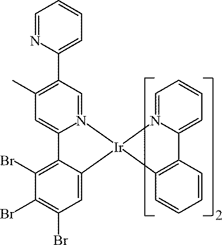

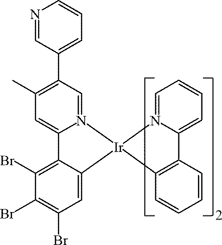

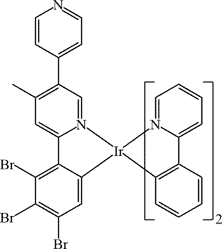

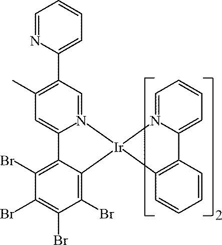

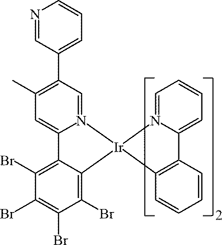

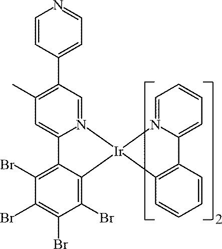

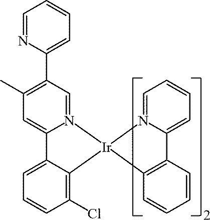

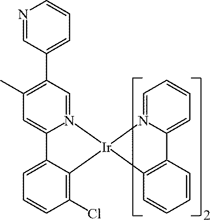

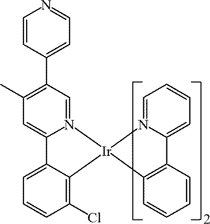

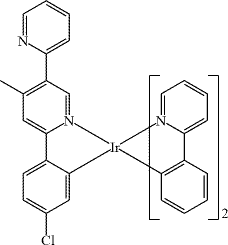

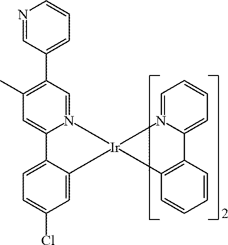

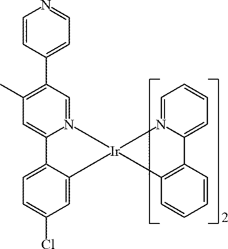

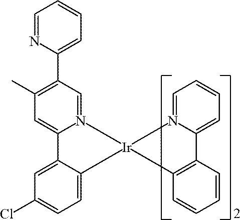

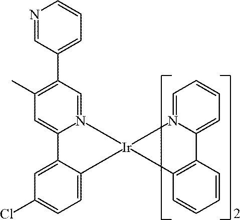

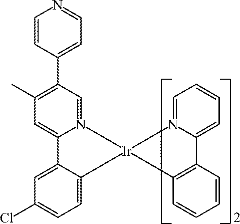

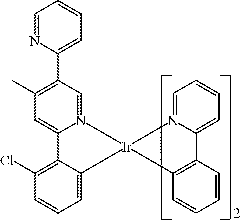

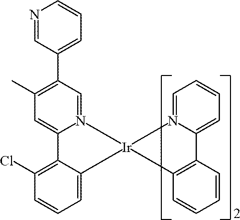

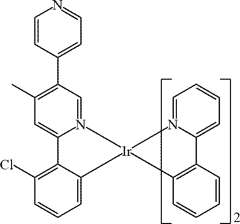

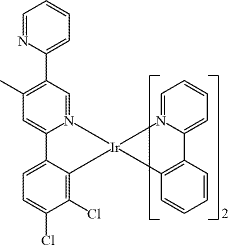

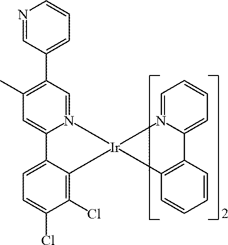

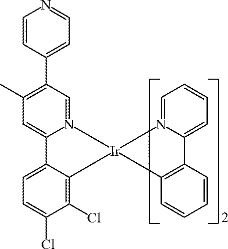

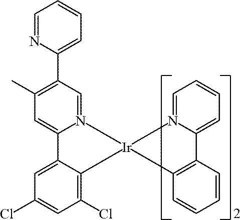

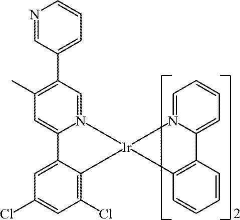

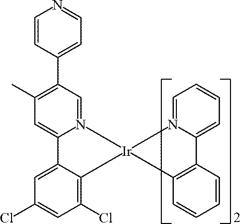

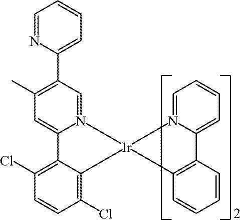

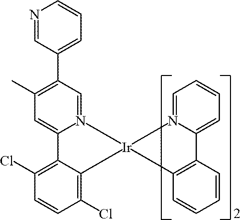

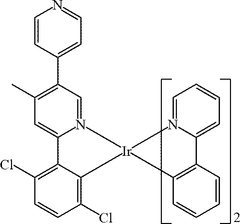

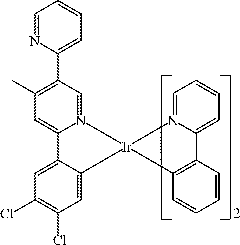

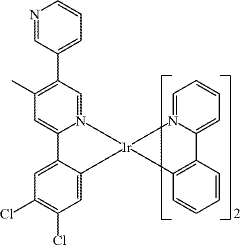

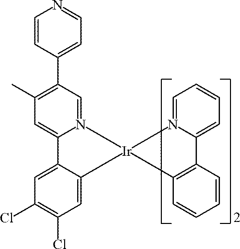

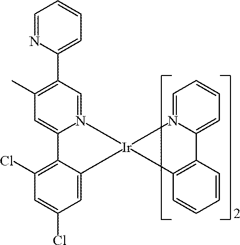

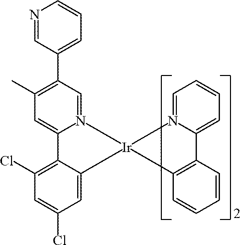

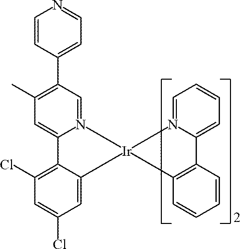

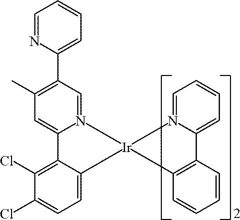

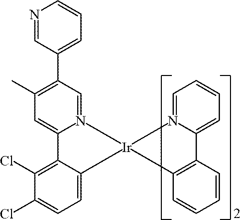

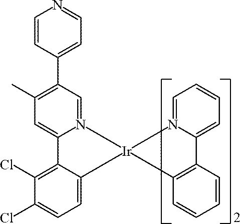

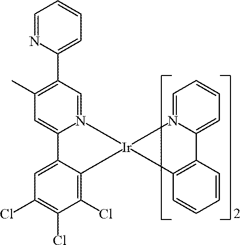

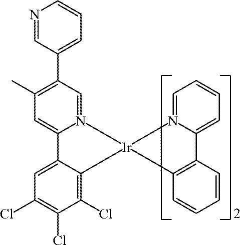

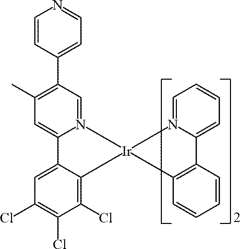

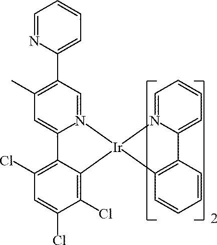

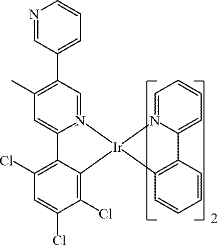

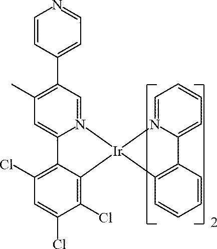

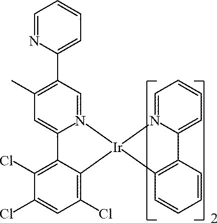

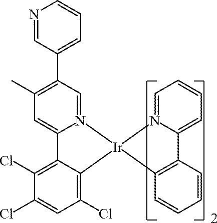

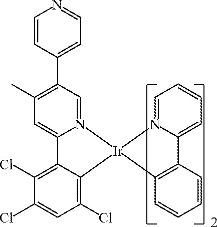

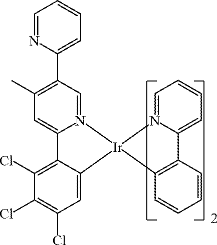

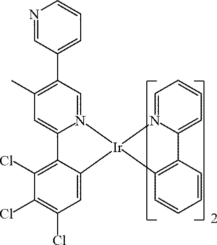

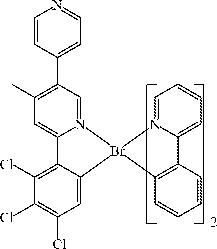

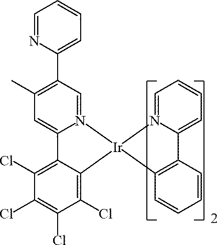

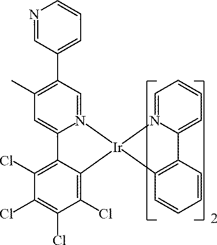

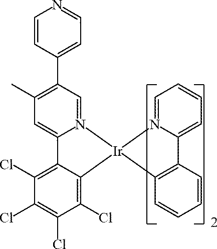

The phosphorescent dopant represented by Chemical Formula 1 may have an energy band gap of 2.0 eV to 3.0 eV, or 2.2 eV to 2.8 eV. In this case, charges can be transported easily, and, thus, the luminous efficiency can be improved without increasing a driving voltage.

The fluorescent dopant is a compound represented by Chemical Formula 2.

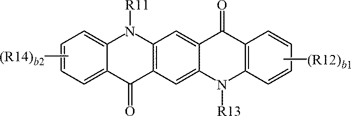

In Chemical Formula 2, each of b1 and b2 is independently an integer of 0 to 4.

In Chemical Formula 2, each of R11 to R14 is independently selected from hydrogen, deuterium, tritium, an alkyl group having 1 to 20 carbon atoms, an aryl group having 6 to 30 carbon atoms and a heteroaryl group having 3 to 40 carbon atoms. In this case, each substituent may form a fused ring with a neighboring substituent.

Specifically, for example, in Chemical Formula 2, each of b1 and b2 may be independently an integer of 0 to 2. In Chemical Formula 2, each of R11 and R13 may be independently selected from an alkyl group having 1 to 20 carbon atoms and an aryl group having 6 to 30 carbon atoms. Also, in Chemical Formula 2, each of R12 and R14 may be independently selected from hydrogen and an alkyl group having 1 to 20 carbon atoms. In this case, energy transfer with the phosphorescent dopant represented by Chemical Formula 1 can be facilitated, and, thus, the luminous efficiency can be further improved.

More specifically, for example, the fluorescent dopant may be a compound selected from the following Compound 2-1 to Compound 2-117.

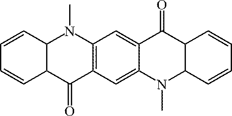 [SMILES: CN1c2cc3c(cc2C(=O)C2C=CC=CC21)N(C)C1C=CC=CC1C3=O]

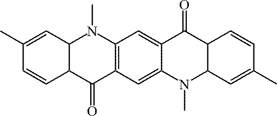

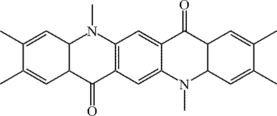

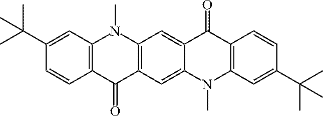 [SMILES: Cn1c2cc(C(C)(C)C)ccc2c(=O)c2cc3c(cc21)c(=O)c1ccc(C(C)(C)C)cc1n3C]

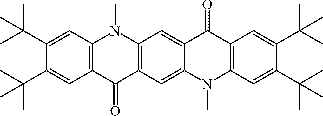 [SMILES: Cn1c2cc(C(C)(C)C)c(C(C)(C)C)cc2c(=O)c2cc3c(cc21)c(=O)c1cc(C(C)(C)C)c(C(C)(C)C)cc1n3C]

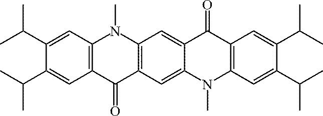 [SMILES: CC(C)c1cc2c(=O)c3cc4c(cc3n(C)c2cc1C(C)C)c(=O)c1cc(C(C)C)c(C(C)C)cc1n4C]

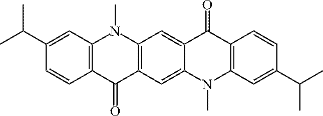 [SMILES: CC(C)c1ccc2c(=O)c3cc4c(cc3n(C)c2c1)c(=O)c1ccc(C(C)C)cc1n4C]

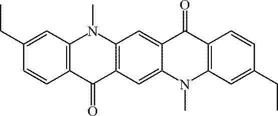 [SMILES: CCc1ccc2c(=O)c3cc4c(cc3n(C)c2c1)c(=O)c1ccc(CC)cc1n4C]

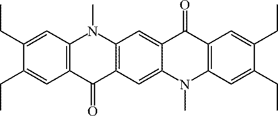 [SMILES: CCc1cc2c(=O)c3cc4c(cc3n(C)c2cc1CC)c(=O)c1cc(CC)c(CC)cc1n4C]

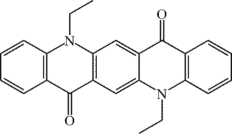 [SMILES: CCn1c2ccccc2c(=O)c2cc3c(cc21)c(=O)c1ccccc1n3CC]

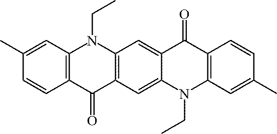

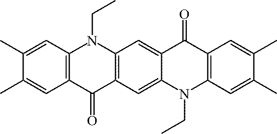

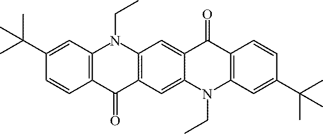 [SMILES: CCn1c2cc(C(C)(C)C)ccc2c(=O)c2cc3c(cc21)c(=O)c1ccc(C(C)(C)C)cc1n3CC]

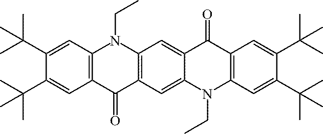 [SMILES: CCn1c2cc(C(C)(C)C)c(C(C)(C)C)cc2c(=O)c2cc3c(cc21)c(=O)c1cc(C(C)(C)C)c(C(C)(C)C)cc1n3CC]

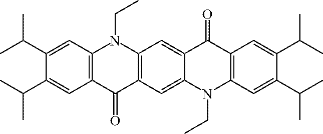 [SMILES: CCn1c2cc(C(C)C)c(C(C)C)cc2c(=O)c2cc3c(cc21)c(=O)c1cc(C(C)C)c(C(C)C)cc1n3CC]

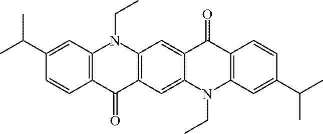 [SMILES: CCn1c2cc(C(C)C)ccc2c(=O)c2cc3c(cc21)c(=O)c1ccc(C(C)C)cc1n3CC]

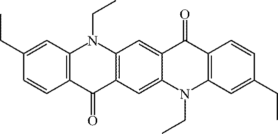 [SMILES: CCc1ccc2c(=O)c3cc4c(cc3n(CC)c2c1)c(=O)c1ccc(CC)cc1n4CC]

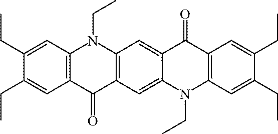 [SMILES: CCc1cc2c(=O)c3cc4c(cc3n(CC)c2cc1CC)c(=O)c1cc(CC)c(CC)cc1n4CC]

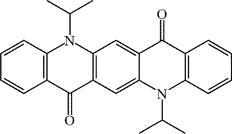 [SMILES: CC(C)n1c2ccccc2c(=O)c2cc3c(cc21)c(=O)c1ccccc1n3C(C)C]

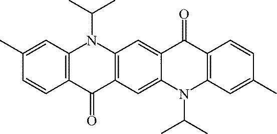

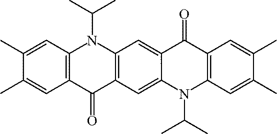

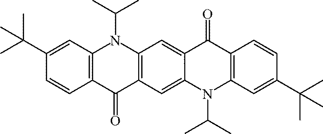 [SMILES: CC(C)n1c2cc(C(C)(C)C)ccc2c(=O)c2cc3c(cc21)c(=O)c1ccc(C(C)(C)C)cc1n3C(C)C]

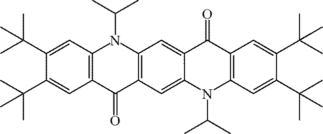 [SMILES: CC(C)n1c2cc(C(C)(C)C)c(C(C)(C)C)cc2c(=O)c2cc3c(cc21)c(=O)c1cc(C(C)(C)C)c(C(C)(C)C)cc1n3C(C)C]

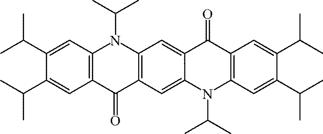 [SMILES: CC(C)c1cc2c(=O)c3cc4c(cc3n(C(C)C)c2cc1C(C)C)c(=O)c1cc(C(C)C)c(C(C)C)cc1n4C(C)C]

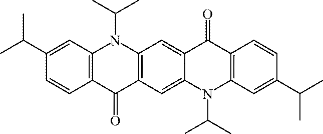 [SMILES: CC(C)c1ccc2c(=O)c3cc4c(cc3n(C(C)C)c2c1)c(=O)c1ccc(C(C)C)cc1n4C(C)C]

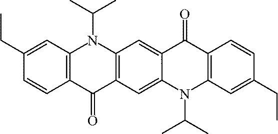 [SMILES: CCc1ccc2c(=O)c3cc4c(cc3n(C(C)C)c2c1)c(=O)c1ccc(CC)cc1n4C(C)C]

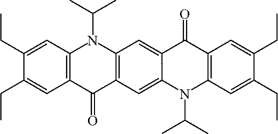 [SMILES: CCc1cc2c(=O)c3cc4c(cc3n(C(C)C)c2cc1CC)c(=O)c1cc(CC)c(CC)cc1n4C(C)C]

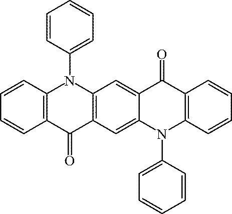 [SMILES: O=c1c2ccccc2n(-c2ccccc2)c2cc3c(=O)c4ccccc4n(-c4ccccc4)c3cc12]

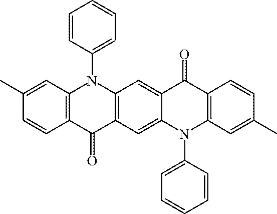

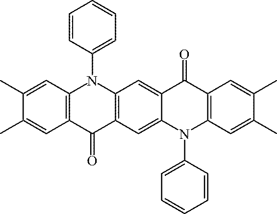

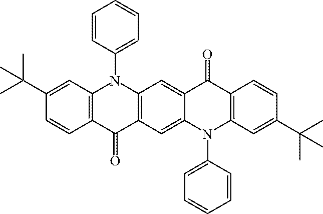 [SMILES: CC(C)(C)c1ccc2c(=O)c3cc4c(cc3n(-c3ccccc3)c2c1)c(=O)c1ccc(C(C)(C)C)cc1n4-c1ccccc1]

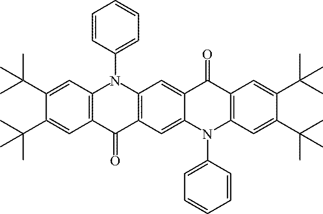 [SMILES: CC(C)(C)c1cc2c(=O)c3cc4c(cc3n(-c3ccccc3)c2cc1C(C)(C)C)c(=O)c1cc(C(C)(C)C)c(C(C)(C)C)cc1n4-c1ccccc1]

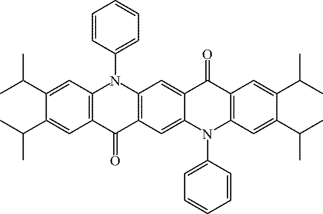 [SMILES: CC(C)c1cc2c(=O)c3cc4c(cc3n(-c3ccccc3)c2cc1C(C)C)c(=O)c1cc(C(C)C)c(C(C)C)cc1n4-c1ccccc1]

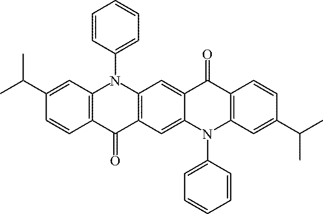 [SMILES: CC(C)c1ccc2c(=O)c3cc4c(cc3n(-c3ccccc3)c2c1)c(=O)c1ccc(C(C)C)cc1n4-c1ccccc1]

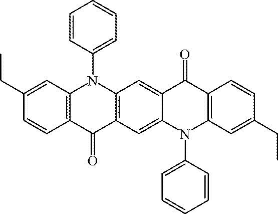 [SMILES: CCc1ccc2c(=O)c3cc4c(cc3n(-c3ccccc3)c2c1)c(=O)c1ccc(CC)cc1n4-c1ccccc1]

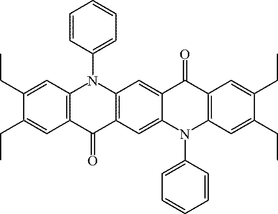 [SMILES: CCc1cc2c(=O)c3cc4c(cc3n(-c3ccccc3)c2cc1CC)c(=O)c1cc(CC)c(CC)cc1n4-c1ccccc1]

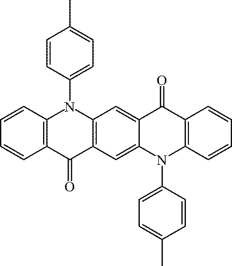 [SMILES: Cc1ccc(-n2c3ccccc3c(=O)c3cc4c(cc32)c(=O)c2ccccc2n4-c2ccc(C)cc2)cc1]

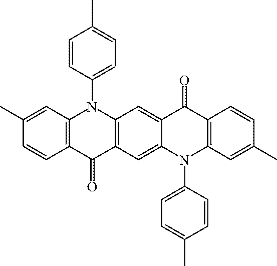

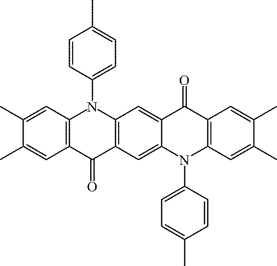

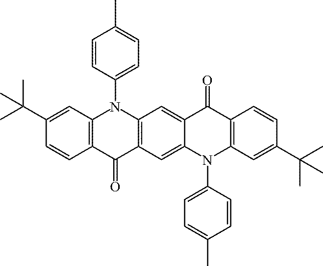 [SMILES: Cc1ccc(-n2c3cc(C(C)(C)C)ccc3c(=O)c3cc4c(cc32)c(=O)c2ccc(C(C)(C)C)cc2n4-c2ccc(C)cc2)cc1]

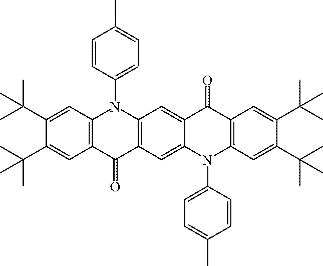 [SMILES: Cc1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C)cc2)cc1]

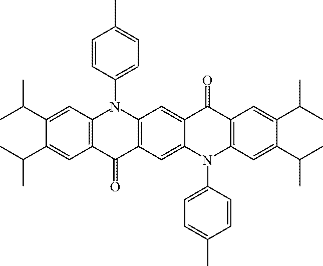 [SMILES: Cc1ccc(-n2c3cc(C(C)C)c(C(C)C)cc3c(=O)c3cc4c(cc32)c(=O)c2cc(C(C)C)c(C(C)C)cc2n4-c2ccc(C)cc2)cc1]

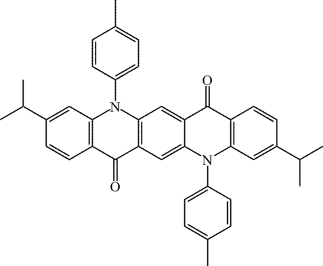 [SMILES: Cc1ccc(-n2c3cc(C(C)C)ccc3c(=O)c3cc4c(cc32)c(=O)c2ccc(C(C)C)cc2n4-c2ccc(C)cc2)cc1]

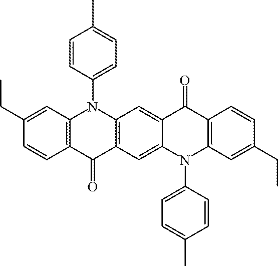 [SMILES: CCc1ccc2c(=O)c3cc4c(cc3n(-c3ccc(C)cc3)c2c1)c(=O)c1ccc(CC)cc1n4-c1ccc(C)cc1]

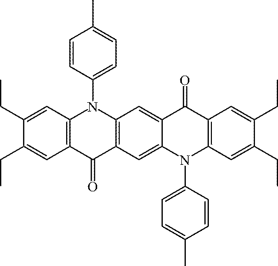 [SMILES: CCc1cc2c(=O)c3cc4c(cc3n(-c3ccc(C)cc3)c2cc1CC)c(=O)c1cc(CC)c(CC)cc1n4-c1ccc(C)cc1]

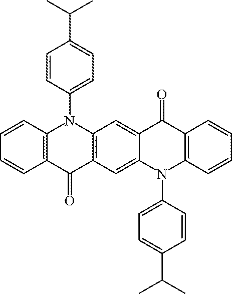 [SMILES: CC(C)c1ccc(-n2c3ccccc3c(=O)c3cc4c(cc32)c(=O)c2ccccc2n4-c2ccc(C(C)C)cc2)cc1]

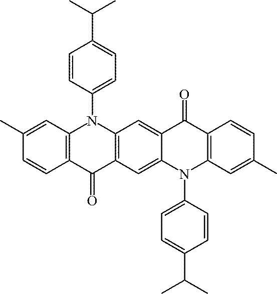

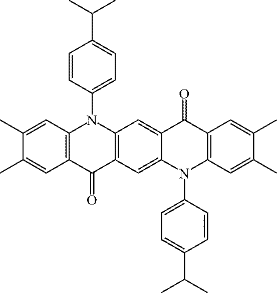

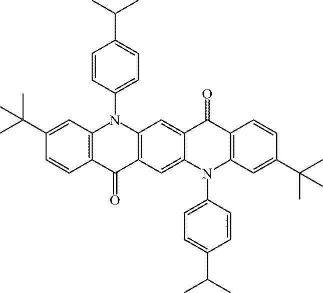 [SMILES: CC(C)c1ccc(-n2c3cc(C(C)(C)C)ccc3c(=O)c3cc4c(cc32)c(=O)c2ccc(C(C)(C)C)cc2n4-c2ccc(C(C)C)cc2)cc1]

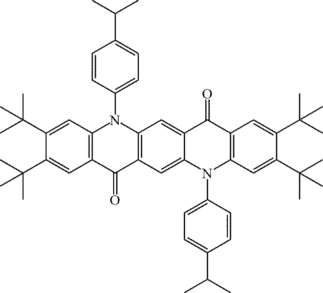 [SMILES: CC(C)c1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C(C)C)cc2)cc1]

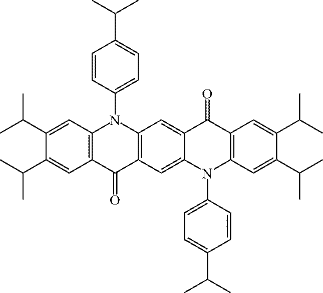 [SMILES: CC(C)c1ccc(-n2c3cc(C(C)C)c(C(C)C)cc3c(=O)c3cc4c(cc32)c(=O)c2cc(C(C)C)c(C(C)C)cc2n4-c2ccc(C(C)C)cc2)cc1]

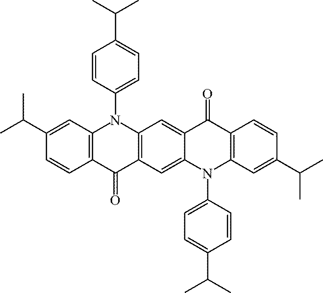 [SMILES: CC(C)c1ccc(-n2c3cc(C(C)C)ccc3c(=O)c3cc4c(cc32)c(=O)c2ccc(C(C)C)cc2n4-c2ccc(C(C)C)cc2)cc1]

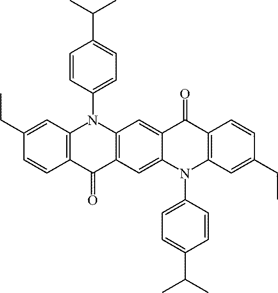 [SMILES: CCc1ccc2c(=O)c3cc4c(cc3n(-c3ccc(C(C)C)cc3)c2c1)c(=O)c1ccc(CC)cc1n4-c1ccc(C(C)C)cc1]

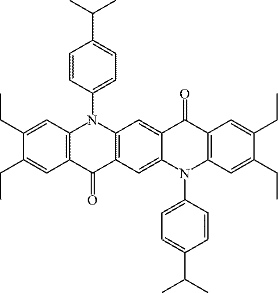 [SMILES: CCc1cc2c(=O)c3cc4c(cc3n(-c3ccc(C(C)C)cc3)c2cc1CC)c(=O)c1cc(CC)c(CC)cc1n4-c1ccc(C(C)C)cc1]

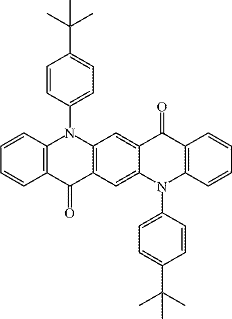 [SMILES: CC(C)(C)c1ccc(-n2c3ccccc3c(=O)c3cc4c(cc32)c(=O)c2ccccc2n4-c2ccc(C(C)(C)C)cc2)cc1]

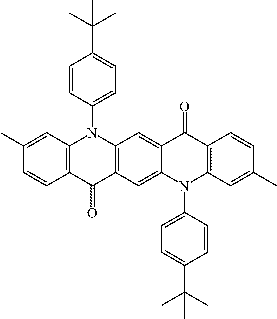

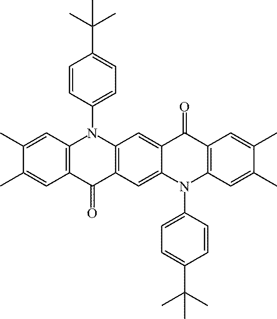

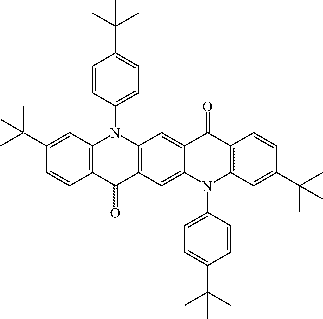 [SMILES: CC(C)(C)c1ccc(-n2c3cc(C(C)(C)C)ccc3c(=O)c3cc4c(cc32)c(=O)c2ccc(C(C)(C)C)cc2n4-c2ccc(C(C)(C)C)cc2)cc1]

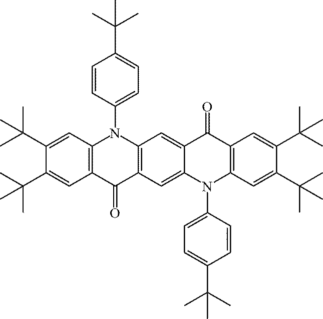 [SMILES: CC(C)(C)c1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C(C)(C)C)cc2)cc1]

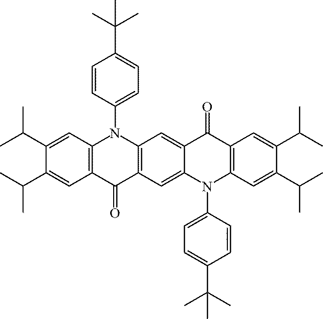 [SMILES: CC(C)c1cc2c(=O)c3cc4c(cc3n(-c3ccc(C(C)(C)C)cc3)c2cc1C(C)C)c(=O)c1cc(C(C)C)c(C(C)C)cc1n4-c1ccc(C(C)(C)C)cc1]

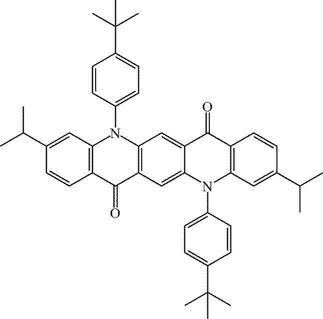 [SMILES: CC(C)c1ccc2c(=O)c3cc4c(cc3n(-c3ccc(C(C)(C)C)cc3)c2c1)c(=O)c1ccc(C(C)C)cc1n4-c1ccc(C(C)(C)C)cc1]

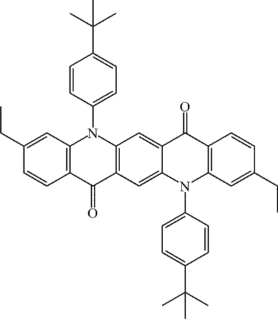 [SMILES: CCc1ccc2c(=O)c3cc4c(cc3n(-c3ccc(C(C)(C)C)cc3)c2c1)c(=O)c1ccc(CC)cc1n4-c1ccc(C(C)(C)C)cc1]

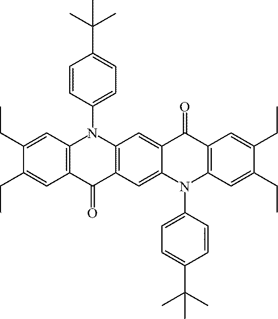 [SMILES: CCc1cc2c(=O)c3cc4c(cc3n(-c3ccc(C(C)(C)C)cc3)c2cc1CC)c(=O)c1cc(CC)c(CC)cc1n4-c1ccc(C(C)(C)C)cc1]

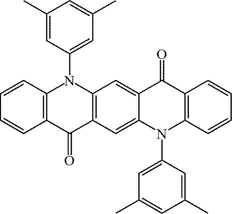 [SMILES: Cc1cc(C)cc(-n2c3ccccc3c(=O)c3cc4c(cc32)c(=O)c2ccccc2n4-c2cc(C)cc(C)c2)c1]

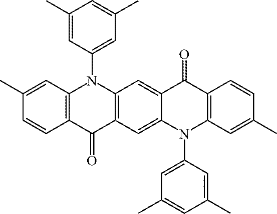

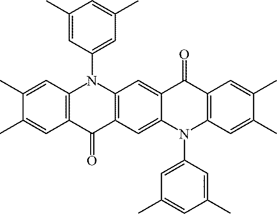

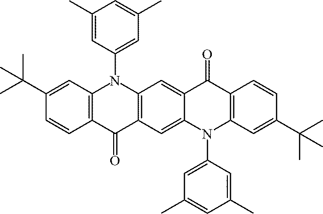 [SMILES: Cc1cc(C)cc(-n2c3cc(C(C)(C)C)ccc3c(=O)c3cc4c(cc32)c(=O)c2ccc(C(C)(C)C)cc2n4-c2cc(C)cc(C)c2)c1]

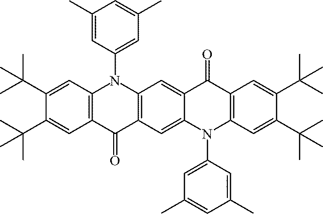 [SMILES: Cc1cc(C)cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C)cc(C)c2)c1]

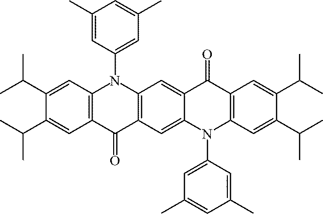 [SMILES: Cc1cc(C)cc(-n2c3cc(C(C)C)c(C(C)C)cc3c(=O)c3cc4c(cc32)c(=O)c2cc(C(C)C)c(C(C)C)cc2n4-c2cc(C)cc(C)c2)c1]

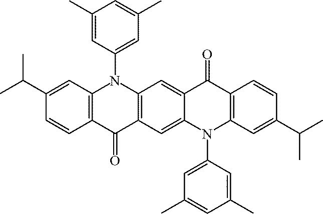 [SMILES: Cc1cc(C)cc(-n2c3cc(C(C)C)ccc3c(=O)c3cc4c(cc32)c(=O)c2ccc(C(C)C)cc2n4-c2cc(C)cc(C)c2)c1]

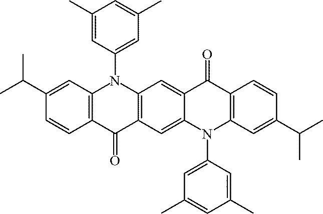 [SMILES: Cc1cc(C)cc(-n2c3cc(C(C)C)ccc3c(=O)c3cc4c(cc32)c(=O)c2ccc(C(C)C)cc2n4-c2cc(C)cc(C)c2)c1]

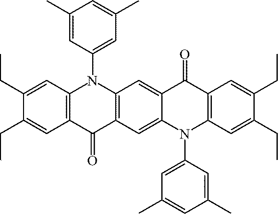 [SMILES: CCc1cc2c(=O)c3cc4c(cc3n(-c3cc(C)cc(C)c3)c2cc1CC)c(=O)c1cc(CC)c(CC)cc1n4-c1cc(C)cc(C)c1]

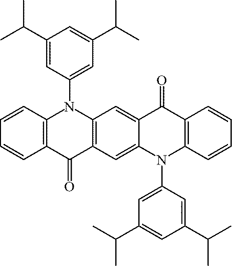 [SMILES: CC(C)c1cc(C(C)C)cc(-n2c3ccccc3c(=O)c3cc4c(cc32)c(=O)c2ccccc2n4-c2cc(C(C)C)cc(C(C)C)c2)c1]

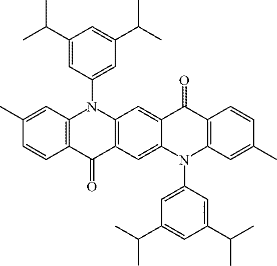

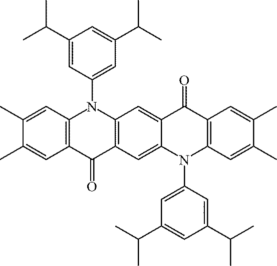

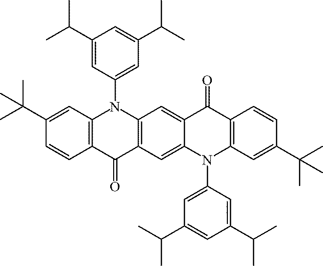 [SMILES: CC(C)c1cc(C(C)C)cc(-n2c3cc(C(C)(C)C)ccc3c(=O)c3cc4c(cc32)c(=O)c2ccc(C(C)(C)C)cc2n4-c2cc(C(C)C)cc(C(C)C)c2)c1]

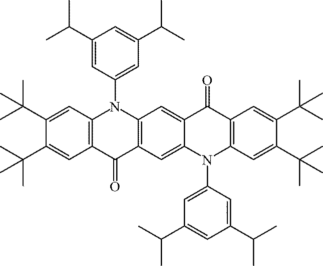 [SMILES: CC(C)c1cc(C(C)C)cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C(C)C)cc(C(C)C)c2)c1]

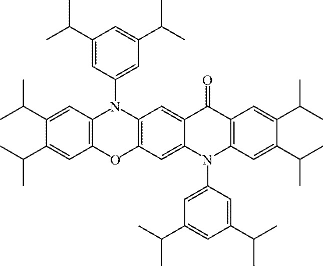 [SMILES: CC(C)c1cc(C(C)C)cc(N2c3cc(C(C)C)c(C(C)C)cc3Oc3cc4c(cc32)c(=O)c2cc(C(C)C)c(C(C)C)cc2n4-c2cc(C(C)C)cc(C(C)C)c2)c1]

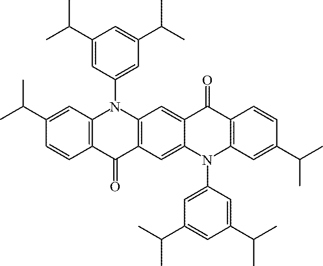 [SMILES: CC(C)c1cc(C(C)C)cc(-n2c3cc(C(C)C)ccc3c(=O)c3cc4c(cc32)c(=O)c2ccc(C(C)C)cc2n4-c2cc(C(C)C)cc(C(C)C)c2)c1]

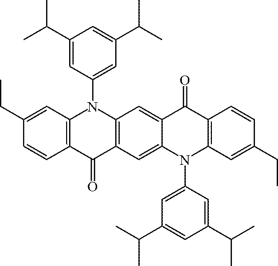 [SMILES: CCc1ccc2c(=O)c3cc4c(cc3n(-c3cc(C(C)C)cc(C(C)C)c3)c2c1)c(=O)c1ccc(CC)cc1n4-c1cc(C(C)C)cc(C(C)C)c1]

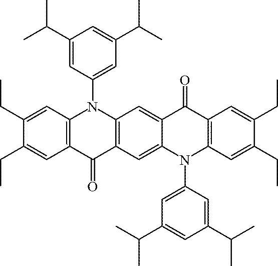 [SMILES: CCc1cc2c(=O)c3cc4c(cc3n(-c3cc(C(C)C)cc(C(C)C)c3)c2cc1CC)c(=O)c1cc(CC)c(CC)cc1n4-c1cc(C(C)C)cc(C(C)C)c1]

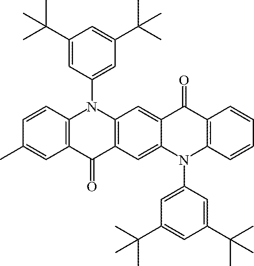 [SMILES: Cc1ccc2c(c1)c(=O)c1cc3c(cc1n2-c1cc(C(C)(C)C)cc(C(C)(C)C)c1)c(=O)c1ccccc1n3-c1cc(C(C)(C)C)cc(C(C)(C)C)c1]

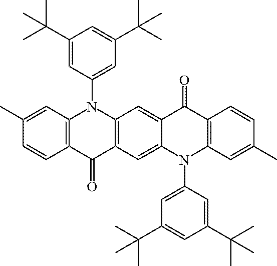

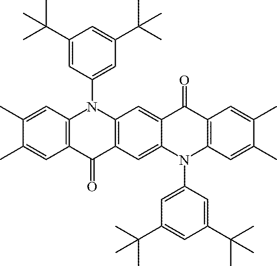

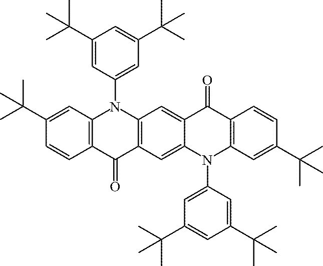 [SMILES: CC(C)(C)c1cc(-n2c3cc(C(C)(C)C)ccc3c(=O)c3cc4c(cc32)c(=O)c2ccc(C(C)(C)C)cc2n4-c2cc(C(C)(C)C)cc(C(C)(C)C)c2)cc(C(C)(C)C)c1]

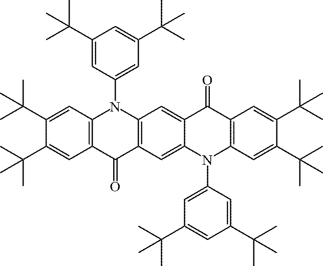 [SMILES: CC(C)(C)c1cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C(C)(C)C)cc(C(C)(C)C)c2)cc(C(C)(C)C)c1]

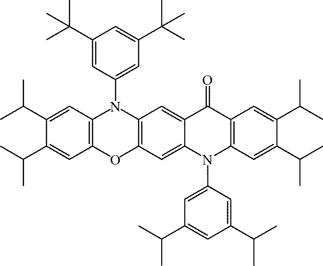 [SMILES: CC(C)c1cc(C(C)C)cc(-n2c3cc4c(cc3c(=O)c3cc(C(C)C)c(C(C)C)cc32)N(c2cc(C(C)(C)C)cc(C(C)(C)C)c2)c2cc(C(C)C)c(C(C)C)cc2O4)c1]

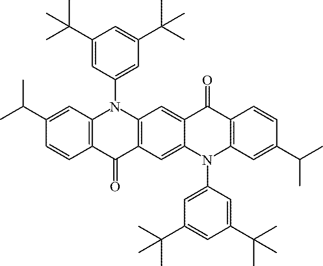 [SMILES: CC(C)c1ccc2c(=O)c3cc4c(cc3n(-c3cc(C(C)(C)C)cc(C(C)(C)C)c3)c2c1)c(=O)c1ccc(C(C)C)cc1n4-c1cc(C(C)(C)C)cc(C(C)(C)C)c1]

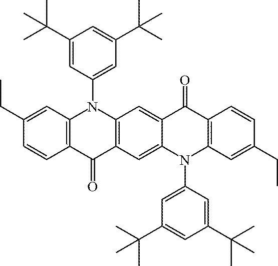 [SMILES: CCc1ccc2c(=O)c3cc4c(cc3n(-c3cc(C(C)(C)C)cc(C(C)(C)C)c3)c2c1)c(=O)c1ccc(CC)cc1n4-c1cc(C(C)(C)C)cc(C(C)(C)C)c1]

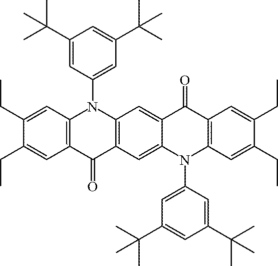 [SMILES: CCc1cc2c(=O)c3cc4c(cc3n(-c3cc(C(C)(C)C)cc(C(C)(C)C)c3)c2cc1CC)c(=O)c1cc(CC)c(CC)cc1n4-c1cc(C(C)(C)C)cc(C(C)(C)C)c1]

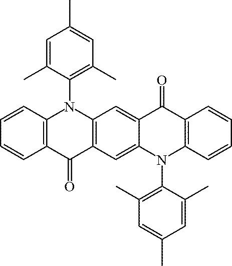 [SMILES: Cc1cc(C)c(-n2c3ccccc3c(=O)c3cc4c(cc32)c(=O)c2ccccc2n4-c2c(C)cc(C)cc2C)c(C)c1]

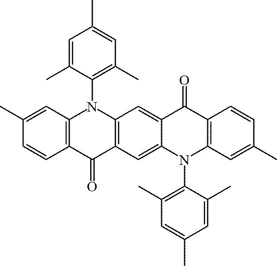

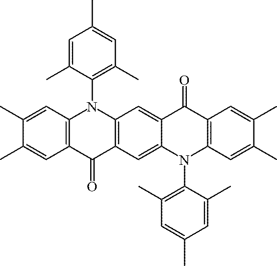

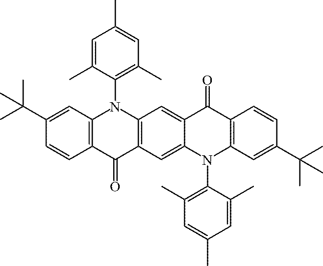 [SMILES: Cc1cc(C)c(-n2c3cc(C(C)(C)C)ccc3c(=O)c3cc4c(cc32)c(=O)c2ccc(C(C)(C)C)cc2n4-c2c(C)cc(C)cc2C)c(C)c1]

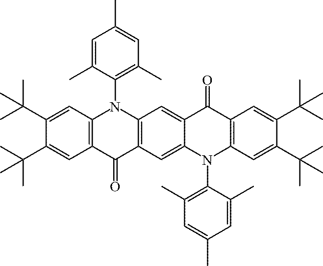 [SMILES: Cc1cc(C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C)cc(C)cc2C)c(C)c1]

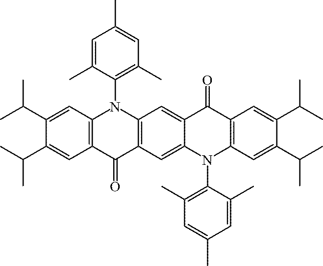 [SMILES: Cc1cc(C)c(-n2c3cc(C(C)C)c(C(C)C)cc3c(=O)c3cc4c(cc32)c(=O)c2cc(C(C)C)c(C(C)C)cc2n4-c2c(C)cc(C)cc2C)c(C)c1]

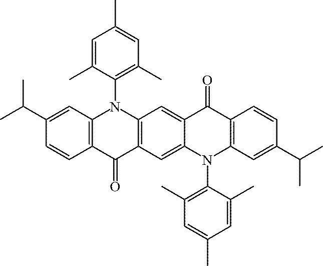 [SMILES: Cc1cc(C)c(-n2c3cc(C(C)C)ccc3c(=O)c3cc4c(cc32)c(=O)c2ccc(C(C)C)cc2n4-c2c(C)cc(C)cc2C)c(C)c1]

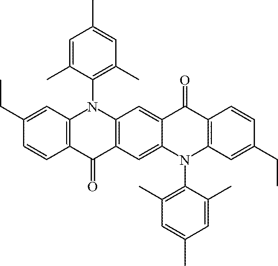 [SMILES: CCc1ccc2c(=O)c3cc4c(cc3n(-c3c(C)cc(C)cc3C)c2c1)c(=O)c1ccc(CC)cc1n4-c1c(C)cc(C)cc1C]

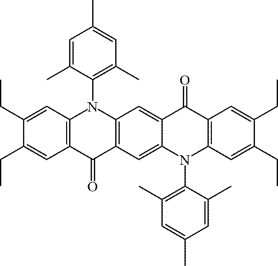 [SMILES: CCc1cc2c(=O)c3cc4c(cc3n(-c3c(C)cc(C)cc3C)c2cc1CC)c(=O)c1cc(CC)c(CC)cc1n4-c1c(C)cc(C)cc1C]

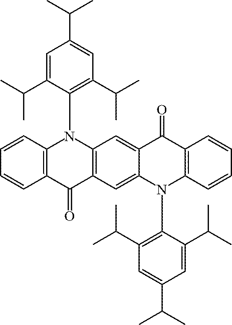 [SMILES: CC(C)c1cc(C(C)C)c(-n2c3ccccc3c(=O)c3cc4c(cc32)c(=O)c2ccccc2n4-c2c(C(C)C)cc(C(C)C)cc2C(C)C)c(C(C)C)c1]

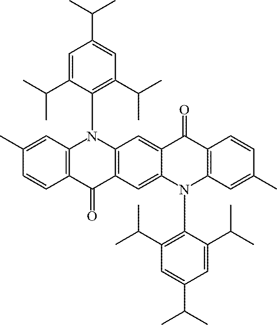

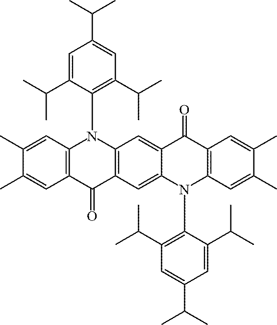

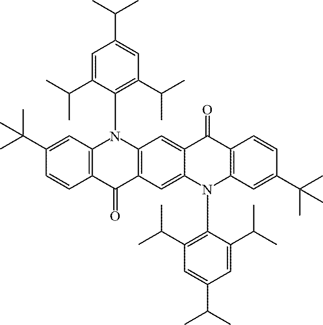 [SMILES: CC(C)c1cc(C(C)C)c(-n2c3cc(C(C)(C)C)ccc3c(=O)c3cc4c(cc32)c(=O)c2ccc(C(C)(C)C)cc2n4-c2c(C(C)C)cc(C(C)C)cc2C(C)C)c(C(C)C)c1]

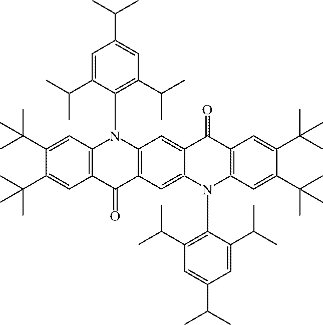 [SMILES: CC(C)c1cc(C(C)C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C(C)C)cc(C(C)C)cc2C(C)C)c(C(C)C)c1]

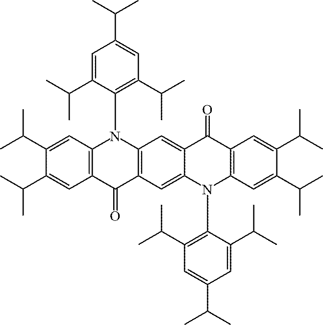 [SMILES: CC(C)c1cc(C(C)C)c(-n2c3cc(C(C)C)c(C(C)C)cc3c(=O)c3cc4c(cc32)c(=O)c2cc(C(C)C)c(C(C)C)cc2n4-c2c(C(C)C)cc(C(C)C)cc2C(C)C)c(C(C)C)c1]

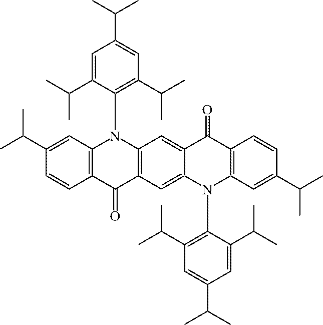 [SMILES: CC(C)c1cc(C(C)C)c(-n2c3cc(C(C)C)ccc3c(=O)c3cc4c(cc32)c(=O)c2ccc(C(C)C)cc2n4-c2c(C(C)C)cc(C(C)C)cc2C(C)C)c(C(C)C)c1]

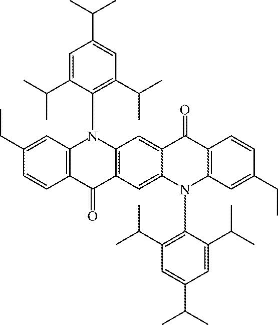 [SMILES: CCc1ccc2c(=O)c3cc4c(cc3n(-c3c(C(C)C)cc(C(C)C)cc3C(C)C)c2c1)c(=O)c1ccc(CC)cc1n4-c1c(C(C)C)cc(C(C)C)cc1C(C)C]

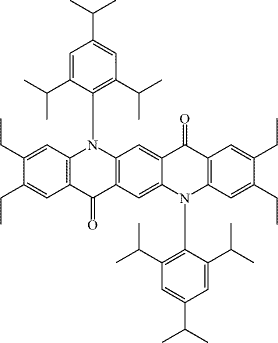 [SMILES: CCc1cc2c(=O)c3cc4c(cc3n(-c3c(C(C)C)cc(C(C)C)cc3C(C)C)c2cc1CC)c(=O)c1cc(CC)c(CC)cc1n4-c1c(C(C)C)cc(C(C)C)cc1C(C)C]

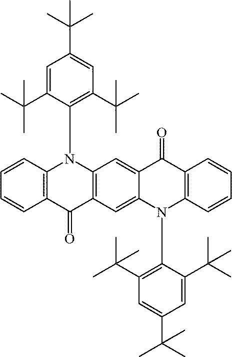 [SMILES: CC(C)(C)c1cc(C(C)(C)C)c(-n2c3ccccc3c(=O)c3cc4c(cc32)c(=O)c2ccccc2n4-c2c(C(C)(C)C)cc(C(C)(C)C)cc2C(C)(C)C)c(C(C)(C)C)c1]

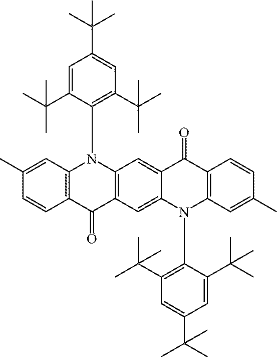

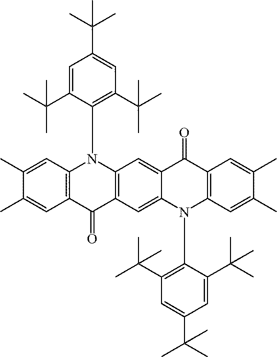

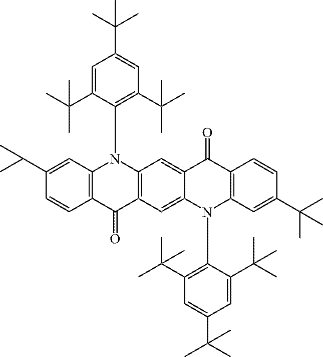 [SMILES: CC(C)c1ccc2c(=O)c3cc4c(cc3n(-c3c(C(C)(C)C)cc(C(C)(C)C)cc3C(C)(C)C)c2c1)c(=O)c1ccc(C(C)(C)C)cc1n4-c1c(C(C)(C)C)cc(C(C)(C)C)cc1C(C)(C)C]

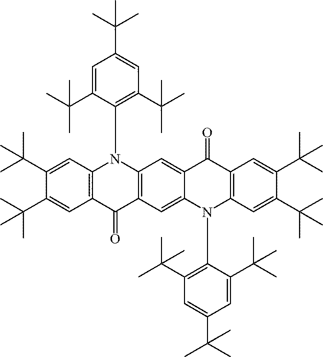 [SMILES: CC(C)(C)c1cc(C(C)(C)C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C(C)(C)C)cc(C(C)(C)C)cc2C(C)(C)C)c(C(C)(C)C)c1]

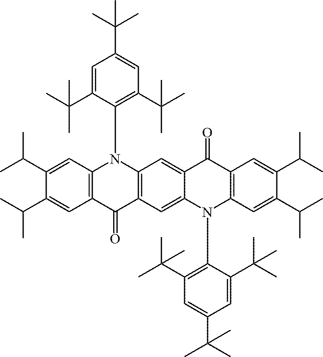 [SMILES: CC(C)c1cc2c(=O)c3cc4c(cc3n(-c3c(C(C)(C)C)cc(C(C)(C)C)cc3C(C)(C)C)c2cc1C(C)C)c(=O)c1cc(C(C)C)c(C(C)C)cc1n4-c1c(C(C)(C)C)cc(C(C)(C)C)cc1C(C)(C)C]

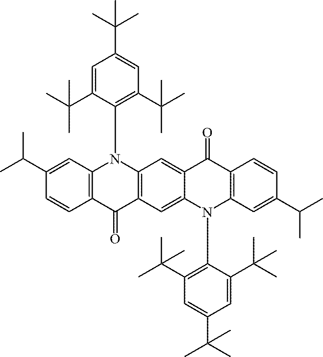 [SMILES: CC(C)c1ccc2c(=O)c3cc4c(cc3n(-c3c(C(C)(C)C)cc(C(C)(C)C)cc3C(C)(C)C)c2c1)c(=O)c1ccc(C(C)C)cc1n4-c1c(C(C)(C)C)cc(C(C)(C)C)cc1C(C)(C)C]

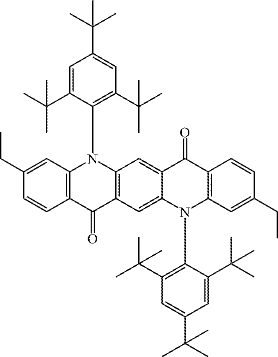 [SMILES: CCc1ccc2c(=O)c3cc4c(cc3n(-c3c(C(C)(C)C)cc(C(C)(C)C)cc3C(C)(C)C)c2c1)c(=O)c1ccc(CC)cc1n4-c1c(C(C)(C)C)cc(C(C)(C)C)cc1C(C)(C)C]

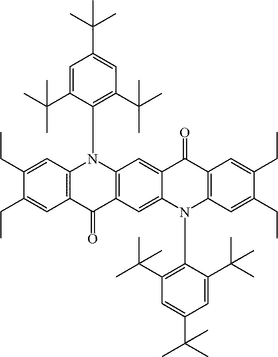 [SMILES: CCc1cc2c(=O)c3cc4c(cc3n(-c3c(C(C)(C)C)cc(C(C)(C)C)cc3C(C)(C)C)c2cc1CC)c(=O)c1cc(CC)c(CC)cc1n4-c1c(C(C)(C)C)cc(C(C)(C)C)cc1C(C)(C)C]

As described above, the phosphorescent dopant represented by Chemical Formula 1 is introduced with a substituent W including at least one of a cyano group, a nitro group and a halogen group at a specific site. These substituents W serve as acceptors. The phosphorescent dopant represented by Chemical Formula 1 and introduced with the substituent W as an acceptor at a specific site shifts an emission peak wavelength to a short wavelength range compared to a compound without an acceptor. Therefore, the difference between a maximum emission peak wavelength of the phosphorescent dopant represented by Chemical Formula 1 and a maximum absorption peak wavelength of the luminous dopant represented by Chemical Formula 2 can be reduced. Also, an emission peak of the phosphorescent dopant represented by Chemical Formula 1 may overlap with an absorption peak of the fluorescent dopant represented by Chemical Formula 2. In this case, energy transfer between the materials of the emission layer EML can be facilitated, and, thus, the luminous efficiency can be improved.

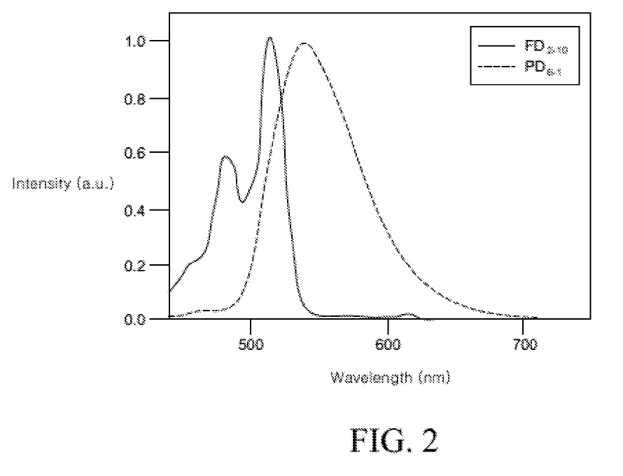

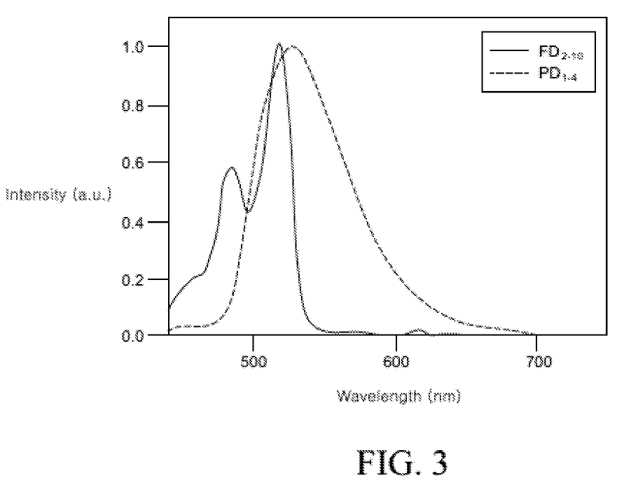

Hereinafter, the effect of the present disclosure will be described in more detail with reference to FIG. 2 and FIG. 3. FIG. 2 is a graph showing an absorption spectrum of a fluorescent dopant represented by Chemical Formula 2 and an emission spectrum of a phosphorescent dopant without a substituent W serving as an acceptor. FIG. 3 is a graph showing the absorption spectrum of the fluorescent dopant represented by Chemical Formula 2 and an emission spectrum of a phosphorescent dopant represented by Chemical Formula 1. Specifically, FIG. 2 is a graph showing an absorption spectrum (FD₂₋₁₀) of Compound 2-10, which is a fluorescent dopant, and an emission spectrum (PD₆₋₁) of Compound 6-1, which is a phosphorescent dopant. FIG. 3 is a graph showing the absorption spectrum (FD₂₋₁₀) of Compound 2-10, which is a fluorescent dopant, and an emission spectrum (PD₁₋₄) of Compound 1-4, which is a phosphorescent dopant.

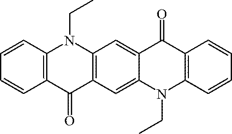 [SMILES: CCn1c2ccccc2c(=O)c2cc3c(cc21)c(=O)c1ccccc1n3CC]

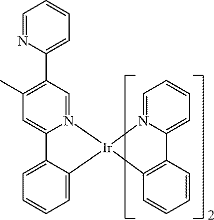

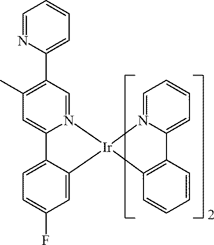

First, referring to FIG. 2, a maximum absorption peak wavelength of Compound 2-10 is 516 nm and a maximum emission peak wavelength of Compound 6-1 is 540 nm. The difference between the peak wavelengths is 24 nm. It can be seen that an overlap area between an absorption peak of Compound 2-10 and an emission peak of Compound 6-1 is 31% of the entire area thereof.

Referring to FIG. 3, Compound 1-4 is introduced with a substituent —F at a specific site, and the substituent —F serves as an acceptor. Thus, it can be seen that Compound 1-4 shifts an emission peak wavelength to a short wavelength range compared to Compound 6-1. In this case, a maximum emission peak wavelength of Compound 1-4 is 526 nm. Therefore, the difference between the maximum emission peak wavelength of Compound 1-4 and the maximum absorption peak wavelength of Compound 2-10 is reduced to 10 nm. In this case, an overlap area between the absorption peak of Compound 2-10 and an emission peak of Compound 1-4 is greatly increased to 40% of the entire area thereof. As such, if a peak overlap intensity between an emission peak of the phosphorescent dopant and an absorption peak of the fluorescent dopant increases, energy can be transferred effectively without energy loss. Therefore, the luminous efficiency is increased.

For example, the difference between a maximum emission peak wavelength of the phosphorescent dopant represented by Chemical Formula 1 and a maximum absorption peak wavelength of the fluorescent dopant represented by Chemical Formula 2 may be 5 nm to 20 nm. If the difference is in this range, an emission peak of the phosphorescent dopant and an absorption peak of the fluorescent dopant may have a large overlap area. Thus, the luminous efficiency can be greatly improved.

For example, an overlap area between an emission peak of the phosphorescent dopant represented by Chemical Formula 1 and an absorption peak of the fluorescent dopant represented by Chemical Formula 2 may be 35% or more of the entire area of the emission peak and the absorption peak. If the overlap area is in this range, energy transfer efficiency may be improved. Thus, the luminous efficiency can be greatly improved.

Meanwhile, the energy level of each of the host, the phosphorescent dopant represented by Chemical Formula 1 and the fluorescent dopant represented by Chemical Formula 2 of the emission layer EML needs to be adjusted appropriately. In this case, the luminous efficiency can be improved without increasing a driving voltage.

For example, a highest occupied molecular orbital energy level HOMO_{FD} of the fluorescent dopant represented by Chemical Formula 2 may be equal to or higher than a highest occupied molecular orbital energy level HOMO_{PD} of the phosphorescent dopant represented by Chemical Formula 1.

For example, the difference between a lowest unoccupied molecular orbital energy level LUMO_{FD} of the fluorescent dopant represented by Chemical Formula 2 and a lowest unoccupied molecular orbital energy level LUMO_{PD} of the phosphorescent dopant represented by Chemical Formula 1 may satisfy Inequation A.

$$0.1 \geq \text{LU} \text{} {\text{MO}}_{\text{FD}} \text{-} {\text{LUMO}}_{\text{PD}} \geq \text{-} \text{0} \text{.6}$$

For example, a singlet energy level S1^{H} of the host, a singlet energy level S1^{PD} of the phosphorescent dopant and a singlet energy level S1^{FD} of the fluorescent dopant may satisfy Inequation B.

$${\text{S1}}^{\text{H}} > {\text{S1}}^{\text{PD}} > {\text{S1}}^{\text{FD}}$$

For example, a triplet energy level T1^{H} of the host, a triplet energy level T1^{PD} of the phosphorescent dopant and a triplet energy level T1^{FD} of the fluorescent dopant may satisfy Inequation C.

$${\text{T1}}^{\text{H}} > {\text{T1}}^{\text{PD}} > {\text{T1}}^{\text{FD}}$$

If the respective energy levels of the host, the phosphorescent dopant represented by Chemical Formula 1 and the fluorescent dopant represented by Chemical Formula 2 satisfy the above requirements, energy transfer between the luminous materials can be facilitated. Also, reverse charge shift of excitons of the triplet energy level of the phosphorescent dopant to excitons of the triplet energy level of the host is suppressed. Thus, non-emission annihilation can be minimized. Accordingly, the luminous efficiency of the emission layer EML can be greatly improved.

The phosphorescent dopant represented by Chemical Formula 1 and the fluorescent dopant represented by Chemical Formula 2 may be mixed at a weight ratio of 7:3 to 10:1. If the weight ratio is in this range, the luminous efficiency can be further improved.

In the organic light emitting diode OLED according to an exemplary aspect of the present disclosure, the emission layer EML is formed by mixing the fluorescent dopant with the phosphorescent dopant including an acceptor at a specific site. Accordingly, energy loss during an emission process can be minimized and energy transfer efficiency can be improved. Therefore, the luminous efficiency can be improved.

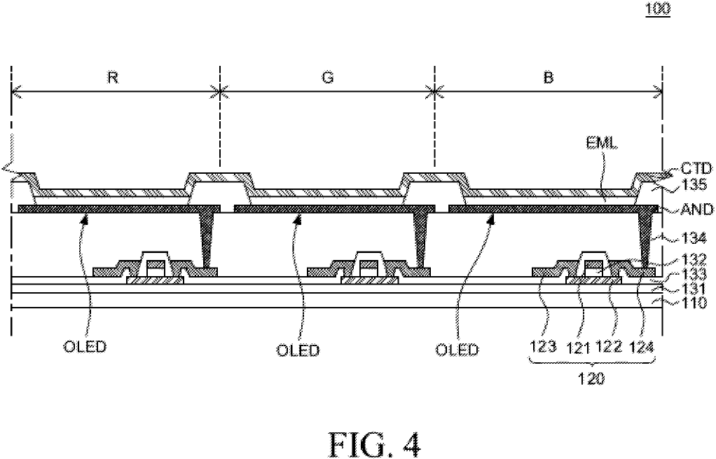

Hereinafter, an organic light emitting display device having an organic light emitting diode of the present disclosure will be described with reference to FIG. 4. FIG. 4 is a schematic cross-sectional view of an organic light emitting display device according to an exemplary aspect of the present disclosure. The hole injection layer, the hole transport layer, the electron transport layer and the electron injection layer of the organic light emitting diode OLED are not illustrated in FIG. 4 for the convenience of description. However, the organic light emitting diode OLED of an organic light emitting display device 100 illustrated in FIG. 4 is substantially the same as the organic light emitting diode OLED illustrated in FIG. 1. Therefore, a redundant description of the organic light emitting diode OLED will be omitted.

Referring to FIG. 4, the organic light emitting display device 100 according to an exemplary aspect of the present disclosure may be divided into a display area and a non-display area. The display area refers to an area where a plurality of pixels is disposed and an image is substantially displayed. In the display area, pixels including an emission area for displaying an image and a driving circuit for driving the pixels may be disposed. The non-display area encloses the display area. The non-display area refers to an area where an image is not substantially displayed and various lines and printed circuit boards for driving the pixels and driving circuits disposed in the display area are disposed.

The plurality of pixels may be disposed in a matrix form, and each of the plurality of pixels includes a plurality of sub-pixels. Each sub-pixel is an element for displaying a single color, and includes an emission area from which light is emitted and a non-emission area from which light is not emitted. Each of the plurality of sub-pixels may be any one of a red sub-pixel R, a green sub-pixel G, a blue sub-pixel B and a white sub-pixel.

FIG. 4 illustrates that the organic light emitting display device 100 is driven in a top emission type, but the present disclosure is not limited thereto.

A substrate 110 serves to support various elements of the organic light emitting display device 100. The substrate 110 may be a glass substrate or a plastic substrate.

A buffer layer 131 is disposed on the substrate 110. The buffer layer 131 protects various elements of the organic light emitting display device 100 against permeation of oxygen or moisture from the outside and suppresses introduction of foreign materials on the substrate 110 into a thin film transistor 120.

The thin film transistor 120 including a gate electrode 121, an active layer 122, a source electrode 123 and a drain electrode 124 is disposed on the buffer layer 131. The thin film transistor 120 is formed in each of the red sub-pixel R, the green sub-pixel G and the blue sub-pixel B.

Specifically, the active layer 122 is disposed on the substrate 110, and a gate insulating layer 132 for insulating the active layer 122 from the gate electrode 121 is disposed on the active layer 122. Also, an interlayer insulating layer 133 for insulating the gate electrode 121 from the source electrode 123 and the drain electrode 124 is disposed on the buffer layer 131. The source electrode 123 and the drain electrode 124 each in contact with the active layer 122 are disposed on the interlayer insulating layer 133.

An overcoating layer 134 may be disposed on the thin film transistor 120. The overcoating layer 134 flattens an upper portion of the substrate 110 disposed thereunder. The overcoating layer 134 may include a contact hole for electrically connecting the thin film transistor 120 to an anode AND of the organic light emitting diode OLED.

The organic light emitting diode OLED is disposed on the overcoating layer 134. The organic light emitting diode OLED is disposed in each of the red sub-pixel R, the green sub-pixel G and the blue sub-pixel B. The organic light emitting diode OLED disposed in each sub-pixel includes the anode AND, the emission layer EML and the cathode CTD.

The anode AND may be formed separately for each of the red sub-pixel R, the green sub-pixel G and the blue sub-pixel B. A bank 135 is disposed on the anode AND and the overcoating layer 134 to distinguish adjacent sub-pixels. Also, the bank 135 may distinguish a pixel composed of a plurality of sub-pixels. The bank 135 may be made of an insulating material to insulate the anodes AND of the adjacent sub-pixels from each other. Further, the bank 135 may be configured as a black bank 135 having a high light absorptivity to avoid color mixing between the adjacent sub-pixels.

As described above, the emission layer EML includes the host, the phosphorescent dopant represented by Chemical Formula 1 and the fluorescent dopant represented by Chemical Formula 2. The emission layer EML may be patterned for each sub-pixel. The emission layer EML patterned for each sub-pixel may be configured to emit light of a color corresponding to a color of a corresponding sub-pixel. For example, the emission layer EML disposed in the red sub-pixel R includes a dopant that emits red light. Also, the emission layer EML disposed in the green sub-pixel G includes a dopant that emits green light. Further, the emission layer EML disposed in the blue sub-pixel B includes a dopant that emits blue light.

The cathode CTD is not patterned, but formed as one layer on the emission layer EML. That is, the cathode CTD is formed as one layer on the entire sub-pixel area. If the organic light emitting display device 100 is driven in a top emission type, the cathode CTD is formed to a very small thickness and thus is substantially transparent.

In the organic light emitting display device 100 according to an exemplary aspect of the present disclosure, the emission layer EML includes the host, the phosphorescent dopant represented by Chemical Formula 1 and the fluorescent dopant represented by Chemical Formula 2. The phosphorescent dopant represented by Chemical Formula 1 is introduced with an acceptor and thus shifts an emission peak wavelength to a short wavelength range. Thus, an emission peak of the phosphorescent dopant represented by Chemical Formula 1 overlaps with an absorption peak of the fluorescent dopant represented by Chemical Formula 2 with a large overlap area. Accordingly, the energy transfer efficiency between the fluorescent dopant and the phosphorescent dopant can be improved, which results in excellent luminous efficiency.

Hereinafter, the above-described effects of the present disclosure will be described in more detail with reference to Examples and Comparative Examples. However, the following Examples are provided for the purpose of illustration, but do not limit the scope of the present disclosure.

### [Synthesis Example 1] Synthesis of Compound 1-4

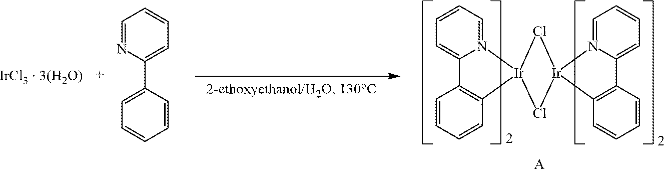

Iridium chloride hydrate (8.00 g, 26.79 mmol), 2-phenylpyridine (20.79 g, 133.97 mmol) and a mixed solvent (2-ethoxyethanol:H₂O = 90 ml:30 ml) were put into a 250 mL round bottom flask under a nitrogen atmosphere and stirred at 130° C. for 24 hours. After completion of the reaction, the temperature was lowered to room temperature, and the produced solid in methanol was vacuum-filtered to obtain 9.9 g of a solid intermediate A (69%).

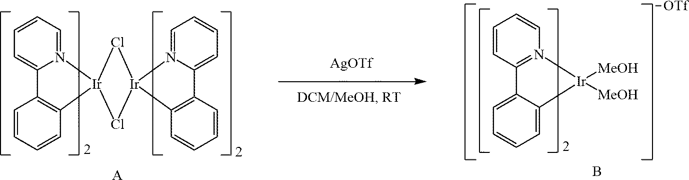

The intermediate A (9.00 g, 8.39 mmol), silver trifluoromethanesulfonate (AgOTf) (6.47 g, 25.28 mmol) and a mixed solvent (dichloromethane:MeOH = 500 ml:50 ml) were put into a 1000 mL round bottom flask under a nitrogen atmosphere and stirred at room temperature for 24 hours. After completion of the reaction, the mixture was filtered with celite to remove the solid, and the solvent was removed by vacuum distillation to obtain 9.0 g of a solid intermediate B (75%).

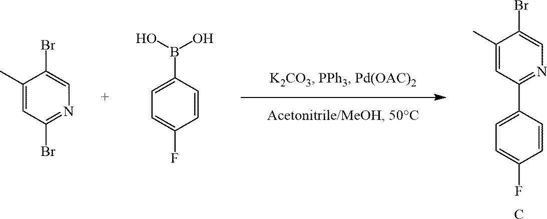

2,5-dibromo-4-methylpyridine (4.00 g, 18.94 mmol), (4-fluorophenyl)boronic acid (2.57 g, 18.33 mmol), K₂CO₃ (4.41 g, 31.88 mmol), triphenylphosphine (PPh₃) (0.84 g, 3.19 mmol), palladium(II) acetate [Pd(OAC)₂] (0.36 g, 1.59 mmol) and a mixed solvent (acetonitrile:MeOH = 100 ml:50 ml) were put into a 250 mL round bottom flask under a nitrogen atmosphere and stirred at 50° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 3.3 g of a solid intermediate C (78%).

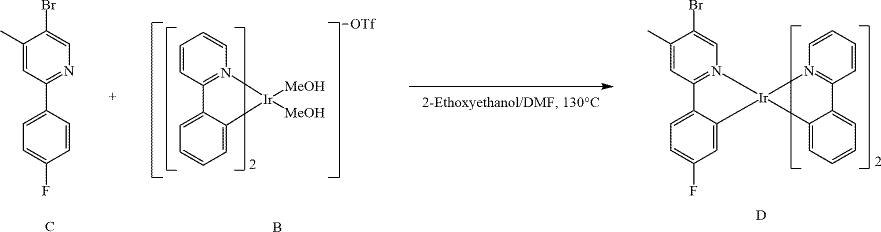

The intermediate C (2.90 g, 10.51 mmol), the intermediate B (3.00 g, 4.20 mmol) and a mixed solvent (2-ethoxyethanol:DMF = 75 ml:75 ml) were put into a 100 mL round bottom flask under a nitrogen atmosphere and stirred at 130° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 2.1 g of a solid intermediate D (65%).

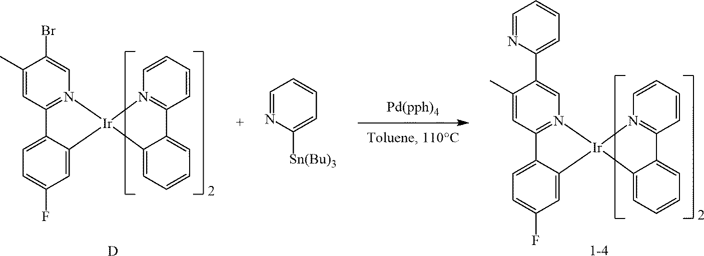

The intermediate D (2.00 g, 2.61 mmol), 2-(tributylstannyl)pyridine (1.92 g, 5.22 mmol), tetrakis(triphenylphosphine)palladium [Pd(pph)₄] (0.48 g, 0.52 mmol) and toluene (50 ml) were put into a 100 mL round bottom flask under a nitrogen atmosphere and stirred at 110° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 1.6 g of a solid compound 1-4 (81%).

### [Synthesis Example 2] Synthesis of Compound 1-26

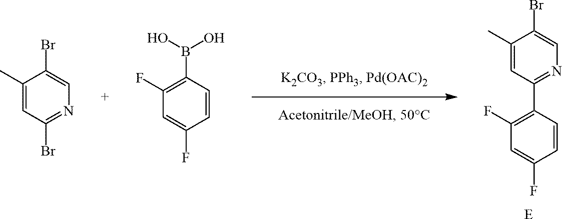

2,5-dibromo-4-methylpyridine (4.00 g, 15.94 mmol), 2,4-difluorophenyl)boronic acid (2.89 g, 18.33 mmol, K₂CO₃ (4.41 g, 31.88 mmol), PPh₃ (0.84 g, 3.19 mmol), Pd(OAC)₂ (0.36 g, 1.59 mmol) and a mixed solvent (acetonitrile:MeOH = 100 ml:50 ml) were put into a 250 mL round bottom flask under a nitrogen atmosphere and stirred at 50° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 3.3 g of a solid intermediate E (72%).

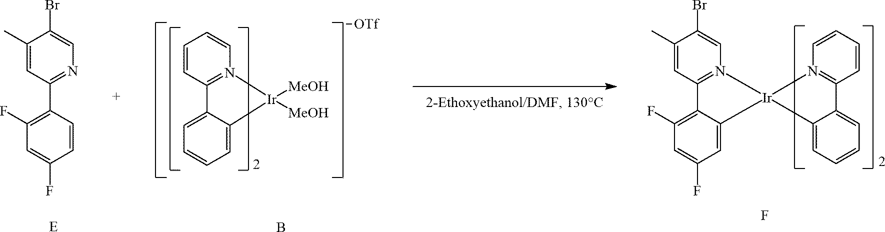

The intermediate E (2.99 g, 10.51 mmol), the intermediate B (3.00 g, 4.20 mmol) and a mixed solution (2-ethoxyethanol:dimethylformamide = 75 ml:75 ml) were put into a 100 mL round bottom flask under a nitrogen atmosphere and stirred at 130° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 2.1 g of a solid intermediate F (63%).

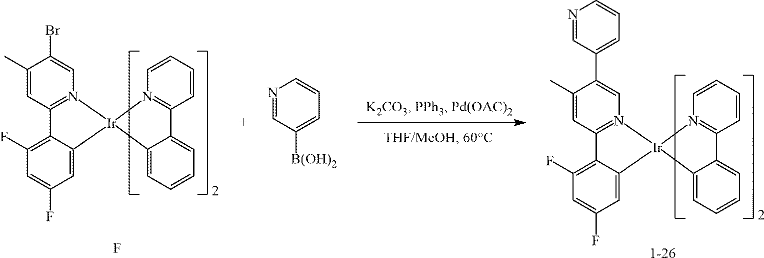

The intermediate F (2.00 g, 2.55 mmol), (pyridin-3-yl)boronic acid (1.57 g, 12.76 mmol), K₂CO₃ (0.71 g, 5.1 mmol), PPh₃ (0.13 g, 0.51 mmol), Pd(OAC)₂ (0.06 g, 0.26 mmol) and a mixed solvent (THF:MeOH = 100 ml:50 ml) were put into a 250 mL round bottom flask under a nitrogen atmosphere and stirred at 60° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 1.6 g of a solid compound 1-26 (78%).

### [Synthesis Example 3] Synthesis of Compound 1-27

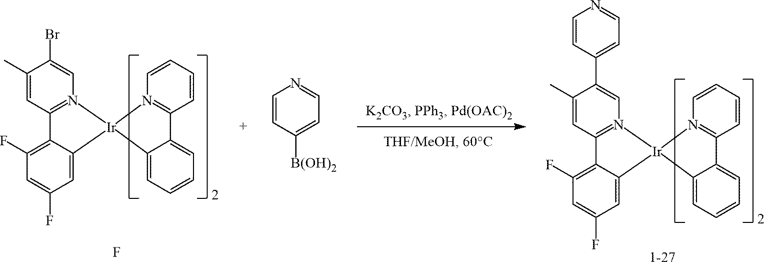

The intermediate F (2.00 g, 2.55 mmol), (pyridin-4-yl)boronic acid (1.57 g, 12.76 mmol), K₂CO₃ (0.71 g, 5.10 mmol), PPh₃ (0.13 g, 0.51 mmol), Pd(OAC)₂ (0.06 g, 0.26 mmol) and a mixed solvent (THF:MeOH = 100 ml:50 ml) were put into a 250 mL round bottom flask under a nitrogen atmosphere and stirred at 60° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 1.3 g of a solid compound 1-27 (67%).

### [Synthesis Example 4] Synthesis of Compound 1-70

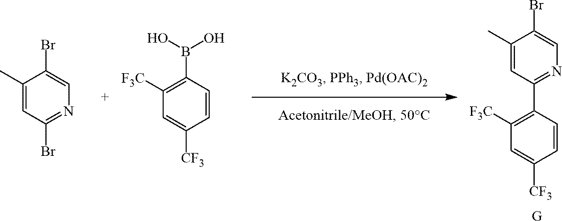

2,5-dibromo-4-methylpyridine (4.00 g, 15.94 mmol), (2,4-bis(trifluoromethyl)phenyl) boronic acid (4.73 g, 18.33 mmol), K₂CO₃ (4.41 g, 31.88 mmol), PPh₃ (0.84 g, 3.19 mmol), Pd(OAC)₂ (0.36 g, 1.59 mmol) and a mixed solvent (acetonitrile:MeOH = 100 ml:50 ml) were put into a 250 mL round bottom flask under a nitrogen atmosphere and stirred at 50° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 4.7 g of a solid intermediate G (77%).

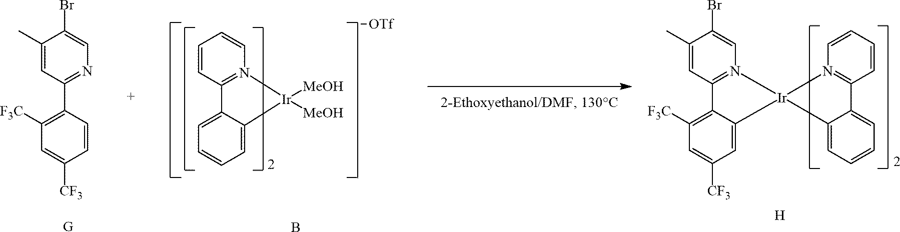

The intermediate G (4.04 g, 10.51 mmol), the intermediate B (3.00 g, 4.20 mmol) and a mixed solvent (2-ethoxyethanol:DMF = 75 ml:75 ml) were put into a 100 mL round bottom flask under a nitrogen atmosphere and stirred at 130° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 2.5 g of a solid intermediate H (68%).

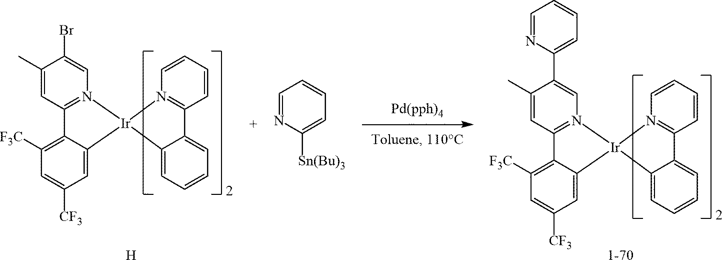

The intermediate H (2.00 g, 2.26 mmol), 2-(tributylstannyl)pyridine (1.67 g, 4.53 mmol), Pd(pph)₄ (0.41 g, 0.45 mmol) and toluene (50 ml) were put into a 100 mL round bottom flask under a nitrogen atmosphere and stirred at 110° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 1.4 g of a solid compound 1-70 (68%).

### [Synthesis Example 5] Synthesis of Compound 1-96

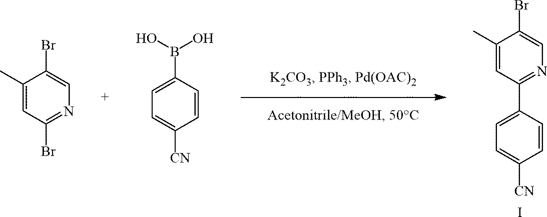

2,5-dibromo-4-methylpyridine (4.00 g, 15.94 mmol), (4-cyanophenyl)boronic acid (2.69 g, 18.33 mmol), K₂CO₃ (4.41 g, 31.88 mmol), PPh₃ (0.84 g, 3.19 mmol), Pd(OAC)₂ (0.36 g, 1.59 mmol) and a mixed solvent (acetonitrile:MeOH = 100 ml:50 ml) were put into a 250 mL round bottom flask under a nitrogen atmosphere and stirred at 50° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 3.3 g of a solid intermediate I (75%).

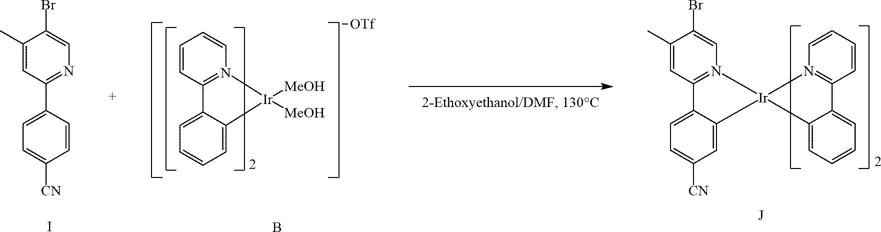

The intermediate I (2.87 g, 10.51 mmol) and the intermediate B (.00 g, 4.20 mmol) were added into a mixed solution (2-ethoxyethanol:DMF = 75 ml:75 ml) in a 100 mL round bottom flask under a nitrogen atmosphere and stirred at 130° C. for 24 hours. After completion of the reaction, the temperature was lowered to room temperature, and an organic layer was extracted with dichloromethane and distilled water. The water was removed by adding magnesium sulfate anhydrous. The filtrate obtained through filtration was depressurized to obtain a crude product. The crude product was purified by column chromatography using toluene and hexane to obtain 2.3 g of a solid intermediate J (71%).

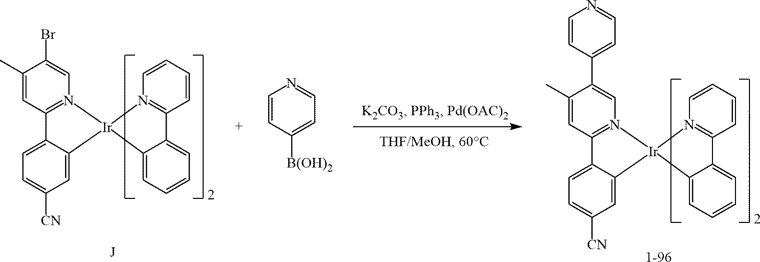

The intermediate J (2.00 g, 2.59 mmol), (pyridine-4-yl)boronic acid (1.59 g, 12.94 mmol), K₂CO₃ (0.72 g, 5.18 mmol), PPh₃ (0.14 g, 0.52 mmol), Pd(OAC)₂ (0.06 g, 0.26 mmol) and a mixed solvent (THF:MeOH = 100 ml:50 ml) were put into a 250 mL round bottom flask under a nitrogen atmosphere and stirred at 60° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 1.4 g of a solid compound 1-96 (69%).

### [Synthesis Example 6] Synthesis of Compound 2-10

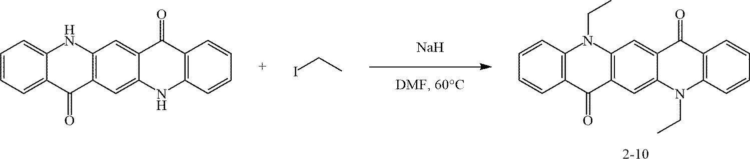

Quinolino[2,3-b]acridine-7,14(5H,12H)-dione (2.00 g, 6.40 mmol) and DMF (50 ml) were put into a 100 mL round bottom flask under a nitrogen atmosphere and dissolved, followed by addition of NaH (0.38 g, 16.01 mmol) at 0° C. After the reaction mixture was stirred at 60° C. for 30 minutes, iodoethane (2.50 g, 16.01 mmol) was added into the mixture and stirred at 60° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and dissolved in dichloromethane and recrystallized with methanol to obtain 1.6 g of a solid compound 2-10 (68%).

### [Synthesis Example 7] Synthesis of Compound 2-28

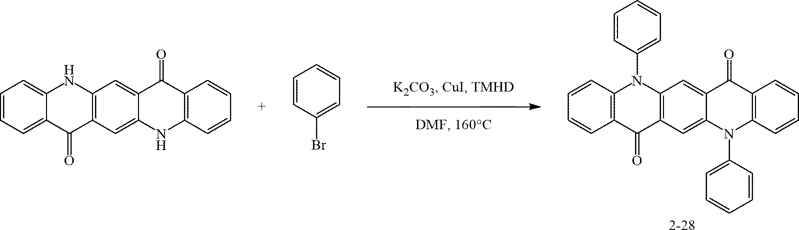

Quinolino[2,3-b]acridine-7,14(5H,12H)-dione (2.00 g, 6.40 mmol), bromobenzne (1.11 g, 7.04 mmol), K₂CO₃ (1.77 g, 12.81 mmol), copper iodide (CuI) (0.12 g, 0.64 mmol), 2,2,6,6-tetramethyl-3,5-heptanedione (0.24 g, 1.28 mmol) and DMF (100 ml) were put into a 250 mL round bottom flask under a nitrogen atmosphere and stirred at 160° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 2.0 g of a solid compound 2-28 (68%).

### [Synthesis Example 8] Synthesis of Compound 2-73

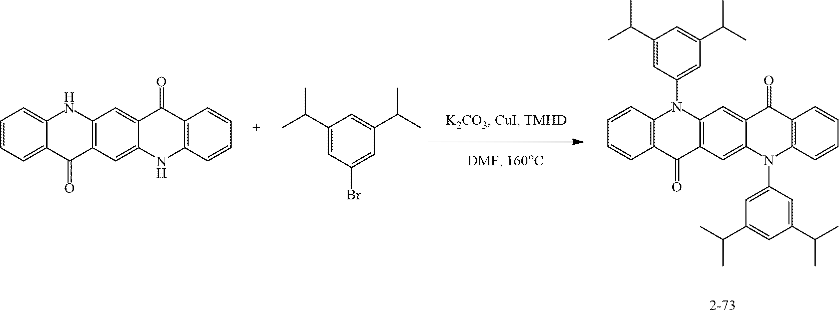

Quinolino[2,3-b]acridine-7,14(5H,12H)-dione (2.00 g, 6.40 mmol), 1-bromo-3,5-diisopropylbenzene (1.70 g, 7.04 mmol), K₂CO₃ (1.77 g, 12.81 mmol), CuI (0.12 g, 0.64 mmol), 2,2,6,6-tetramethyl-3,5-heptanedione (0.24 g, 1.28 mmol) and DMF (100 ml) were put into a 250 mL round bottom flask under a nitrogen atmosphere and stirred at 160° C. for 24 hours. After completion of the reaction, the temperature was lowered to room temperature, and an organic layer was extracted with dichloromethane and sufficiently washed with water. After the water was removed by magnesium sulfate anhydrous, the filtered solution was vacuum-concentrated and then separated by column chromatography using ethyl acetate and hexane to obtain 2.6 g of a solid compound 2-73 (64%).

### [Example 1] Fabrication of Organic Light Emitting Diode

First, an ITO (70 µm)-attached glass substrate of 40 mm × 40 mm × thickness 0.5 mm was ultrasonic washed with each of isopropyl alcohol, acetone and distilled water for 5 minutes and then dried in an oven at 100° C. The substrate was treated with O₂ plasma under vacuum for 2 minutes and then was transferred to a deposition chamber in order to deposit other layers on the substrate. Each layer was deposited by evaporation by a heated boat under about 10⁻⁷ torr. In this case, a deposition rate was set to 1 Å. Specifically, an organic light emitting diode was fabricated by sequentially laminating a hole injection layer (Chemical Formula 5-1, 10 nm), a hole transport layer (Chemical Formula 5-2, 140 nm), an electron blocking layer (Chemical Formula 5-3, 10 nm), an emission layer (40 nm), a hole blocking layer (Chemical Formula 5-4, 10 nm), an electron transport layer (Chemical Formula 5-5, 30 nm), an electron injection layer (Liq, 1 nm) and a cathode (Mg:Ag, 10 nm) on the ITO substrate. In this case, the emission layer was formed by mixing Compound 3-1 (89 wt%) represented by Chemical Formula 3, Compound 1-4 (10 wt%) and Compound 2-10 (1 wt%).

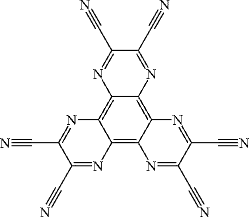 [SMILES: N#Cc1nc2c3nc(C#N)c(C#N)nc3c3nc(C#N)c(C#N)nc3c2nc1C#N]

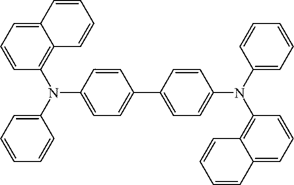 [SMILES: c1ccc(N(c2ccc(-c3ccc(N(c4ccccc4)c4cccc5ccccc45)cc3)cc2)c2cccc3ccccc23)cc1]

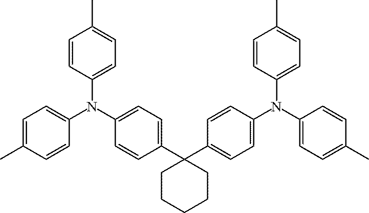

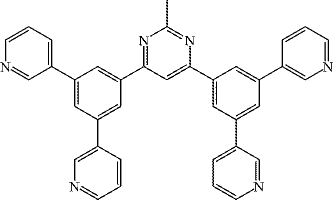 [SMILES: Cc1nc(-c2cc(-c3cccnc3)cc(-c3cccnc3)c2)cc(-c2cc(-c3cccnc3)cc(-c3cccnc3)c2)n1]

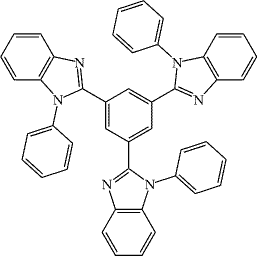 [SMILES: c1ccc(-n2c(-c3cc(-c4nc5ccccc5n4-c4ccccc4)cc(-c4nc5ccccc5n4-c4ccccc4)c3)nc3ccccc32)cc1]

### Example 2

An organic light emitting diode was fabricated in the same manner as in Example 1 except that Compound 1-26 (10 wt%) was used instead of Compound 1-4 (10 wt%) when the emission layer was formed.

### Example 3

An organic light emitting diode was fabricated in the same manner as in Example 1 except that Compound 1-27 (10 wt%) was used instead of Compound 1-4 (10 wt%) when the emission layer was formed.

### Example 4

An organic light emitting diode was fabricated in the same manner as in Example 1 except that Compound 1-70 (10 wt%) was used instead of Compound 1-4 (10 wt%) when the emission layer was formed.

### Example 5

An organic light emitting diode was fabricated in the same manner as in Example 1 except that Compound 1-96 (10 wt%) was used instead of Compound 1-4 (10 wt%) when the emission layer was formed.

### Example 6

An organic light emitting diode was fabricated in the same manner as in Example 1 except that Compound 2-28 (1 wt%) was used instead of Compound 2-10 (1 wt%) when the emission layer was formed.

### Example 7

An organic light emitting diode was fabricated in the same manner as in Example 1 except that Compound 2-73 (1 wt%) was used instead of Compound 2-10 (1 wt%) when the emission layer was formed.

### Comparative Example 1

An organic light emitting diode was fabricated in the same manner as in Example 1 except that Compound 6-1 (10 wt%) was used instead of Compound 1-4 (10 wt%) when the emission layer was formed.

### Comparative Example 2

An organic light emitting diode was fabricated in the same manner as in Example 1 except that Compound 6-2 (10 wt%) was used instead of Compound 1-4 (10 wt%) when the emission layer was formed.

### Comparative Example 3

An organic light emitting diode was fabricated in the same manner as in Example 1 except that Compound 6-3 (10 wt%) was used instead of Compound 1-4 (10 wt%) when the emission layer was formed.

### Comparative Example 4

An organic light emitting diode was fabricated in the same manner as in Example 1 except that Compound 6-4 (10 wt%) was used instead of Compound 1-4 (10 wt%) when the emission layer was formed.

### Comparative Example 5

An organic light emitting diode was fabricated in the same manner as in Example 1 except that Compound 6-5 (10 wt%) was used instead of Compound 1-4 (10 wt%) when the emission layer was formed.

### Comparative Example 6

An organic light emitting diode was fabricated in the same manner as in Example 1 except that Compound 6-1 (10 wt%) was used instead of Compound 1-4 (10 wt%) and Compound 2-28 (1 wt%) was used instead of Compound 2-10 (1 wt%) when the emission layer was formed.

### Comparative Example 7

An organic light emitting diode was fabricated in the same manner as in Example 1 except that Compound 6-1 (10 wt%) was used instead of Compound 1-4 (10 wt%) and Compound 2-73 (1 wt%) was used instead of Compound 2-10 (1 wt%) when the emission layer was formed.

The compounds used as a phosphorescent dopant and a fluorescent dopant in Examples and Comparative Examples have the following Chemical Formulas, respectively.

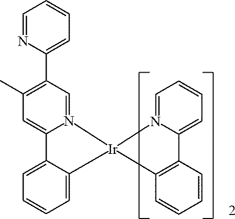

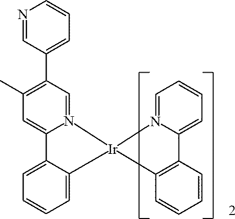

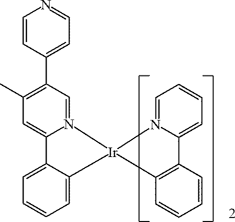

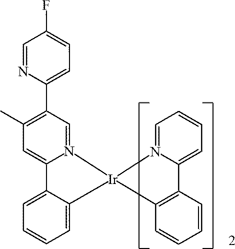

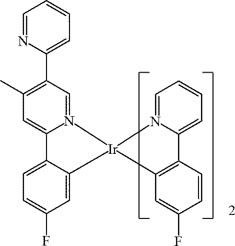

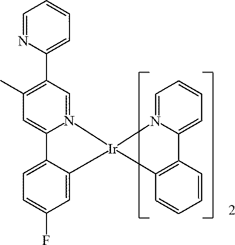

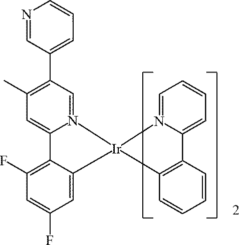

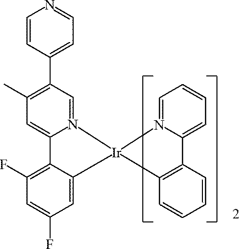

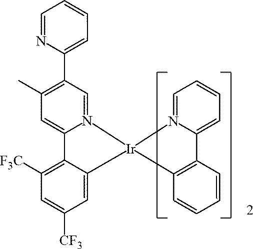

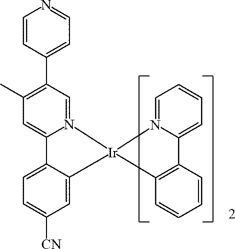

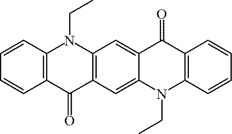 [SMILES: CCn1c2ccccc2c(=O)c2cc3c(cc21)c(=O)c1ccccc1n3CC]

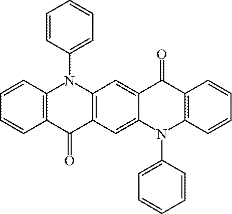 [SMILES: O=c1c2ccccc2n(-c2ccccc2)c2cc3c(=O)c4ccccc4n(-c4ccccc4)c3cc12]

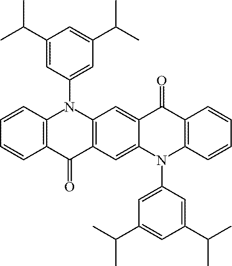 [SMILES: CC(C)c1cc(C(C)C)cc(-n2c3ccccc3c(=O)c3cc4c(cc32)c(=O)c2ccccc2n4-c2cc(C(C)C)cc(C(C)C)c2)c1]

### Experimental Example

First, emission spectra PD_{EL} of phosphorescent dopants PD and absorption spectra FD_{ads} of fluorescent dopants FD used in Example 1 to Example 7 and Comparative Example 1 to Comparative Example 7, respectively, were analyzed. Maximum emission peak wavelengths of the phosphorescent dopants and maximum absorption peak wavelengths of the fluorescent dopants are shown in the following Table 1. Also, overlap areas between emission peaks of the phosphorescent dopants and absorption peaks of the fluorescent dopants are shown in the following Table 1.

Also, characteristics of the organic light emitting diodes fabricated in Example 1 to Example 7 and Comparative Example 1 to Comparative Example 7 were measured. Each of the fabricated organic light emitting diodes was connected to an external power source. Then, characteristics of the diodes were evaluated using a current source (KEITHLEY) and a photometer (PR 650) at room temperature. A driving voltage (V) and a current efficiency (cd/A) of each diode were measured at a current density of 10 mA/cm². The results thereof are shown in the following Table 1.

TABLE 1

| | PD | FD | Driving Voltage [V] | Current Efficiency [cd/A] | λₘₐₓ [nm] | | Overlap Area [%] |
|---|---|---|---|---|---|---|---|
| | | | | | PD_{EL} | FD_{ads} | |
| Comparative Example 1 | 6-1 | 2-10 | 3.4 | 80 | 540 | 516 | 31 |
| Comparative Example 2 | 6-2 | | 3.4 | 64 | 552 | | 25 |
| Comparative Example 3 | 6-3 | | 3.5 | 40 | 568 | | 22 |
| Comparative Example 4 | 6-4 | | 3.5 | 72 | 550 | | 24 |
| Comparative Example 5 | 6-5 | | 3.4 | 100 | 498 | | 32 |
| Example 1 | 1-4 | | 3.5 | 142 | 526 | | 40 |
| Example 2 | 1-26 | | 3.4 | 136 | 528 | | 41 |
| Example 3 | 1-27 | | 3.5 | 132 | 535 | | 37 |
| Example 4 | 1-70 | | 3.4 | 128 | 530 | | 38 |
| Example 5 | 1-96 | | 3.3 | 118 | 536 | | 36 |
| Comparative Example 6 | 6-1 | 2-28 | 3.4 | 90 | 540 | 518 | 33 |
| Example 6 | 1-4 | | 3.4 | 144 | 526 | | 41 |
| Comparative Example 7 | 6-1 | 2-73 | 3.5 | 92 | 540 | 518 | 33 |
| Example 7 | 1-4 | | 3.4 | 138 | 526 | | 41 |

Referring to Table 1, it can be seen that in Example 1 to Example 7 where a dopant of the emission layer was formed by mixing the phosphorescent dopant compound represented by Chemical Formula 1 and the fluorescent dopant compound represented by Chemical Formula 2, the current efficiency is greatly improved with an equivalent driving voltage compared to Comparative Example 1 to Comparative Example 7.

It can be seen that by comparison with Example 1 to Example 7, the phosphorescent dopant compounds used in Comparative Example 1 to Comparative Example 7 have a maximum emission peak in a long wavelength range compared to the fluorescent dopants. Accordingly, it can be seen that Comparative Example 1 to Comparative Example 7 exhibit a small overlap area between an emission peak of the phosphorescent dopant and an absorption peak of the fluorescent dopant.

However, the phosphorescent dopant compounds used in Example 1 to Example 7 are introduced with an acceptor, such as a halogen group, a cyano group or a trifluoromethyl group, at a specific site. Thus, the phosphorescent dopant compounds used in Example 1 to Example 7 shift the peak wavelength to a short wavelength range compared to the phosphorescent dopant compounds used in Comparative Example 1 to Comparative Example 7. Thus, Examples 1 to 7 exhibit an increase in overlap area between an emission peak of the phosphorescent dopant and an absorption peak of the fluorescent dopant to 35% or more. Accordingly, it can be seen that the energy transfer efficiency between the fluorescent dopant and the phosphorescent dopant is improved, which results in great improvement in the characteristics of the diodes.

Meanwhile, Compound 6-4 used in Comparative Example 4 has the same chemical structure as Compound 1-4 used in Example 1 except a site of an acceptor “F”. However, it can be seen that there is a significant difference in current efficiency between 72 cd/A in Comparative Example 4 and 142 cd/A in Example 1. Also, Compound 6-5 used in Comparative Example 5 has the same chemical structure as Compound 1-27 used in Example 3 except a site of an acceptor “F”. However, it can be seen that there is a significant difference in current efficiency between 100 cd/A in Comparative Example 5 and 132 cd/A in Example 3. Accordingly, it can be seen that the effect of the present disclosure can be achieved only when an acceptor is introduced at a specific site as in the phosphorescent dopant represented by Chemical Formula 1.

The exemplary aspects of the present disclosure can also be described as follows:

According to an aspect of the present disclosure, an organic light emitting diode comprise an anode; an emission layer disposed on the anode and including a host, a phosphorescent dopant represented by the following Chemical Formula 1 and a fluorescent dopant represented by the following Chemical Formula 2; and a cathode disposed on the emission layer:

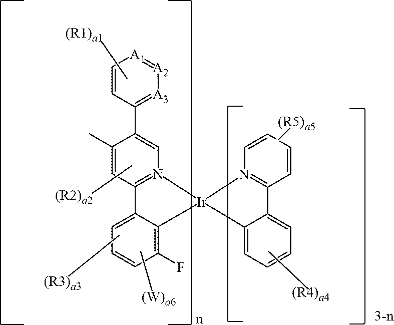

wherein in Chemical Formula 1, each of A1 to A3 is independently nitrogen or carbon, at least one of A1 to A3 is nitrogen, each of a1 and a3 to a5 is independently an integer of 0 to 4, a2 is an integer of 0 to 2, a6 is an integer of 1 to 4, and the sum of a3 and a6 is 4 or less, each of R1 to R5 is independently selected from hydrogen, deuterium, tritium, an alkyl group having 1 to 20 carbon atoms, an aryl group having 6 to 30 carbon atoms and a heteroaryl group having 3 to 40 carbon atoms, and each substituent may form a fused ring with a neighboring substituent, and W is selected from a cyano group, a nitro group, a halogen group, a substituted alkyl group having 1 to 20 carbon atoms, a substituted aryl group having 6 to 30 carbon atoms and a substituted heteroaryl group having 3 to 40 carbon atoms, and in this case, each of the substituted alkyl group, the substituted aryl group and the substituted heteroaryl group includes at least one substituent selected from a cyano group, a nitro group and a halogen group, and n is an integer of 0 to 3, and

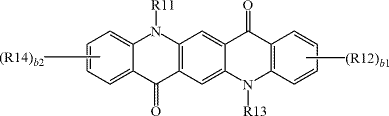

in Chemical Formula 2, each of b1 and b2 is independently an integer of 0 to 4, and each of R11 to R14 is selected from hydrogen, deuterium, tritium, an alkyl group having 1 to 20 carbon atoms, an aryl group having 6 to 30 carbon atoms and a heteroaryl group having 3 to 40 carbon atoms, and each substituent may form a fused ring with a neighboring substituent.

An emission peak of the phosphorescent dopant represented by Chemical Formula 1 may overlap with an absorption peak of the fluorescent dopant represented by Chemical Formula 2, and an overlap area between the emission peak and the absorption peak may be 35% or more of the entire area of the emission peak and the absorption peak.

The difference between a maximum emission peak wavelength of the phosphorescent dopant represented by Chemical Formula 1 and a maximum absorption peak wavelength of the fluorescent dopant represented by Chemical Formula 2 may be 5 nm to 20 nm.

The difference between a lowest unoccupied molecular orbital energy level LUMO_{FD} of the fluorescent dopant represented by Chemical Formula 2 and a lowest unoccupied molecular orbital energy level LUMO_{PD} of the phosphorescent dopant represented by Chemical Formula 1 may satisfy the following Inequation A:

[Inequation A] 0.1 ≥ LUMO_{FD} - LUMO_{PD} ≥ - 0.6.

A highest occupied molecular orbital energy level HOMO_{FD} of the fluorescent dopant represented by Chemical Formula 2 may be equal to or higher than a highest occupied molecular orbital energy level HOMO_{PD} of the phosphorescent dopant represented by Chemical Formula 1.

The phosphorescent dopant represented by Chemical Formula 1 may have an energy band gap of 2.0 eV to 3.0 eV.

In Chemical Formula 1, each of A1 to A3 may be independently nitrogen or carbon, one of A1 to A3 may be nitrogen, each of a1 to a5 may be 0, a6 may be an integer of 1 to 4, W may be selected from a cyano group, a nitro group, a halogen group and an alkyl group substituted with at least one substituent selected from a cyano group, a nitro group and a halogen group and having 1 to 20 carbon atoms, and n may be 1.

In Chemical Formula 2, each of b1 and b2 may be independently an integer of 0 to 2, each of R11 and R13 may be independently selected from an alkyl group having 1 to 20 carbon atoms and an aryl group having 6 to 30 carbon atoms, and each of R12 and R14 may be independently selected from hydrogen and an alkyl group having 1 to 20 carbon atoms.

The phosphorescent dopant may be selected from the following Compound 1-1 to Compound 1-315:

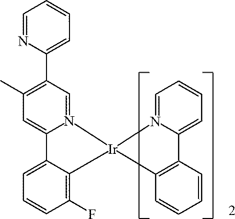

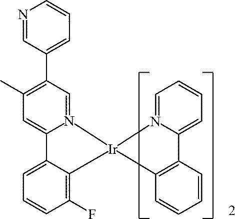

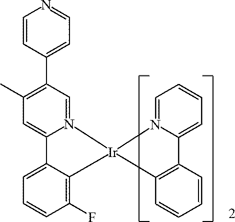

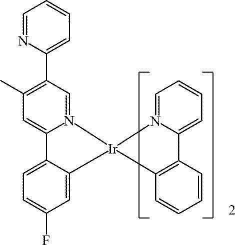

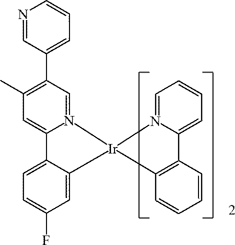

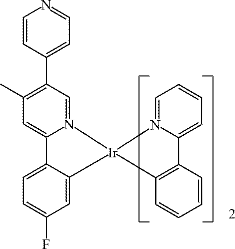

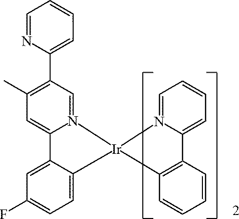

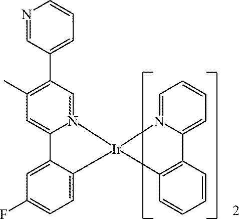

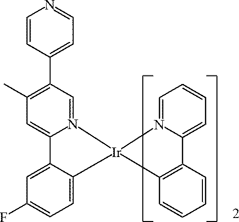

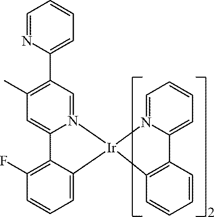

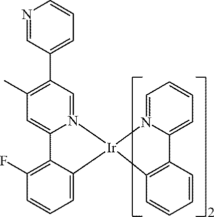

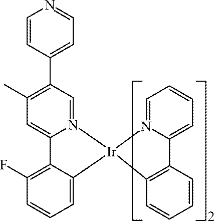

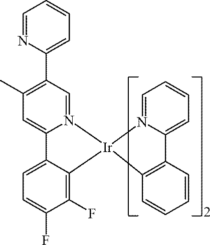

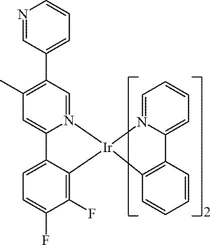

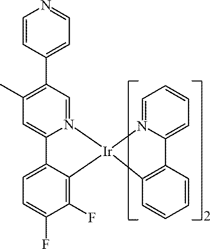

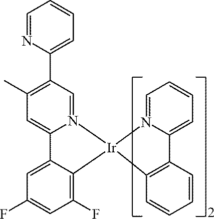

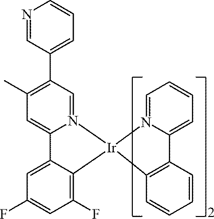

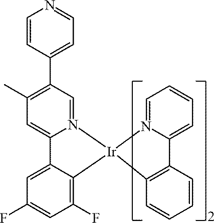

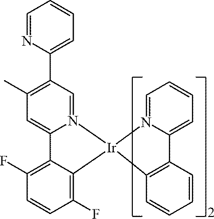

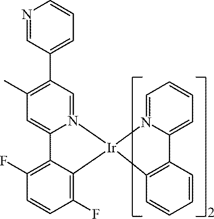

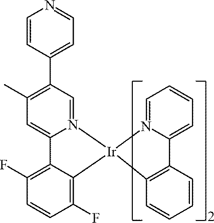

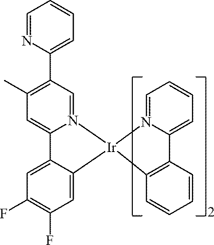

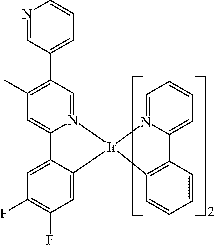

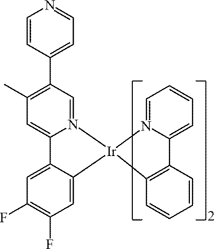

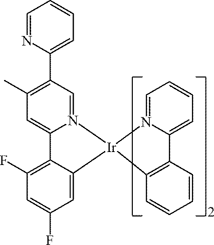

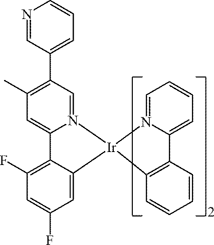

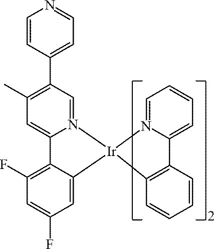

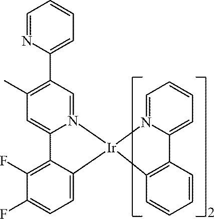

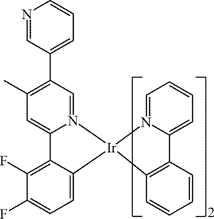

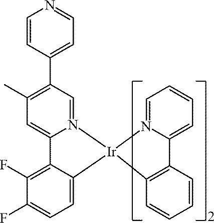

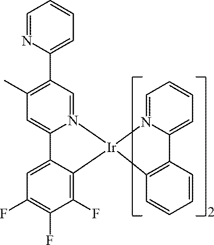

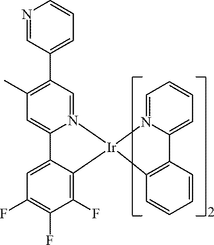

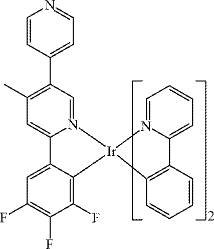

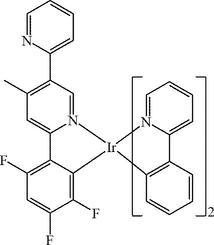

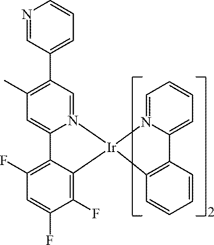

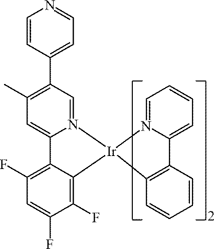

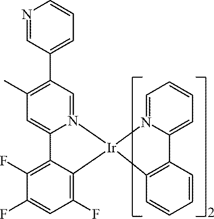

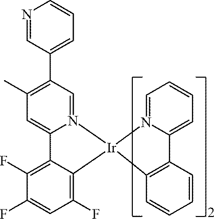

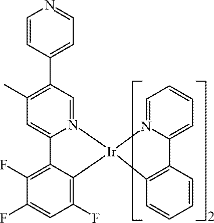

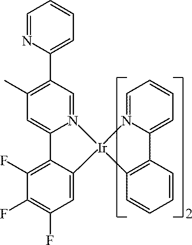

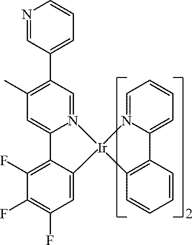

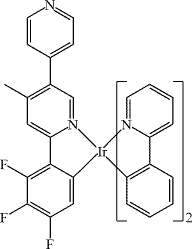

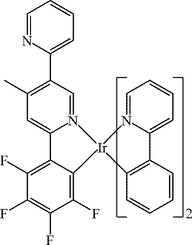

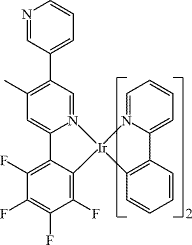

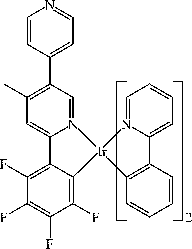

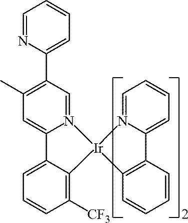

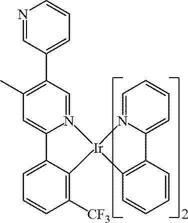

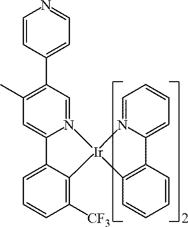

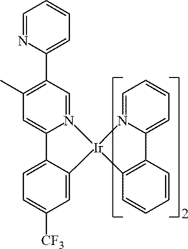

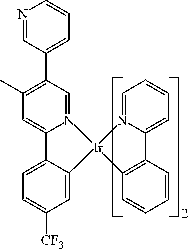

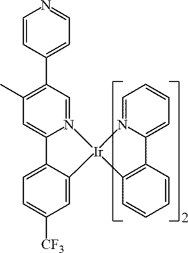

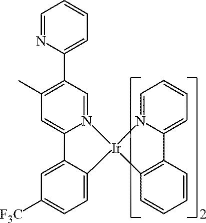

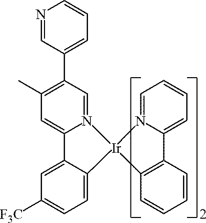

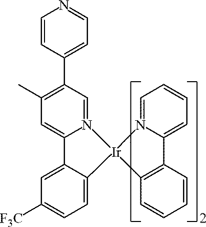

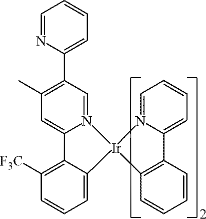

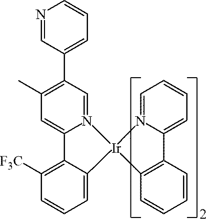

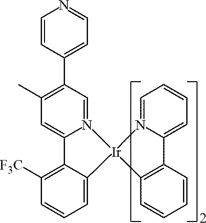

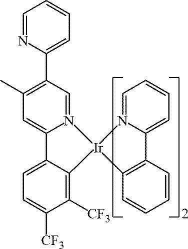

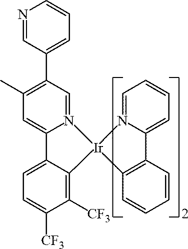

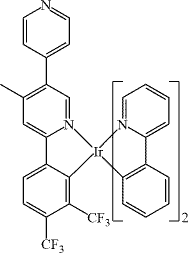

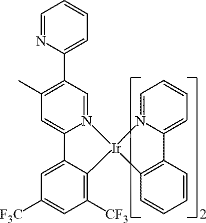

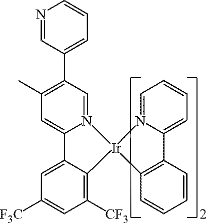

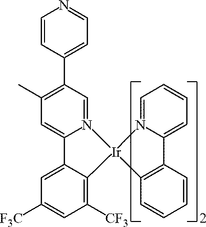

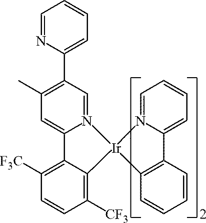

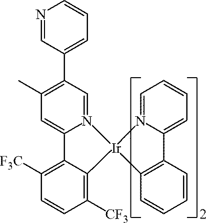

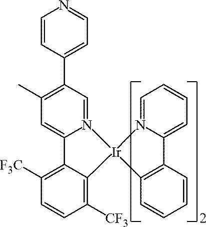

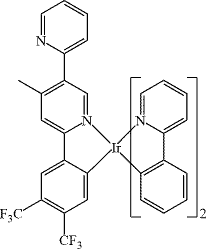

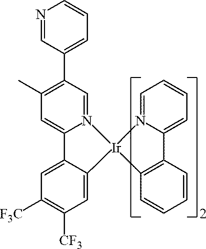

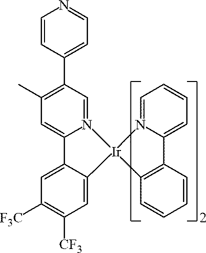

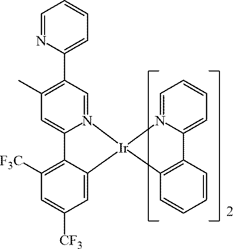

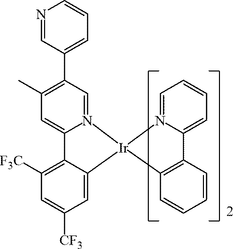

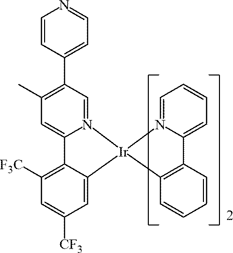

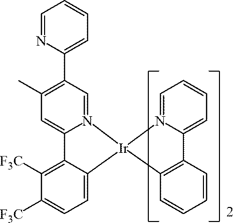

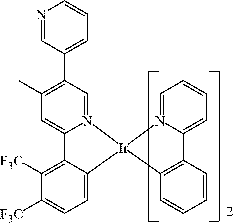

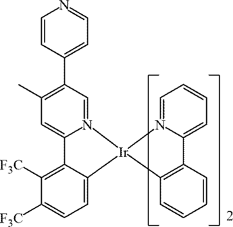

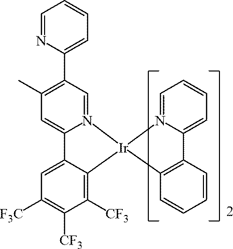

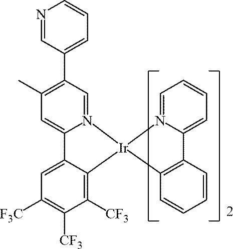

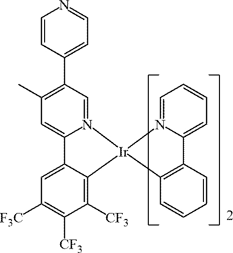

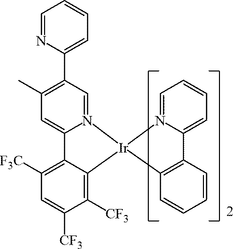

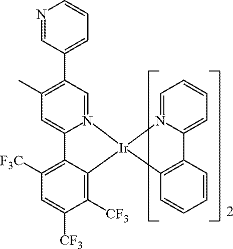

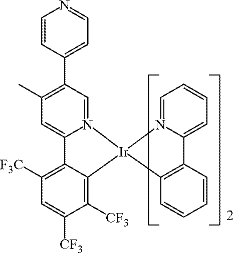

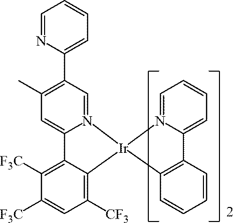

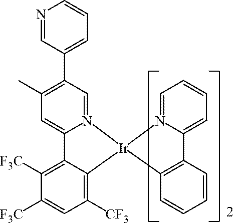

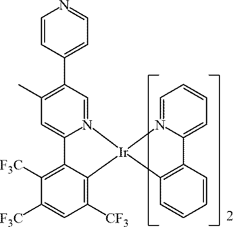

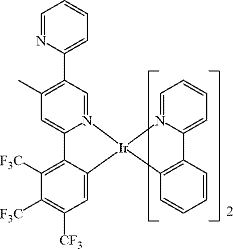

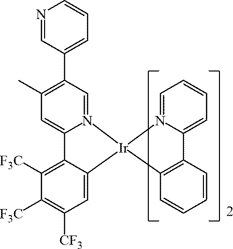

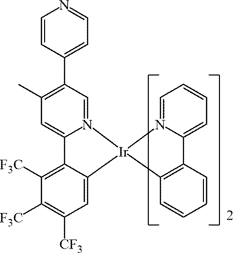

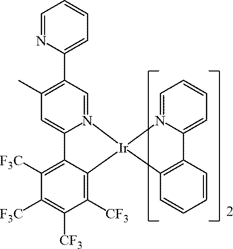

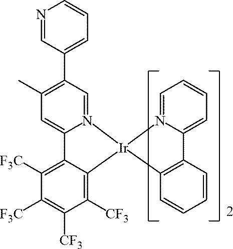

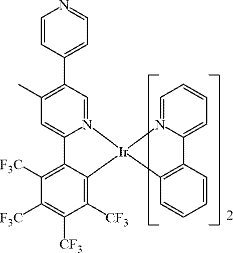

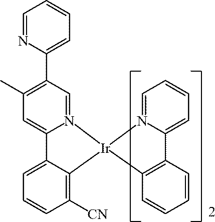

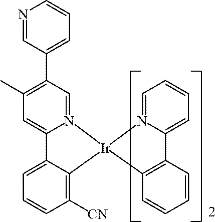

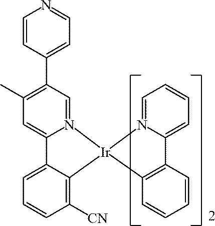

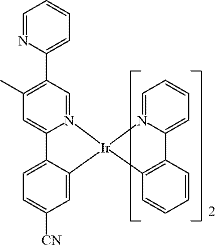

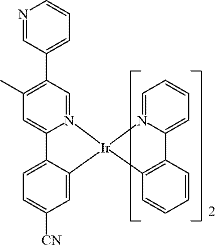

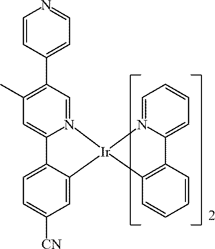

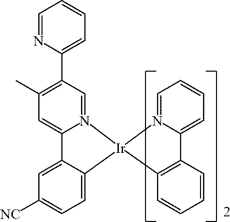

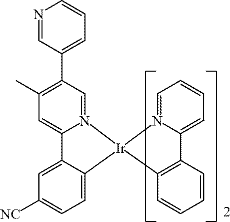

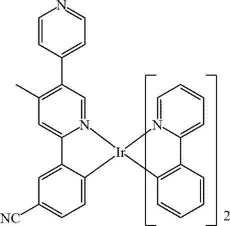

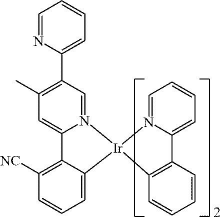

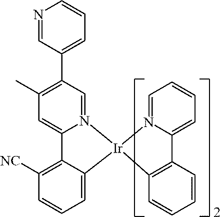

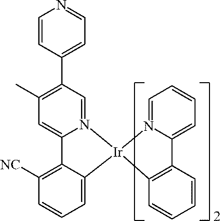

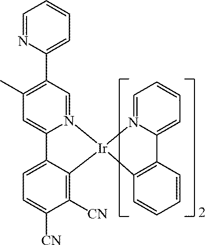

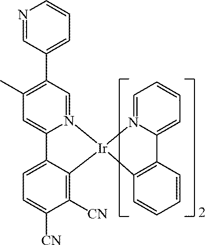

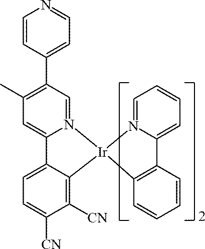

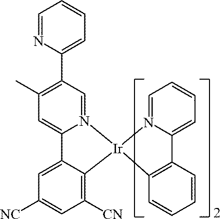

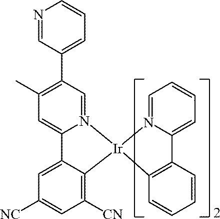

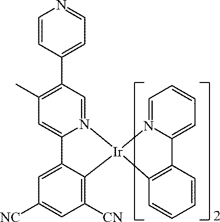

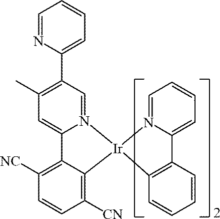

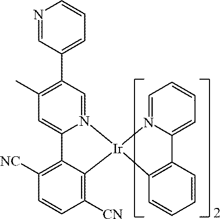

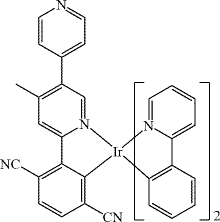

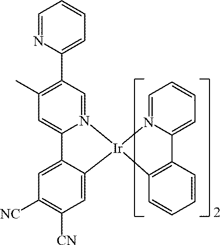

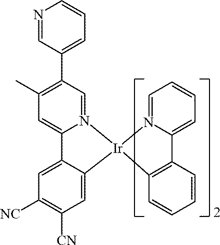

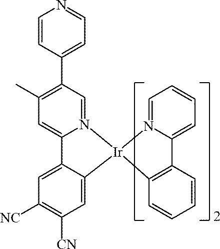

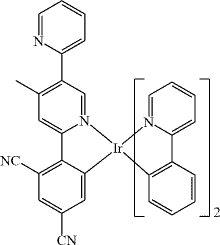

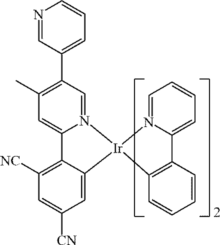

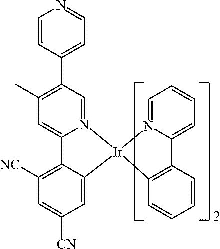

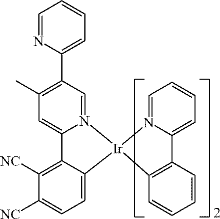

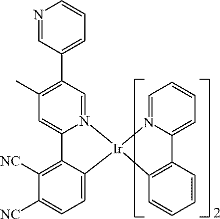

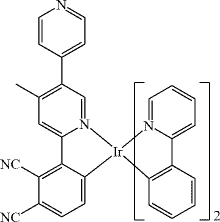

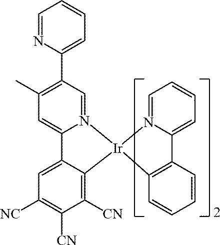

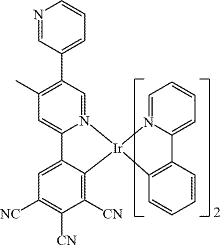

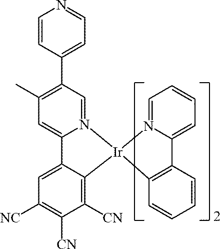

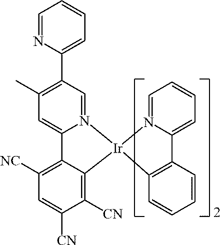

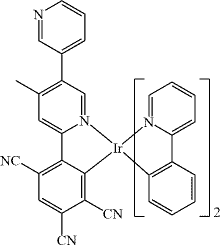

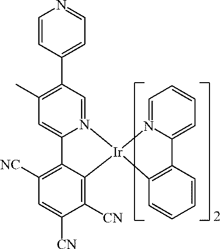

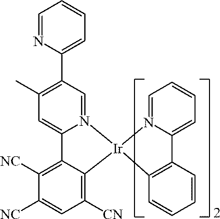

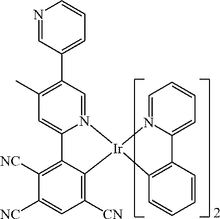

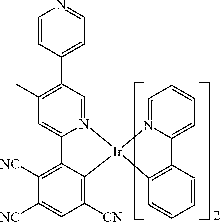

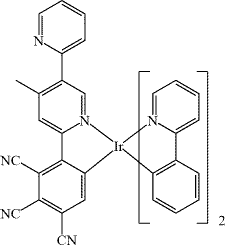

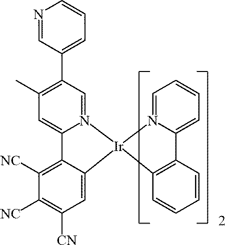

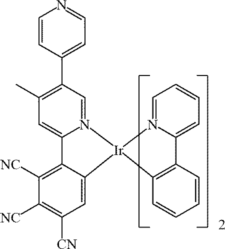

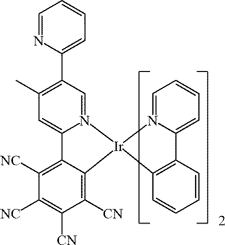

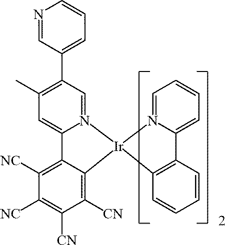

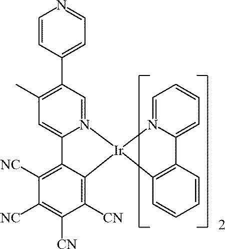

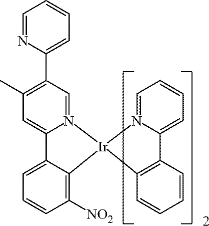

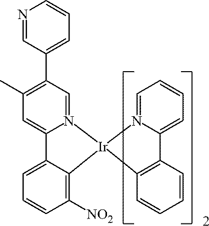

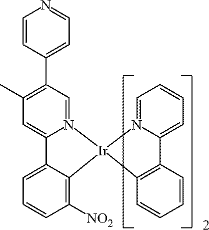

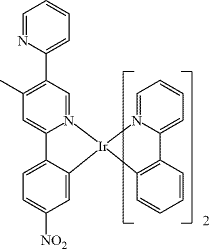

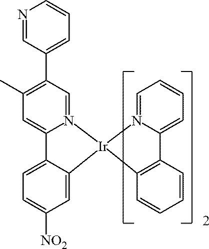

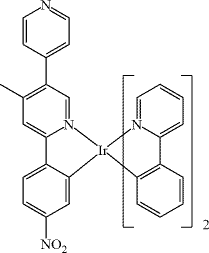

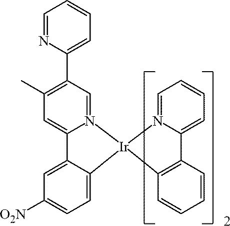

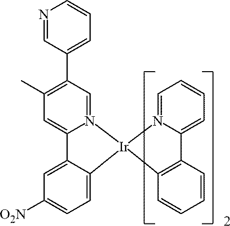

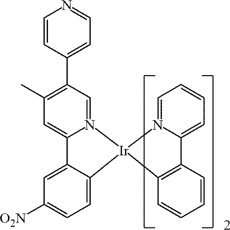

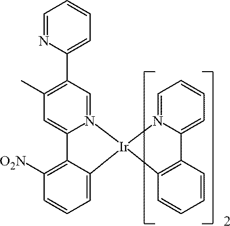

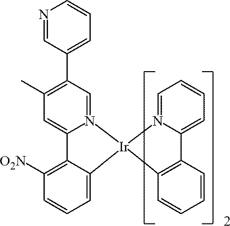

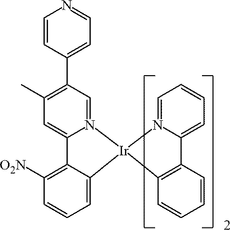

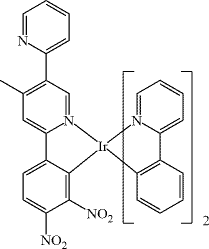

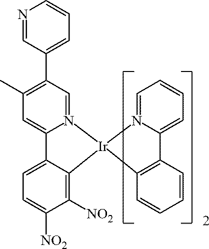

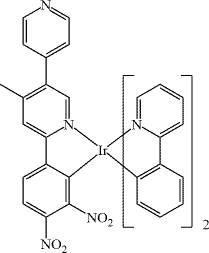

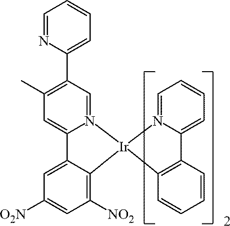

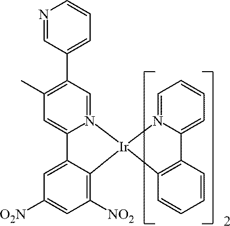

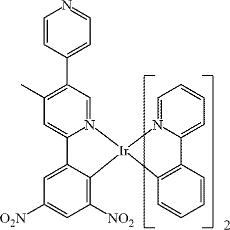

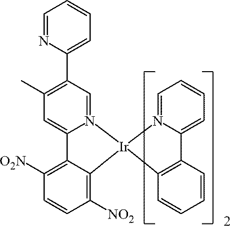

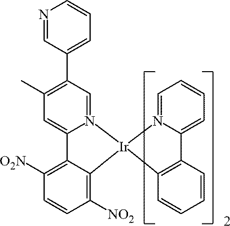

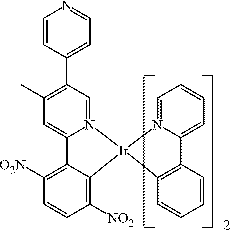

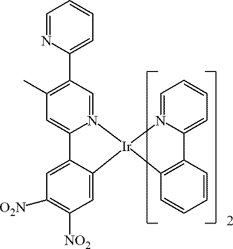

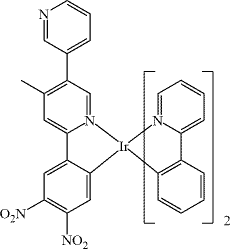

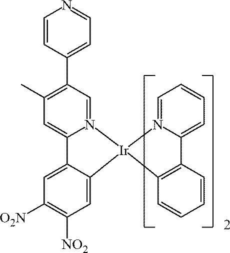

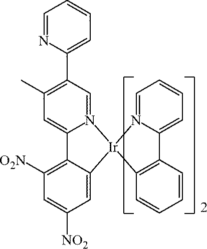

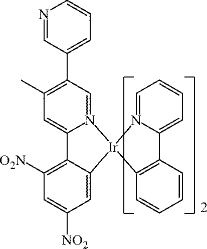

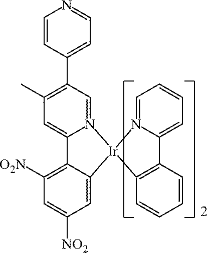

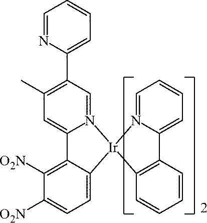

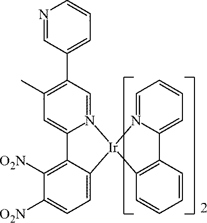

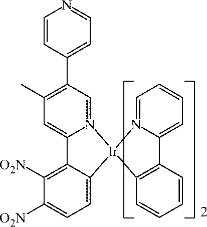

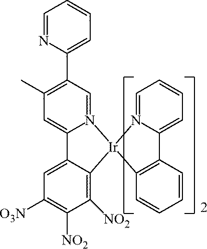

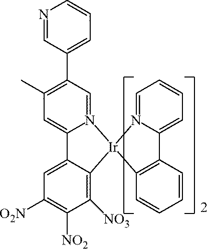

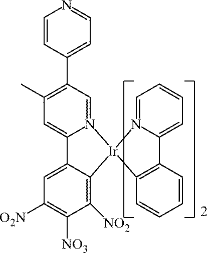

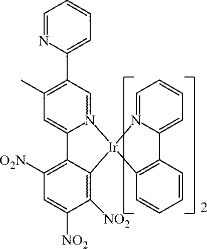

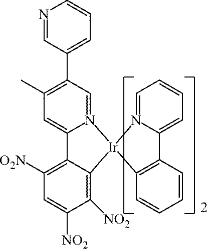

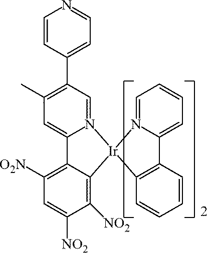

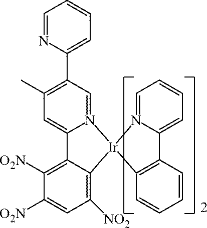

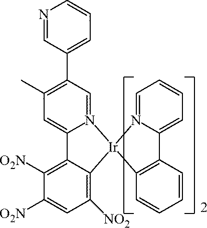

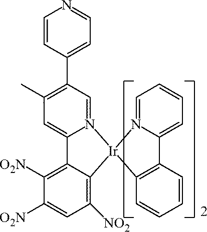

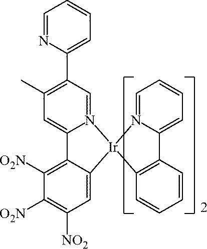

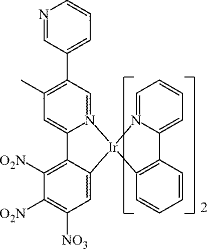

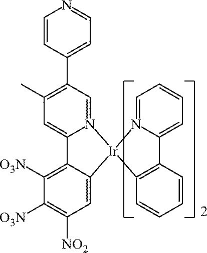

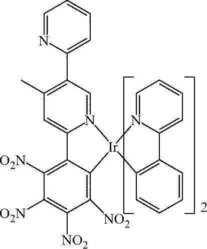

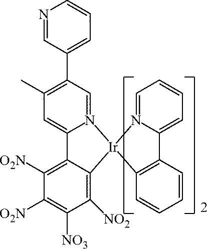

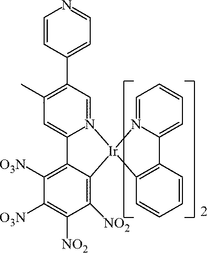

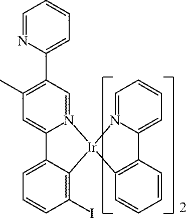

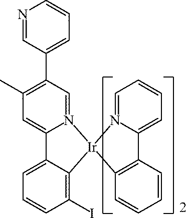

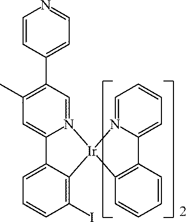

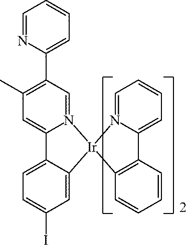

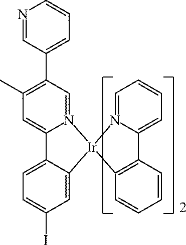

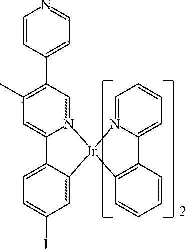

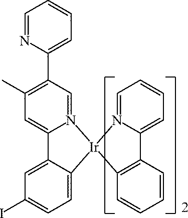

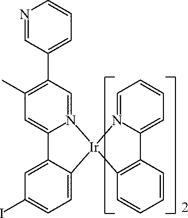

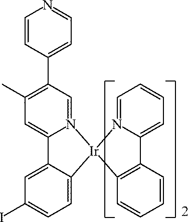

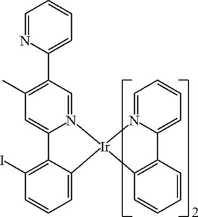

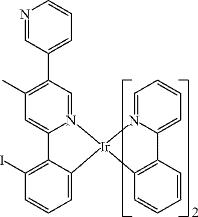

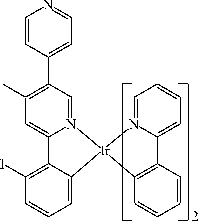

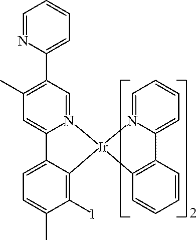

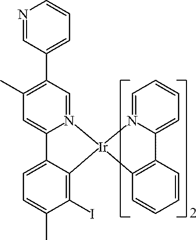

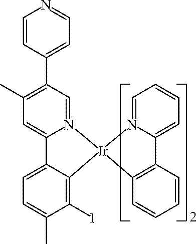

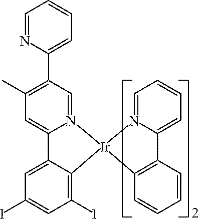

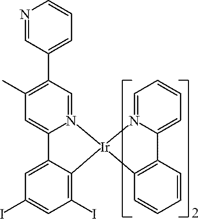

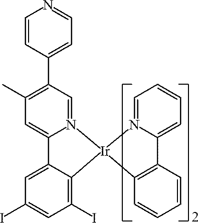

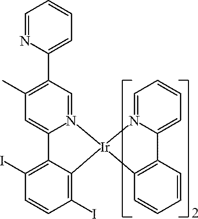

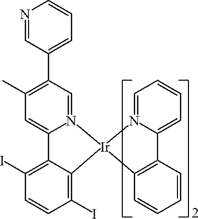

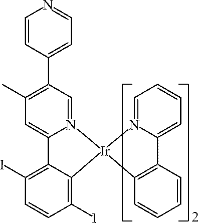

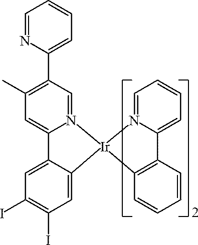

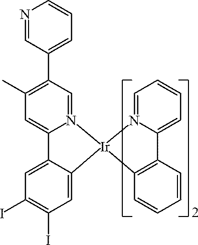

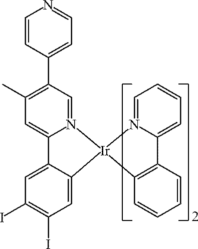

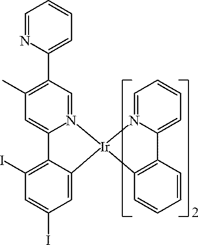

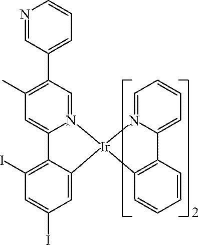

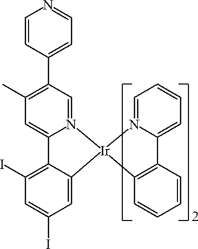

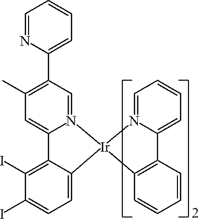

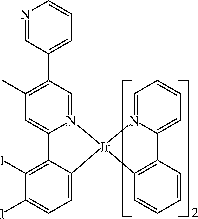

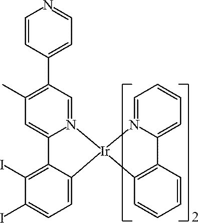

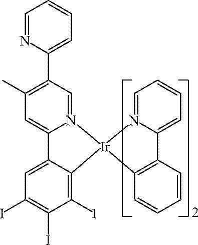

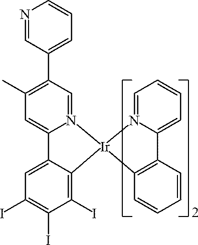

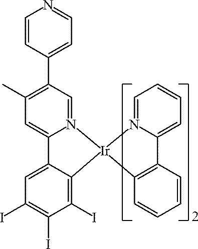

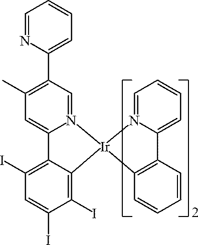

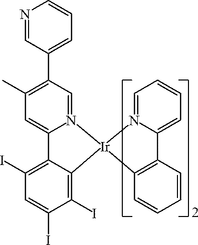

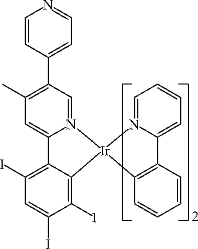

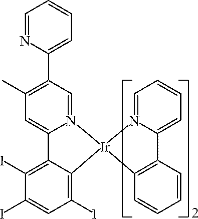

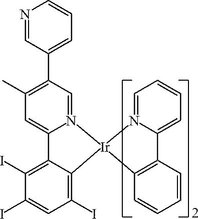

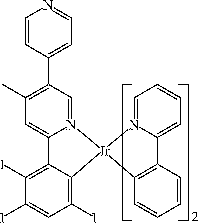

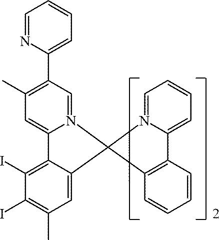

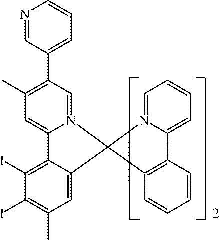

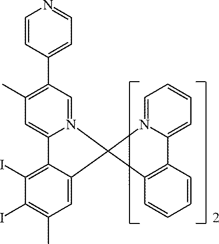

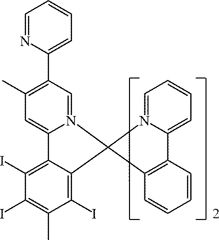

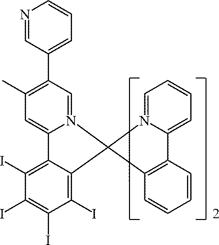

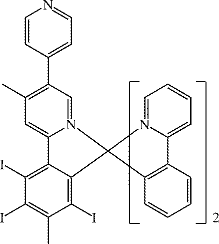

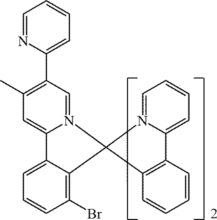

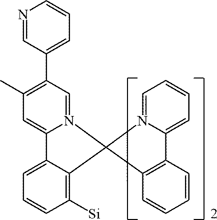

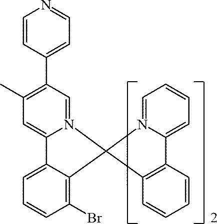

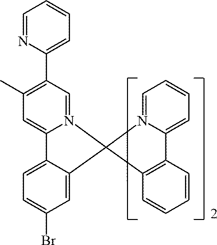

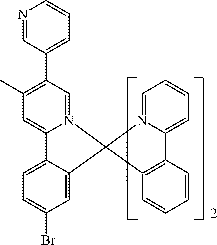

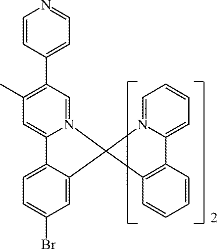

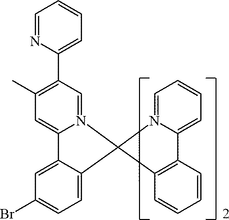

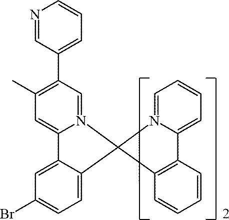

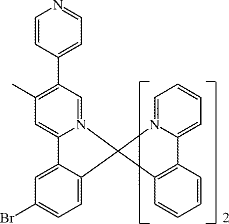

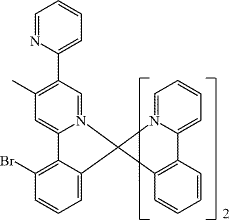

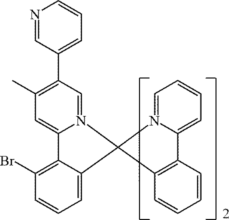

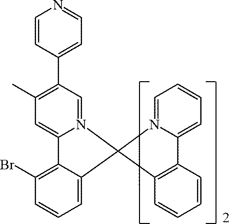

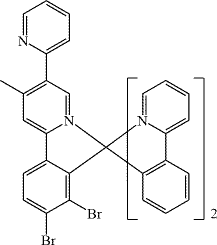

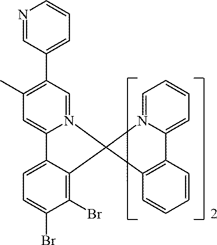

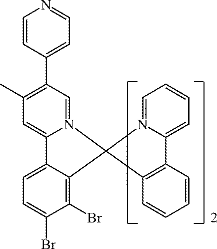

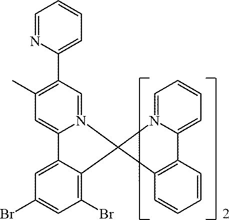

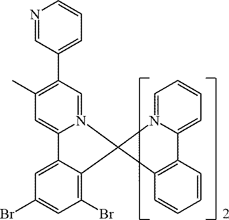

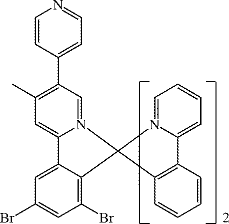

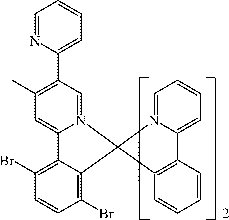

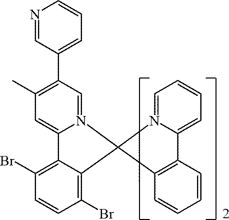

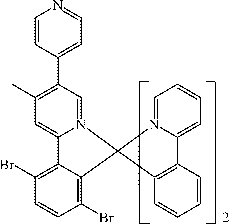

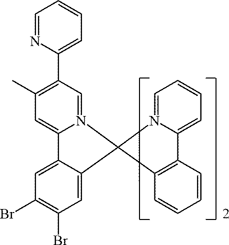

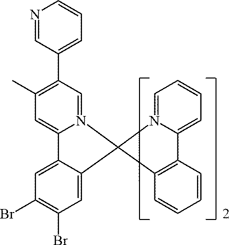

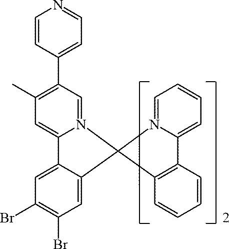

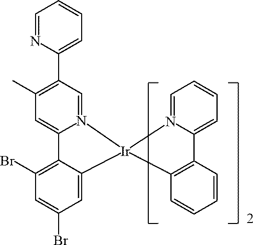

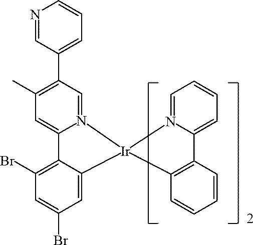

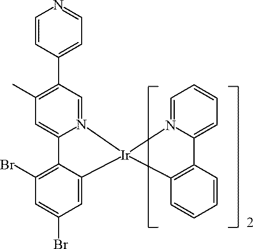

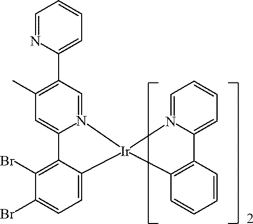

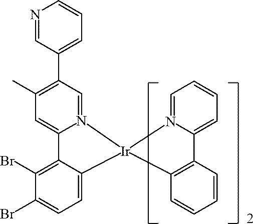

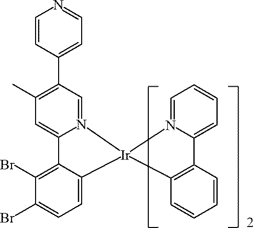

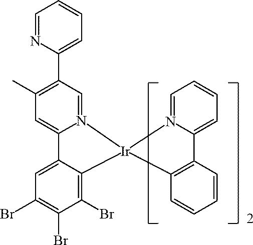

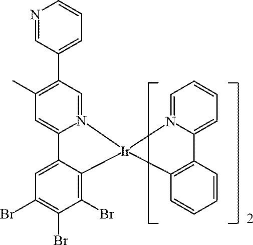

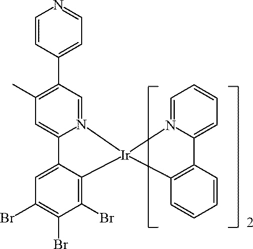

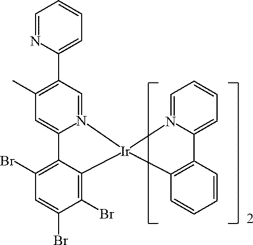

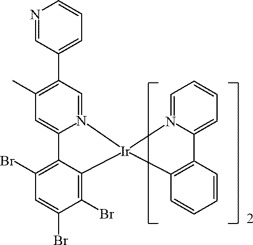

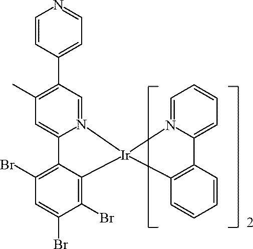

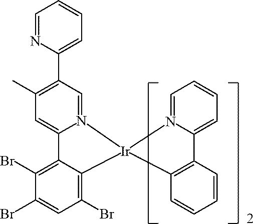

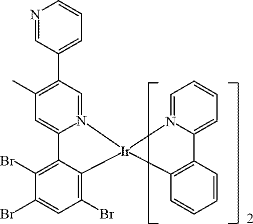

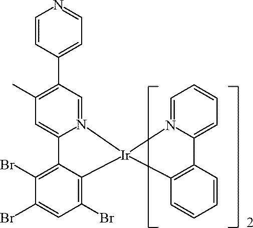

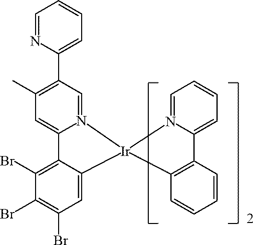

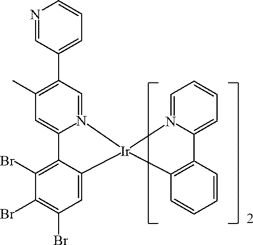

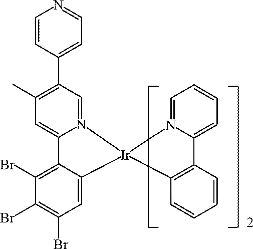

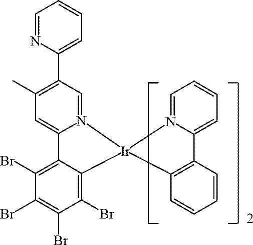

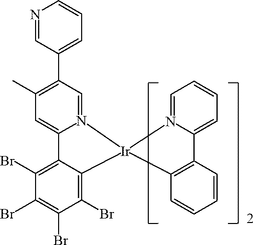

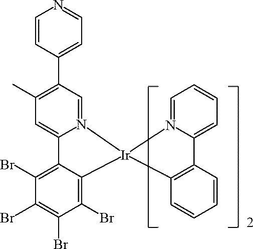

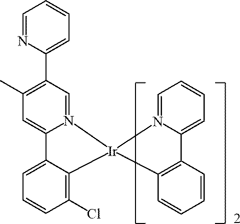

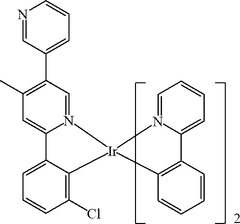

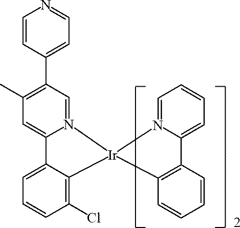

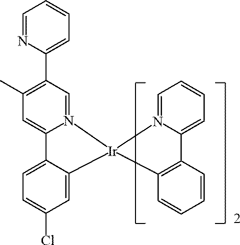

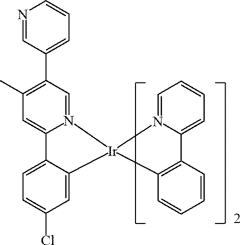

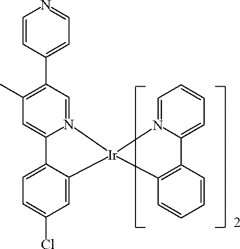

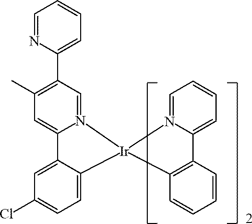

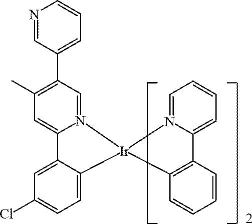

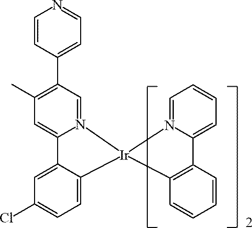

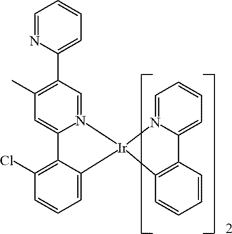

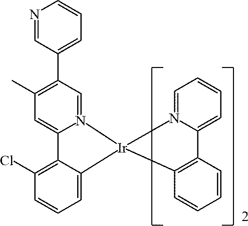

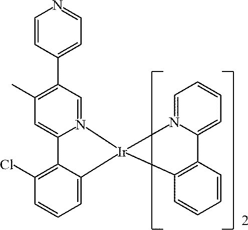

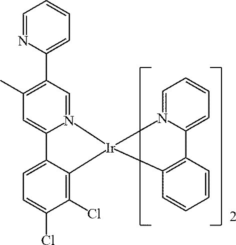

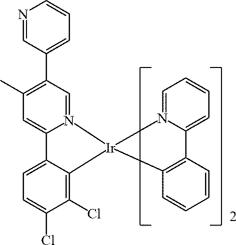

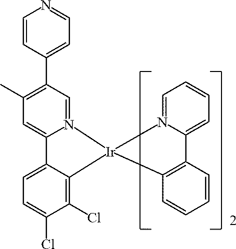

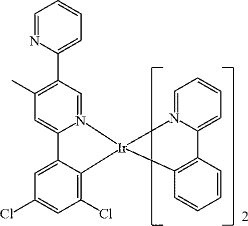

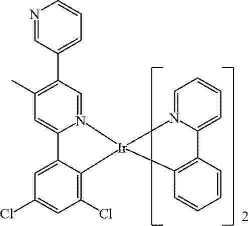

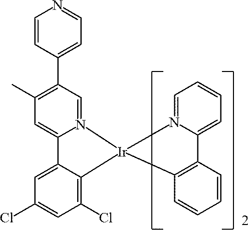

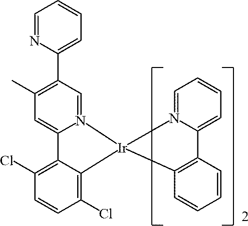

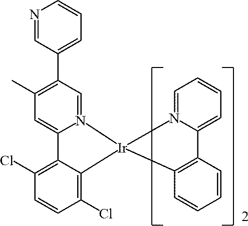

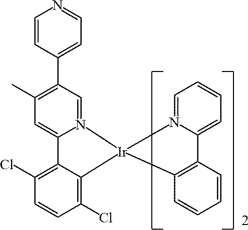

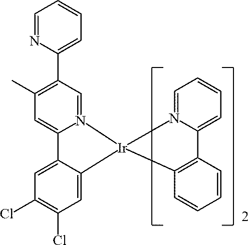

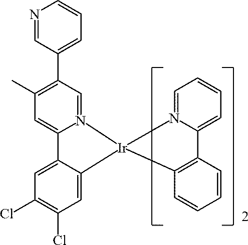

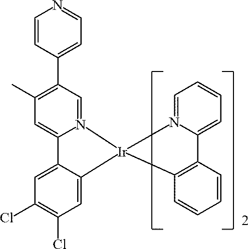

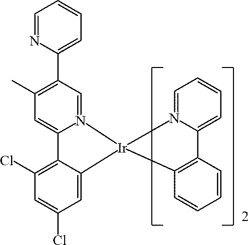

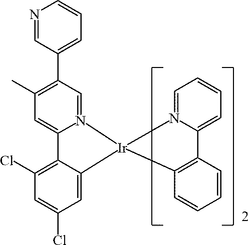

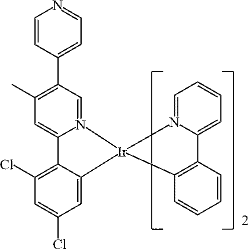

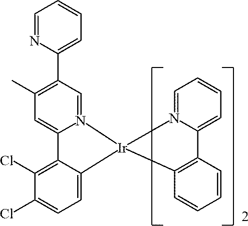

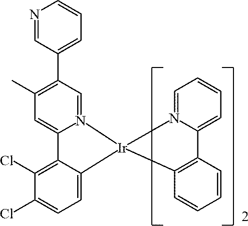

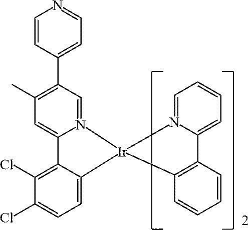

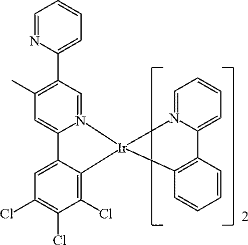

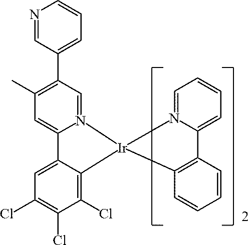

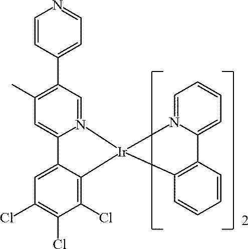

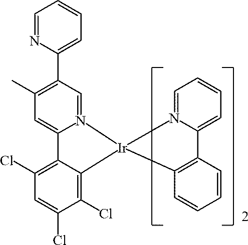

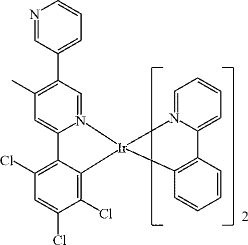

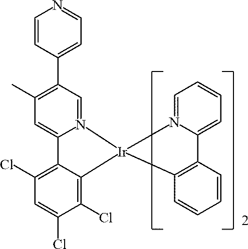

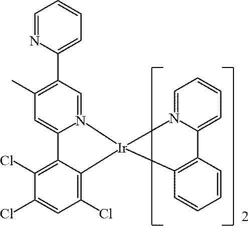

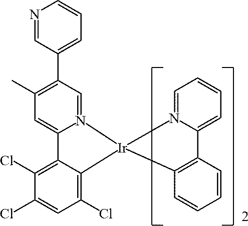

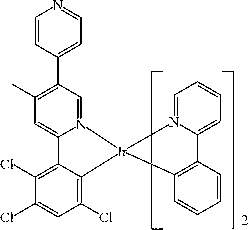

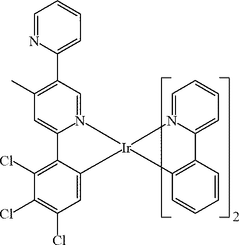

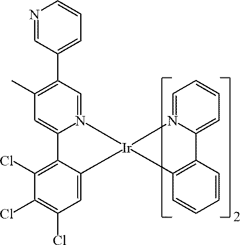

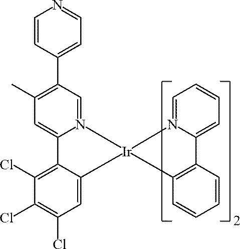

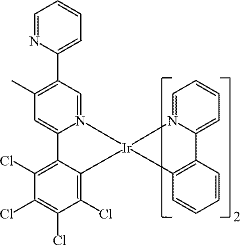

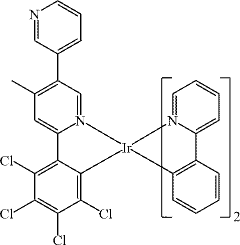

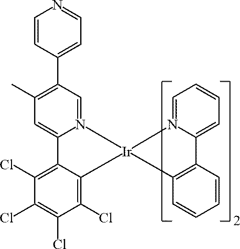

The fluorescent dopant may be selected from the following Compound 2-1 to Compound 2-117:

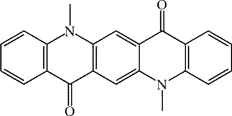 [SMILES: Cn1c2ccccc2c(=O)c2cc3c(cc21)c(=O)c1ccccc1n3C]

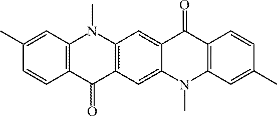

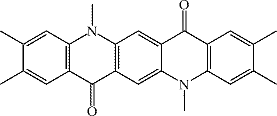

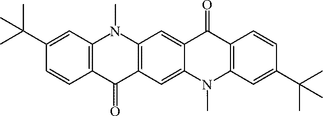 [SMILES: Cn1c2cc(C(C)(C)C)ccc2c(=O)c2cc3c(cc21)c(=O)c1ccc(C(C)(C)C)cc1n3C]

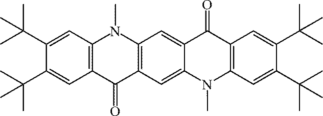 [SMILES: Cn1c2cc(C(C)(C)C)c(C(C)(C)C)cc2c(=O)c2cc3c(cc21)c(=O)c1cc(C(C)(C)C)c(C(C)(C)C)cc1n3C]

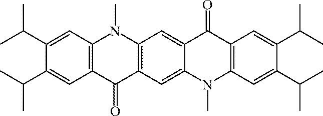 [SMILES: CC(C)c1cc2c(=O)c3cc4c(cc3n(C)c2cc1C(C)C)c(=O)c1cc(C(C)C)c(C(C)C)cc1n4C]

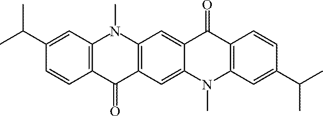 [SMILES: CC(C)c1ccc2c(=O)c3cc4c(cc3n(C)c2c1)c(=O)c1ccc(C(C)C)cc1n4C]

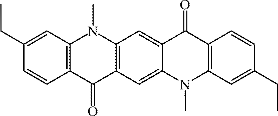 [SMILES: CCc1ccc2c(=O)c3cc4c(cc3n(C)c2c1)c(=O)c1ccc(CC)cc1n4C]

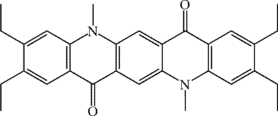 [SMILES: CCc1cc2c(=O)c3cc4c(cc3n(C)c2cc1CC)c(=O)c1cc(CC)c(CC)cc1n4C]

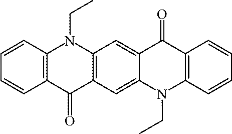 [SMILES: CCn1c2ccccc2c(=O)c2cc3c(cc21)c(=O)c1ccccc1n3CC]

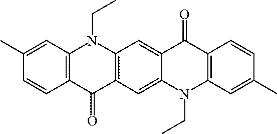

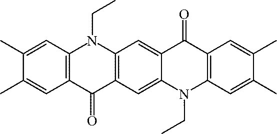

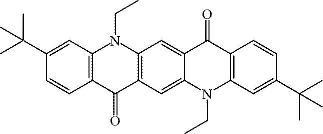 [SMILES: CCn1c2cc(C(C)(C)C)ccc2c(=O)c2cc3c(cc21)c(=O)c1ccc(C(C)(C)C)cc1n3CC]

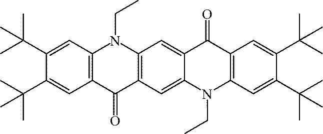 [SMILES: CCn1c2cc(C(C)(C)C)c(C(C)(C)C)cc2c(=O)c2cc3c(cc21)c(=O)c1cc(C(C)(C)C)c(C(C)(C)C)cc1n3CC]

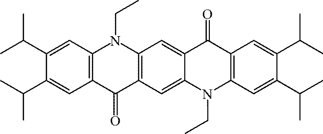 [SMILES: CCn1c2cc(C(C)C)c(C(C)C)cc2c(=O)c2cc3c(cc21)c(=O)c1cc(C(C)C)c(C(C)C)cc1n3CC]

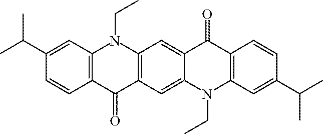 [SMILES: CCn1c2cc(C(C)C)ccc2c(=O)c2cc3c(cc21)c(=O)c1ccc(C(C)C)cc1n3CC]

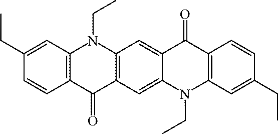 [SMILES: CCc1ccc2c(=O)c3cc4c(cc3n(CC)c2c1)c(=O)c1ccc(CC)cc1n4CC]

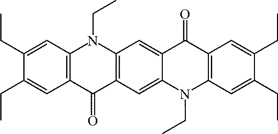 [SMILES: CCc1cc2c(=O)c3cc4c(cc3n(CC)c2cc1CC)c(=O)c1cc(CC)c(CC)cc1n4CC]

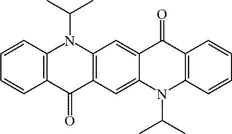 [SMILES: CC(C)n1c2ccccc2c(=O)c2cc3c(cc21)c(=O)c1ccccc1n3C(C)C]

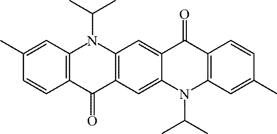

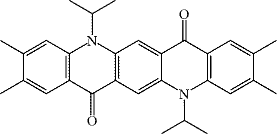

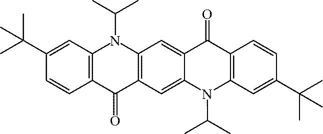 [SMILES: CC(C)n1c2cc(C(C)(C)C)ccc2c(=O)c2cc3c(cc21)c(=O)c1ccc(C(C)(C)C)cc1n3C(C)C]

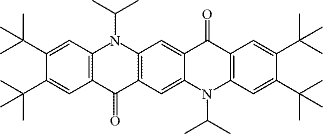 [SMILES: CC(C)n1c2cc(C(C)(C)C)c(C(C)(C)C)cc2c(=O)c2cc3c(cc21)c(=O)c1cc(C(C)(C)C)c(C(C)(C)C)cc1n3C(C)C]

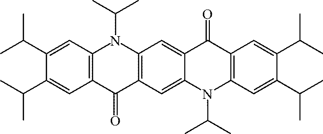 [SMILES: CC(C)c1cc2c(=O)c3cc4c(cc3n(C(C)C)c2cc1C(C)C)c(=O)c1cc(C(C)C)c(C(C)C)cc1n4C(C)C]

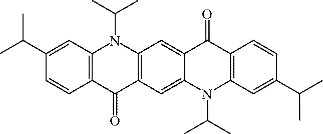 [SMILES: CC(C)c1ccc2c(=O)c3cc4c(cc3n(C(C)C)c2c1)c(=O)c1ccc(C(C)C)cc1n4C(C)C]

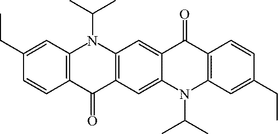 [SMILES: CCc1ccc2c(=O)c3cc4c(cc3n(C(C)C)c2c1)c(=O)c1ccc(CC)cc1n4C(C)C]

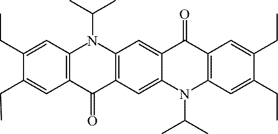 [SMILES: CCc1cc2c(=O)c3cc4c(cc3n(C(C)C)c2cc1CC)c(=O)c1cc(CC)c(CC)cc1n4C(C)C]

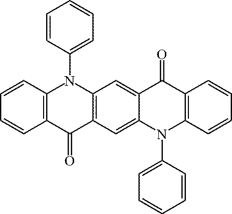 [SMILES: O=c1c2ccccc2n(-c2ccccc2)c2cc3c(=O)c4ccccc4n(-c4ccccc4)c3cc12]

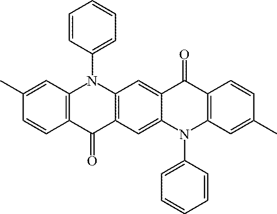

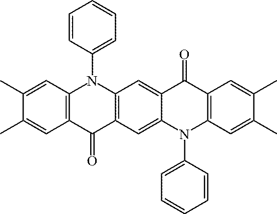

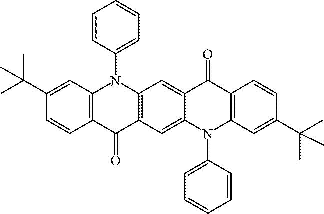 [SMILES: CC(C)(C)c1ccc2c(=O)c3cc4c(cc3n(-c3ccccc3)c2c1)c(=O)c1ccc(C(C)(C)C)cc1n4-c1ccccc1]

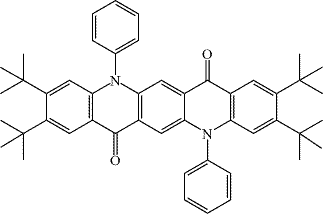 [SMILES: CC(C)(C)c1cc2c(=O)c3cc4c(cc3n(-c3ccccc3)c2cc1C(C)(C)C)c(=O)c1cc(C(C)(C)C)c(C(C)(C)C)cc1n4-c1ccccc1]

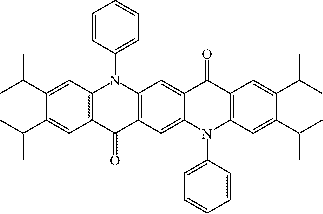 [SMILES: CC(C)c1cc2c(=O)c3cc4c(cc3n(-c3ccccc3)c2cc1C(C)C)c(=O)c1cc(C(C)C)c(C(C)C)cc1n4-c1ccccc1]

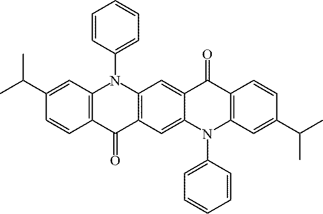 [SMILES: CC(C)c1ccc2c(=O)c3cc4c(cc3n(-c3ccccc3)c2c1)c(=O)c1ccc(C(C)C)cc1n4-c1ccccc1]

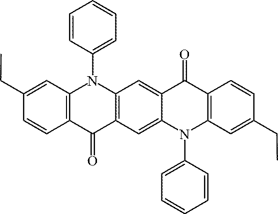 [SMILES: CCc1ccc2c(=O)c3cc4c(cc3n(-c3ccccc3)c2c1)c(=O)c1ccc(CC)cc1n4-c1ccccc1]

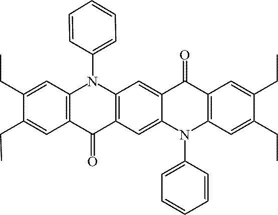 [SMILES: CCc1cc2c(=O)c3cc4c(cc3n(-c3ccccc3)c2cc1CC)c(=O)c1cc(CC)c(CC)cc1n4-c1ccccc1]

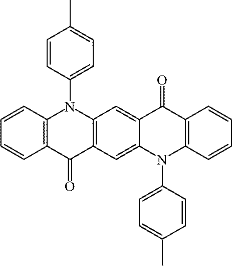 [SMILES: Cc1ccc(-n2c3ccccc3c(=O)c3cc4c(cc32)c(=O)c2ccccc2n4-c2ccc(C)cc2)cc1]

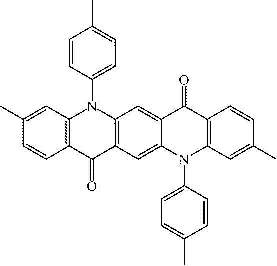

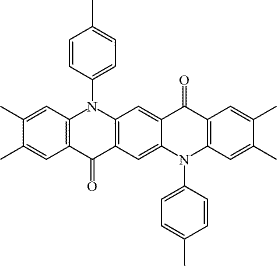

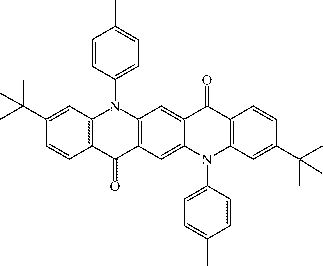 [SMILES: Cc1ccc(-n2c3cc(C(C)(C)C)ccc3c(=O)c3cc4c(cc32)c(=O)c2ccc(C(C)(C)C)cc2n4-c2ccc(C)cc2)cc1]

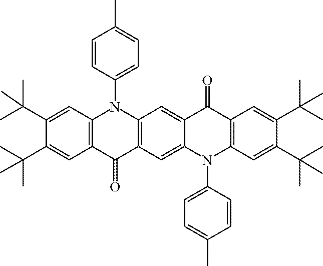 [SMILES: Cc1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C)cc2)cc1]

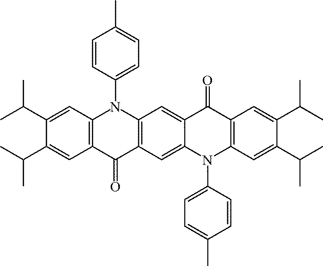 [SMILES: Cc1ccc(-n2c3cc(C(C)C)c(C(C)C)cc3c(=O)c3cc4c(cc32)c(=O)c2cc(C(C)C)c(C(C)C)cc2n4-c2ccc(C)cc2)cc1]

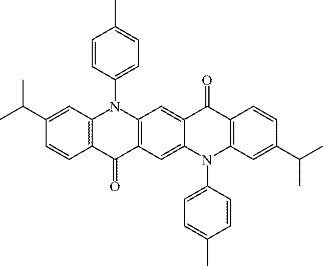 [SMILES: Cc1ccc(-n2c3cc(C(C)C)ccc3c(=O)c3cc4c(cc32)c(=O)c2ccc(C(C)C)cc2n4-c2ccc(C)cc2)cc1]

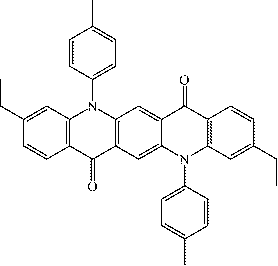 [SMILES: CCc1ccc2c(=O)c3cc4c(cc3n(-c3ccc(C)cc3)c2c1)c(=O)c1ccc(CC)cc1n4-c1ccc(C)cc1]

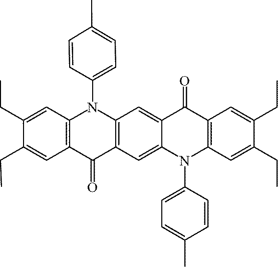 [SMILES: CCc1cc2c(=O)c3cc4c(cc3n(-c3ccc(C)cc3)c2cc1CC)c(=O)c1cc(CC)c(CC)cc1n4-c1ccc(C)cc1]

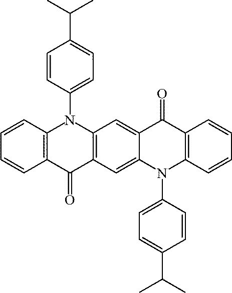 [SMILES: CC(C)c1ccc(-n2c3ccccc3c(=O)c3cc4c(cc32)c(=O)c2ccccc2n4-c2ccc(C(C)C)cc2)cc1]

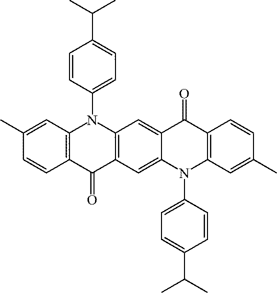

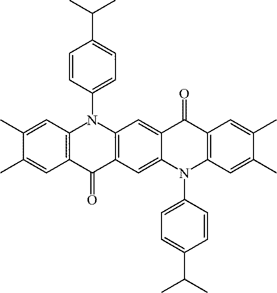

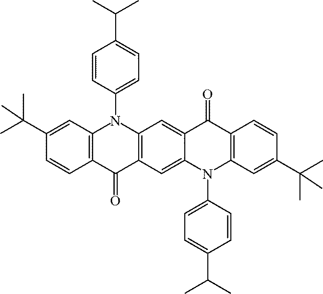 [SMILES: CC(C)c1ccc(-n2c3cc(C(C)(C)C)ccc3c(=O)c3cc4c(cc32)c(=O)c2ccc(C(C)(C)C)cc2n4-c2ccc(C(C)C)cc2)cc1]

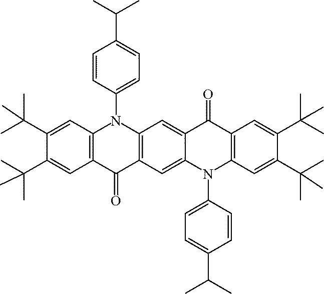 [SMILES: CC(C)c1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C(C)C)cc2)cc1]

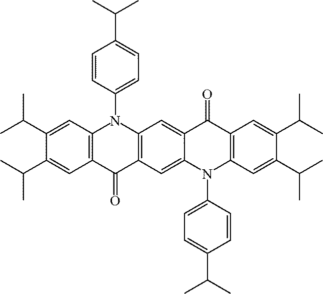 [SMILES: CC(C)c1ccc(-n2c3cc(C(C)C)c(C(C)C)cc3c(=O)c3cc4c(cc32)c(=O)c2cc(C(C)C)c(C(C)C)cc2n4-c2ccc(C(C)C)cc2)cc1]

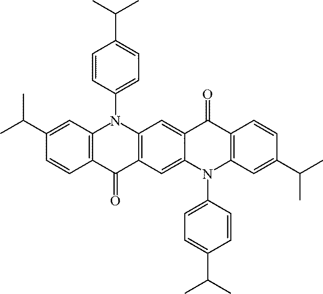 [SMILES: CC(C)c1ccc(-n2c3cc(C(C)C)ccc3c(=O)c3cc4c(cc32)c(=O)c2ccc(C(C)C)cc2n4-c2ccc(C(C)C)cc2)cc1]

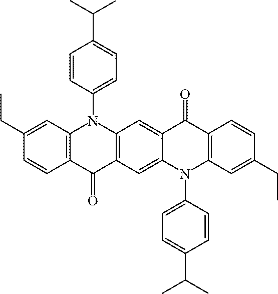 [SMILES: CCc1ccc2c(=O)c3cc4c(cc3n(-c3ccc(C(C)C)cc3)c2c1)c(=O)c1ccc(CC)cc1n4-c1ccc(C(C)C)cc1]

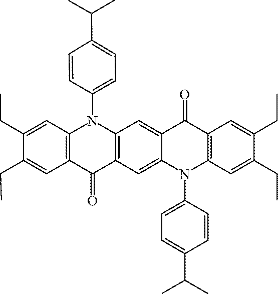 [SMILES: CCc1cc2c(=O)c3cc4c(cc3n(-c3ccc(C(C)C)cc3)c2cc1CC)c(=O)c1cc(CC)c(CC)cc1n4-c1ccc(C(C)C)cc1]

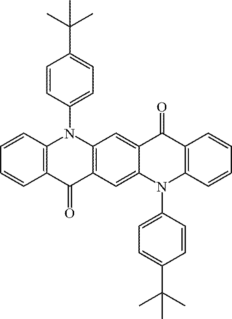 [SMILES: CC(C)(C)c1ccc(-n2c3ccccc3c(=O)c3cc4c(cc32)c(=O)c2ccccc2n4-c2ccc(C(C)(C)C)cc2)cc1]

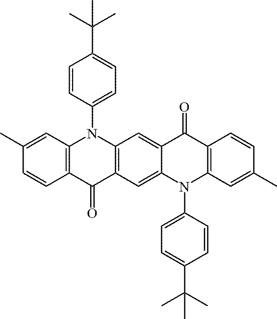

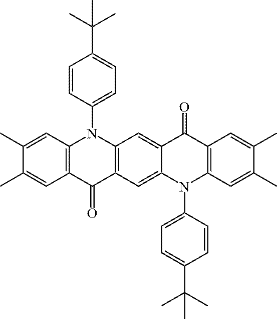

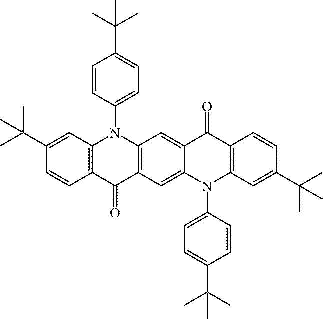 [SMILES: CC(C)(C)c1ccc(-n2c3cc(C(C)(C)C)ccc3c(=O)c3cc4c(cc32)c(=O)c2ccc(C(C)(C)C)cc2n4-c2ccc(C(C)(C)C)cc2)cc1]

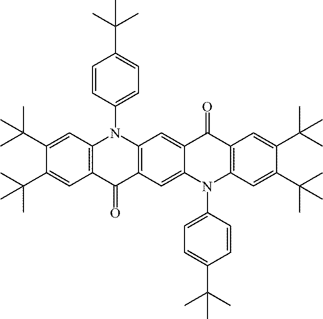 [SMILES: CC(C)(C)c1ccc(-n2c3cc(C(C)(C)C)c(C(C)(C)C)cc3c(=O)c3cc4c(cc32)c(=O)c2cc(C(C)(C)C)c(C(C)(C)C)cc2n4-c2ccc(C(C)(C)C)cc2)cc1]

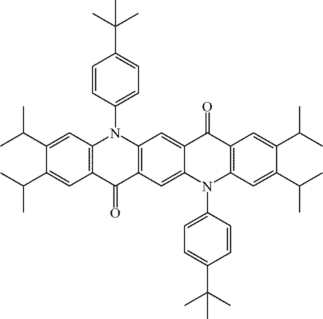 [SMILES: CC(C)c1cc2c(=O)c3cc4c(cc3n(-c3ccc(C(C)(C)C)cc3)c2cc1C(C)C)c(=O)c1cc(C(C)C)c(C(C)C)cc1n4-c1ccc(C(C)(C)C)cc1]

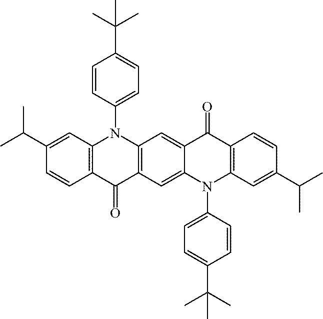 [SMILES: CC(C)c1ccc2c(=O)c3cc4c(cc3n(-c3ccc(C(C)(C)C)cc3)c2c1)c(=O)c1ccc(C(C)C)cc1n4-c1ccc(C(C)(C)C)cc1]

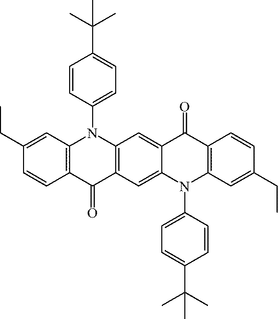 [SMILES: CCc1ccc2c(=O)c3cc4c(cc3n(-c3ccc(C(C)(C)C)cc3)c2c1)c(=O)c1ccc(CC)cc1n4-c1ccc(C(C)(C)C)cc1]

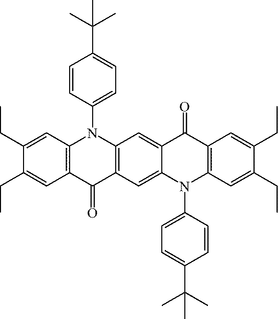 [SMILES: CCc1cc2c(=O)c3cc4c(cc3n(-c3ccc(C(C)(C)C)cc3)c2cc1CC)c(=O)c1cc(CC)c(CC)cc1n4-c1ccc(C(C)(C)C)cc1]

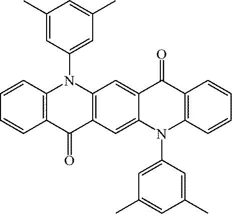 [SMILES: Cc1cc(C)cc(-n2c3ccccc3c(=O)c3cc4c(cc32)c(=O)c2ccccc2n4-c2cc(C)cc(C)c2)c1]

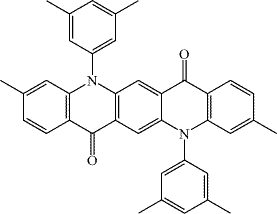

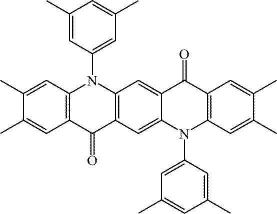

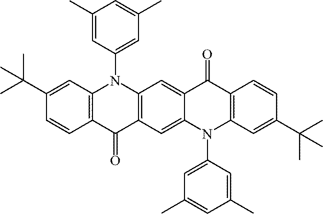 [SMILES: Cc1cc(C)cc(-n2c3cc(C(C)(C)C)ccc3c(=O)c3cc4c(cc32)c(=O)c2ccc(C(C)(C)C)cc2n4-c2cc(C)cc(C)c2)c1]

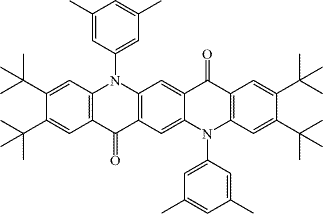 [SMILES: Cc1cc(C)cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C)cc(C)c2)c1]

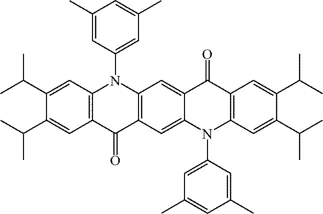 [SMILES: Cc1cc(C)cc(-n2c3cc(C(C)C)c(C(C)C)cc3c(=O)c3cc4c(cc32)c(=O)c2cc(C(C)C)c(C(C)C)cc2n4-c2cc(C)cc(C)c2)c1]

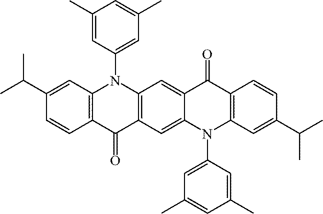 [SMILES: Cc1cc(C)cc(-n2c3cc(C(C)C)ccc3c(=O)c3cc4c(cc32)c(=O)c2ccc(C(C)C)cc2n4-c2cc(C)cc(C)c2)c1]

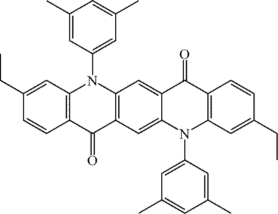 [SMILES: CCc1ccc2c(=O)c3cc4c(cc3n(-c3cc(C)cc(C)c3)c2c1)c(=O)c1ccc(CC)cc1n4-c1cc(C)cc(C)c1]

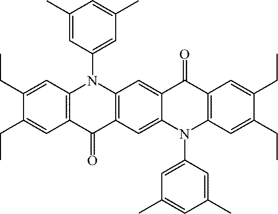 [SMILES: CCc1cc2c(=O)c3cc4c(cc3n(-c3cc(C)cc(C)c3)c2cc1CC)c(=O)c1cc(CC)c(CC)cc1n4-c1cc(C)cc(C)c1]

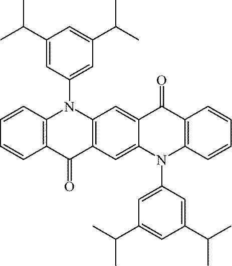 [SMILES: CC(C)c1cc(C(C)C)cc(-n2c3ccccc3c(=O)c3cc4c(cc32)c(=O)c2ccccc2n4-c2cc(C(C)C)cc(C(C)C)c2)c1]

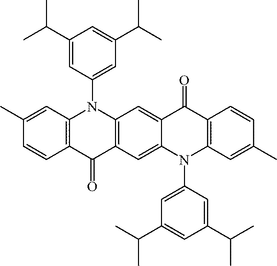

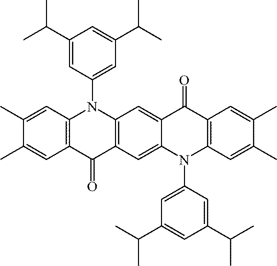

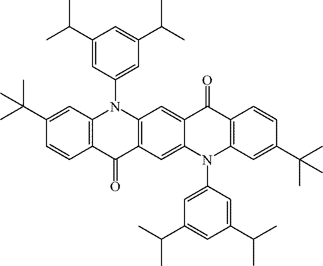 [SMILES: CC(C)c1cc(C(C)C)cc(-n2c3cc(C(C)(C)C)ccc3c(=O)c3cc4c(cc32)c(=O)c2ccc(C(C)(C)C)cc2n4-c2cc(C(C)C)cc(C(C)C)c2)c1]

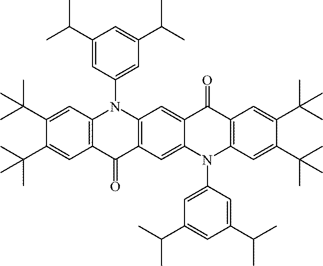 [SMILES: CC(C)c1cc(C(C)C)cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C(C)C)cc(C(C)C)c2)c1]

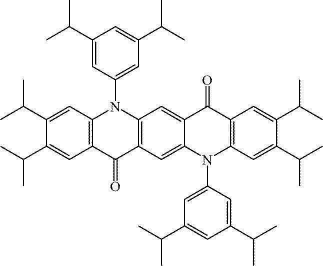 [SMILES: CC(C)c1cc(C(C)C)cc(-n2c3cc(C(C)C)c(C(C)C)cc3c(=O)c3cc4c(cc32)c(=O)c2cc(C(C)C)c(C(C)C)cc2n4-c2cc(C(C)C)cc(C(C)C)c2)c1]

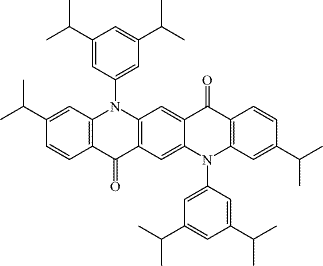 [SMILES: CC(C)c1cc(C(C)C)cc(-n2c3cc(C(C)C)ccc3c(=O)c3cc4c(cc32)c(=O)c2ccc(C(C)C)cc2n4-c2cc(C(C)C)cc(C(C)C)c2)c1]

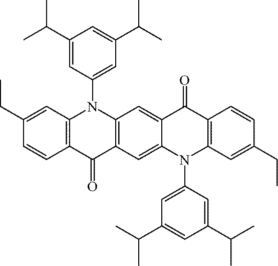 [SMILES: CCc1ccc2c(=O)c3cc4c(cc3n(-c3cc(C(C)C)cc(C(C)C)c3)c2c1)c(=O)c1ccc(CC)cc1n4-c1cc(C(C)C)cc(C(C)C)c1]

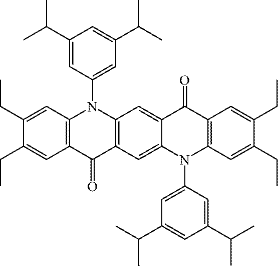 [SMILES: CCc1cc2c(=O)c3cc4c(cc3n(-c3cc(C(C)C)cc(C(C)C)c3)c2cc1CC)c(=O)c1cc(CC)c(CC)cc1n4-c1cc(C(C)C)cc(C(C)C)c1]

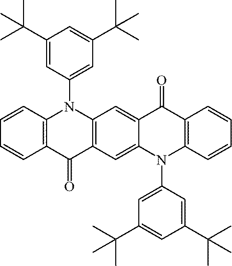 [SMILES: CC(C)(C)c1cc(-n2c3ccccc3c(=O)c3cc4c(cc32)c(=O)c2ccccc2n4-c2cc(C(C)(C)C)cc(C(C)(C)C)c2)cc(C(C)(C)C)c1]

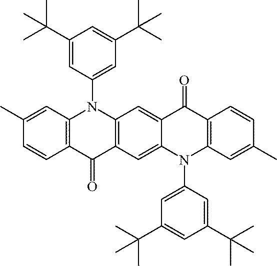

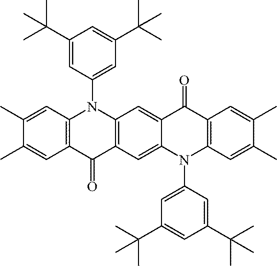

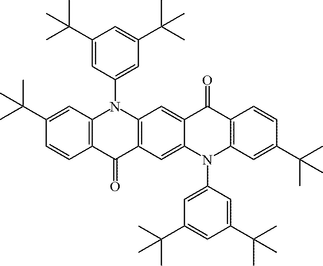 [SMILES: CC(C)(C)c1cc(-n2c3cc(C(C)(C)C)ccc3c(=O)c3cc4c(cc32)c(=O)c2ccc(C(C)(C)C)cc2n4-c2cc(C(C)(C)C)cc(C(C)(C)C)c2)cc(C(C)(C)C)c1]

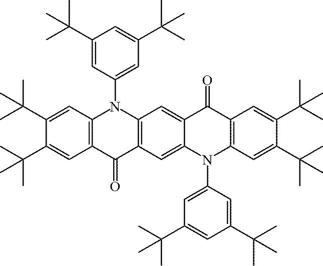 [SMILES: CC(C)(C)c1cc(-n2c3cc(C(C)(C)C)c(C(C)(C)C)cc3c(=O)c3cc4c(cc32)c(=O)c2cc(C(C)(C)C)c(C(C)(C)C)cc2n4-c2cc(C(C)(C)C)cc(C(C)(C)C)c2)cc(C(C)(C)C)c1]

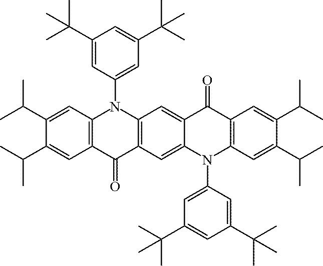 [SMILES: CC(C)c1cc2c(=O)c3cc4c(cc3n(-c3cc(C(C)(C)C)cc(C(C)(C)C)c3)c2cc1C(C)C)c(=O)c1cc(C(C)C)c(C(C)C)cc1n4-c1cc(C(C)(C)C)cc(C(C)(C)C)c1]

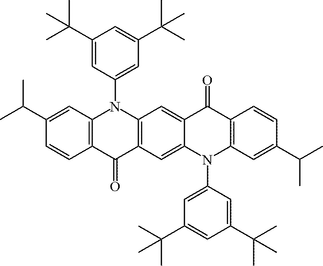 [SMILES: CC(C)c1ccc2c(=O)c3cc4c(cc3n(-c3cc(C(C)(C)C)cc(C(C)(C)C)c3)c2c1)c(=O)c1ccc(C(C)C)cc1n4-c1cc(C(C)(C)C)cc(C(C)(C)C)c1]

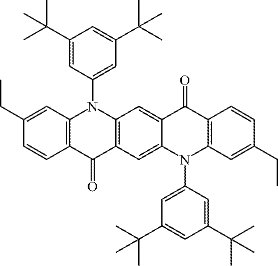 [SMILES: CCc1ccc2c(=O)c3cc4c(cc3n(-c3cc(C(C)(C)C)cc(C(C)(C)C)c3)c2c1)c(=O)c1ccc(CC)cc1n4-c1cc(C(C)(C)C)cc(C(C)(C)C)c1]

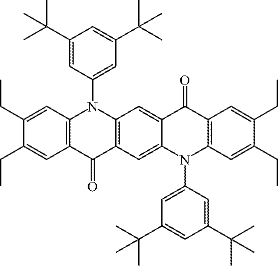 [SMILES: CCc1cc2c(=O)c3cc4c(cc3n(-c3cc(C(C)(C)C)cc(C(C)(C)C)c3)c2cc1CC)c(=O)c1cc(CC)c(CC)cc1n4-c1cc(C(C)(C)C)cc(C(C)(C)C)c1]

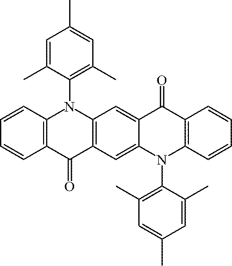 [SMILES: Cc1cc(C)c(-n2c3ccccc3c(=O)c3cc4c(cc32)c(=O)c2ccccc2n4-c2c(C)cc(C)cc2C)c(C)c1]

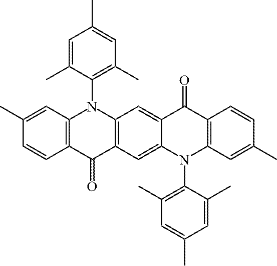

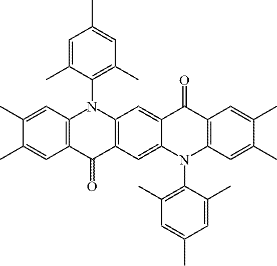

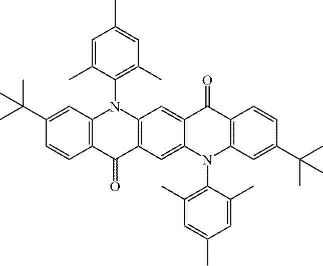 [SMILES: Cc1cc(C)c(-n2c3cc(C(C)(C)C)ccc3c(=O)c3cc4c(cc32)c(=O)c2ccc(C(C)(C)C)cc2n4-c2c(C)cc(C)cc2C)c(C)c1]

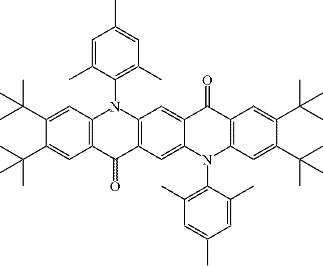 [SMILES: Cc1cc(C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C)cc(C)cc2C)c(C)c1]

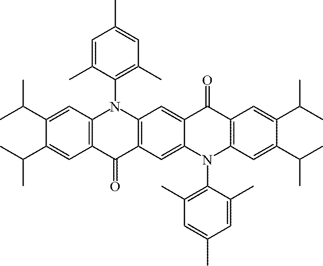 [SMILES: Cc1cc(C)c(-n2c3cc(C(C)C)c(C(C)C)cc3c(=O)c3cc4c(cc32)c(=O)c2cc(C(C)C)c(C(C)C)cc2n4-c2c(C)cc(C)cc2C)c(C)c1]

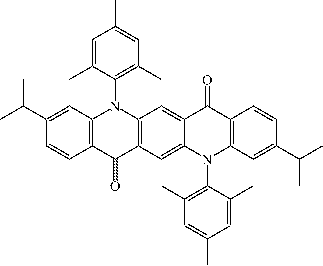 [SMILES: Cc1cc(C)c(-n2c3cc(C(C)C)ccc3c(=O)c3cc4c(cc32)c(=O)c2ccc(C(C)C)cc2n4-c2c(C)cc(C)cc2C)c(C)c1]

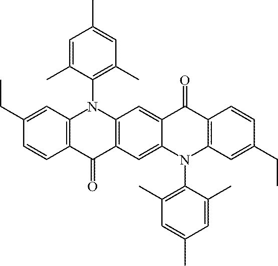 [SMILES: CCc1ccc2c(=O)c3cc4c(cc3n(-c3c(C)cc(C)cc3C)c2c1)c(=O)c1ccc(CC)cc1n4-c1c(C)cc(C)cc1C]

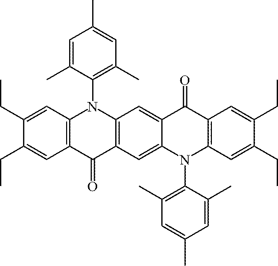 [SMILES: CCc1cc2c(=O)c3cc4c(cc3n(-c3c(C)cc(C)cc3C)c2cc1CC)c(=O)c1cc(CC)c(CC)cc1n4-c1c(C)cc(C)cc1C]

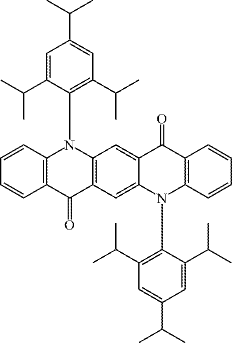 [SMILES: CC(C)c1cc(C(C)C)c(-n2c3ccccc3c(=O)c3cc4c(cc32)c(=O)c2ccccc2n4-c2c(C(C)C)cc(C(C)C)cc2C(C)C)c(C(C)C)c1]

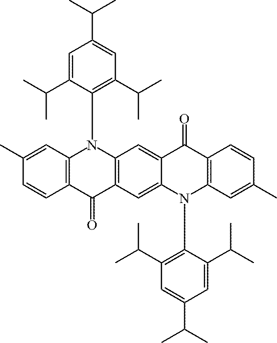

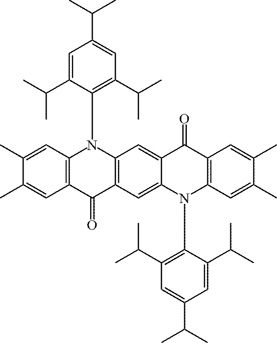

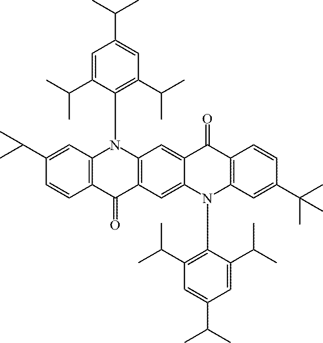 [SMILES: CC(C)c1cc(C(C)C)c(-n2c3cc(C(C)C)ccc3c(=O)c3cc4c(cc32)c(=O)c2ccc(C(C)(C)C)cc2n4-c2c(C(C)C)cc(C(C)C)cc2C(C)C)c(C(C)C)c1]

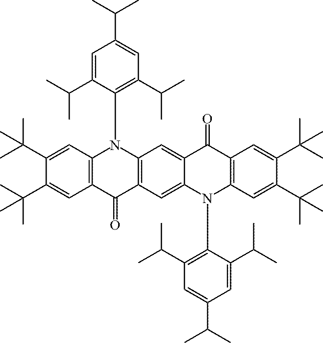 [SMILES: CC(C)c1cc(C(C)C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C(C)C)cc(C(C)C)cc2C(C)C)c(C(C)C)c1]

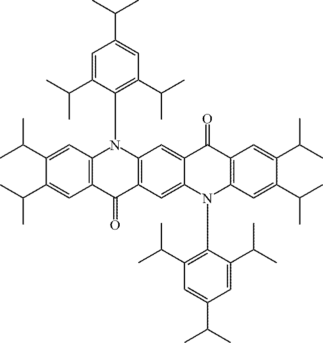 [SMILES: CC(C)c1cc(C(C)C)c(-n2c3cc(C(C)C)c(C(C)C)cc3c(=O)c3cc4c(cc32)c(=O)c2cc(C(C)C)c(C(C)C)cc2n4-c2c(C(C)C)cc(C(C)C)cc2C(C)C)c(C(C)C)c1]

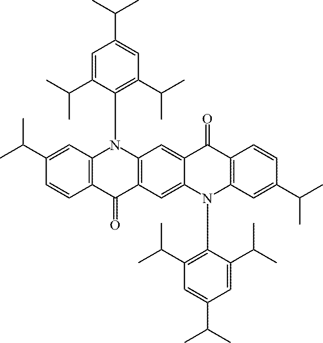 [SMILES: CC(C)c1cc(C(C)C)c(-n2c3cc(C(C)C)ccc3c(=O)c3cc4c(cc32)c(=O)c2ccc(C(C)C)cc2n4-c2c(C(C)C)cc(C(C)C)cc2C(C)C)c(C(C)C)c1]

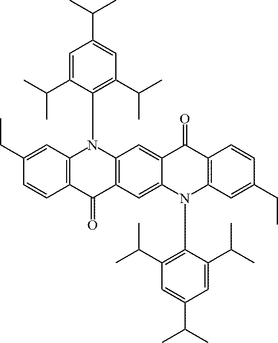 [SMILES: CCc1ccc2c(=O)c3cc4c(cc3n(-c3c(C(C)C)cc(C(C)C)cc3C(C)C)c2c1)c(=O)c1ccc(CC)cc1n4-c1c(C(C)C)cc(C(C)C)cc1C(C)C]

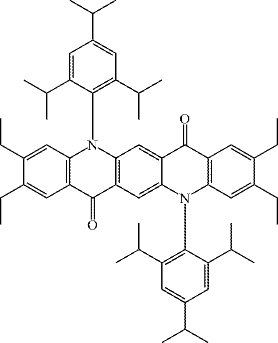 [SMILES: CCc1cc2c(=O)c3cc4c(cc3n(-c3c(C(C)C)cc(C(C)C)cc3C(C)C)c2cc1CC)c(=O)c1cc(CC)c(CC)cc1n4-c1c(C(C)C)cc(C(C)C)cc1C(C)C]

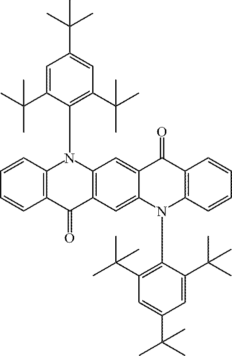 [SMILES: CC(C)(C)c1cc(C(C)(C)C)c(-n2c3ccccc3c(=O)c3cc4c(cc32)c(=O)c2ccccc2n4-c2c(C(C)(C)C)cc(C(C)(C)C)cc2C(C)(C)C)c(C(C)(C)C)c1]

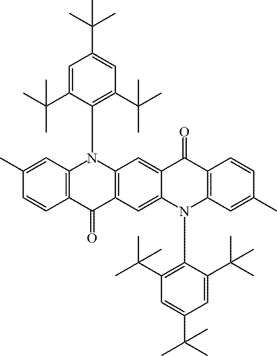

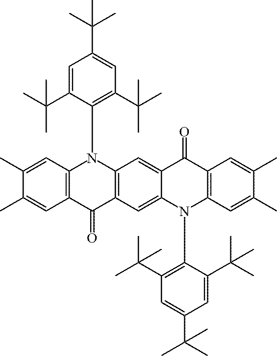

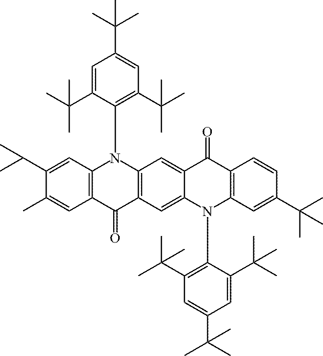 [SMILES: Cc1cc2c(=O)c3cc4c(cc3n(-c3c(C(C)(C)C)cc(C(C)(C)C)cc3C(C)(C)C)c2cc1C(C)C)c(=O)c1ccc(C(C)(C)C)cc1n4-c1c(C(C)(C)C)cc(C(C)(C)C)cc1C(C)(C)C]

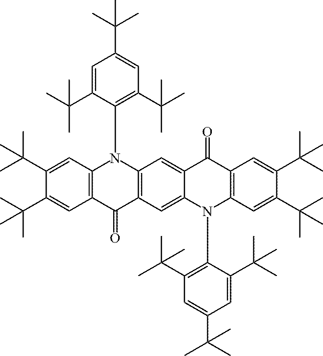 [SMILES: CC(C)(C)c1cc(C(C)(C)C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C(C)(C)C)cc(C(C)(C)C)cc2C(C)(C)C)c(C(C)(C)C)c1]

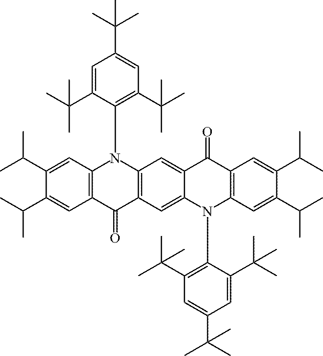 [SMILES: CC(C)c1cc2c(=O)c3cc4c(cc3n(-c3c(C(C)(C)C)cc(C(C)(C)C)cc3C(C)(C)C)c2cc1C(C)C)c(=O)c1cc(C(C)C)c(C(C)C)cc1n4-c1c(C(C)(C)C)cc(C(C)(C)C)cc1C(C)(C)C]

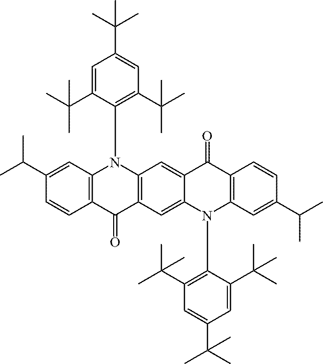 [SMILES: CC(C)c1ccc2c(=O)c3cc4c(cc3n(-c3c(C(C)(C)C)cc(C(C)(C)C)cc3C(C)(C)C)c2c1)c(=O)c1ccc(C(C)C)cc1n4-c1c(C(C)(C)C)cc(C(C)(C)C)cc1C(C)(C)C]

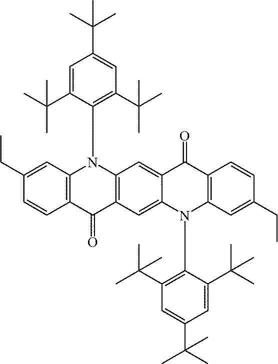 [SMILES: CCc1ccc2c(=O)c3cc4c(cc3n(-c3c(C(C)(C)C)cc(C(C)(C)C)cc3C(C)(C)C)c2c1)c(=O)c1ccc(CC)cc1n4-c1c(C(C)(C)C)cc(C(C)(C)C)cc1C(C)(C)C]

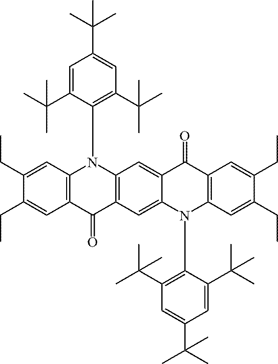 [SMILES: CCc1cc2c(=O)c3cc4c(cc3n(-c3c(C(C)(C)C)cc(C(C)(C)C)cc3C(C)(C)C)c2cc1CC)c(=O)c1cc(CC)c(CC)cc1n4-c1c(C(C)(C)C)cc(C(C)(C)C)cc1C(C)(C)C]

The phosphorescent dopant and the fluorescent dopant may be mixed at a weight ratio of 7:3 to 10:1.

A singlet energy level S1^{H} of the host, a singlet energy level S1^{PD} of the phosphorescent dopant and a singlet energy level S1^{FD} of the fluorescent dopant may satisfy the following Inequation B, and a triplet energy level T1^{H} of the host, a triplet energy level T1^{PD} of the phosphorescent dopant and a triplet energy level T1^{FD} of the fluorescent dopant may satisfy the following Inequation C:

$${\text{S1}}^{\text{H}} > {\text{S1}}^{\text{PD}} > {\text{S1}}^{\text{FD}}$$

$${\text{T1}}^{\text{H}} > {\text{T1}}^{\text{PD}} > {\text{T1}}^{\text{FD}} .$$

The host may be selected from the following Compound 3-1 to Compound 3-24:

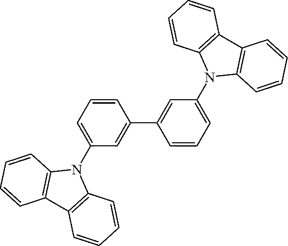 [SMILES: c1cc(-c2cccc(-n3c4ccccc4c4ccccc43)c2)cc(-n2c3ccccc3c3ccccc32)c1]

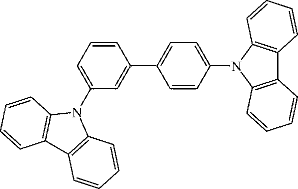 [SMILES: c1cc(-c2ccc(-n3c4ccccc4c4ccccc43)cc2)cc(-n2c3ccccc3c3ccccc32)c1]

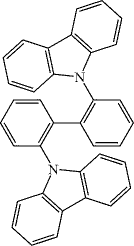 [SMILES: c1ccc(-n2c3ccccc3c3ccccc32)c(-c2ccccc2-n2c3ccccc3c3ccccc32)c1]

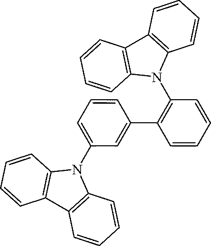 [SMILES: c1cc(-c2ccccc2-n2c3ccccc3c3ccccc32)cc(-n2c3ccccc3c3ccccc32)c1]

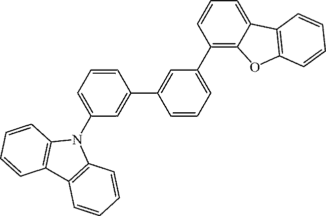 [SMILES: c1cc(-c2cccc(-n3c4ccccc4c4ccccc43)c2)cc(-c2cccc3c2oc2ccccc23)c1]

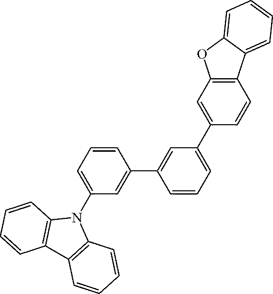 [SMILES: c1cc(-c2cccc(-n3c4ccccc4c4ccccc43)c2)cc(-c2ccc3c(c2)oc2ccccc23)c1]

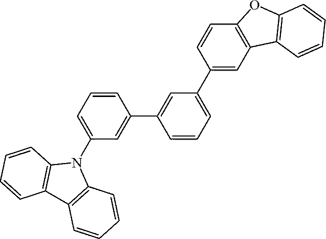 [SMILES: c1cc(-c2cccc(-n3c4ccccc4c4ccccc43)c2)cc(-c2ccc3oc4ccccc4c3c2)c1]

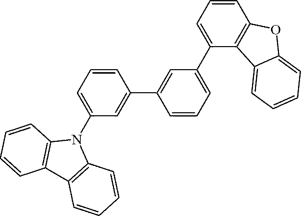 [SMILES: c1cc(-c2cccc(-n3c4ccccc4c4ccccc43)c2)cc(-c2cccc3oc4ccccc4c23)c1]

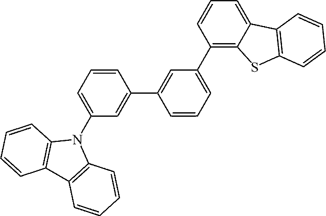 [SMILES: c1cc(-c2cccc(-n3c4ccccc4c4ccccc43)c2)cc(-c2cccc3c2sc2ccccc23)c1]

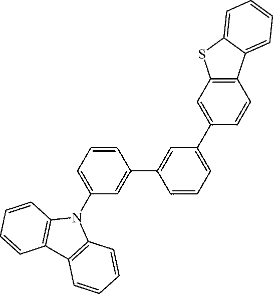 [SMILES: c1cc(-c2cccc(-n3c4ccccc4c4ccccc43)c2)cc(-c2ccc3c(c2)sc2ccccc23)c1]

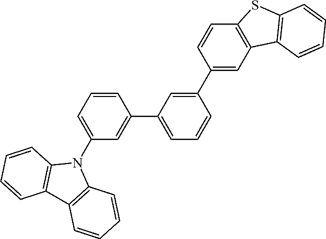 [SMILES: c1cc(-c2cccc(-n3c4ccccc4c4ccccc43)c2)cc(-c2ccc3sc4ccccc4c3c2)c1]

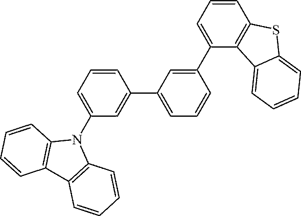 [SMILES: c1cc(-c2cccc(-n3c4ccccc4c4ccccc43)c2)cc(-c2cccc3sc4ccccc4c23)c1]

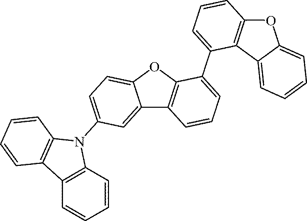 [SMILES: c1ccc2c(c1)oc1cccc(-c3cccc4c3oc3ccc(-n5c6ccccc6c6ccccc65)cc34)c12]

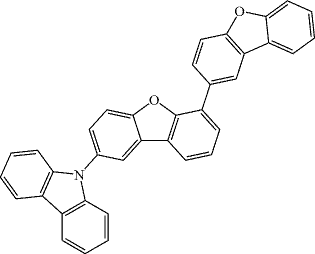 [SMILES: c1ccc2c(c1)oc1ccc(-c3cccc4c3oc3ccc(-n5c6ccccc6c6ccccc65)cc34)cc12]

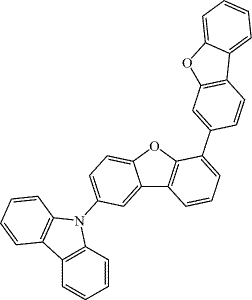 [SMILES: c1ccc2c(c1)oc1cc(-c3cccc4c3oc3ccc(-n5c6ccccc6c6ccccc65)cc34)ccc12]

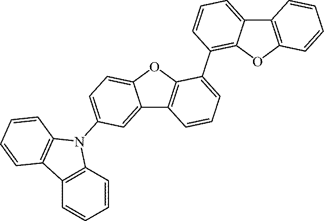 [SMILES: c1ccc2c(c1)oc1c(-c3cccc4c3oc3ccc(-n5c6ccccc6c6ccccc65)cc34)cccc12]

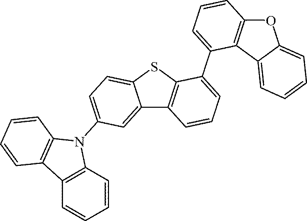 [SMILES: c1ccc2c(c1)oc1cccc(-c3cccc4c3sc3ccc(-n5c6ccccc6c6ccccc65)cc34)c12]

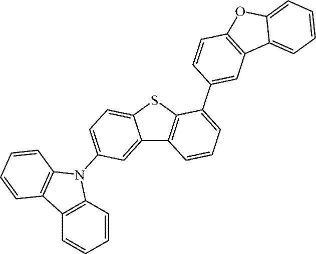 [SMILES: c1ccc2c(c1)oc1ccc(-c3cccc4c3sc3ccc(-n5c6ccccc6c6ccccc65)cc34)cc12]

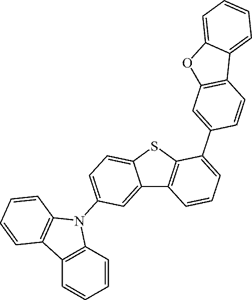 [SMILES: c1ccc2c(c1)oc1cc(-c3cccc4c3sc3ccc(-n5c6ccccc6c6ccccc65)cc34)ccc12]

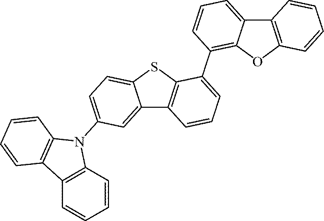 [SMILES: c1ccc2c(c1)oc1c(-c3cccc4c3sc3ccc(-n5c6ccccc6c6ccccc65)cc34)cccc12]

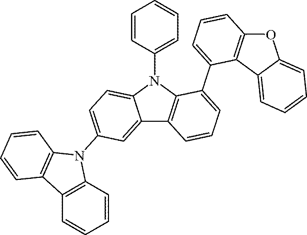 [SMILES: c1ccc(-n2c3ccc(-n4c5ccccc5c5ccccc54)cc3c3cccc(-c4cccc5oc6ccccc6c45)c32)cc1]

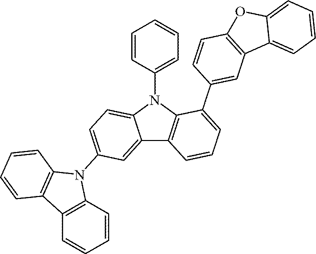 [SMILES: c1ccc(-n2c3ccc(-n4c5ccccc5c5ccccc54)cc3c3cccc(-c4ccc5oc6ccccc6c5c4)c32)cc1]

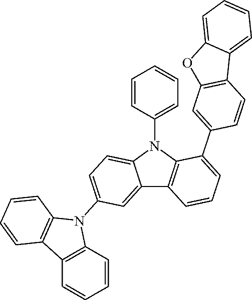 [SMILES: c1ccc(-n2c3ccc(-n4c5ccccc5c5ccccc54)cc3c3cccc(-c4ccc5c(c4)oc4ccccc45)c32)cc1]

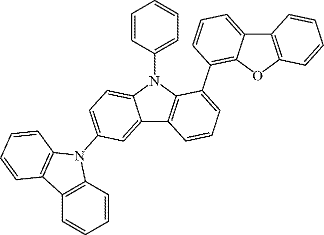 [SMILES: c1ccc(-n2c3ccc(-n4c5ccccc5c5ccccc54)cc3c3cccc(-c4cccc5c4oc4ccccc45)c32)cc1]

The organic light emitting diode may include a plurality of emission layers, and at least one of the plurality of emission layers may include the host, the phosphorescent dopant represented by Chemical Formula 1 and the fluorescent dopant represented by Chemical Formula 2.

The organic light emitting diode may further comprise at least one layer selected from a hole injection layer, a hole transport layer, a hole blocking layer, an electron blocking layer, an electron transport layer and an electron injection layer.

According to another aspect of the present disclosure, an organic light emitting display device comprise a substrate; a thin film transistor on the substrate; and an organic light emitting diode disposed on the thin film transistor, wherein the organic light emitting diode is an organic light emitting diode.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting diode, comprising:
an anode;
an emission layer disposed on the anode and including a host, a phosphorescent dopant represented by the following Chemical Formula 1 and a fluorescent dopant represented by the following Chemical Formula 2; and
a cathode disposed on the emission layer: 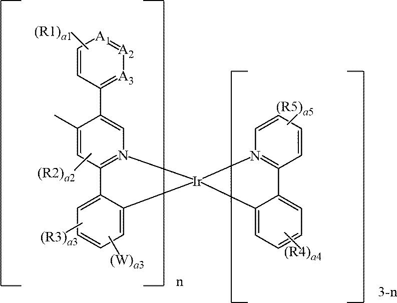
wherein in Chemical Formula 1, each of A1 to A3 is independently nitrogen or carbon, at least one of A1 to A3 is nitrogen, each of a1 and a3 to a5 is independently an integer of 0 to 4, a2 is an integer of 0 to 2, a6 is an integer of 1 to 4, and the sum of a3 and a6 is 4 or less,
each of R1 to R5 is independently selected from hydrogen, deuterium, tritium, an alkyl group having 1 to 20 carbon atoms, an aryl group having 6 to 30 carbon atoms and a heteroaryl group having 3 to 40 carbon atoms, and each substituent may form a fused ring with a neighboring substituent, and
W is selected from a cyano group, a nitro group, a halogen group, a substituted alkyl group having 1 to 20 carbon atoms, a substituted aryl group having 6 to 30 carbon atoms and a substituted heteroaryl group having 3 to 40 carbon atoms, and in this case, each of the substituted alkyl group, the substituted aryl group and the substituted heteroaryl group includes at least one substituent selected from a cyano group, a nitro group and a halogen group, and n is an integer of 0 to 3, and 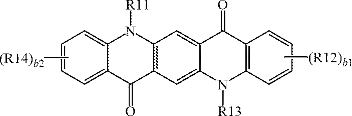
in Chemical Formula 2, each of b1 and b2 is independently an integer of 0 to 4, and
each of R11 to R14 is selected from hydrogen, deuterium, tritium, an alkyl group having 1 to 20 carbon atoms, an aryl group having 6 to 30 carbon atoms and a heteroaryl group having 3 to 40 carbon atoms, and each substituent may form a fused ring with a neighboring substituent.

2. The organic light emitting diode according to claim 1, wherein an emission peak of the phosphorescent dopant represented by Chemical Formula 1 overlaps with an absorption peak of the fluorescent dopant represented by Chemical Formula 2, and an overlap area between the emission peak and the absorption peak is 35% or more of an entire area of the emission peak and the absorption peak.

3. The organic light emitting diode according to claim 1, wherein a difference between a maximum emission peak wavelength of the phosphorescent dopant represented by Chemical Formula 1 and a maximum absorption peak wavelength of the fluorescent dopant represented by Chemical Formula 2 is 5 nm to 20 nm.

4. The organic light emitting diode according to claim 1, wherein a difference between a lowest unoccupied molecular orbital energy level LUMO_{FD} of the fluorescent dopant represented by Chemical Formula 2 and a lowest unoccupied molecular orbital energy level LUMO_{PD} of the phosphorescent dopant represented by Chemical Formula 1 satisfies the following Inequation A:
$$\text{0} \text{.1} \geq {\text{LUMO}}_{\text{FD}} \text{-} {\text{LUMO}}_{\text{PD}} \geq \text{-} \text{0} \text{.6} \text{.}$$
.

5. The organic light emitting diode according to claim 1, wherein a highest occupied molecular orbital energy level HOMO_{FD} of the fluorescent dopant represented by Chemical Formula 2 is equal to or higher than a highest occupied molecular orbital energy level HOMO_{PD} of the phosphorescent dopant represented by Chemical Formula 1.

6. The organic light emitting diode according to claim 1, wherein the phosphorescent dopant represented by Chemical Formula 1 has an energy band gap of 2.0 eV to 3.0 eV.

7. The organic light emitting diode according to claim 1, wherein, in Chemical Formula 1, each of A1 to A3 is independently nitrogen or carbon, one of A1 to A3 is nitrogen, each of a1 to a5 is 0, a6 is an integer of 1 to 4, W is selected from a cyano group, a nitro group, a halogen group and an alkyl group substituted with at least one substituent selected from a cyano group, a nitro group and a halogen group and having 1 to 20 carbon atoms, and n is 1.

8. The organic light emitting diode according to claim 1, wherein, in Chemical Formula 2, each of b1 and b2 is independently an integer of 0 to 2, each of R11 and R13 is independently selected from an alkyl group having 1 to 20 carbon atoms and an aryl group having 6 to 30 carbon atoms, and each of R12 and R14 is independently selected from hydrogen and an alkyl group having 1 to 20 carbon atoms.

9. The organic light emitting diode according to claim 1, wherein the phosphorescent dopant is selected from the following Compound 1-1 to Compound 1-315: 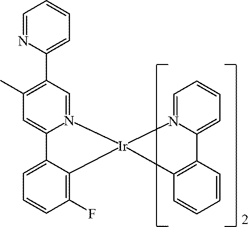 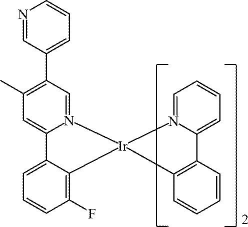 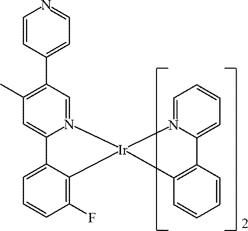 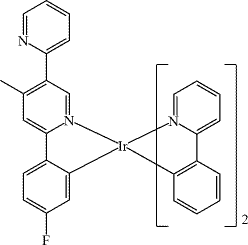 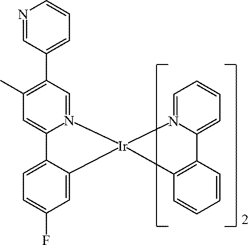 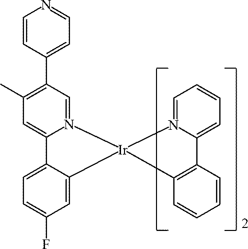 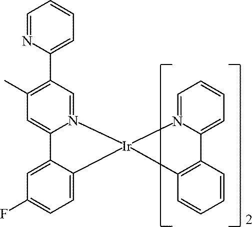 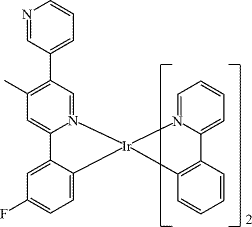 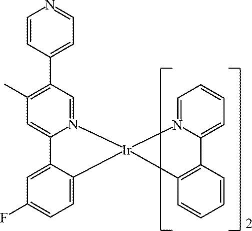 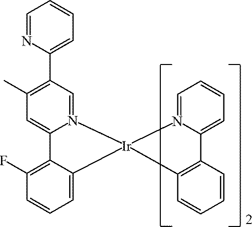 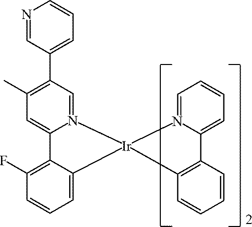 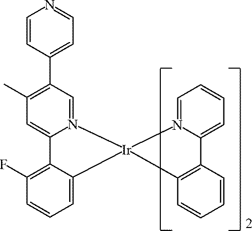 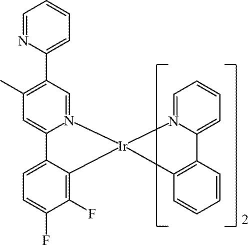 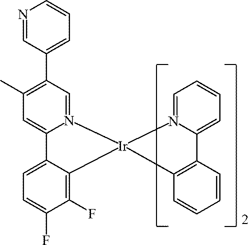 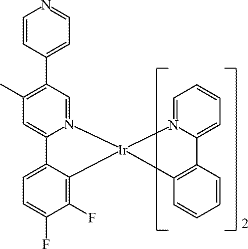 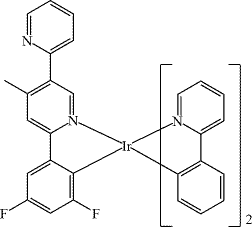 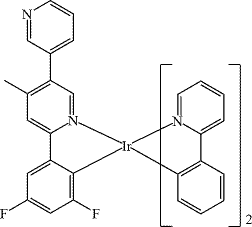 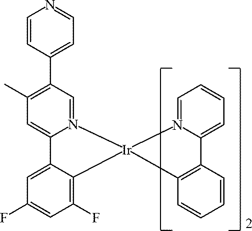 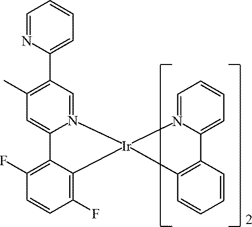 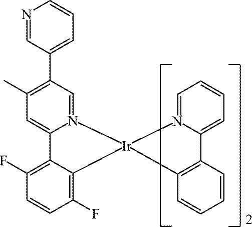 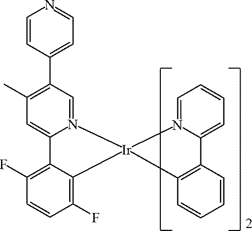 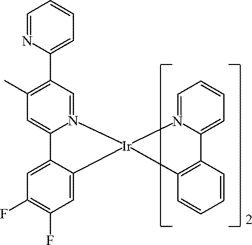 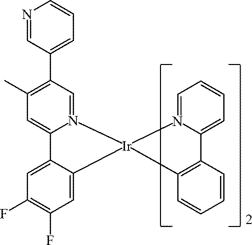 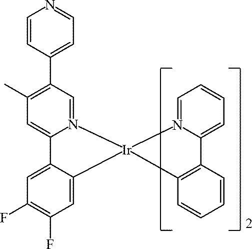 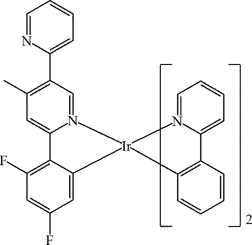 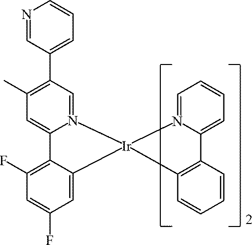 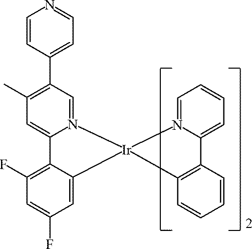 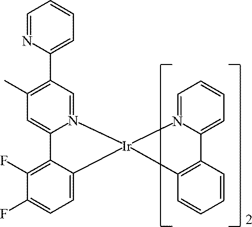 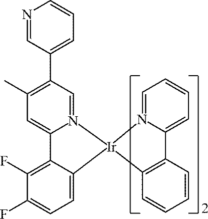 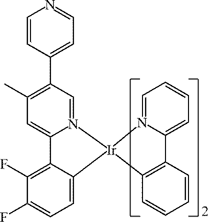 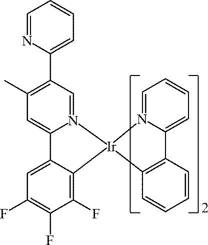 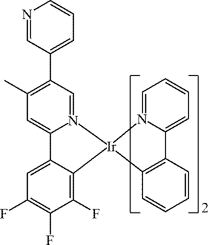 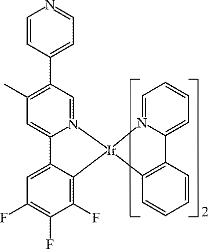 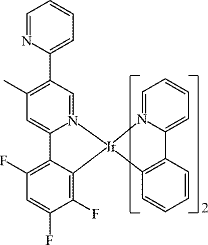 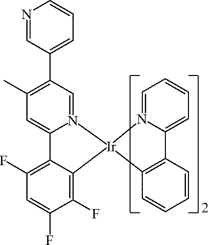 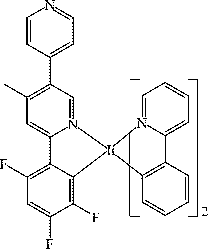 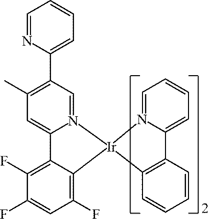 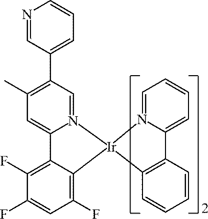 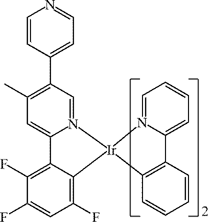 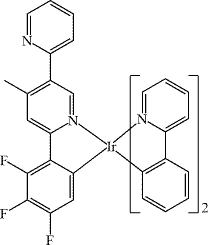 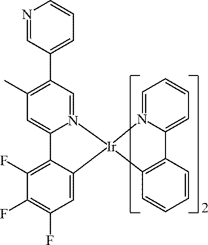 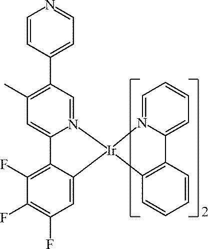 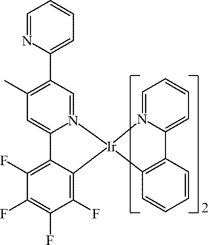 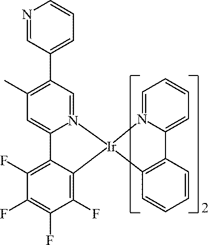 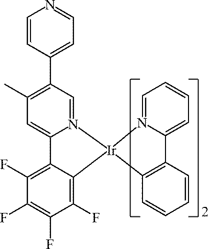 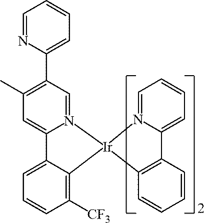 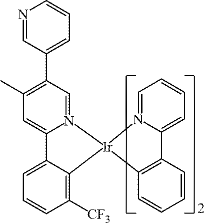 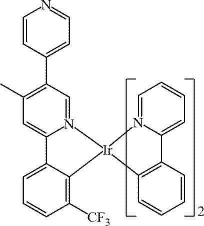 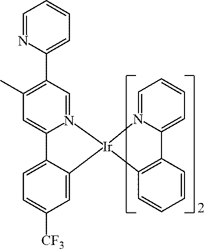 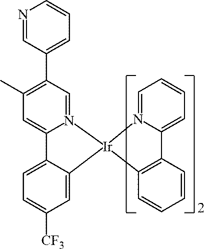 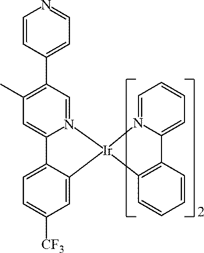 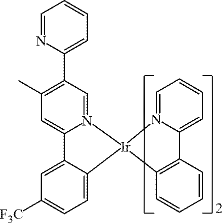 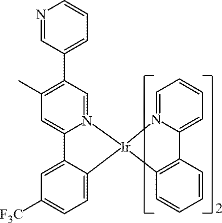 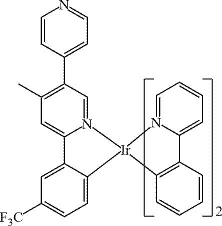 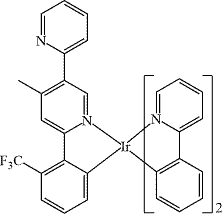 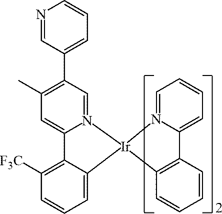 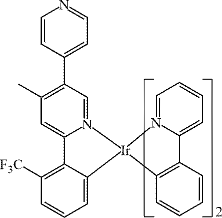 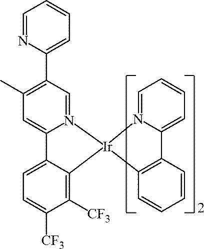 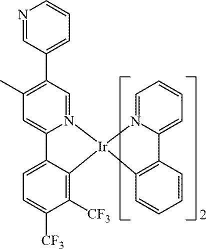 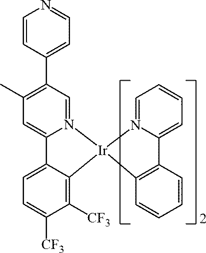 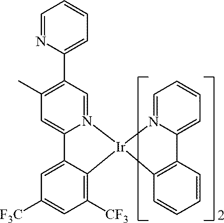 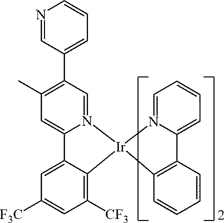 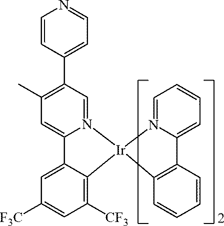 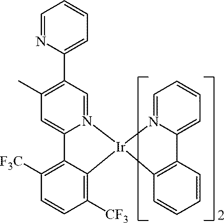 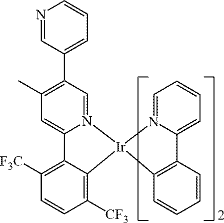 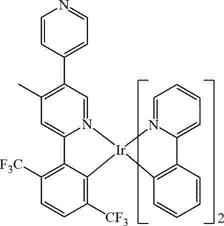 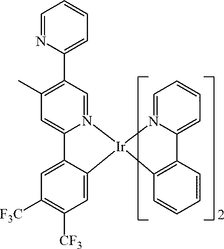 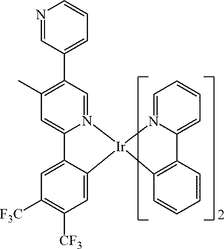 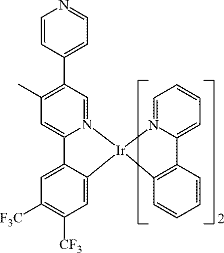 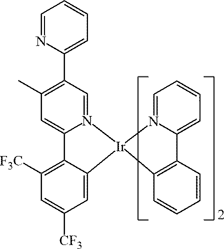 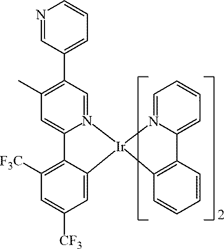 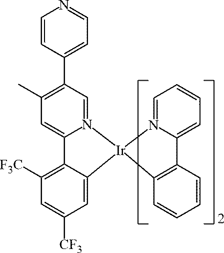 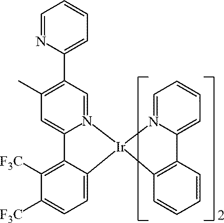 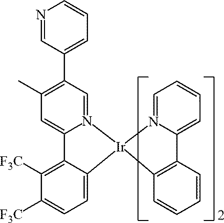 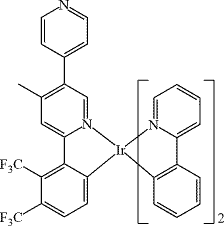 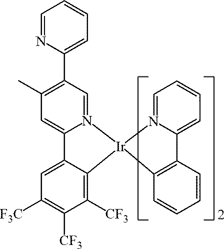 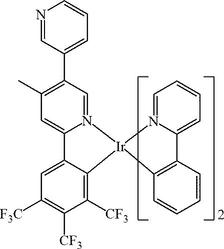 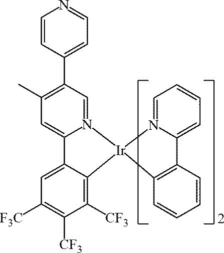 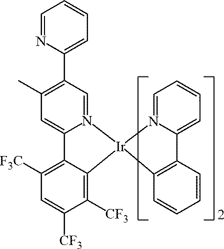 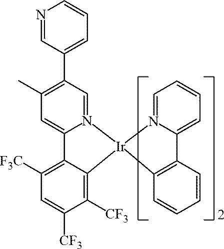 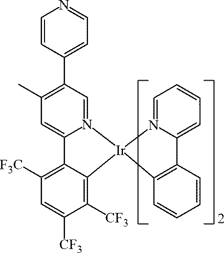 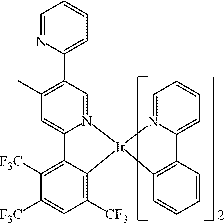 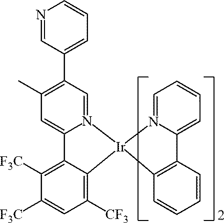 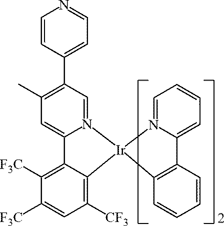 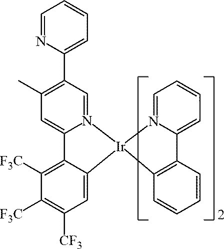 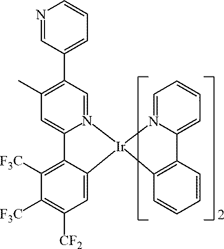 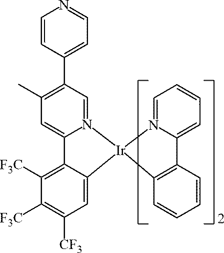 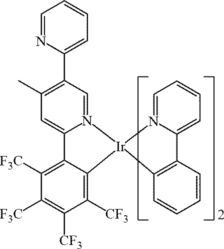 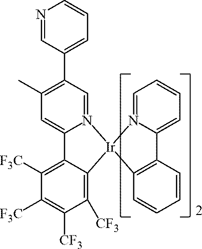 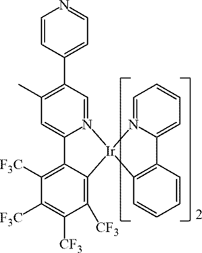 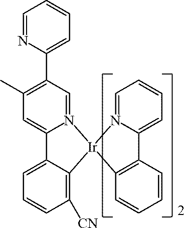 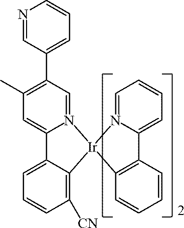 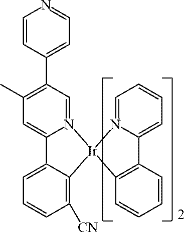 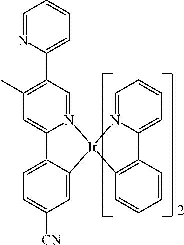 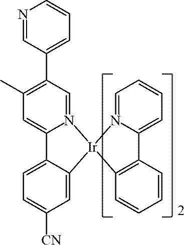 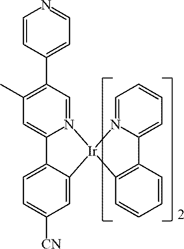 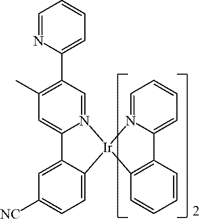 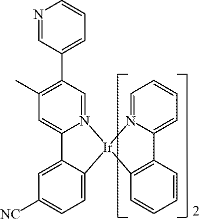 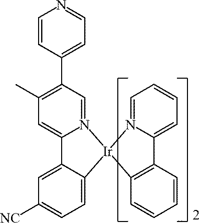 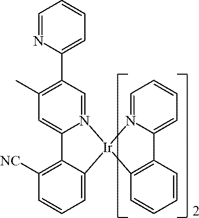 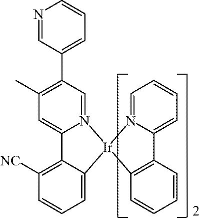 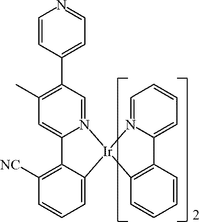 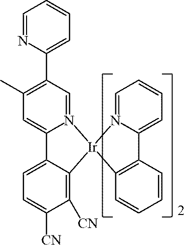 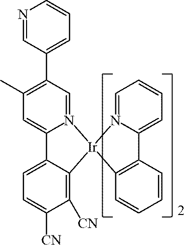 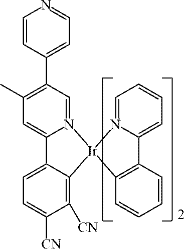 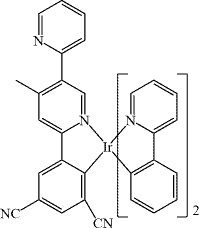 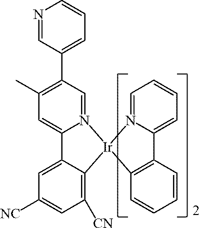 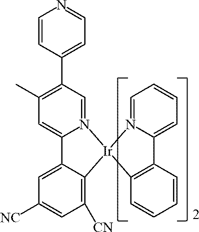 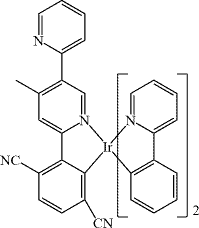 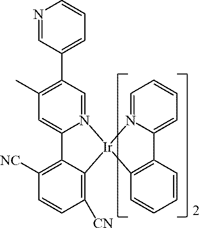 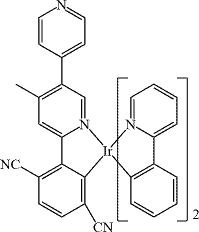 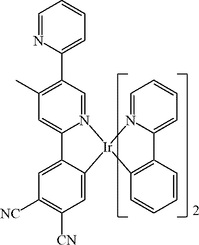 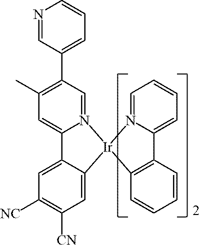 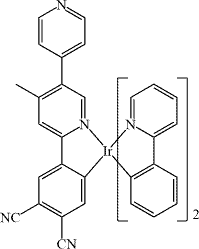 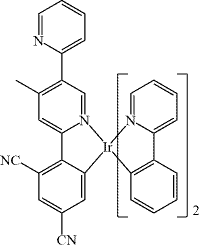 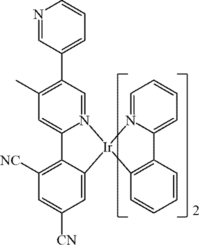 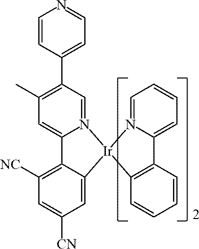 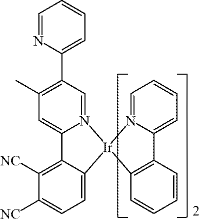 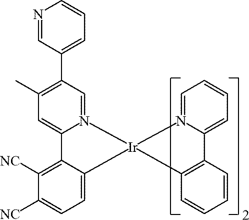 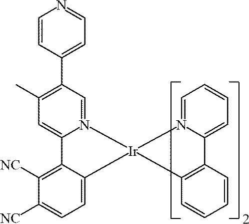 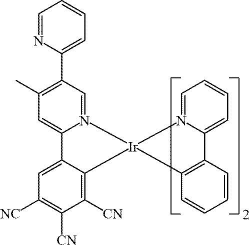 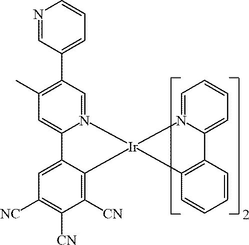 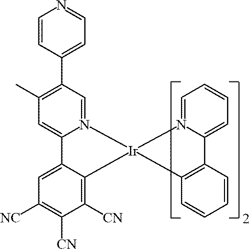 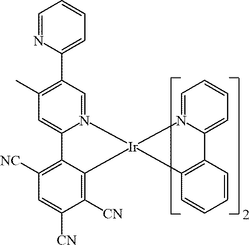 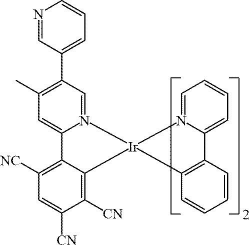 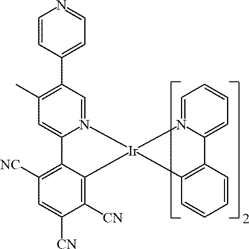 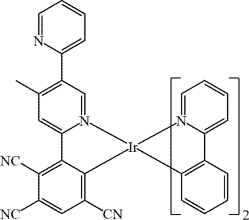 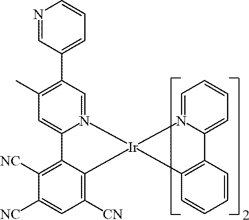 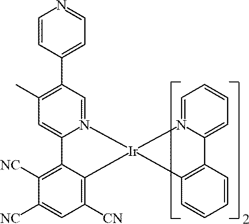 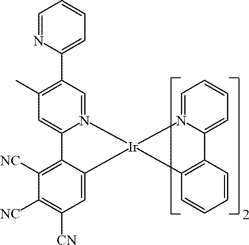 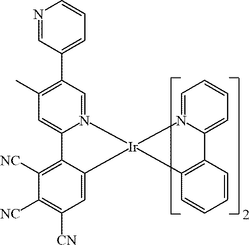 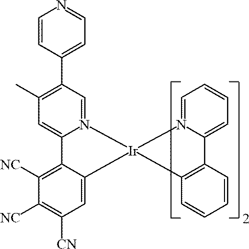 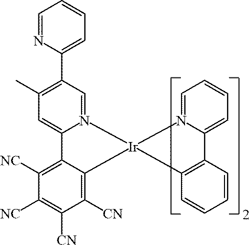 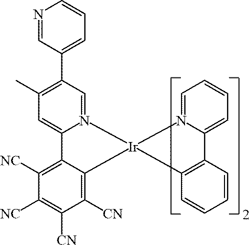 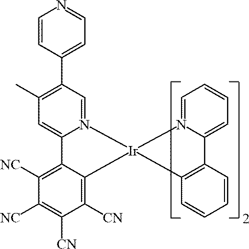 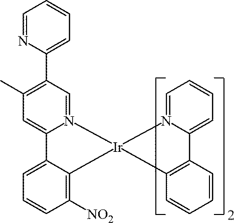 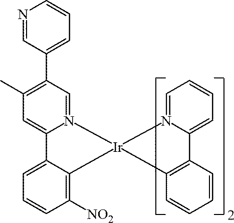 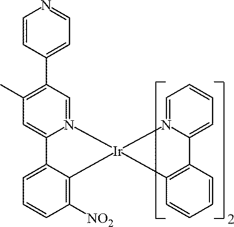 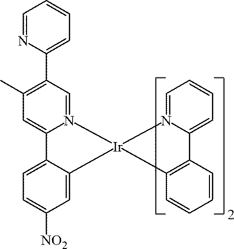 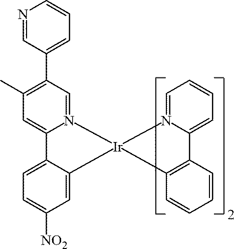 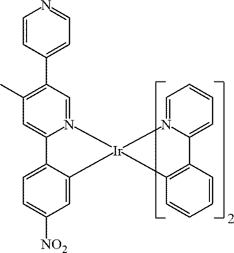 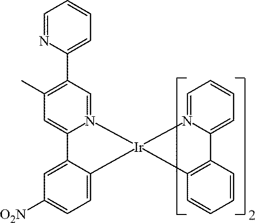 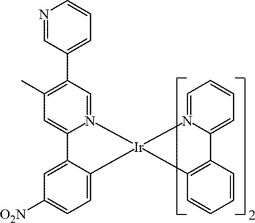 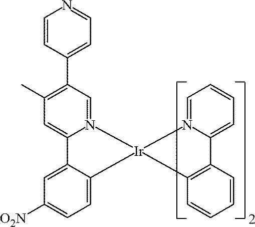 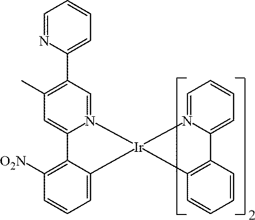 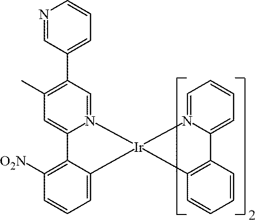 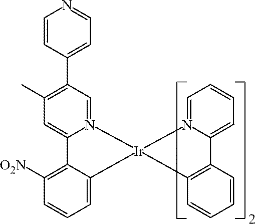 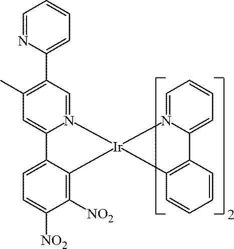 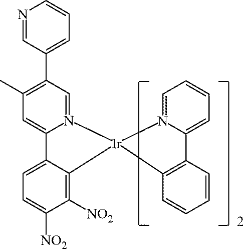 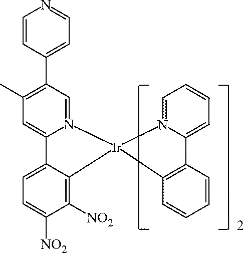 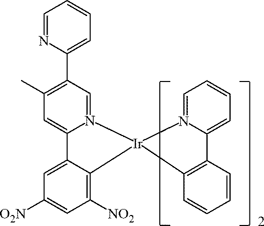 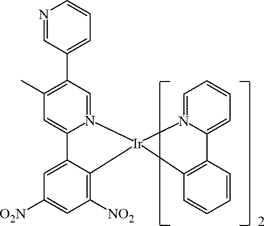 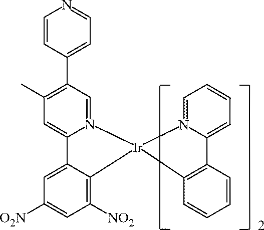 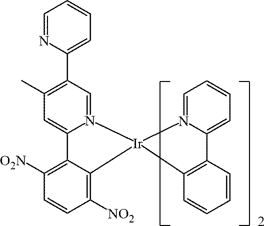 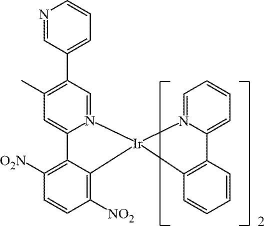 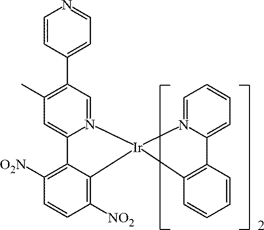 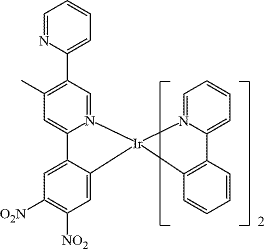 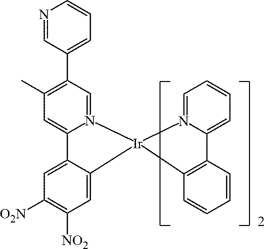 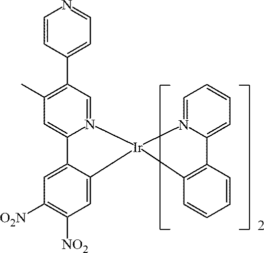 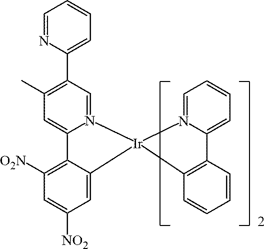 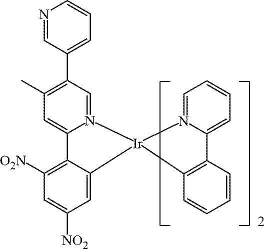 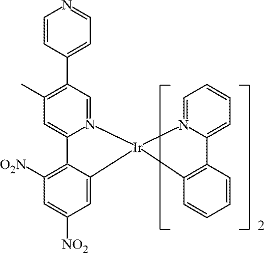 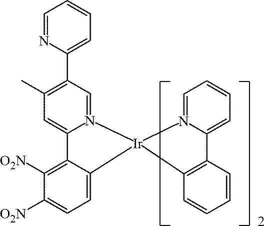 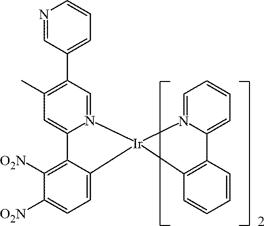 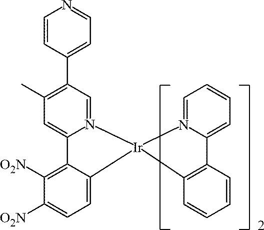 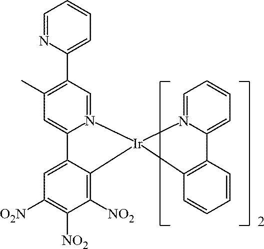 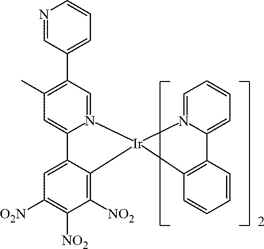 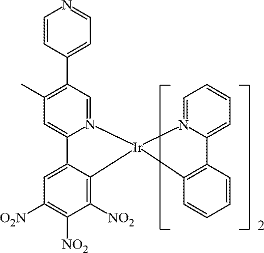 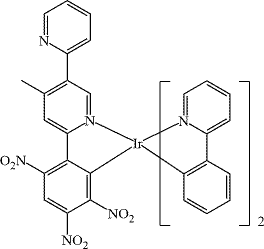 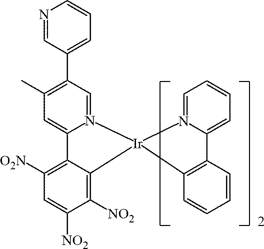 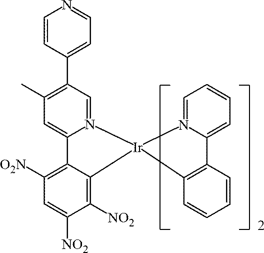 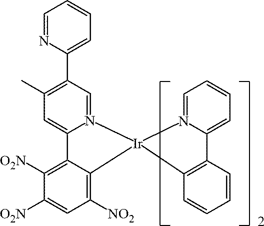 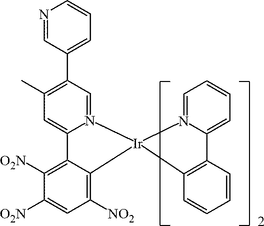 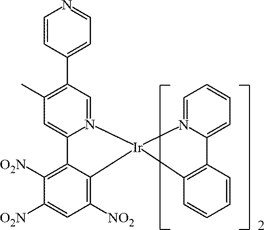 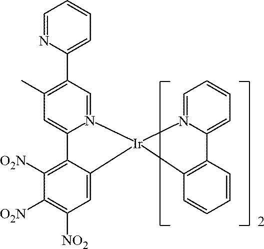 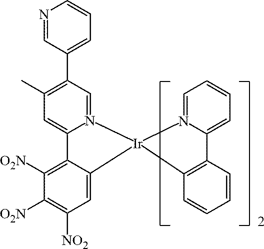 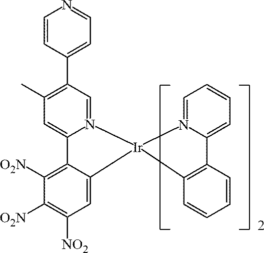 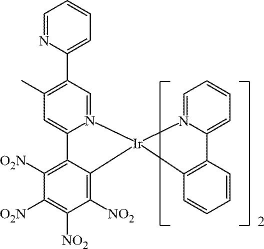 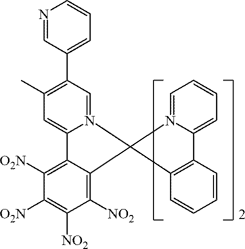 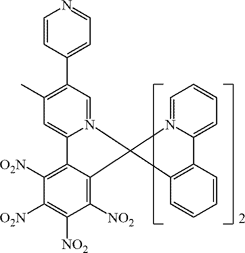 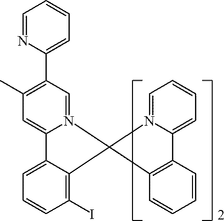 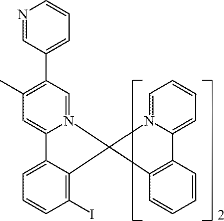 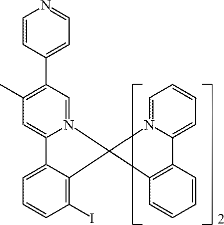 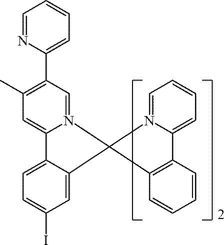 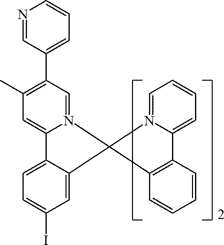 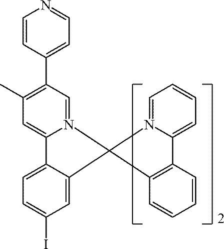 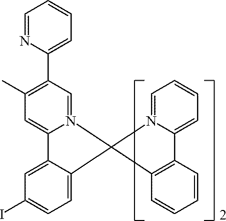 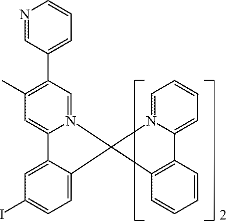 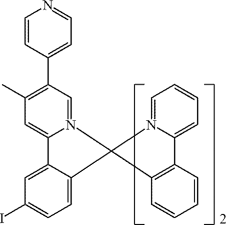 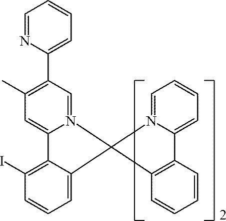 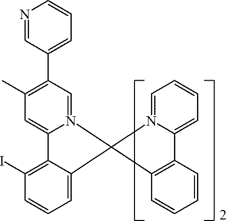 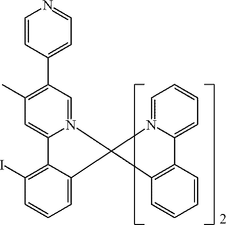 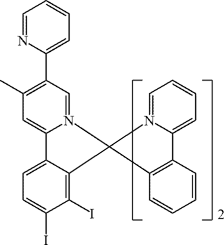 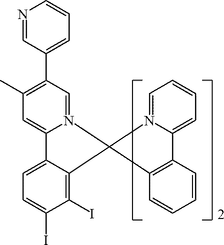 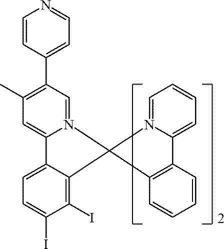 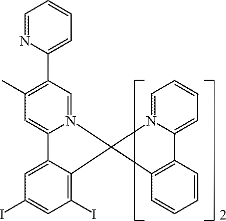 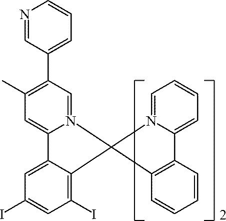 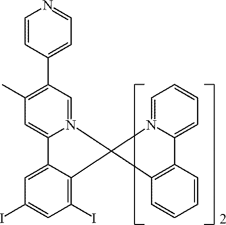 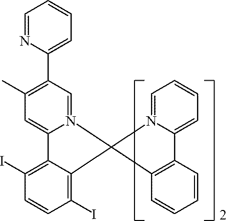 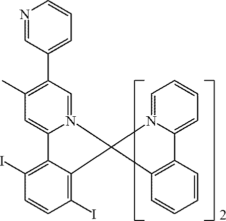 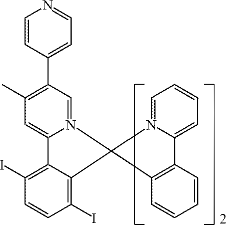 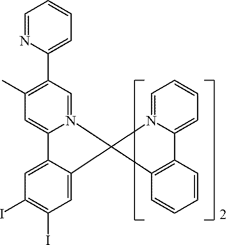 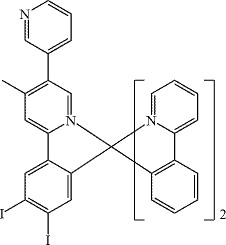 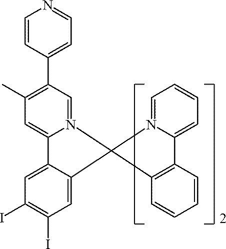 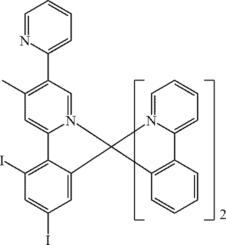 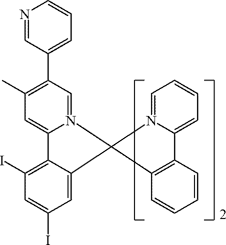 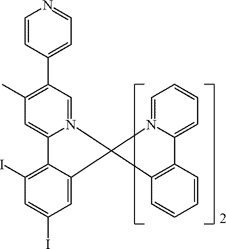 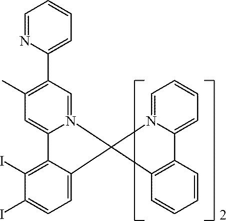 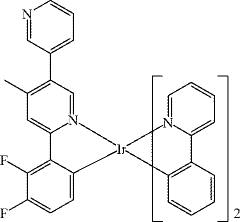 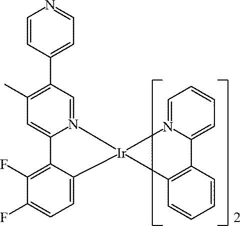 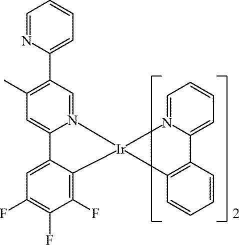 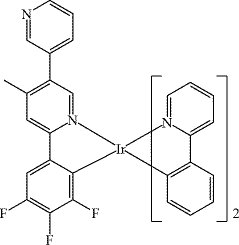 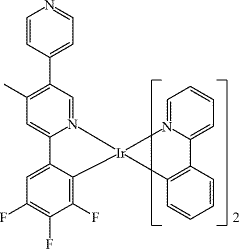 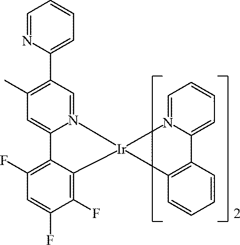 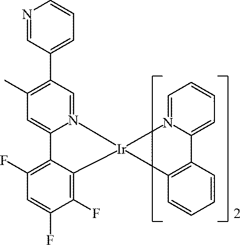 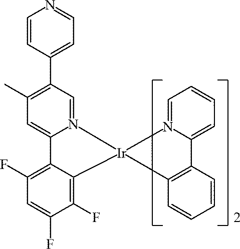 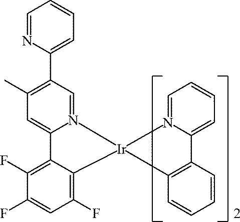 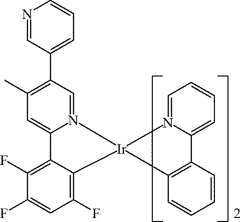 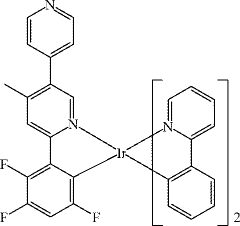 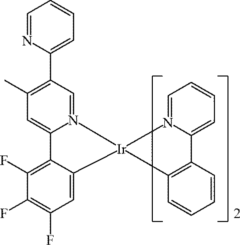 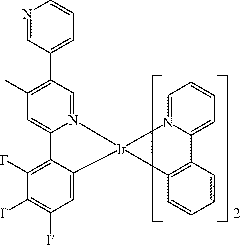 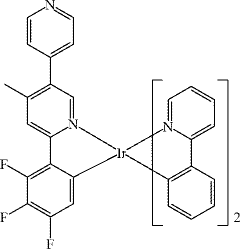 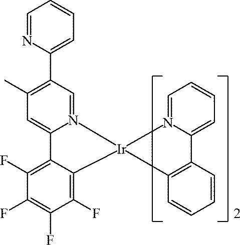 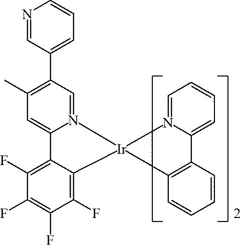 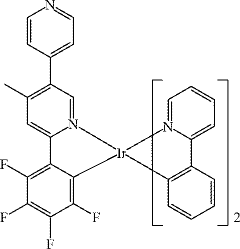 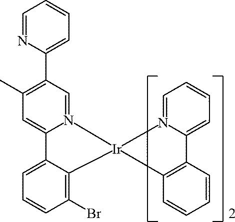 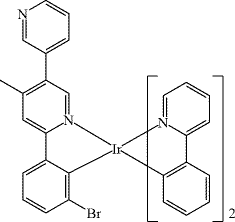 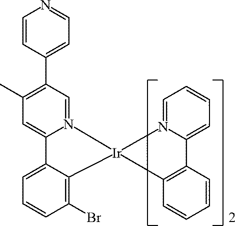 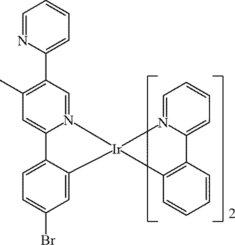 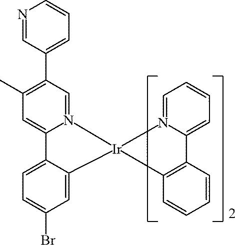 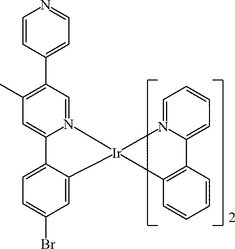 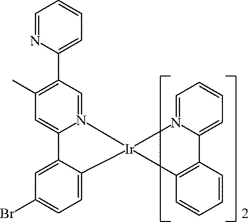 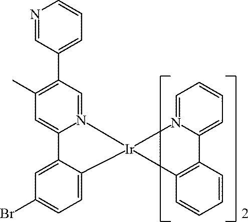 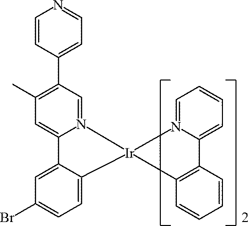 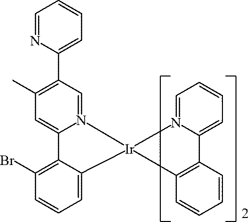 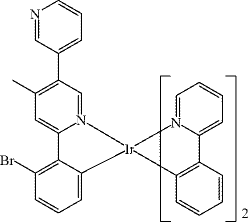 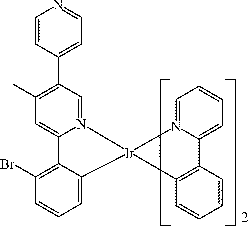 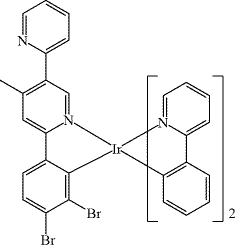 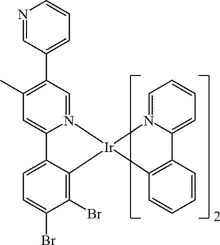 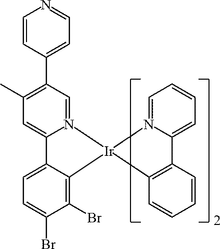 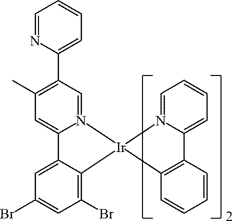 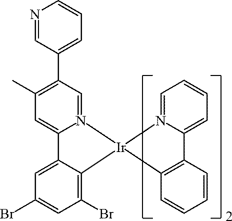 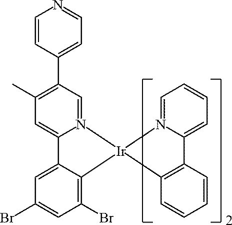 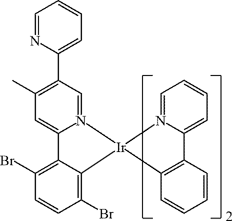 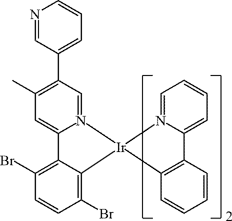 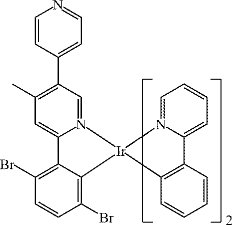 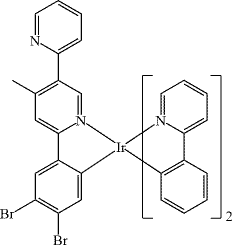 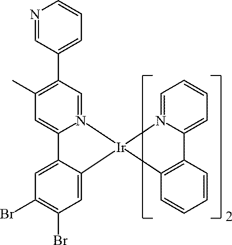 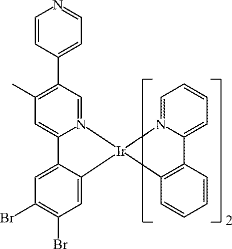 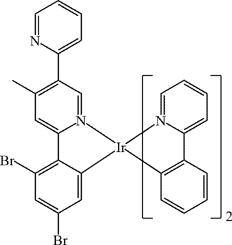 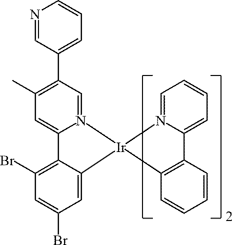 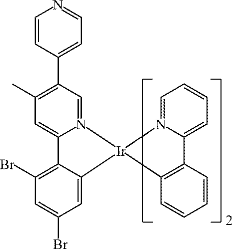 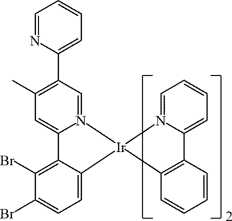 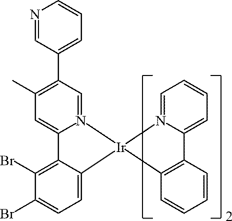 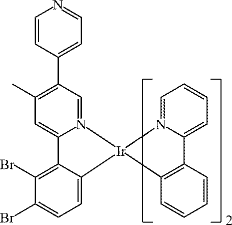 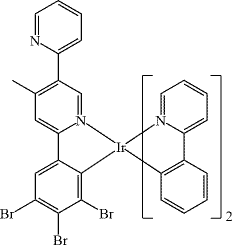 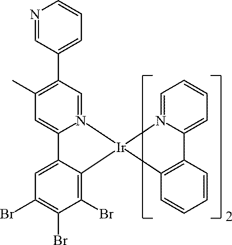 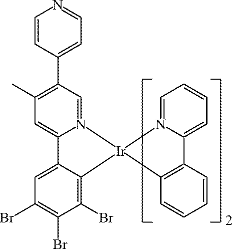 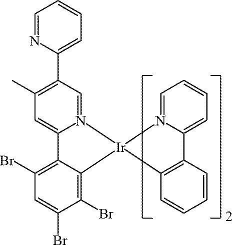 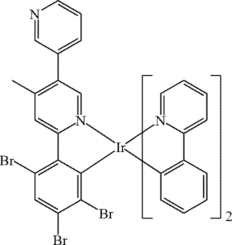 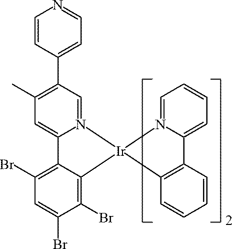 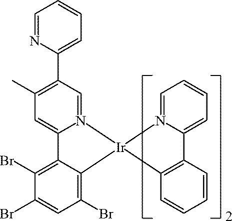 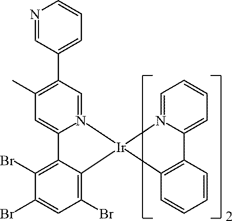 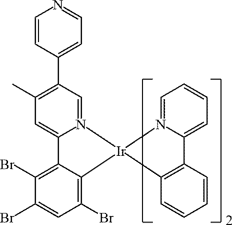 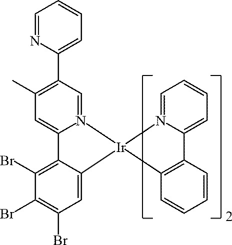 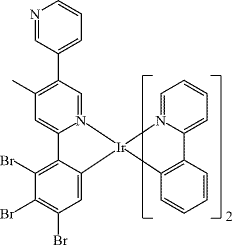 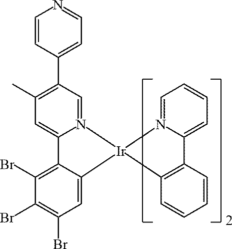 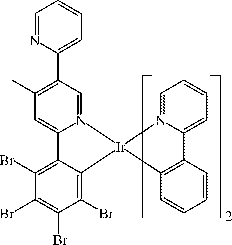 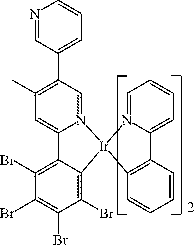 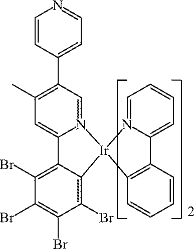 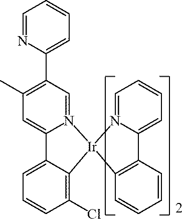 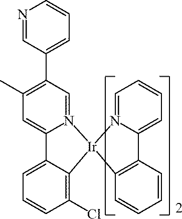 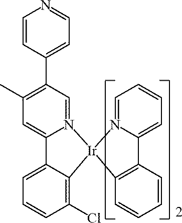 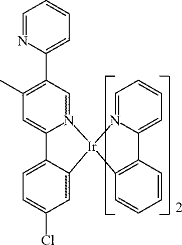 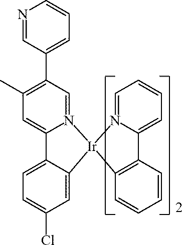 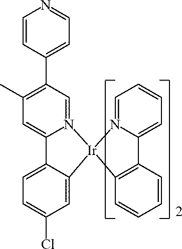 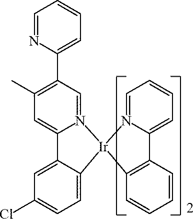 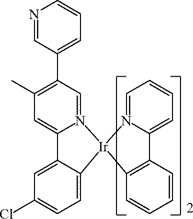 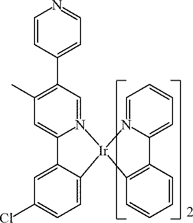 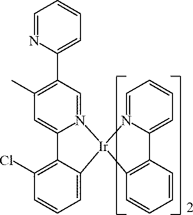 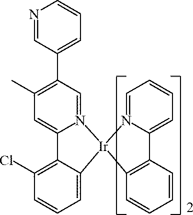 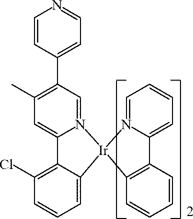 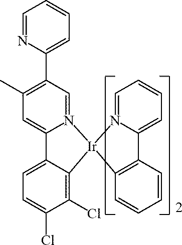 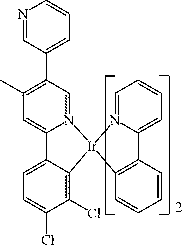 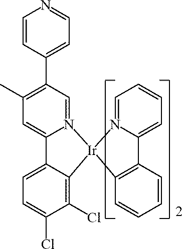 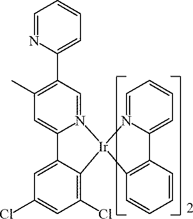 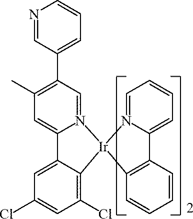 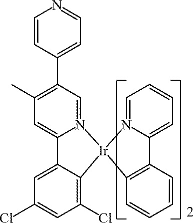 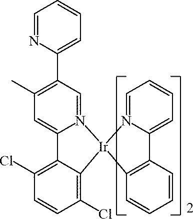 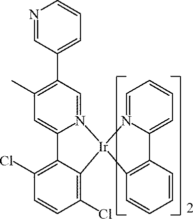 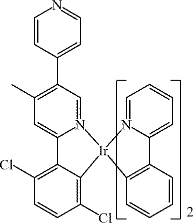 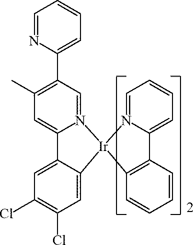 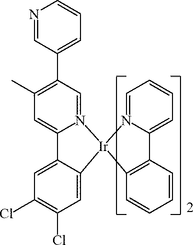 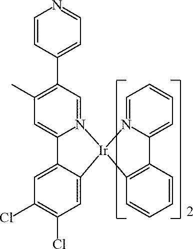 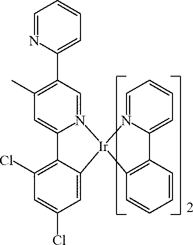 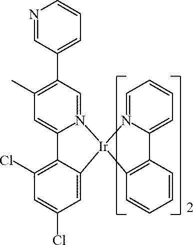 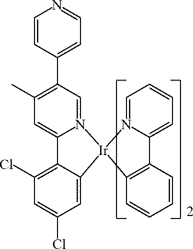 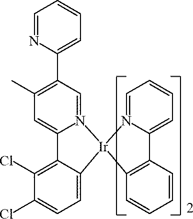 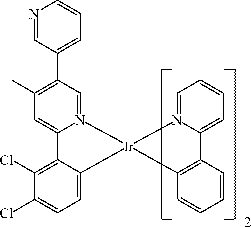 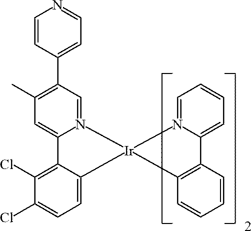 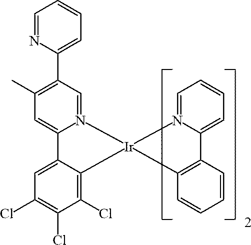 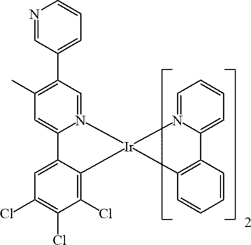 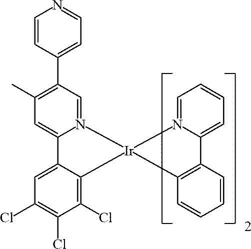 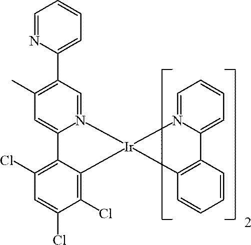 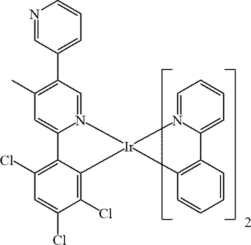 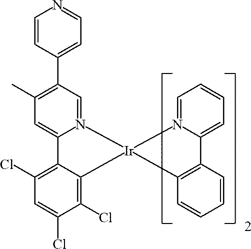 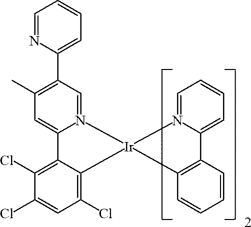 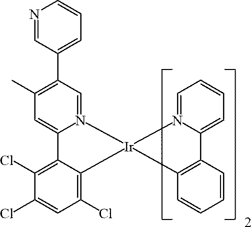 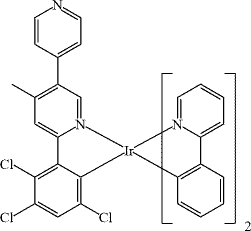 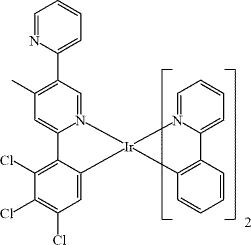 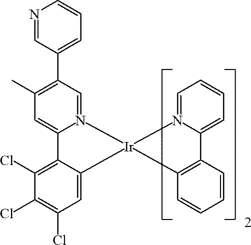 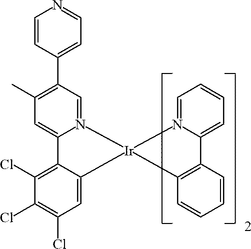 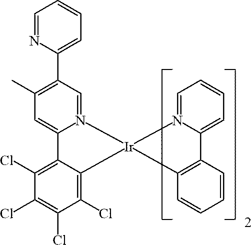 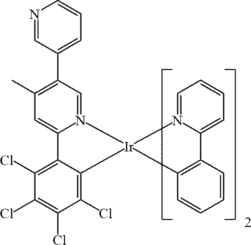 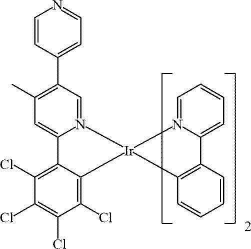
.

10. The organic light emitting diode according to claim 1, wherein the fluorescent dopant is selected from the following Compound 2-1 to Compound 2-117: 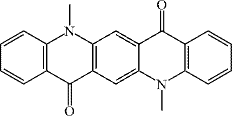 [SMILES: Cn1c2ccccc2c(=O)c2cc3c(cc21)c(=O)c1ccccc1n3C] 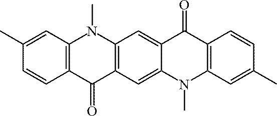 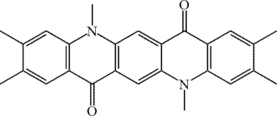 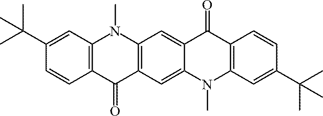 [SMILES: Cn1c2cc(C(C)(C)C)ccc2c(=O)c2cc3c(cc21)c(=O)c1ccc(C(C)(C)C)cc1n3C] 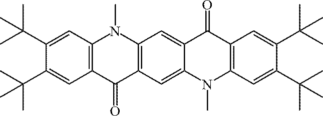 [SMILES: Cn1c2cc(C(C)(C)C)c(C(C)(C)C)cc2c(=O)c2cc3c(cc21)c(=O)c1cc(C(C)(C)C)c(C(C)(C)C)cc1n3C] 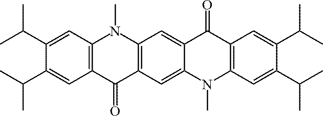 [SMILES: CC(C)c1cc2c(=O)c3cc4c(cc3n(C)c2cc1C(C)C)c(=O)c1cc(C(C)C)c(C(C)C)cc1n4C] 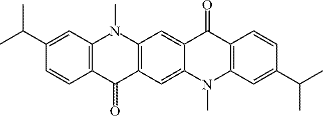 [SMILES: CC(C)c1ccc2c(=O)c3cc4c(cc3n(C)c2c1)c(=O)c1ccc(C(C)C)cc1n4C] 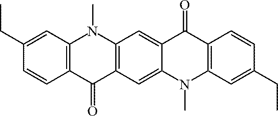 [SMILES: CCc1ccc2c(=O)c3cc4c(cc3n(C)c2c1)c(=O)c1ccc(CC)cc1n4C] 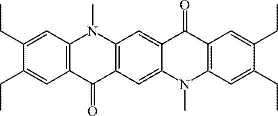 [SMILES: CCc1cc2c(=O)c3cc4c(cc3n(C)c2cc1CC)c(=O)c1cc(CC)c(CC)cc1n4C] 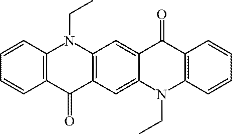 [SMILES: CCn1c2ccccc2c(=O)c2cc3c(cc21)c(=O)c1ccccc1n3CC] 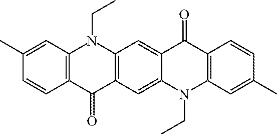 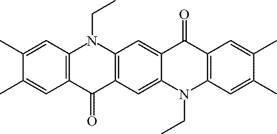 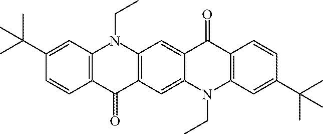 [SMILES: CCn1c2cc(C(C)(C)C)ccc2c(=O)c2cc3c(cc21)c(=O)c1ccc(C(C)(C)C)cc1n3CC] 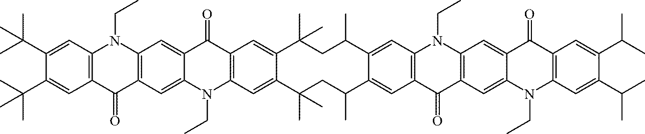 [SMILES: CCn1c2cc(C(C)C)c(C(C)C)cc2c(=O)c2cc3c(cc21)c(=O)c1cc2c(cc1n3CC)C(C)CC(C)(C)c1cc3c(=O)c4cc5c(cc4n(CC)c3cc1C(C)(C)CC2C)c(=O)c1cc(C(C)(C)C)c(C(C)(C)C)cc1n5CC] 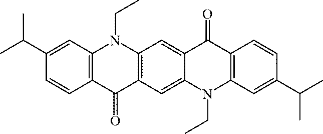 [SMILES: CCn1c2cc(C(C)C)ccc2c(=O)c2cc3c(cc21)c(=O)c1ccc(C(C)C)cc1n3CC] 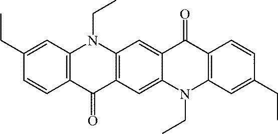 [SMILES: CCc1ccc2c(=O)c3cc4c(cc3n(CC)c2c1)c(=O)c1ccc(CC)cc1n4CC] 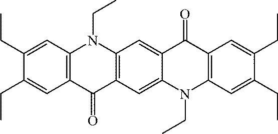 [SMILES: CCc1cc2c(=O)c3cc4c(cc3n(CC)c2cc1CC)c(=O)c1cc(CC)c(CC)cc1n4CC] 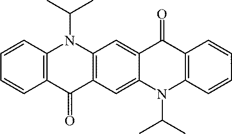 [SMILES: CC(C)n1c2ccccc2c(=O)c2cc3c(cc21)c(=O)c1ccccc1n3C(C)C] 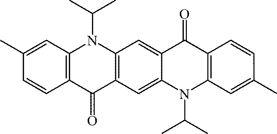 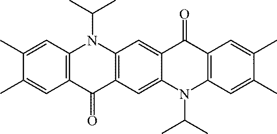 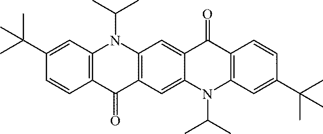 [SMILES: CC(C)n1c2cc(C(C)(C)C)ccc2c(=O)c2cc3c(cc21)c(=O)c1ccc(C(C)(C)C)cc1n3C(C)C] 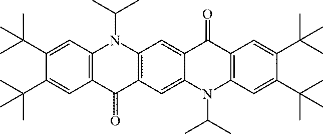 [SMILES: CC(C)n1c2cc(C(C)(C)C)c(C(C)(C)C)cc2c(=O)c2cc3c(cc21)c(=O)c1cc(C(C)(C)C)c(C(C)(C)C)cc1n3C(C)C] 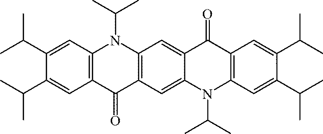 [SMILES: CC(C)c1cc2c(=O)c3cc4c(cc3n(C(C)C)c2cc1C(C)C)c(=O)c1cc(C(C)C)c(C(C)C)cc1n4C(C)C] 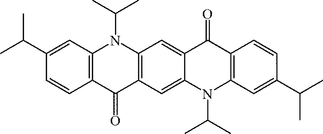 [SMILES: CC(C)c1ccc2c(=O)c3cc4c(cc3n(C(C)C)c2c1)c(=O)c1ccc(C(C)C)cc1n4C(C)C] 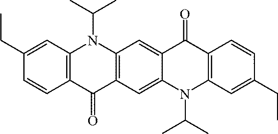 [SMILES: CCc1ccc2c(=O)c3cc4c(cc3n(C(C)C)c2c1)c(=O)c1ccc(CC)cc1n4C(C)C] 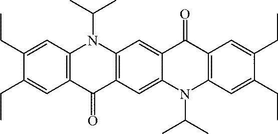 [SMILES: CCc1cc2c(=O)c3cc4c(cc3n(C(C)C)c2cc1CC)c(=O)c1cc(CC)c(CC)cc1n4C(C)C] 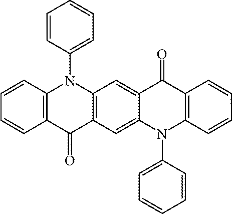 [SMILES: O=c1c2ccccc2n(-c2ccccc2)c2cc3c(=O)c4ccccc4n(-c4ccccc4)c3cc12] 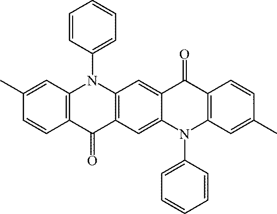 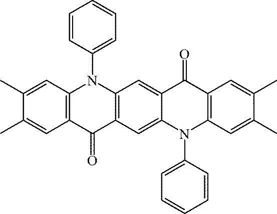 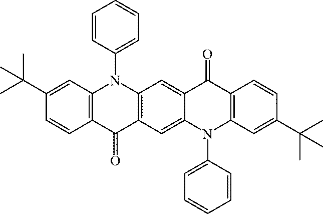 [SMILES: CC(C)(C)c1ccc2c(=O)c3cc4c(cc3n(-c3ccccc3)c2c1)c(=O)c1ccc(C(C)(C)C)cc1n4-c1ccccc1] 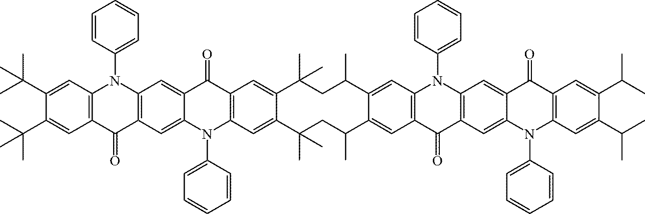 [SMILES: CC(C)c1cc2c(=O)c3cc4c(cc3n(-c3ccccc3)c2cc1C(C)C)c(=O)c1cc2c(cc1n4-c1ccccc1)C(C)CC(C)(C)c1cc3c(=O)c4cc5c(cc4n(-c4ccccc4)c3cc1C(C)(C)CC2C)c(=O)c1cc(C(C)(C)C)c(C(C)(C)C)cc1n5-c1ccccc1] 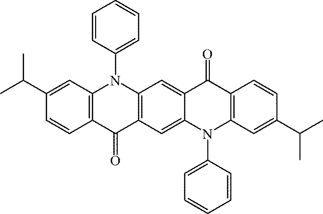 [SMILES: CC(C)c1ccc2c(=O)c3cc4c(cc3n(-c3ccccc3)c2c1)c(=O)c1ccc(C(C)C)cc1n4-c1ccccc1] 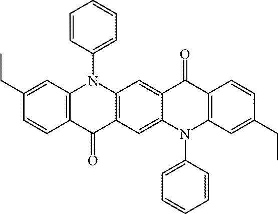 [SMILES: CCc1ccc2c(=O)c3cc4c(cc3n(-c3ccccc3)c2c1)c(=O)c1ccc(CC)cc1n4-c1ccccc1] 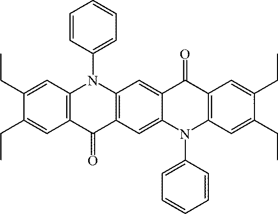 [SMILES: CCc1cc2c(=O)c3cc4c(cc3n(-c3ccccc3)c2cc1CC)c(=O)c1cc(CC)c(CC)cc1n4-c1ccccc1] 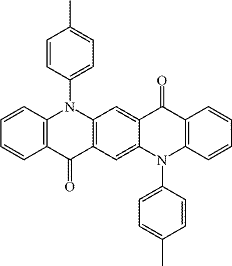 [SMILES: Cc1ccc(-n2c3ccccc3c(=O)c3cc4c(cc32)c(=O)c2ccccc2n4-c2ccc(C)cc2)cc1] 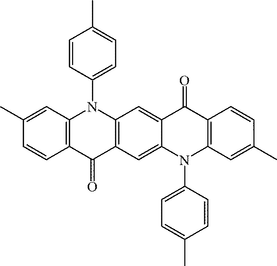 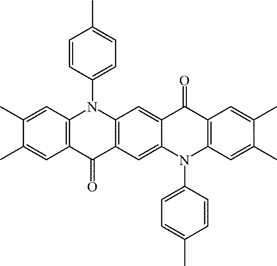 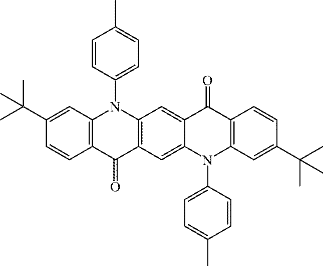 [SMILES: Cc1ccc(-n2c3cc(C(C)(C)C)ccc3c(=O)c3cc4c(cc32)c(=O)c2ccc(C(C)(C)C)cc2n4-c2ccc(C)cc2)cc1] 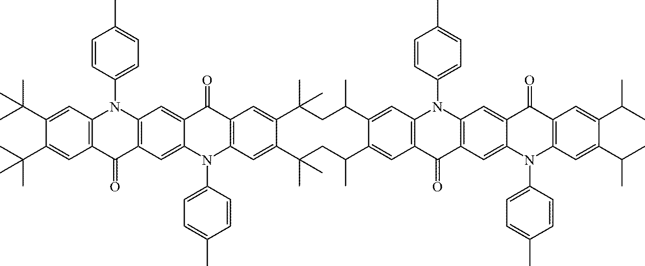 [SMILES: Cc1ccc(-n2c3cc(C(C)C)c(C(C)C)cc3c(=O)c3cc4c(cc32)c(=O)c2cc3c(cc2n4-c2ccc(C)cc2)C(C)CC(C)(C)c2cc4c(=O)c5cc6c(cc5n(-c5ccc(C)cc5)c4cc2C(C)(C)CC3C)c(=O)c2cc(C(C)(C)C)c(C(C)(C)C)cc2n6-c2ccc(C)cc2)cc1] 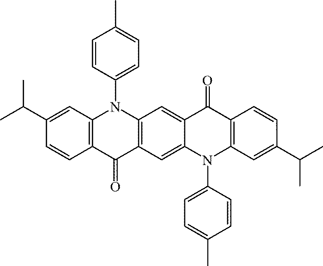 [SMILES: Cc1ccc(-n2c3cc(C(C)C)ccc3c(=O)c3cc4c(cc32)c(=O)c2ccc(C(C)C)cc2n4-c2ccc(C)cc2)cc1] 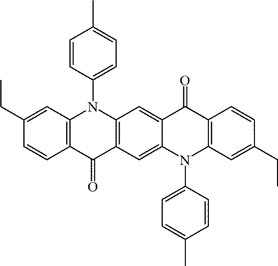 [SMILES: CCc1ccc2c(=O)c3cc4c(cc3n(-c3ccc(C)cc3)c2c1)c(=O)c1ccc(CC)cc1n4-c1ccc(C)cc1] 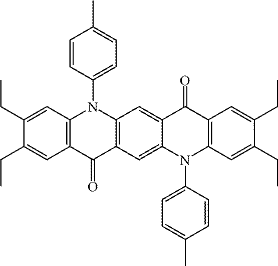 [SMILES: CCc1cc2c(=O)c3cc4c(cc3n(-c3ccc(C)cc3)c2cc1CC)c(=O)c1cc(CC)c(CC)cc1n4-c1ccc(C)cc1] 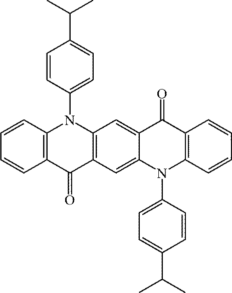 [SMILES: CC(C)c1ccc(-n2c3ccccc3c(=O)c3cc4c(cc32)c(=O)c2ccccc2n4-c2ccc(C(C)C)cc2)cc1] 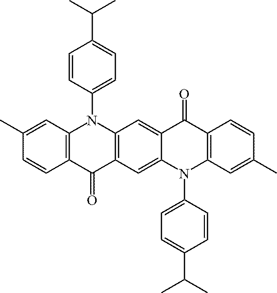 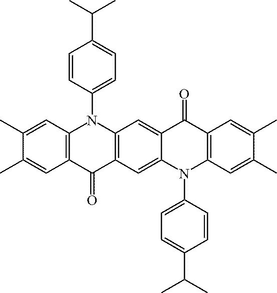 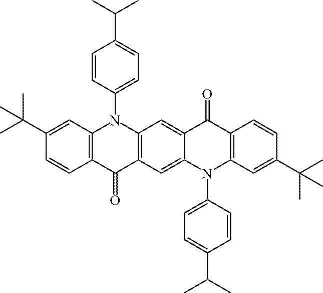 [SMILES: CC(C)c1ccc(-n2c3cc(C(C)(C)C)ccc3c(=O)c3cc4c(cc32)c(=O)c2ccc(C(C)(C)C)cc2n4-c2ccc(C(C)C)cc2)cc1] 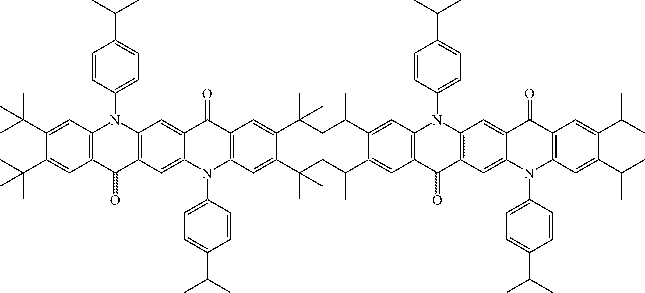 [SMILES: CC(C)c1ccc(-n2c3cc(C(C)C)c(C(C)C)cc3c(=O)c3cc4c(cc32)c(=O)c2cc3c(cc2n4-c2ccc(C(C)C)cc2)C(C)CC(C)(C)c2cc4c(=O)c5cc6c(cc5n(-c5ccc(C(C)C)cc5)c4cc2C(C)(C)CC3C)c(=O)c2cc(C(C)(C)C)c(C(C)(C)C)cc2n6-c2ccc(C(C)C)cc2)cc1] 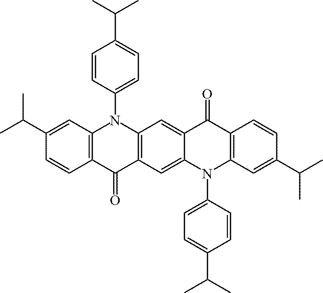 [SMILES: CC(C)c1ccc(-n2c3cc(C(C)C)ccc3c(=O)c3cc4c(cc32)c(=O)c2ccc(C(C)C)cc2n4-c2ccc(C(C)C)cc2)cc1] 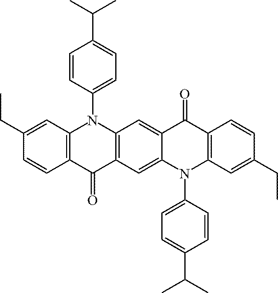 [SMILES: CCc1ccc2c(=O)c3cc4c(cc3n(-c3ccc(C(C)C)cc3)c2c1)c(=O)c1ccc(CC)cc1n4-c1ccc(C(C)C)cc1] 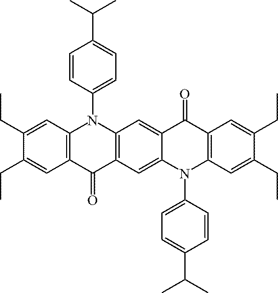 [SMILES: CCc1cc2c(=O)c3cc4c(cc3n(-c3ccc(C(C)C)cc3)c2cc1CC)c(=O)c1cc(CC)c(CC)cc1n4-c1ccc(C(C)C)cc1] 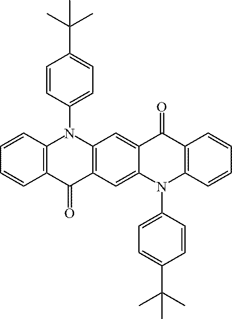 [SMILES: CC(C)(C)c1ccc(-n2c3ccccc3c(=O)c3cc4c(cc32)c(=O)c2ccccc2n4-c2ccc(C(C)(C)C)cc2)cc1] 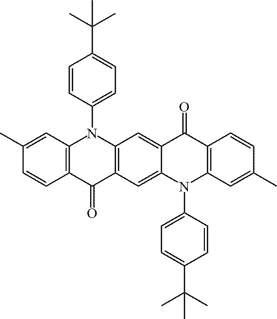 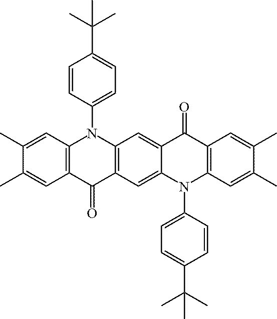 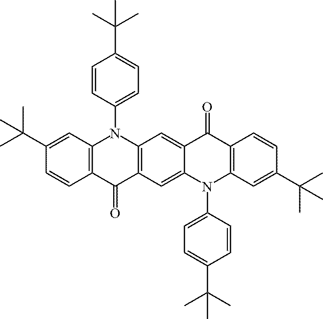 [SMILES: CC(C)(C)c1ccc(-n2c3cc(C(C)(C)C)ccc3c(=O)c3cc4c(cc32)c(=O)c2ccc(C(C)(C)C)cc2n4-c2ccc(C(C)(C)C)cc2)cc1] 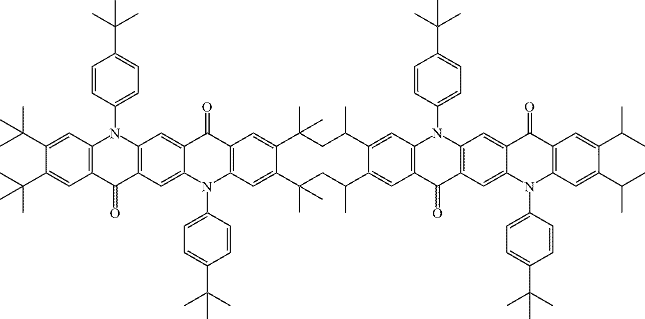 [SMILES: CC(C)c1cc2c(=O)c3cc4c(cc3n(-c3ccc(C(C)(C)C)cc3)c2cc1C(C)C)c(=O)c1cc2c(cc1n4-c1ccc(C(C)(C)C)cc1)C(C)CC(C)(C)c1cc3c(=O)c4cc5c(cc4n(-c4ccc(C(C)(C)C)cc4)c3cc1C(C)(C)CC2C)c(=O)c1cc(C(C)(C)C)c(C(C)(C)C)cc1n5-c1ccc(C(C)(C)C)cc1] 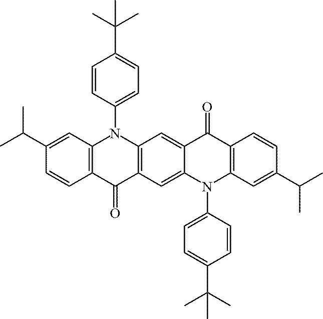 [SMILES: CC(C)c1ccc2c(=O)c3cc4c(cc3n(-c3ccc(C(C)(C)C)cc3)c2c1)c(=O)c1ccc(C(C)C)cc1n4-c1ccc(C(C)(C)C)cc1] 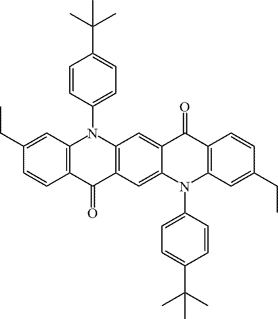 [SMILES: CCc1ccc2c(=O)c3cc4c(cc3n(-c3ccc(C(C)(C)C)cc3)c2c1)c(=O)c1ccc(CC)cc1n4-c1ccc(C(C)(C)C)cc1] 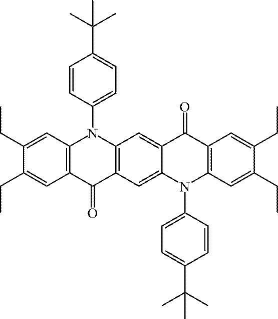 [SMILES: CCc1cc2c(=O)c3cc4c(cc3n(-c3ccc(C(C)(C)C)cc3)c2cc1CC)c(=O)c1cc(CC)c(CC)cc1n4-c1ccc(C(C)(C)C)cc1] 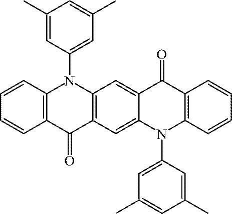 [SMILES: Cc1cc(C)cc(-n2c3ccccc3c(=O)c3cc4c(cc32)c(=O)c2ccccc2n4-c2cc(C)cc(C)c2)c1] 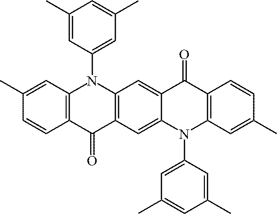 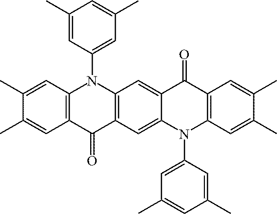 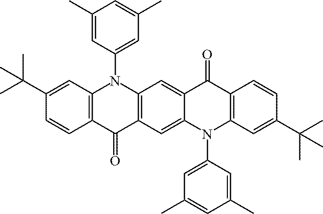 [SMILES: Cc1cc(C)cc(-n2c3cc(C(C)(C)C)ccc3c(=O)c3cc4c(cc32)c(=O)c2ccc(C(C)(C)C)cc2n4-c2cc(C)cc(C)c2)c1] 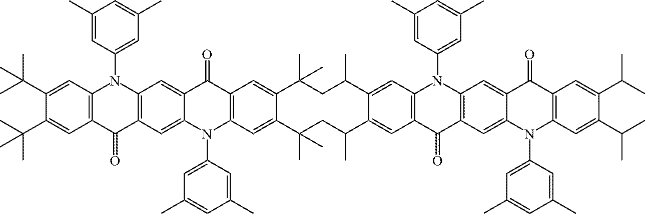 [SMILES: Cc1cc(C)cc(-n2c3cc(C(C)C)c(C(C)C)cc3c(=O)c3cc4c(cc32)c(=O)c2cc3c(cc2n4-c2cc(C)cc(C)c2)C(C)CC(C)(C)c2cc4c(=O)c5cc6c(cc5n(-c5cc(C)cc(C)c5)c4cc2C(C)(C)CC3C)c(=O)c2cc(C(C)(C)C)c(C(C)(C)C)cc2n6-c2cc(C)cc(C)c2)c1] 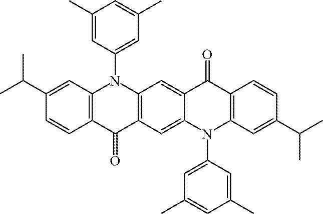 [SMILES: Cc1cc(C)cc(-n2c3cc(C(C)C)ccc3c(=O)c3cc4c(cc32)c(=O)c2ccc(C(C)C)cc2n4-c2cc(C)cc(C)c2)c1] 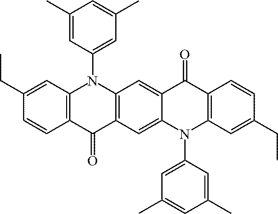 [SMILES: CCc1ccc2c(=O)c3cc4c(cc3n(-c3cc(C)cc(C)c3)c2c1)c(=O)c1ccc(CC)cc1n4-c1cc(C)cc(C)c1] 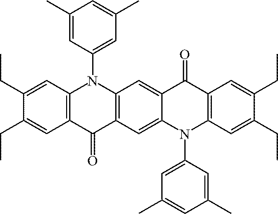 [SMILES: CCc1cc2c(=O)c3cc4c(cc3n(-c3cc(C)cc(C)c3)c2cc1CC)c(=O)c1cc(CC)c(CC)cc1n4-c1cc(C)cc(C)c1] 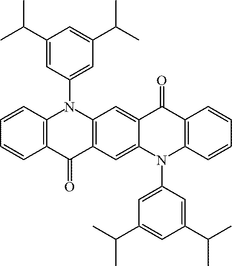 [SMILES: CC(C)c1cc(C(C)C)cc(-n2c3ccccc3c(=O)c3cc4c(cc32)c(=O)c2ccccc2n4-c2cc(C(C)C)cc(C(C)C)c2)c1] 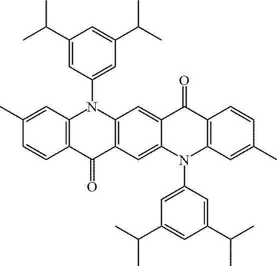 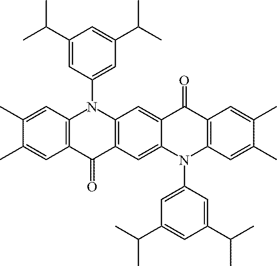 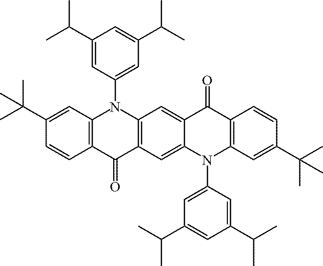 [SMILES: CC(C)c1cc(C(C)C)cc(-n2c3cc(C(C)(C)C)ccc3c(=O)c3cc4c(cc32)c(=O)c2ccc(C(C)(C)C)cc2n4-c2cc(C(C)C)cc(C(C)C)c2)c1] 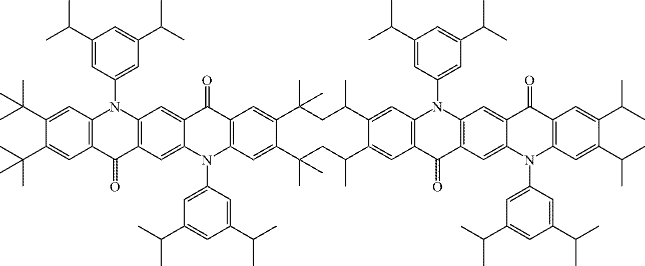 [SMILES: CC(C)c1cc(C(C)C)cc(-n2c3cc(C(C)C)c(C(C)C)cc3c(=O)c3cc4c(cc32)c(=O)c2cc3c(cc2n4-c2cc(C(C)C)cc(C(C)C)c2)C(C)CC(C)(C)c2cc4c(=O)c5cc6c(cc5n(-c5cc(C(C)C)cc(C(C)C)c5)c4cc2C(C)(C)CC3C)c(=O)c2cc(C(C)(C)C)c(C(C)(C)C)cc2n6-c2cc(C(C)C)cc(C(C)C)c2)c1] 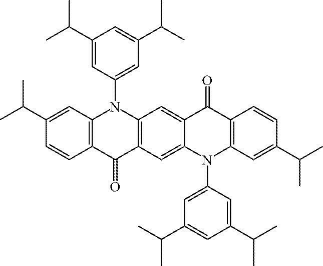 [SMILES: CC(C)c1cc(C(C)C)cc(-n2c3cc(C(C)C)ccc3c(=O)c3cc4c(cc32)c(=O)c2ccc(C(C)C)cc2n4-c2cc(C(C)C)cc(C(C)C)c2)c1] 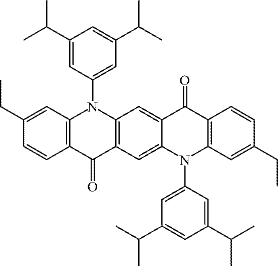 [SMILES: CCc1ccc2c(=O)c3cc4c(cc3n(-c3cc(C(C)C)cc(C(C)C)c3)c2c1)c(=O)c1ccc(CC)cc1n4-c1cc(C(C)C)cc(C(C)C)c1] 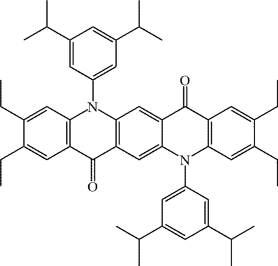 [SMILES: CCc1cc2c(=O)c3cc4c(cc3n(-c3cc(C(C)C)cc(C(C)C)c3)c2cc1CC)c(=O)c1cc(CC)c(CC)cc1n4-c1cc(C(C)C)cc(C(C)C)c1] 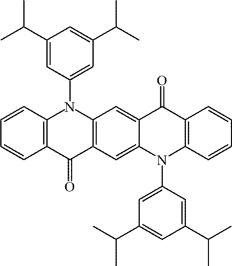 [SMILES: CC(C)c1cc(C(C)C)cc(-n2c3ccccc3c(=O)c3cc4c(cc32)c(=O)c2ccccc2n4-c2cc(C(C)C)cc(C(C)C)c2)c1] 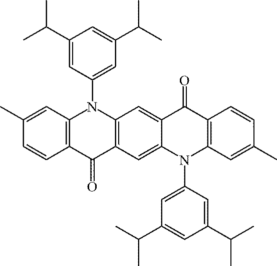 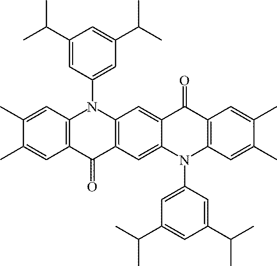 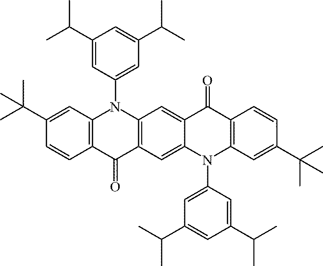 [SMILES: CC(C)c1cc(C(C)C)cc(-n2c3cc(C(C)(C)C)ccc3c(=O)c3cc4c(cc32)c(=O)c2ccc(C(C)(C)C)cc2n4-c2cc(C(C)C)cc(C(C)C)c2)c1] 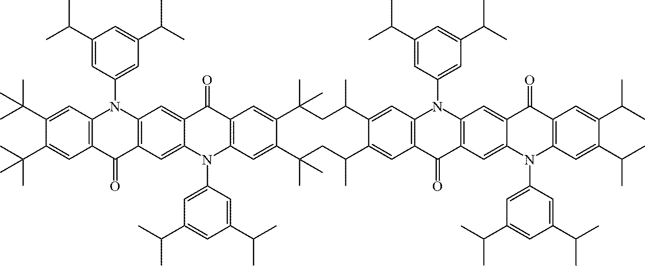 [SMILES: CC(C)c1cc(C(C)C)cc(-n2c3cc(C(C)C)c(C(C)C)cc3c(=O)c3cc4c(cc32)c(=O)c2cc3c(cc2n4-c2cc(C(C)C)cc(C(C)C)c2)C(C)CC(C)(C)c2cc4c(=O)c5cc6c(cc5n(-c5cc(C(C)C)cc(C(C)C)c5)c4cc2C(C)(C)CC3C)c(=O)c2cc(C(C)(C)C)c(C(C)(C)C)cc2n6-c2cc(C(C)C)cc(C(C)C)c2)c1] 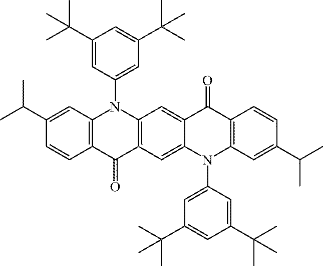 [SMILES: CC(C)c1ccc2c(=O)c3cc4c(cc3n(-c3cc(C(C)(C)C)cc(C(C)(C)C)c3)c2c1)c(=O)c1ccc(C(C)C)cc1n4-c1cc(C(C)(C)C)cc(C(C)(C)C)c1] 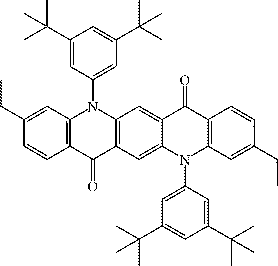 [SMILES: CCc1ccc2c(=O)c3cc4c(cc3n(-c3cc(C(C)(C)C)cc(C(C)(C)C)c3)c2c1)c(=O)c1ccc(CC)cc1n4-c1cc(C(C)(C)C)cc(C(C)(C)C)c1] 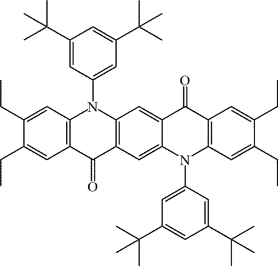 [SMILES: CCc1cc2c(=O)c3cc4c(cc3n(-c3cc(C(C)(C)C)cc(C(C)(C)C)c3)c2cc1CC)c(=O)c1cc(CC)c(CC)cc1n4-c1cc(C(C)(C)C)cc(C(C)(C)C)c1] 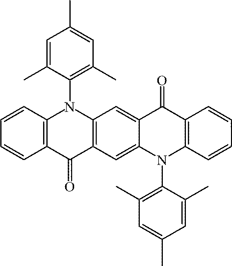 [SMILES: Cc1cc(C)c(-n2c3ccccc3c(=O)c3cc4c(cc32)c(=O)c2ccccc2n4-c2c(C)cc(C)cc2C)c(C)c1] 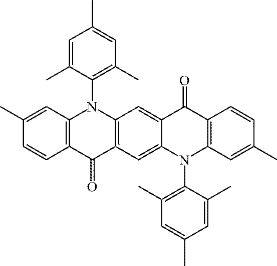 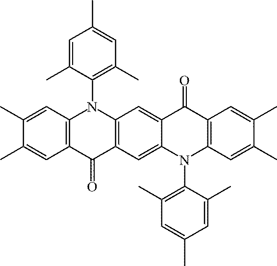 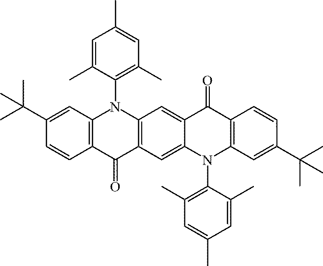 [SMILES: Cc1cc(C)c(-n2c3cc(C(C)(C)C)ccc3c(=O)c3cc4c(cc32)c(=O)c2ccc(C(C)(C)C)cc2n4-c2c(C)cc(C)cc2C)c(C)c1] 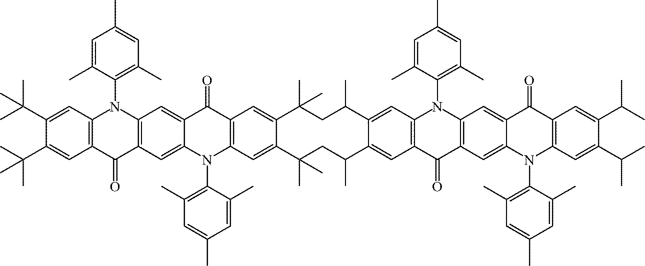 [SMILES: Cc1cc(C)c(-n2c3cc(C(C)C)c(C(C)C)cc3c(=O)c3cc4c(cc32)c(=O)c2cc3c(cc2n4-c2c(C)cc(C)cc2C)C(C)CC(C)(C)c2cc4c(=O)c5cc6c(cc5n(-c5c(C)cc(C)cc5C)c4cc2C(C)(C)CC3C)c(=O)c2cc(C(C)(C)C)c(C(C)(C)C)cc2n6-c2c(C)cc(C)cc2C)c(C)c1] 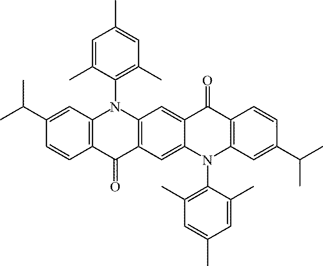 [SMILES: Cc1cc(C)c(-n2c3cc(C(C)C)ccc3c(=O)c3cc4c(cc32)c(=O)c2ccc(C(C)C)cc2n4-c2c(C)cc(C)cc2C)c(C)c1] 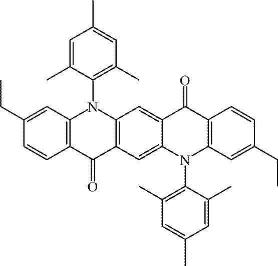 [SMILES: CCc1ccc2c(=O)c3cc4c(cc3n(-c3c(C)cc(C)cc3C)c2c1)c(=O)c1ccc(CC)cc1n4-c1c(C)cc(C)cc1C] 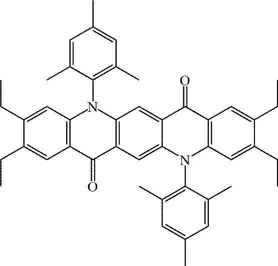 [SMILES: CCc1cc2c(=O)c3cc4c(cc3n(-c3c(C)cc(C)cc3C)c2cc1CC)c(=O)c1cc(CC)c(CC)cc1n4-c1c(C)cc(C)cc1C] 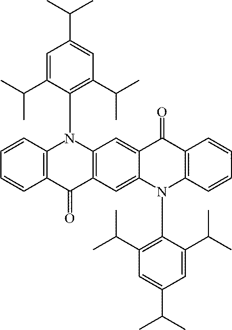 [SMILES: CC(C)c1cc(C(C)C)c(-n2c3ccccc3c(=O)c3cc4c(cc32)c(=O)c2ccccc2n4-c2c(C(C)C)cc(C(C)C)cc2C(C)C)c(C(C)C)c1] 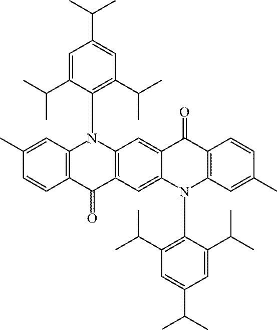 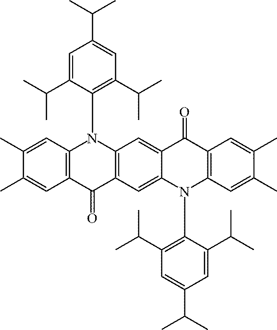 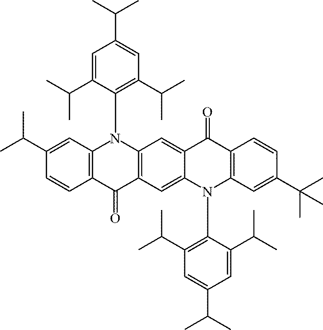 [SMILES: CC(C)c1cc(C(C)C)c(-n2c3cc(C(C)C)ccc3c(=O)c3cc4c(cc32)c(=O)c2ccc(C(C)(C)C)cc2n4-c2c(C(C)C)cc(C(C)C)cc2C(C)C)c(C(C)C)c1] 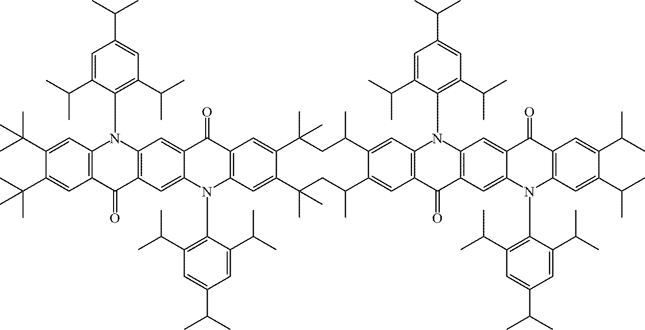 [SMILES: CC(C)c1cc(C(C)C)c(-n2c3cc(C(C)C)c(C(C)C)cc3c(=O)c3cc4c(cc32)c(=O)c2cc3c(cc2n4-c2c(C(C)C)cc(C(C)C)cc2C(C)C)C(C)CC(C)(C)c2cc4c(=O)c5cc6c(cc5n(-c5c(C(C)C)cc(C(C)C)cc5C(C)C)c4cc2C(C)(C)CC3C)c(=O)c2cc(C(C)(C)C)c(C(C)(C)C)cc2n6-c2c(C(C)C)cc(C(C)C)cc2C(C)C)c(C(C)C)c1] 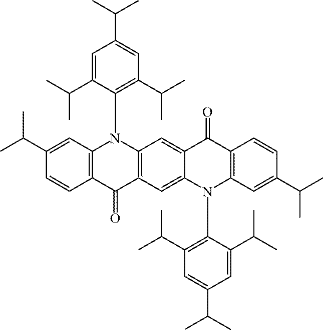 [SMILES: CC(C)c1cc(C(C)C)c(-n2c3cc(C(C)C)ccc3c(=O)c3cc4c(cc32)c(=O)c2ccc(C(C)C)cc2n4-c2c(C(C)C)cc(C(C)C)cc2C(C)C)c(C(C)C)c1] 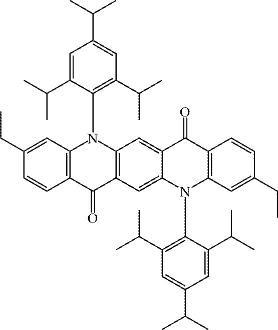 [SMILES: CCc1ccc2c(=O)c3cc4c(cc3n(-c3c(C(C)C)cc(C(C)C)cc3C(C)C)c2c1)c(=O)c1ccc(CC)cc1n4-c1c(C(C)C)cc(C(C)C)cc1C(C)C] 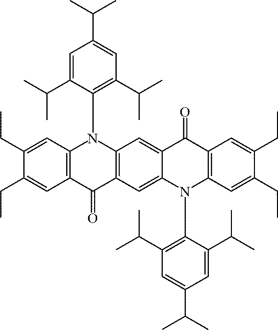 [SMILES: CCc1cc2c(=O)c3cc4c(cc3n(-c3c(C(C)C)cc(C(C)C)cc3C(C)C)c2cc1CC)c(=O)c1cc(CC)c(CC)cc1n4-c1c(C(C)C)cc(C(C)C)cc1C(C)C] 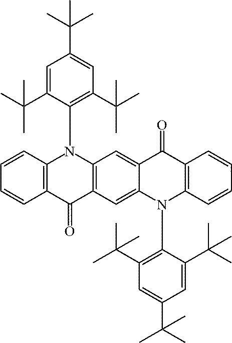 [SMILES: CC(C)(C)c1cc(C(C)(C)C)c(-n2c3ccccc3c(=O)c3cc4c(cc32)c(=O)c2ccccc2n4-c2c(C(C)(C)C)cc(C(C)(C)C)cc2C(C)(C)C)c(C(C)(C)C)c1] 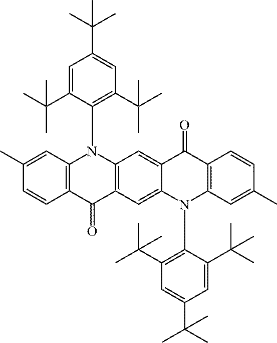 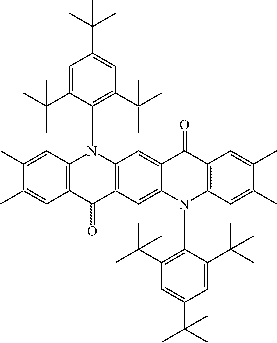 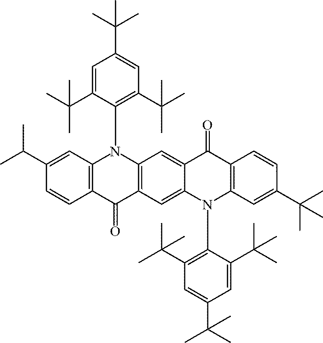 [SMILES: CC(C)c1ccc2c(=O)c3cc4c(cc3n(-c3c(C(C)(C)C)cc(C(C)(C)C)cc3C(C)(C)C)c2c1)c(=O)c1ccc(C(C)(C)C)cc1n4-c1c(C(C)(C)C)cc(C(C)(C)C)cc1C(C)(C)C] 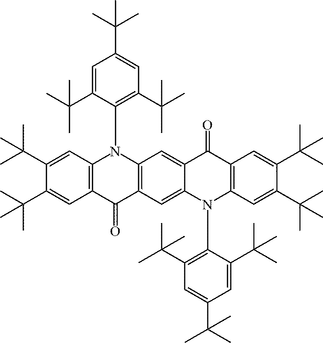 [SMILES: CC(C)(C)c1cc(C(C)(C)C)c(-n2c3cc(C(C)(C)C)c(C(C)(C)C)cc3c(=O)c3cc4c(cc32)c(=O)c2cc(C(C)(C)C)c(C(C)(C)C)cc2n4-c2c(C(C)(C)C)cc(C(C)(C)C)cc2C(C)(C)C)c(C(C)(C)C)c1] 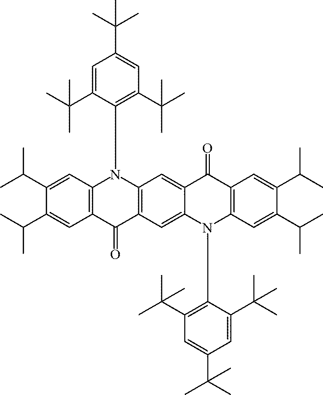 [SMILES: CC(C)c1cc2c(=O)c3cc4c(cc3n(-c3c(C(C)(C)C)cc(C(C)(C)C)cc3C(C)(C)C)c2cc1C(C)C)c(=O)c1cc(C(C)C)c(C(C)C)cc1n4-c1c(C(C)(C)C)cc(C(C)(C)C)cc1C(C)(C)C] 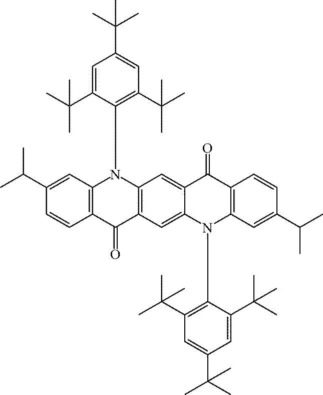 [SMILES: CC(C)c1ccc2c(=O)c3cc4c(cc3n(-c3c(C(C)(C)C)cc(C(C)(C)C)cc3C(C)(C)C)c2c1)c(=O)c1ccc(C(C)C)cc1n4-c1c(C(C)(C)C)cc(C(C)(C)C)cc1C(C)(C)C] 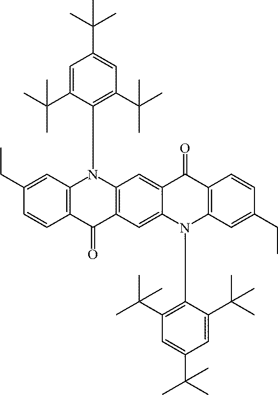 [SMILES: CCc1ccc2c(=O)c3cc4c(cc3n(-c3c(C(C)(C)C)cc(C(C)(C)C)cc3C(C)(C)C)c2c1)c(=O)c1ccc(CC)cc1n4-c1c(C(C)(C)C)cc(C(C)(C)C)cc1C(C)(C)C] 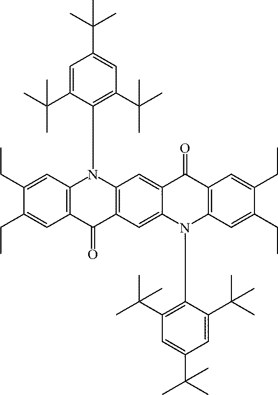 [SMILES: CCc1cc2c(=O)c3cc4c(cc3n(-c3c(C(C)(C)C)cc(C(C)(C)C)cc3C(C)(C)C)c2cc1CC)c(=O)c1cc(CC)c(CC)cc1n4-c1c(C(C)(C)C)cc(C(C)(C)C)cc1C(C)(C)C]
.

11. The organic light emitting diode according to claim 1, wherein the phosphorescent dopant and the fluorescent dopant are mixed at a weight ratio of 7:3 to 10:1.

12. The organic light emitting diode according to claim 1, wherein a singlet energy level S1^{H} of the host, a singlet energy level S1^{PD} of the phosphorescent dopant and a singlet energy level S1^{FD} of the fluorescent dopant satisfy the following Inequation B, and
a triplet energy level T1^{H} of the host, a triplet energy level T1^{PD} of the phosphorescent dopant and a triplet energy level T1^{FD} of the fluorescent dopant satisfy the following Inequation C:
$${\text{S1}}^{\text{H}} \text{>} {\text{S1}}^{\text{PD}} \text{>} {\text{S1}}^{\text{FD}}$$
$${\text{T1}}^{\text{H}} \text{>} {\text{T1}}^{\text{PD}} \text{>} {\text{T1}}^{\text{FD}} \text{.}$$
.

13. The organic light emitting diode according to claim 1, wherein the host is selected from the following Compound 3-1 to Compound 3-24: 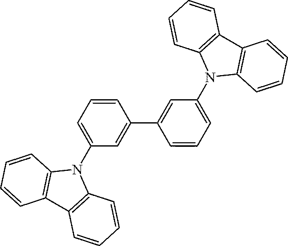 [SMILES: c1cc(-c2cccc(-n3c4ccccc4c4ccccc43)c2)cc(-n2c3ccccc3c3ccccc32)c1] 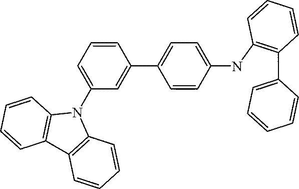 [SMILES: c1ccc(-c2ccccc2Nc2ccc(-c3cccc(-n4c5ccccc5c5ccccc54)c3)cc2)cc1] 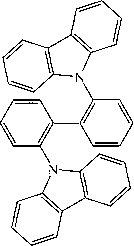 [SMILES: c1ccc(-n2c3ccccc3c3ccccc32)c(-c2ccccc2-n2c3ccccc3c3ccccc32)c1] 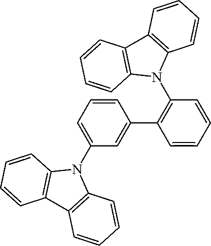 [SMILES: c1cc(-c2ccccc2-n2c3ccccc3c3ccccc32)cc(-n2c3ccccc3c3ccccc32)c1] 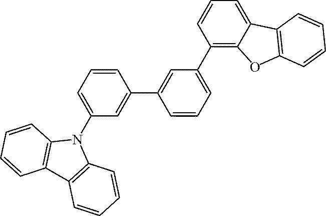 [SMILES: c1cc(-c2cccc(-n3c4ccccc4c4ccccc43)c2)cc(-c2cccc3c2oc2ccccc23)c1] 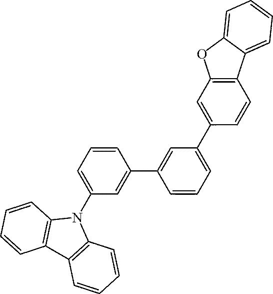 [SMILES: c1cc(-c2cccc(-n3c4ccccc4c4ccccc43)c2)cc(-c2ccc3c(c2)oc2ccccc23)c1] 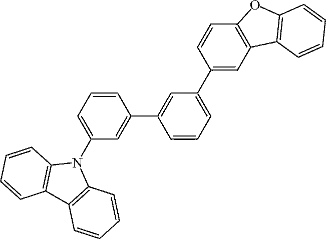 [SMILES: c1cc(-c2cccc(-n3c4ccccc4c4ccccc43)c2)cc(-c2ccc3oc4ccccc4c3c2)c1] 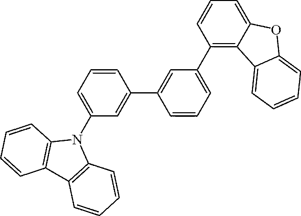 [SMILES: c1cc(-c2cccc(-n3c4ccccc4c4ccccc43)c2)cc(-c2cccc3oc4ccccc4c23)c1] 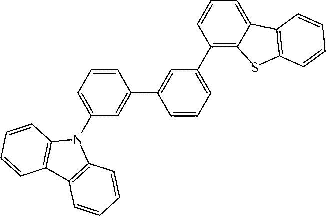 [SMILES: c1cc(-c2cccc(-n3c4ccccc4c4ccccc43)c2)cc(-c2cccc3c2sc2ccccc23)c1] 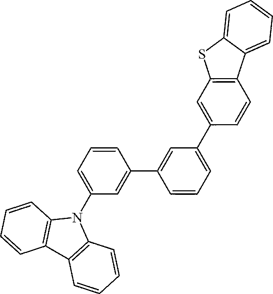 [SMILES: c1cc(-c2cccc(-n3c4ccccc4c4ccccc43)c2)cc(-c2ccc3c(c2)sc2ccccc23)c1] 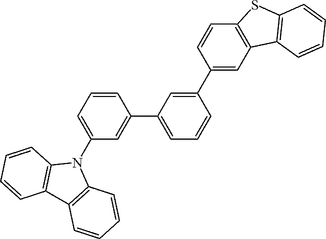 [SMILES: c1cc(-c2cccc(-n3c4ccccc4c4ccccc43)c2)cc(-c2ccc3sc4ccccc4c3c2)c1] 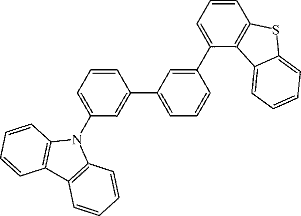 [SMILES: c1cc(-c2cccc(-n3c4ccccc4c4ccccc43)c2)cc(-c2cccc3sc4ccccc4c23)c1] 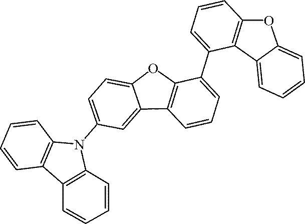 [SMILES: c1ccc2c(c1)oc1cccc(-c3cccc4c3oc3ccc(-n5c6ccccc6c6ccccc65)cc34)c12] 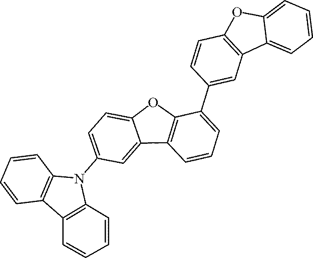 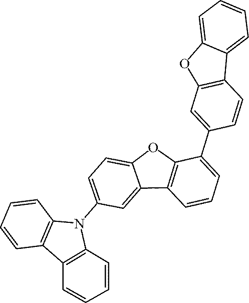 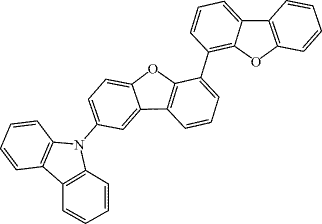 [SMILES: c1ccc2c(c1)oc1c(-c3cccc4c3oc3ccc(-n5c6ccccc6c6ccccc65)cc34)cccc12] 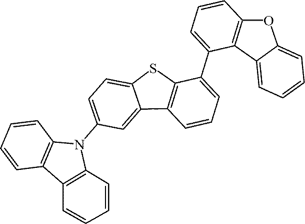 [SMILES: c1ccc2c(c1)oc1cccc(-c3cccc4c3sc3ccc(-n5c6ccccc6c6ccccc65)cc34)c12] 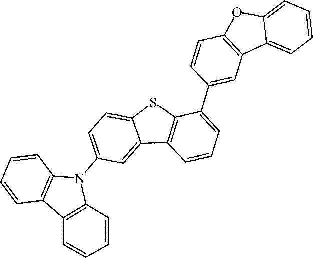 [SMILES: c1ccc2c(c1)oc1ccc(-c3cccc4c3sc3ccc(-n5c6ccccc6c6ccccc65)cc34)cc12] 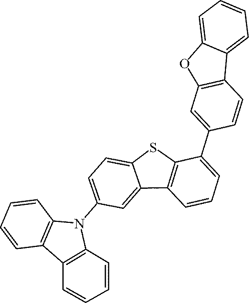 [SMILES: c1ccc2c(c1)oc1cc(-c3cccc4c3sc3ccc(-n5c6ccccc6c6ccccc65)cc34)ccc12] 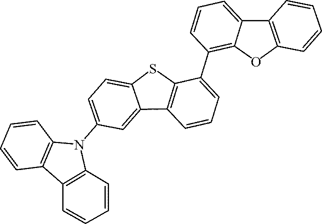 [SMILES: c1ccc2c(c1)oc1c(-c3cccc4c3sc3ccc(-n5c6ccccc6c6ccccc65)cc34)cccc12] 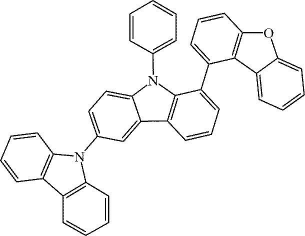 [SMILES: c1ccc(-n2c3ccc(-n4c5ccccc5c5ccccc54)cc3c3cccc(-c4cccc5oc6ccccc6c45)c32)cc1] 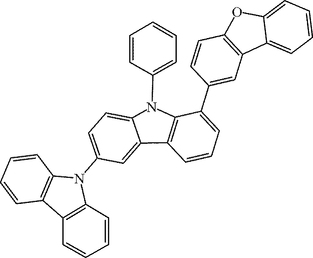 [SMILES: c1ccc(-n2c3ccc(-n4c5ccccc5c5ccccc54)cc3c3cccc(-c4ccc5oc6ccccc6c5c4)c32)cc1] 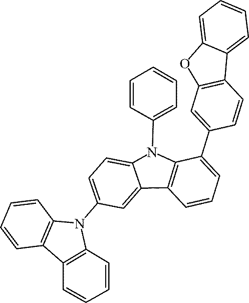 [SMILES: c1ccc(-n2c3ccc(-n4c5ccccc5c5ccccc54)cc3c3cccc(-c4ccc5c(c4)oc4ccccc45)c32)cc1] 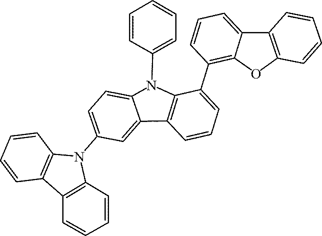 [SMILES: c1ccc(-n2c3ccc(-n4c5ccccc5c5ccccc54)cc3c3cccc(-c4cccc5c4oc4ccccc45)c32)cc1]
.

14. The organic light emitting diode according to claim 1, wherein the organic light emitting diode includes a plurality of emission layers, and
at least one of the plurality of emission layers includes the host, the phosphorescent dopant represented by Chemical Formula 1 and the fluorescent dopant represented by Chemical Formula 2.

15. The organic light emitting diode according to claim 1, further comprising at least one layer selected from a hole injection layer, a hole transport layer, a hole blocking layer, an electron blocking layer, an electron transport layer and an electron injection layer.

16. An organic light emitting display device, comprising:
a substrate;
a thin film transistor on the substrate; and an organic light emitting diode disposed on the thin film transistor,
wherein the organic light emitting diode is an organic light emitting diode according to claim 1.
